(19) United States
(12) Patent Application Publication
(10) Pub. No.: US 2013/0022911 A1
(43) Pub. Date: Jan. 24, 2013

(54) POLYMER, RESIST COMPOSITION AND METHOD OF FORMING RESIST PATTERN

(71) Applicants: Yoshiyuki Utsumi, Kawasaki-shi (JP); Takahiro Dazai, Kawasaki-shi (JP)

(72) Inventors: Yoshiyuki Utsumi, Kawasaki-shi (JP); Takahiro Dazai, Kawasaki-shi (JP)

(73) Assignee: TOKYO OHKA KOGYO CO., LTD., Kawasaki-shi (JP)

(21) Appl. No.: 13/552,485

(22) Filed: Jul. 18, 2012

(30) Foreign Application Priority Data
Jul. 21, 2011 (JP) 2011-160237
Aug. 1, 2011 (JP) 2011-168716
Aug. 18, 2011 (JP) 2011-179004
Sep. 15, 2011 (JP) 2011-202210
Sep. 26, 2011 (JP) 2011-209191

(51) Int. Cl. C08F 228/06; G03F 7/20; G03F 7/004

(52) U.S. Cl. 430/270.1; 526/257; 430/325

(57) ABSTRACT

A polymer containing an anion part which generates acid upon exposure on at least one terminal of the main chain, and at least one structural unit selected from the group consisting of a structural unit (a0) containing a —SO₂-containing cyclic group, a structural unit (a3) containing at least one group selected from the group consisting of —OH, —COOH, —CN, —SO₂NH₂ and —CONH₂ and a structural unit (a5) which generates acid upon exposure.

### TECHNICAL FIELD

The present invention relates to a polymer useful for a resist composition, a resist composition containing the polymer, and a method of forming a resist pattern using the resist composition.

Priority is claimed on Japanese Patent Application No. 2011-160237, filed Jul. 21, 2011, Japanese Patent Application No. 2011-168716, filed Aug. 1, 2011, Japanese Patent Application No. 2011-179004, filed Aug. 18, 2011, Japanese Patent Application No. 2011-202210, filed Sep. 15, 2011, and Japanese Patent Application No. 2011-209191, filed Sep. 26, 2011, the contents of which are incorporated herein by reference.

### BACKGROUND ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid-generator component that generates acid upon exposure.

For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid-generator component, and the action of this acid causes an increase in the solubility of the resin component in an alkali developing solution, making the exposed portions soluble in the alkali developing solution. In this manner, the unexposed portions remain to form a positive resist pattern. The base resin used exhibits increased polarity by the action of acid, thereby exhibiting increased solubility in an alkali developing solution, whereas the solubility in an organic solvent is decreased. When such a base resin is applied to a process using a developing solution containing an organic solvent (organic developing solution) (hereafter, this process is referred to as “solvent developing process” or “negative tone-developing process”) instead of an alkali developing process, the solubility of the exposed portions in an organic developing solution is decreased. As a result, in the solvent developing process, the unexposed portions of the resist film are dissolved and removed by the organic developing solution, and a negative resist pattern in which the exposed portions are remaining is formed. The negative tone-developing process and the resist composition used for the process are proposed, for example, in Patent Document 1.

Currently, resins that contain structural units derived from (meth)acrylate esters within the main chain (acrylic resins) are now widely used as base resins for resist compositions that use ArF excimer laser lithography, as they exhibit excellent transparency in the vicinity of 193 nm (for example, see Patent Document 2).

The base resin contains a plurality of structural units for improving lithography properties and the like. For example, in the case of a resin component which exhibits increased polarity by the action of acid, a base resin containing a structural unit having an acid decomposable group which is decomposed by the action of an acid generated from the acid generator to increase the polarity, a structural unit having a polar group such as —OH, —CN and —SO₂NH, a structural unit having a lactone structure, and the like is typically used. In particular, the structural units having a polar group is widely used because it is effective in increasing the compatibility with an alkali developing solution, thereby contributing to improvement in various lithography properties such as resolution.

Recently, As a base resin, a resin which contains a structural unit having a cyclic group including —SO₂— has been proposed (for example, see Patent Documents 6 and 7).

Further, the base resin contributes to improvement in lithography properties such as mask reproducibility and shape of the resist pattern such as reducing roughness. Roughness means a surface roughness of the resist pattern, and causes various defects in the shape of the resist pattern.

For example, roughness on the line width (line width roughness (LWR)) can cause various defects such as non-uniformity of the line width of line and space patterns.

Such defects of the resist pattern adversely affect the formation of very fine semiconductor elements, and improvement in these characteristics becomes more important as the pattern becomes finer.

In recent years, base resins that include a structural unit which functions as an acid generator have also been used (see for example, Patent Documents 8 and 9).

As a technique for further improving the resolution, a lithography method called liquid immersion lithography (hereafter, frequently referred to as “immersion exposure”) is known in which exposure (immersion exposure) is conducted in a state where the region between the lens and the resist layer formed on a wafer is filled with a solvent (a immersion medium) that has a larger refractive index than the refractive index of air (see for example, Non-Patent Document 1).

According to this type of immersion exposure, it is considered that higher resolutions equivalent to those obtained using a shorter wavelength light source or a larger NA lens can be obtained using the same exposure light source wavelength, with no lowering of the depth of focus. Furthermore, immersion exposure can be conducted using a conventional exposure apparatus. As a result, immersion exposure is widely used in recent years, because it enables the formation of resist patterns of higher resolution and superior depth of focus at lower costs.

Immersion lithography is effective in forming patterns having various shapes. Further, immersion exposure is expected to be capable of being used in combination with super-resolution techniques, such as phase shift method and modified illumination method. Currently, as the immersion exposure technique, technique using an ArF excimer laser as an exposure source is being actively studied. Further, water is mainly used as the immersion medium.

In addition, a resist composition for immersion exposure containing a fluorine-containing polymeric compound has been reported in order to provide a resist film with water repellency in immersion exposure (see, for example, Non-Patent Document 1).

Fluorine-containing compounds have been attracting attention for their properties such as water repellency and transparency, and active research and development of fluorine-containing compounds have been conducted in various fields, such as in the fields of resist materials for immersion exposure. For example, in the fields of resist materials, fluorine-containing polymers that include a structural unit containing a fluorine atom have also been used in recent years (see Patent Document 10).

The polymers used in the base resin and the fluorine-containing polymer is generally provided by a radical polymerization of monomers having a variety of functions. As a polymerization initiator used in the radical polymerization, azo-type polymerization initiators such as azobisisobutyronitrile (AIBN) and dimethyl 2,2′-azobis(2-methylpropionate) has been commonly used.

Azo-type polymerization initiators are decomposed by heat or light to provide a radical and nitrogen gas. Then, a polymer is synthesized by addition-polymerization of monomers to each other by the action of the radical. Therefore, at the terminal of the synthesized polymer, the partial structure of azo-type polymerization initiator has been introduced.

In recent years, the partial structure of the polymerization initiator introduced at the terminal of the polymer has been attracting attention. Also, a polymerization initiator having a base dissociable group which is a function group as the partial structure and a polymer obtained by polymerization using the polymerization initiator have been disclosed

### DOCUMENTS OF RELATED ART

[Patent Documents]
[Patent Document 1] Japanese Unexamined Patent Application, First Publication No. 2009-025723
[Patent Document 2] Japanese Unexamined Patent Application, First Publication No. 2003-241385
[Patent Document 3] Japanese Unexamined Patent Application, First Publication No. 2005-300998
[Patent Document 4] WO 2004/067592
[Patent Document 5] Japanese Unexamined Patent Application, First Publication No. 2009-288441
[Patent Document 6] Japanese Unexamined Patent Application, First Publication No. 2009-062491
[Patent Document 7] Japanese Unexamined Patent Application, First Publication No. 2010-134417
[Patent Document 8] Japanese Unexamined Patent Application, First Publication No. 2006-04531
[Patent Document 9] Japanese Patent No. 4425776
[Patent Document 10] Japanese Unexamined Patent Application, First Publication No. 2010-277043
[Patent Document 11] Japanese Unexamined Patent Application, First Publication No. 2010-37528

[Non-Patent Documents]
[Non-Patent Document 1] Proceedings of SPIE (U.S.), vol. 5754, pp. 119-128 (2005)

### SUMMARY OF THE INVENTION

As further progress is made in lithography techniques and the application field for lithography techniques is expanded, development of a novel material for use in lithography will be desired. For example, as miniaturization of resist patterns progress, further improvement will be demanded for resist materials with respect to various lithography properties such as roughness (LWR (line width roughness: non-uniformity of the line width) in the line pattern, and circularity in the hole pattern), mask reproducibility, exposure latitude and the like and the pattern shape as well as sensitivity and resolution.

In addition, in order to perform a fine patterning with a high precision, in addition to improvement of lithography properties, reduction of defects (surface defects) that occur after development is also required. The term “defects” refers to general abnormalities within a resist film that are detected when observed from directly above the developed resist pattern using, for example, a surface defect detection apparatus (product name: “KLA”) manufactured by KLA-TENCOR Corporation. Examples of these abnormalities include abnormalities caused by the adhesion of foreign particles and precipitates to the surface of resist pattern such as post-developing scum (resist residue), foam and dust, abnormalities in pattern shape such as bridges formed between line patterns, filled holes of the contact hole pattern, and abnormalities in color irregularities.

However, when base resins as those disclosed in Patent Documents 2 to 11 were used as resist materials, they cannot satisfy the required level of lithography properties and pattern shape.

The present invention takes the above circumstances into consideration, with an object of providing a resist composition which exhibits excellent lithography properties and resist pattern shape, and which can reduce defects, a new polymer useful for a resist composition, and a method of forming a resist pattern using the resist composition.

For solving the above-mentioned problems, the present invention employs the following aspects.

That is, a first aspect of the present invention is a polymer containing an anion part which generates acid upon exposure on at least one terminal of the main chain, and at least one structural unit selected from the group consisting of a structural unit (a0) containing a —SO₂-containing cyclic group, a structural unit (a3) containing at least one group selected from the group consisting of —OH, —COOH, —CN, —SO₂NH₂ and —CONH₂ and a structural unit (a5) which generates acid upon exposure.

A second aspect of the present invention is a resist composition containing the polymer of the first aspect of the present invention.

A third aspect of the present invention is a method of forming a resist pattern, including using a resist composition according to the second aspect to form a resist film on a substrate, subjecting the resist film to exposure, and subjecting the resist film to developing to form a resist pattern.

A fourth aspect of the present invention is a polymer containing an anion part which generates acid upon exposure on at least one terminal of the main chain, and a structural unit (f1) containing a fluorine atom.

A fifth aspect of the present invention is a resist composition including: a base component (A) which exhibits changed solubility in a developing solution under action of acid; a fluorine-containing polymeric compound component (F) which generates acid upon exposure; and an acid generator component (B) which generates acid upon exposure, provided that the fluorine-containing polymeric compound component (F) is excluded, wherein the fluorine-containing polymeric compound component (F) contains the polymer of the fourth aspect.

A sixth aspect of the present invention is a method of forming a resist pattern, including using a resist composition according to the fifth aspect to form a resist film on a substrate, subjecting the resist film to exposure, and subjecting the resist film to developing to form a resist pattern.

In the present description and claims, the term “exposure” is used as a general concept that includes irradiation with any form of radiation.

The term “structural unit” refers to a monomer unit that contributes to the formation of a polymeric compound (resin, polymer and copolymer).

The term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified.

The term “alkylene group” includes linear, branched or cyclic, divalent saturated hydrocarbon, unless otherwise specified. The same applies for the alkyl group within an alkoxy group.

A “halogenated alkyl group” is a group in which part or all of the hydrogen atoms of an alkyl group are substituted with a halogen atom, and a “halogenated alkylene group” is a group in which part or all of the hydrogen atoms of an alkylene group are substituted with a halogen atom. Examples of the halogen atom include a fluorine atom, a chlorine atom, a bromine atom and an iodine atom.

The fluorinated alkyl group is a group in which part or all of the hydrogen atoms of an alkyl group are substituted with a fluorine atom, and a “fluorinated alkylene group” is a group in which part or all of the hydrogen atoms of an alkylene group is substituted with a fluorine atom.

According to the present invention, there are provided a resist composition which exhibits excellent lithography properties and resist pattern shape, a new polymer useful for the resist composition, and a method of forming a resist pattern using the resist composition.

### DETAILED DESCRIPTION OF THE INVENTION

### <<Polymer 1>>

The polymer according the first aspect of the present invention contains an anion part which generates acid upon exposure on at least one terminal of the main chain, and at least one structural unit selected from the group consisting of a structural unit (a0) containing a —SO₂-containing cyclic group, a structural unit (a3) containing at least one group selected from the group consisting of —OH, —COOH, —CN, —SO₂NH₂ and —CONH₂ and a structural unit (a5) which generates acid upon exposure.

The polymer can be obtained by a radical polymerization or an anionic polymerization, using monomers including at least one monomer which derives at least one structural unit selected from the group consisting of a structural unit (a0), a structural unit (a3) and a structural unit (a5), using a specific polymerization initiator. Therefore, in the present invention, the “anion part which generates acid upon exposure” is a residue derived from a polymerization initiator instead of monomers which derive structural units. In addition, the term “at least one terminal of the main chain” in the polymer means a part in which a residue derived from a polymerization initiator is bonded to the end of the molecular chain, and which is distinctly different from the terminal of the side chain branched from the main chain (i.e., the terminal of the structure to form a structural unit).

### <<Polymer 2>>

A polymer according to the fourth aspect of the present invention contains an anion part which generates acid upon exposure on at least one terminal of the main chain, and a structural unit (f1) containing a fluorine atom.

The polymer can be obtained by a radical polymerization or an anionic polymerization and the like, using monomers including at least one monomer which derives a structural unit (f1), and using a specific polymerization initiator. Therefore, in the present invention, the “anion part which generates acid upon exposure” is a residue derived from a polymerization initiator instead of monomers which derive structural units. In addition, the term “at least one terminal of the main chain” in the polymer means a part in which a residue derived from a polymerization initiator is bonded to the end of the molecular chain, and which is distinctly different from the terminal of the side chain branched from the main chain (i.e., the terminal of the structure to form a structural unit).

### <Anion Part>

Preferable examples the “anion part which generates acid upon exposure” include an ionic structural part in the sulfonium salt and iodonium salt which are commonly used as an acid generator component that generates an acid upon exposure, and which is used in combination with the base resin in chemically amplified resist composition. In addition, as the acid anion generated upon exposure, a sulfonic acid anion, a carboxylic acid anion, a sulfonylimide anion, a bis(alkylsulfonyl)imide anion, tris(alkylsulfonyl)methide anion are preferred. These acid anions are generated from the terminal of the main chain of the polymer upon exposure.

In particular, the anion part preferably has a group represented by general formula (an1) shown below.

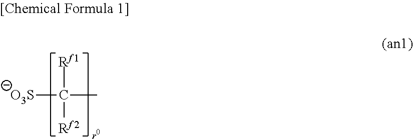

In the formula, each of R^{f1} and R^{f2} independently represents a hydrogen atom, an alkyl group, a fluorine atom or a fluorinated alkyl group; and r⁰ represents an integer of 0 to 8.

In the formula (an1), the alkyl group for R^{f1} and R^{f2} is preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{f1} and R^{f2} is preferably a group in which part or all of the hydrogen atoms within the aforementioned alkyl group for R^{f1} and R^{f2} have been substituted with a fluorine atom.

Each of R^{f1} and R^{f2} is preferably a fluorine atom or a fluorinated alkyl group. In the formula (an1), r⁰ is preferably an integer of 1 to 4, and more preferably 1 or 2.

The polymer of the present invention preferably contains a group represented by general formula (I-1) shown below on at least one terminal of the main chain (hereafter referred to as “terminal group (I-1)”).

By virtue of having the terminal group (I-1), the polymers of the present invention is capable of generating an acid upon exposure. In other words, by virtue of having a sulfonium salt part at the end of the terminal group (I-1), sulfonic acid is generated upon exposure.

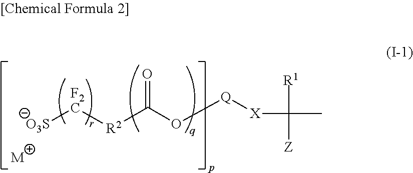

In the formula, R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having —O—C(═O)—, —NH—C(═O)— or —NH—C(═NH)— on at least the terminal bonded to Q; p represents an integer of 0 to 3; Q represents a hydrocarbon group having a valency of (p+1), provided that, p represents 1, Q may represent a single bond; R² represents a single bond, an alkylene group which may have a substituent or an aromatic group which may have a substituent; q represents 0 or 1; r represents an integer of 0 to 8; and M⁺ represents an organic cation.

In general formula (I-1), R¹ represents a hydrocarbon group of 1 to 10 carbon atoms. The hydrocarbon group of 1 to 10 carbon atoms may be either an aliphatic hydrocarbon group or an aromatic hydrocarbon group, an aliphatic hydrocarbon group is preferable, and a monovalent saturated aliphatic hydrocarbon group (alkyl group) is more preferable.

As specific examples of the alkyl group, a linear or branched alkyl group, and an aliphatic hydrocarbon group containing a ring in the structure thereof can be given.

The linear alkyl group preferably has 1 to 8 carbon atoms, more preferably 1 to 5, and most preferably 1 to 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 5 carbon atoms. Specific examples of such branched alkyl groups include an isopropyl group, an isobutyl group, a tert-butyl group, an isopentyl group and a neopentyl group, and an isopropyl group or a tert-butyl group is particularly preferred.

As examples of the hydrocarbon group containing a ring in the structure thereof, a cyclic aliphatic hydrocarbon group (a group in which one hydrogen atom has been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 8 carbon atoms, and more preferably 4 to 6 carbon atoms. Specific examples include groups in which one or more hydrogen atoms have been removed from a monocycloalkane such as cyclopentane or cyclohexane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

In general formula (I-1), Z represents a hydrocarbon group of 1 to 10 carbon atoms or a cyano group.

As the hydrocarbon group of 1 to 10 carbon atoms for Z, the same hydrocarbon groups of 1 to 10 carbon atoms as those described above for R¹ can be used.

R¹ and Z may be mutually bonded to form a ring. Specifically, R¹ and Z each independently represents a linear or branched alkylene group, and the terminal of R¹ may be bonded to the terminal of Z to form a ring. As the ring to be formed, a ring of 3 to 8 carbon atoms is preferable, and cyclopentane, cyclohexane, cycloheptane or cyclooctane is particularly preferred.

In particular, as a combination of R¹ and Z, a combination of a methyl group and a methyl group, a combination of an ethyl group and an ethyl group, a combination of a methyl group and a cyano group, a combination of an ethyl group and a cyano group, and a group in which two carbon atoms have been removed from a cyclopentane formed from R¹ and X which are mutually bonded are preferable, and a combination of a methyl group for R¹ and a cyano group for Z is particularly preferred.

In the formula (I-1), X represents a divalent linking group having —O—C(═O)—, —NH—C(═O)— or —NH—C(═NH)— on at least the terminal bonded to Q in the formula. The terminal bonded to Q in the formula refers to a terminal bonded to —(C(═O)—O)_{q}—, R², —CF₂— or SO₃⁻ in the formula, when Q is a single bond. The divalent linking group for X may be a group consisting of —O—C(═O)—, —NH—C(═O)— or —NH—C(═NH)—. In addition, X may further contain —O—C(═O)—, —NH—C(═O)— or —NH—C(═NH)— in addition to these groups on the terminal bonded to Q.

Preferable examples of the divalent linking group for X include a group consisting of —O—C(═O)—, —NH—C(═O)— or —NH—C(═NH)— and a combination of either a divalent hydrocarbon group which may have a substituent or a divalent linking group containing a hetero atom and either —O—C(═O)—, —NH—C(═O)— or —NH—C(═NH)—.

(Divalent Hydrocarbon Group which May have a Substituent)

In the present invention, the hydrocarbon group “has a substituent” refers to a hydrocarbon group in which part or all of the hydrogen atoms within the hydrocarbon group has been substituted with a group or an atom other than a hydrogen atom.

The divalent hydrocarbon group which may have a substituent for X may be an aliphatic hydrocarbon group or an aromatic hydrocarbon group. An “aliphatic hydrocarbon group” refers to a hydrocarbon group that has no aromaticity.

The aliphatic hydrocarbon group may be saturated or unsaturated. In general, the aliphatic hydrocarbon group is preferably saturated.

As specific examples of the aliphatic hydrocarbon group for the divalent hydrocarbon group, a linear or branched aliphatic hydrocarbon group, and an aliphatic hydrocarbon group having a ring in the structure thereof can be given.

The linear or branched aliphatic hydrocarbon group preferably has 1 to 10 carbon atoms, more preferably 1 to 8, still more preferably 1 to 5, and most preferably 1 or 2. As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂— and —CH(CH₂CH₃)CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group (chain-like aliphatic hydrocarbon group) may or may not have a substituent. Examples of the substituent include a fluorine atom, a fluorinated alkyl group of 1 to 5 carbon atoms and an oxygen atom (═O).

As examples of the hydrocarbon group containing a ring in the structure thereof, a cyclic aliphatic hydrocarbon group (a group in which two hydrogen atoms have been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane.

As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

Examples of the aforementioned aromatic hydrocarbon group for the divalent hydrocarbon group include a divalent aromatic hydrocarbon group in which one hydrogen atom has been removed from a benzene ring of a monovalent aromatic hydrocarbon group such as a phenyl group, a biphenyl group, a fluorenyl group, a naphthyl group, an anthryl group or a phenanthryl group; an aromatic hydrocarbon group in which part of the carbon atoms constituting the ring of the aforementioned divalent aromatic hydrocarbon group has been substituted with a hetero atom such as an oxygen atom, a sulfur atom or a nitrogen atom; and an aromatic hydrocarbon group in which one hydrogen atom has been removed from a benzene ring of an arylalkyl group such as a benzyl group, a phenethyl group, a 1-naphthylmethyl group, a 2-naphthylmethyl group, a 1-naphthylethyl group or a 2-naphthylethyl group.

The aromatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

### (Divalent Linking Group Containing a Hetero Atom)

As the divalent linking group containing a hetero atom for X, examples thereof include —O—, —C(═O)—O—, —C(═O)—, —C(═O)—NH—, —NH—, —NH—C(═NH)— (H may be substituted with a substituent such as an alkyl group or an acyl group), —S—, —S(═O)₂—, —S(═O)₂—O—, “-A-O-B- (wherein O is an oxygen atom, and each of A and B independently represents a divalent hydrocarbon group which may have a substituent)” and a combination of a divalent hydrocarbon group which may have a substituent with a divalent linking group containing a hetero atom. As examples of the divalent hydrocarbon group which may have a substituent, the same groups as those described above for the divalent hydrocarbon group which may have a substituent can be given, and a linear or branched aliphatic hydrocarbon group or an aliphatic hydrocarbon group containing a ring in the structure thereof is preferable.

When X represents a divalent linking group —NH— and the H in the formula is replaced with a substituent such as an alkyl group or an acyl group, the substituent preferably has 1 to 10 carbon atoms, more preferably 1 to 8 carbon atoms, and most preferably 1 to 5 carbon atoms.

When X is “A-O-B”, each of A and B independently represents a divalent hydrocarbon group which may have a substituent.

The hydrocarbon group for A may be either an aliphatic hydrocarbon group, or an aromatic hydrocarbon group. An “aliphatic hydrocarbon group” refers to a hydrocarbon group that has no aromaticity.

The aliphatic hydrocarbon group for A may be either saturated or unsaturated. In general, the aliphatic hydrocarbon group is preferably saturated.

As specific examples of the aliphatic hydrocarbon group for A, a linear or branched aliphatic hydrocarbon group, and an aliphatic hydrocarbon group having a ring in the structure thereof can be given. These groups are the same as defined above.

Among these, as A, a linear aliphatic hydrocarbon group is preferable, more preferably a linear alkylene group, still more preferably a linear alkylene group of 2 to 5 carbon atoms, and most preferably an ethylene group.

As the hydrocarbon group for B, the same divalent hydrocarbon groups as those described above for A can be used.

As B, a linear or branched aliphatic hydrocarbon group is preferable, and a methylene group or an alkylmethylene group is particularly preferred.

The alkyl group within the alkyl methylene group is preferably a linear alkyl group of 1 to 5 carbon atoms, more preferably a linear alkyl group of 1 to 3 carbon atoms, and most preferably a methyl group.

When X consists of any one of —O—C(═O)—, —NH—C(═O)— and —NH—C(═NH)—, X preferably represents —O—C(═O)— or —NH—C(═O)—. The carbon atom in —O—C(═O)— or the carbon atom in —NH—C(═O)— is preferably directly bonded to the carbon atom which is bonded to R¹ and Z.

When X is a combination of the aforementioned divalent group with any one of —O—C(═O)—, —NH—C(═O)— and —NH—C(═NH)—, X is preferably a combination of either a linear or branched aliphatic hydrocarbon group of 1 to 5 carbon atoms or a divalent linking group containing a hetero atom with any one of —O—C(═O)—, —NH—C(═O)— and —NH—C—(═NH)—, more preferably a combination a linking group selected from a methylene group, ethylene group and divalent linking group having an —NH— with any one of —O—C(═O)—, —NH—C(═O)— and —NH—C—(═NH)—, and particularly preferably a combination of two or more groups selected from an ethylene group, —O—C(═O)— and —NH—C(═O)—.

In formula (I-1), p represents an integer of 1 to 3, preferably 1.

When p is 2 or 3, the amount of the sulfonic acid part which can occur in the polymer and have a function as acid (SO₃⁻) is increased, and acid-generating ability can be improved.

In the formula (I-1), Q represents a hydrocarbon group having a valency of (p+1), provided that, when p represents 1, Q may represent a single bond.

When p represents 1, Q represents a single bond or a divalent hydrocarbon group. Examples of the divalent hydrocarbon group include the same groups as the divalent hydrocarbon group which does not have a substituent described above in the explanation for “divalent hydrocarbon group which may have a substituent” for X. In particular, when p is 1, Q preferably represents a single bond or a divalent aliphatic hydrocarbon group, more preferably a single bond or a linear or branched alkylene group, still more preferably a single bond, a methylene group or an ethylene group, and particularly preferably a single bond or an ethylene group.

When p represents 2, Q represents a trivalent hydrocarbon group. When p represents 3, Q represents a tetravalent hydrocarbon group. Examples of the trivalent or tetravalent hydrocarbon group include a group in which one or two hydrogen atom have been removed from the divalent hydrocarbon group which does not have a substituent described above in the explanation of “divalent hydrocarbon group which may have a substituent” for X. Among these, a trivalent or tetravalent aliphatic hydrocarbon group is preferred.

Specific examples of the hydrocarbon group having a valency of (p+1) for Q are shown below.

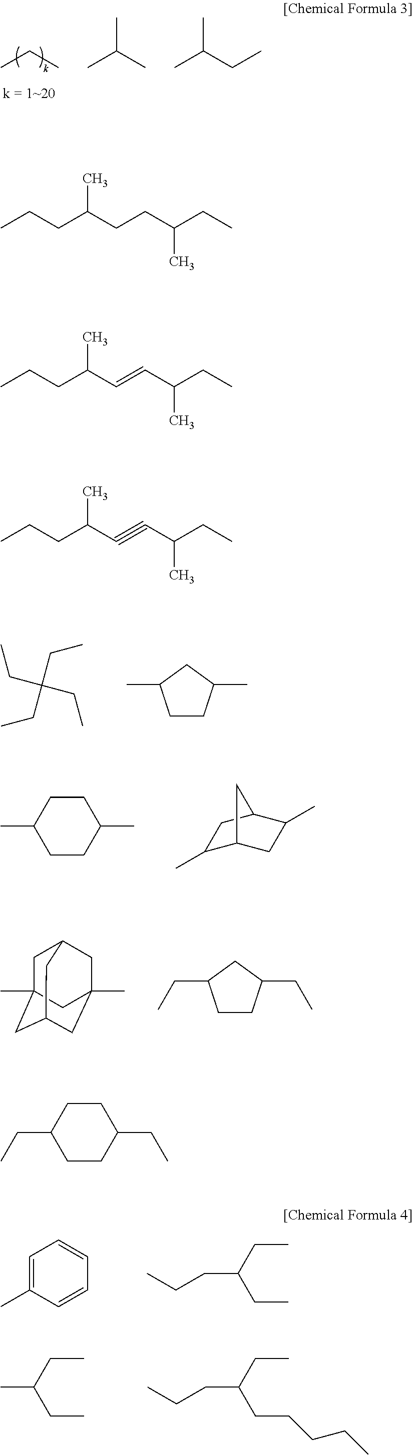

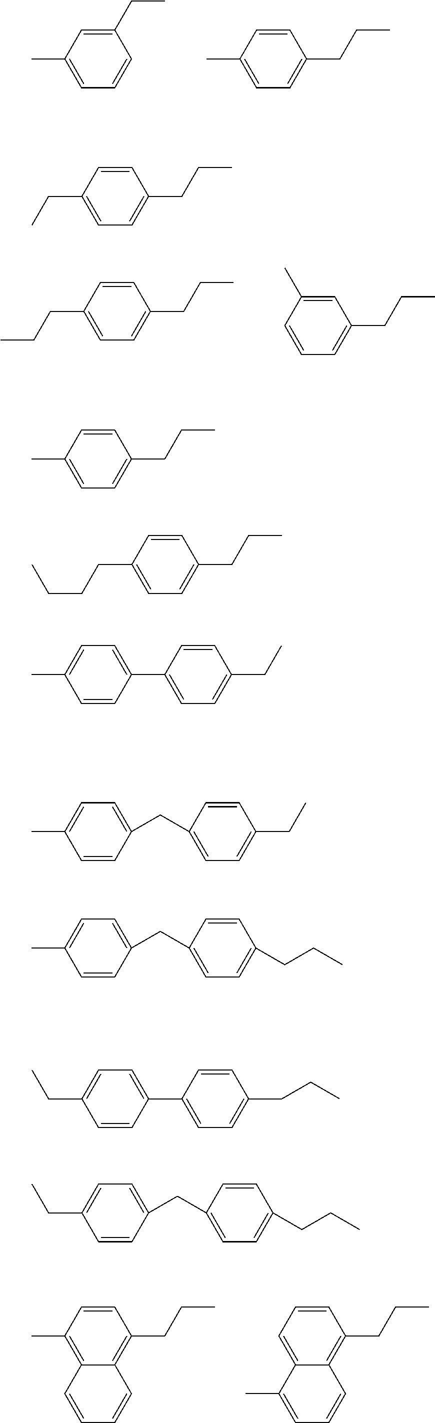

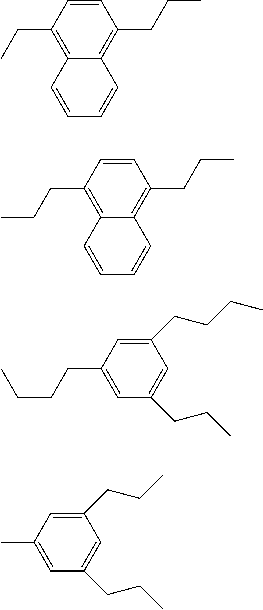

In the formula (I-1), q represents 0 or 1. When q is 0, —C(═O)—O)_{q}— in the formula represents a single bond.

q preferably represents 1, when the divalent linking group for X does not contain —O—C(═O)—. q is preferably represents 0, when the divalent linking group for X contains —O—C(═O)—

In the formula (I-1), R² represents a single bond, an alkylene group which may have a substituent or an aromatic group which may have a substituent.

The alkylene group for R² may be linear or branched. Examples of the alkylene group include the same groups as the “linear or branched aliphatic hydrocarbon groups” and “aliphatic hydrocarbon groups containing a ring in the structure thereof” described above in the explanation of the divalent hydrocarbon group which may have a substituent for X. Among these, an alkylene group for R² is preferably an alkylene group of 1 to 10 carbon atoms, and a methylene group or an ethylene group is more preferable.

The aromatic group which may have a substituent for R² may be either an aromatic hydrocarbon group or an aromatic group having atoms other than carbon atoms in the ring structure (heterocyclic compound).

Examples of the aromatic hydrocarbon group include the same “aromatic hydrocarbon groups” as those described above in relation to the divalent hydrocarbon group which may have a substituent for X. As the aromatic hydrocarbon group for R², a group in which one or more hydrogen atoms have been removed from phenyl group or naphthyl group is preferable. As the aromatic hydrocarbon group for R², a group in which part or all of the hydrogen atoms thereof may be substituted with an alkyl group of 1 to 5 carbon atoms, a fluorine atom, a fluorinated alkyl group of 1 to 5 carbon atoms, and an oxygen atom (═O). Among these, a group in which part or all of the hydrogen atoms thereof are substituted with a fluorine atom is preferred.

As the aromatic group having atoms other than carbon atoms in the ring structure, a group in which two or more hydrogen atoms have been removed from a heterocycle such as quinoline, pyridine, oxole and imidazole is preferable.

Among these, as R², a single bond or an aromatic group which may have a substituent is preferable.

In general formula (I-1), r represents an integer of 0 to 8. When r is 0, —(CF₂)ᵣ— in the formula represents a single bond.

When R² represents a single bond or an alkylene group which may have a substituent, r preferably represents an integer of 1 to 8, more preferably an integer of 1 to 4, an still more preferably 1 or 2. When R² represents an aromatic group which may have a substituent, r preferably represents 0.

Specific examples of groups represented by general formula (I-1) are shown below.

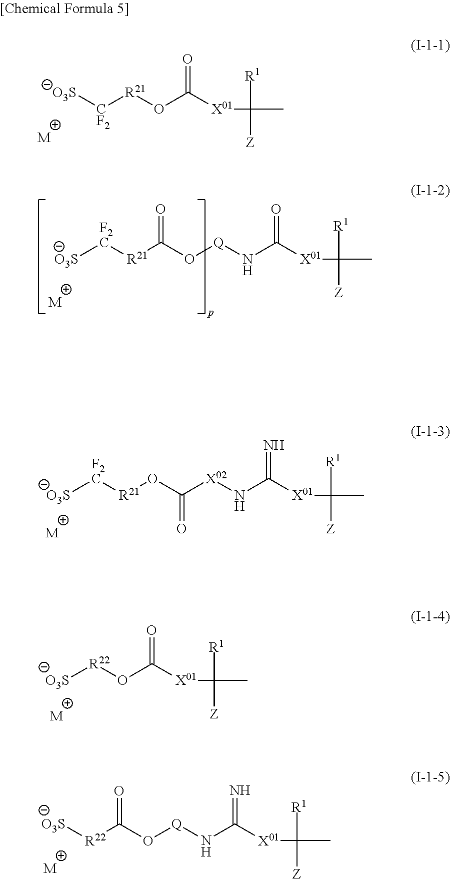

In the formulas, R¹, Z, Q, p and M⁺ are the same as those defined above; X⁰¹ represents a single bond or an alkylene group which may have a substituent; R²¹ represents a single bond or an alkylene group which may have a substituent; X⁰² represents an alkylene group which may have a substituent; and R²² represents an aromatic group which may have a substituent.

In the formulas (I-1-1) to (I-1-5), R¹, Z, Q, p and M⁺ are respectively the same those as R¹, Z, Q, p and M⁺ in the formula (I-1).

In the formulas (I-1-1) to (I-1-5), X⁰¹ represents a single bond or an alkylene group which may have a substituent. Examples of the alkylene group which may have a substituent include the same linear or branched aliphatic hydrocarbon groups and aliphatic hydrocarbon groups containing a ring in the structure thereof as described above in the explanation of the divalent hydrocarbon group which may have a substituent for X. As X⁰¹, a single bond or an ethylene group is particularly preferred.

In the formulas (I-1-1) to (I-1-3), R²¹ represents a single bond or an alkylene group which may have a substituent. The alkylene group which may have a substituent for R²¹ is the same alkylene group which may have a substituent as described for R² in the formula (I-1). As R²¹, a single bond or a methylene group is particularly preferred.

In the formula (I-1-3), X⁰² represents an alkylene group which may have a substituent.

Examples include the same linear or branched aliphatic hydrocarbon groups and aliphatic hydrocarbon groups containing a ring in the structure thereof as described above in relation to the divalent hydrocarbon group which may have a substituent for X in the formula (I-1). As X⁰², an ethylene group is particularly preferred.

In formulas (I-1-4) and (I-1-5), R²² represents an aromatic group which may have a substituent. The aromatic group which may have a substituent as described above for R²² is the same aromatic group which may have a substituent as described above in relation to R² in the formula (I-1). As R²², a group in which one or more hydrogen atoms have been removed from a phenyl group or a naphthyl group, or a group in which two or more hydrogen atoms have been removed from a quinoline group is particularly preferred.

In formula (I-1), M⁺ represents an organic cation.

The organic cation for M⁺ is not particularly limited, and an organic cation conventionally known as the cation moiety of a photo-decomposable base used as a quencher for a resist composition or the cation moiety of an onium salt acid generator for a resist composition can be used.

As the organic cation for M⁺ for example, a cation moiety represented by general formula (c-1) or (c-2) shown below can be used.

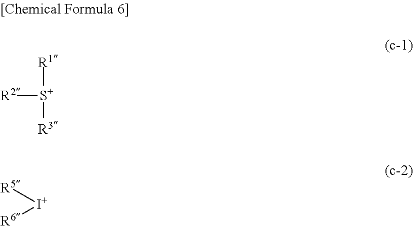

In the formulas, each of R¹″ to R³³″, R⁵″ and R⁶″ independently represents an aryl group or an alkyl group, provided that, in formula (c-1), two of R¹″ to R³″ may be mutually bonded to form a ring with the sulfur atom.

In formula (c-1), R¹″ and R³″ each independently represent an aryl group or alkyl group. In formula (c-1), two of R¹″ to R³″ may be mutually bonded to form a ring with the sulfur atom.

Further, among R¹″ to R³″, it is preferable that at least one group represent an aryl group. Among R¹″ to R³″, it is more preferable that two or more groups are aryl groups, and it is particularly preferable that all of R¹″ to R³″ are aryl groups.

The aryl group for R″ to R³″ is not particularly limited. For example, an aryl group having 6 to 20 carbon atoms may be used in which part or all of the hydrogen atoms of the aryl group may or may not be substituted with alkyl groups, alkoxy groups, halogen atoms or hydroxy groups.

The aryl group is preferably an aryl group having 6 to 10 carbon atoms because it can be synthesized at a low cost. Specific examples thereof include a phenyl group and a naphthyl group.

The alkyl group, with which hydrogen atoms of the aryl group may be substituted, is preferably an alkyl group having 1 to 5 carbon atoms, and most preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

The halogen atom, with which hydrogen atoms of the aryl group may be substituted, is preferably a fluorine atom.

The alkyl group for R″ to R³″ is not particularly limited and includes, for example, a linear, branched or cyclic alkyl group having 1 to 10 carbon atoms. In terms of achieving excellent resolution, the alkyl group preferably has 1 to 5 carbon atoms. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group, and a methyl group is most preferable because it is excellent in resolution and can be synthesized at a low cost.

When two of R¹″ to R³″ in formula (c-1) are mutually bonded to form a ring with the sulfur atom, it is preferable that the two of R¹″ to R³′ form a 3- to 10-membered ring including the sulfur atom, and it is particularly preferable that the two of R¹″ to R³″ form a 5- to 7-membered ring including the sulfur atom.

Specific examples of the ring formed include a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring and a phenazine ring.

When two of R¹″ to R³″ in formula (c-1) are mutually bonded to form a ring with the sulfur atom, the remaining one of R″ to R³″ is preferably an aryl group. As examples of the aryl group, the same aryl groups as those described above for R¹″ to R³″ can be used.

As preferable examples of the cation moiety represented by general formula (c-1), those represented by formulas (c-1-1) to (c-1-32) shown below can be given.

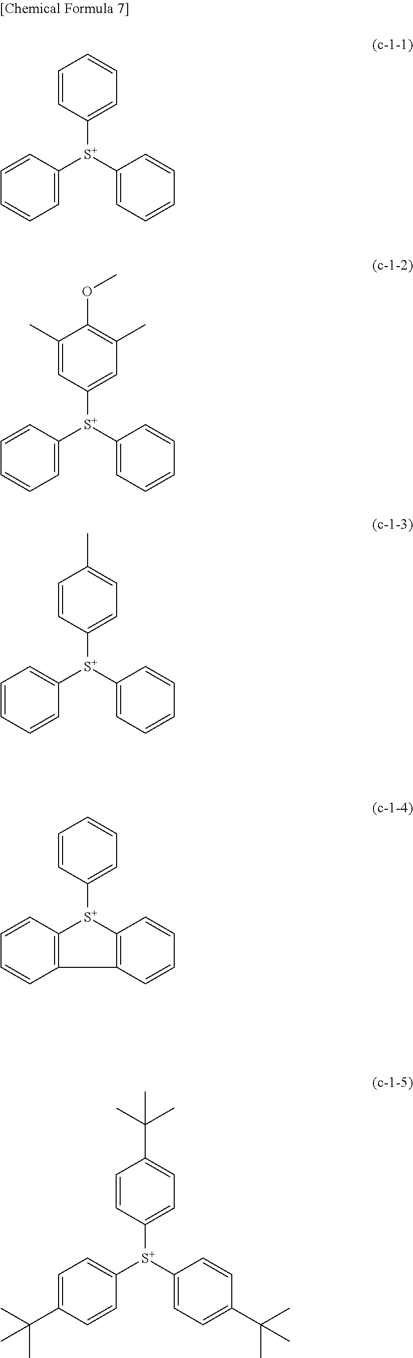

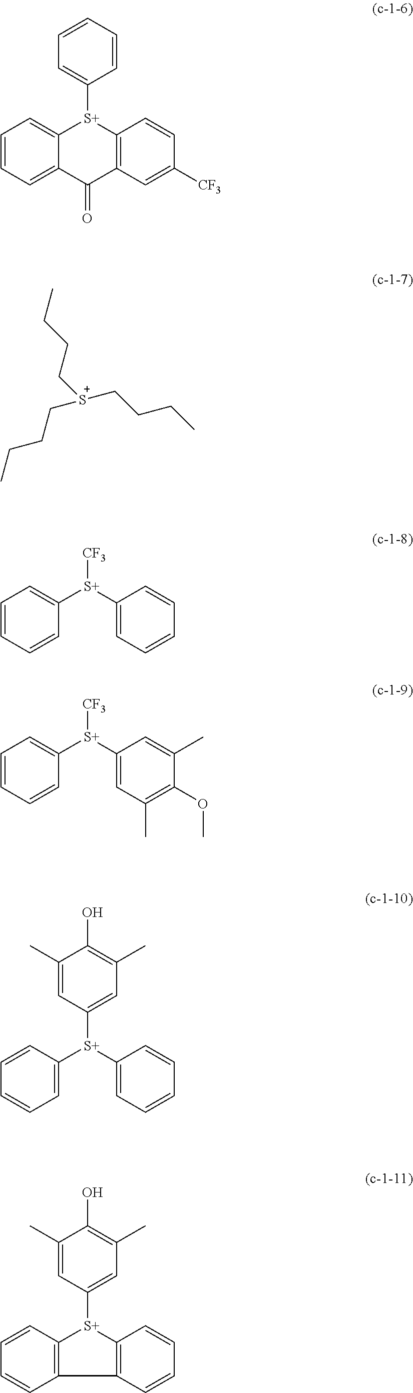

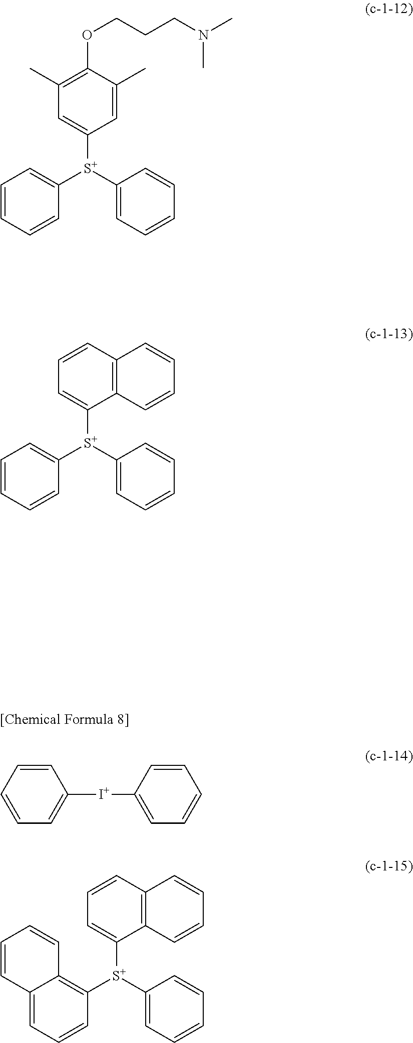

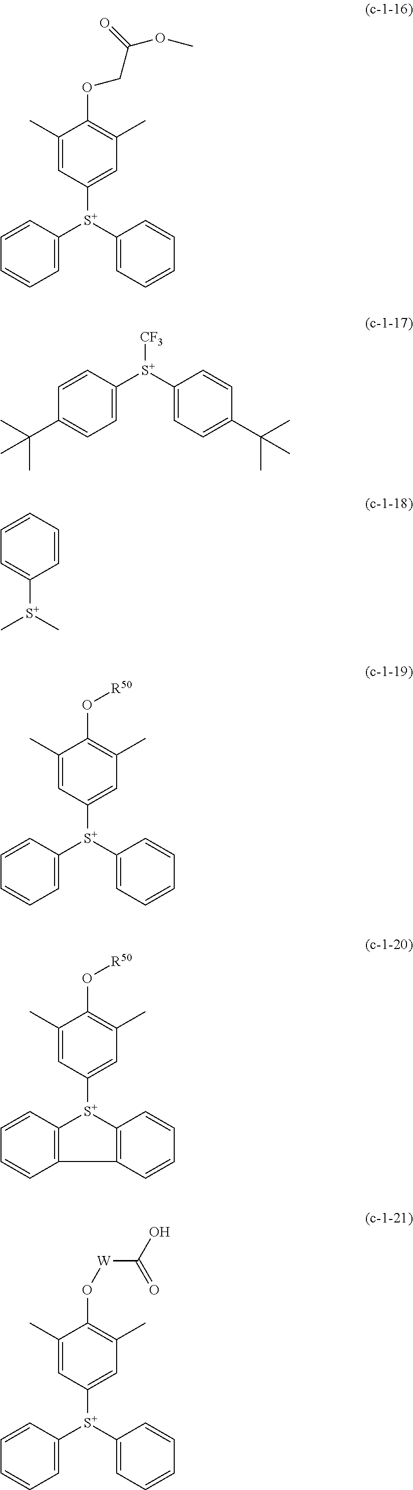

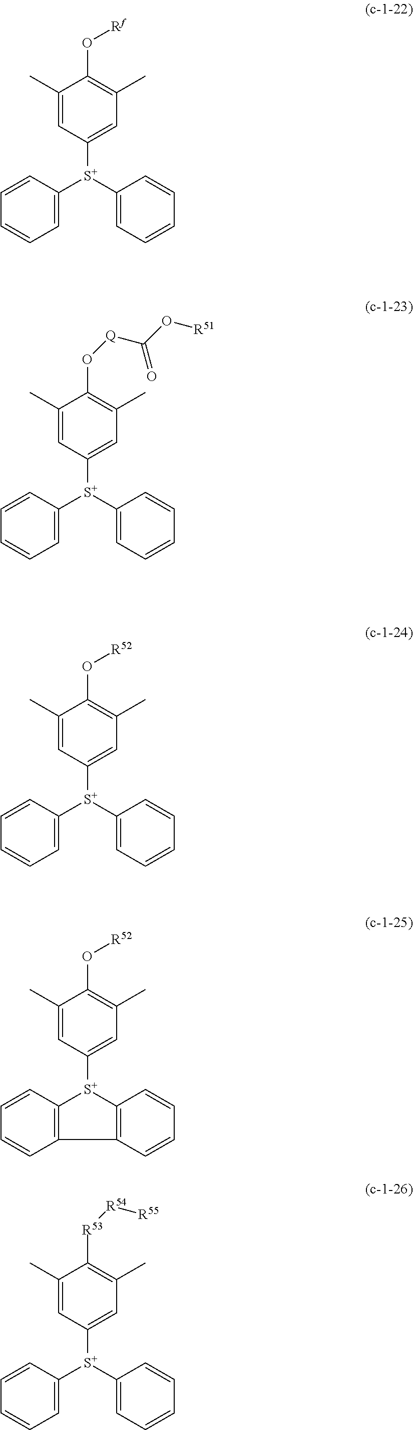

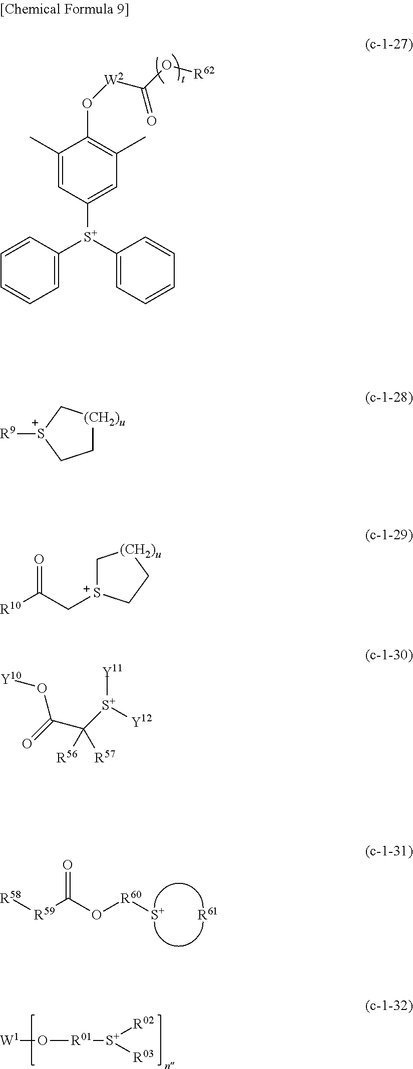

In formulas (c-1-19) and (c-1-20), R⁵⁰ represents a group containing an acid dissociable, dissolution inhibiting group, and is preferably a group represented by the formula (p1), (p1-1) or (p2) described later, or a group in which a group represented by the formula (1-1) to (1-9) or (2-1) to (2-6) described later bonded to the oxygen atom of —R⁹¹—C(═O)—O—. R⁹¹ represents a single bond or a linear or branched alkylene group, and the alkylene group preferably has 1 to 5 carbon atoms.

In formula (c-1-21), W represents a divalent linking group, and examples thereof include the same divalent linking groups as those described above for X in the aforementioned formula (I-1). Among these, a linear or branched alkylene group, a divalent aliphatic cyclic group or a group containing a hetero atom is preferable, a linear or branched alkylene group is more preferable, and a linear alkylene group is still more preferable.

In formula (c-1-22), R^{f} represents a fluorinated alkyl group, i.e., a group in which an unsubstituted alkyl group has part or all of the hydrogen atoms substituted with fluorine atoms. The unsubstituted alkyl group is preferably a linear or branched alkyl group, and more preferably a linear alkyl group.

In formula (c-1-23), Q represents a divalent linking group, and R⁵¹ represents an organic group having a carbonyl group, an ester bond or a sulfonyl group.

Examples of the divalent linking group for Q include the same divalent linking groups as those described above for X in the formula (I-1). As Q, an alkylene group or a divalent linking group containing an ester bond is preferable, and an alkylene group or —R⁹²—C(═O)—O—R⁹³— [each of R⁹² and R⁹³ independently represents an alkylene group] is more preferable.

The organic group having a carbonyl group, an ester bond or a sulfonyl group for R⁵¹ may be either an aromatic hydrocarbon group or a aliphatic hydrocarbon group. Examples of the aromatic hydrocarbon group and the aliphatic hydrocarbon group include the same groups as those described below for X³. Among these, as the organic group having a carbonyl group, an ester bond or a sulfonyl group for R⁵¹ an aliphatic hydrocarbon group is preferable, a bulky aliphatic hydrocarbon group is more preferable, and a cyclic saturated hydrocarbon group is still more preferable. Preferable examples of include a group represented by any one of the formulas (L1) to (L6) and (S1) to (S4) described later, the same group as X³ described below, and a monocyclic or polycyclic group in which the hydrogen atoms bonded thereto have been substituted with an oxygen atom (═O).

In the formulas (c-1-24) and (c-1-25), R⁵² represents an alkyl group of 4 to 10 that is not an acid dissociable group. As R⁵², a linear or branched alkyl group is preferable, and a linear alkyl group is more preferable.

In formula (c-1-26), R⁵³ represents a divalent group having a base dissociable portion, R⁵⁴ represents a divalent linking group, and R⁵⁵ represents a group having an acid dissociable group.

The base dissociable portion within R⁵³ refers to a portion which is dissociable by the action of an alkali developing solution (e.g., a 2.38% by weight aqueous solution of tetramethylammonium hydroxide (TMAH) at 23° C.). By the dissociation of the base dissociable portion, the solubility in an alkali developing solution is increased. The alkali developing solution may be any one of those generally used in the fields of lithography. It is preferable that the base dissociable portion is dissociated the action of a 2.38% by weight aqueous solution of tetramethylammonium hydroxide at 23° C.

The R⁵³ group may be either a group constituted of only a base dissociable portion, or a group in which a base dissociable portion is boned to a group or atom which is not base dissociable.

The base dissociable portion within the R⁵³ group is most preferably an ester group.

Examples of the group or atom which is not base dissociable within R⁵³ include the divalent linking groups described above for X in general formula (I-1) and combinations of the linking groups (provided that groups which are base dissociable are excluded). The “combination of the linking groups” refers to a divalent linking group constituted of divalent linking groups bonded to each together. As such a “combination of linking groups”, a combination of an alkylene group with a divalent linking group containing a hetero atom is preferable. However, it is preferable that the hetero atom is not adjacent to the atom having a bond cleaved by the action of a base within the base dissociable portion.

The alkylene group is the same linear or branched alkylene group as described above for X in the formula (I-1).

The hetero atom is most preferably an oxygen atom. Among the above examples, R⁵³ is preferably a group in which a base dissociable portion is boned to a group or atom which is not base dissociable.

R⁵⁴ represents a divalent linking group, and examples thereof include the same divalent linking groups as those described above for X in the formula (I-1). Among these, an alkylene group or a divalent aliphatic cyclic group is preferable, and an alkylene group is particularly preferred.

R⁵⁵ represents a group having an acid dissociable group.

The acid dissociable group is an organic group which can be dissociated by the action of an acid. The acid dissociable group is not particularly limited, and any group which has been proposed as an acid dissociable, dissolution inhibiting group of a base resin for a chemically amplified resist can be used. Specific examples include the same acid dissociable, dissolution inhibiting groups as those for the structural unit (a1) described below, such as a cyclic or chain-like tertiary alkyl ester-type acid dissociable group or an acetyl-type acid dissociable group (e.g., an alkoxyalkyl group). Among these, a tertiary alkyl ester-type acid dissociable group is particularly preferred.

The group having an acid dissociable group may be either the acid dissociable group itself, or a group in which an acid dissociable group is bonded to a group or atom which is not acid dissociable (a group or atom which remains bonded to the acid generator even after the dissociation of the acid dissociable group). Examples of the group or atom which is not acid dissociable include the same divalent linking groups as those described above for X.

In formula (c-1-27), W² represents a single bond or a divalent linking group, t represents 0 or 1, and R⁶² represents a group which is not dissociable by acid (hereafter, referred to as “acid non-dissociable group”).

As the divalent linking group for W² represents a divalent linking group, and examples thereof include the same divalent linking groups as those described above for X in the formula (I-1). Among these, as W², a single bond is preferable.

t is preferably 0.

The acid non-dissociable group for R⁶² is not particularly limited as long as it is a group which is not dissociable by acid. The acid non-dissociable group is preferably an acid non-dissociable hydrocarbon group which may have a substituent, more preferably a cyclic hydrocarbon group which may have a substituent, and still more preferably a group in which one hydrogen atom has been removed from adamantane.

In formulas (c-1-28) and (c-1-29), each of R⁹ and R¹⁰ independently represents a phenyl group or naphthyl group which may have a substituent, an alkyl group of 1 to 5 carbon atoms, an alkoxy group or a hydroxy group; and u represents an integer of 1 to 3, most preferably 1 or 2.

In formula (I-1-30), Y-10 represents a cyclic hydrocarbon group of 5 or more carbon atoms which may have a substituent, and is an acid dissociable group which may be dissociated by the action of an acid; each of R⁵⁶ and R⁵⁷ independently represents a hydrogen atom, an alkyl group or an aryl group, provided that R⁵⁶ and R⁵⁷ may be mutually bonded to form a ring; each of Y¹¹ and Y¹² independently represents an alkyl group or an aryl group, provided that Y¹¹ and Y¹² may be mutually bonded to form a ring.

Y¹⁰ represents a cyclic hydrocarbon group of 5 or more carbon atoms which may have a substituent, and is an acid dissociable group which may be dissociated by the action of an acid. By virtue of the Y¹⁰ group being a cyclic hydrocarbon group of 5 or more carbon atoms which may have a substituent, and is an acid dissociable group which may be dissociated by the action of an acid, various lithography properties such as resolution, LWR, exposure latitude (EL margin) and resist pattern are improved.

Examples of Y¹⁰ include groups which form a cyclic tertiary alkyl ester with —C(R⁵⁶)(R⁵⁷)—C(═O)—O—.

A “tertiary alkyl ester” refers to a structure in which a tertiary carbon atom within a cyclic hydrocarbon group of 5 or more carbon atoms is bonded to the terminal oxygen atom of —C(R⁵⁶)(R⁵⁷)—C(═O)—O—. In this tertiary alkyl ester, the action of acid causes cleavage of the bond between the oxygen atom and the tertiary carbon atom.

The cyclic hydrocarbon group may have a substituent, and the carbon atom(s) within the substituent is not included in the number of carbon atoms of the “carbon atom of 5 or more carbon atoms”.

Examples of the “aliphatic cyclic group” include monocyclic groups or polycyclic groups which have no aromaticity, and polycyclic groups are preferable.

The “aliphatic cyclic group” may or may not have a substituent. Examples of the substituent include an alkyl group of 1 to 5 carbon atoms, an alkoxyl group of 1 to 5 carbon atoms, a fluorine atom, a fluorinated alkyl group of 1 to 5 carbon atoms, and an oxygen atom (═O).

As such aliphatic cyclic groups, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples include groups in which one or more hydrogen atoms have been removed from a monocycloalkane such as cyclopentane and cyclohexane; and groups in which two or more hydrogen atoms have been removed from a polycycloalkane such as adamantane, norbornane, isobornane, tricyclodecane or tetracyclododecane.

Each of R⁵⁶ and R⁵⁷ independently represents a hydrogen atom, an alkyl group or an aryl group.

Examples of the alkyl group or aryl group for R⁵⁶ and R⁵⁷ include the same alkyl groups and aryl groups as those described above for R¹″ to R³″. Further, R⁵⁶ and R⁵⁷ may be mutually bonded to form a ring, like in the case of the aforementioned R¹″ to R³″.

Among the above-mentioned examples, it is particularly preferable that both R⁵⁶ and R⁵⁷ represent a hydrogen atom.

Each of Y¹¹ and Y¹² independently represents an alkyl group or an aryl group. Examples of the alkyl group or aryl group for Y¹¹ and Y¹² include the same alkyl groups and aryl groups as those described above for R¹″ to R³″.

It is particularly preferable that each of Y¹¹ and Y¹² represents a phenyl group or a naphthyl group. Further, Y¹¹ and Y¹² may be mutually bonded to form a ring, like in the case of the aforementioned R¹″ to R³″.

In formula (c-1-31), R⁵⁸ represents an aliphatic cyclic group; R⁵⁹ represents a single bond or an alkylene group which may have a substituent; R⁶⁰ represents an arylene group which may have a substituent; and R⁶¹ represents an alkylene group of 4 or 5 carbon atoms which may have a substituent.

The aliphatic cyclic group for R⁵⁸ may be either a monocyclic group or a polycyclic group, but is preferably a polycyclic group, more preferably a group in which one or more hydrogen atoms have been removed from a polycycloalkane, and most preferably a group in which one or more hydrogen atoms have been removed from adamantane.

The alkylene group for R⁵⁹ which may have a substituent is preferably a linear or branched alkylene group. Among these, a single bond or an alkylene group of 1 to 3 carbon atoms is preferable.

The arylene group for R⁶⁰ preferably has 6 to 20 carbon atoms, more preferably 6 to 14 carbon atoms, and still more preferably 6 to 10 carbon atoms. Examples of the arylene group include a phenylene group, a biphenylene group, a fluorenylene group, a naphthylene group, an anthrylene group and a phenanthrene group. In terms of synthesis at low cost, a phenylene group or a naphthylene group is preferable.

In formula (c-1-32), R⁰¹ represents an arylene group or an alkylene group; each of R⁰² and R⁰³ independently represents an aryl group or an alkyl group, provided that R⁰² and R⁰³ may be mutually bonded to form a ring with the sulfur atom, and at least one of R⁰¹ to R⁰³ represents an arylene group or an aryl group; W¹ represents a linking group having a valency of n″; and n″ represents 2 or 3.

The arylene group for R⁰¹ is not particularly limited, and examples thereof include arylene groups of 6 to 20 carbon atoms in which part or all of the hydrogen atoms may be substituted. The alkylene group for R⁰¹ is not particularly limited, and examples thereof include linear, branched or cyclic alkylene groups of 1 to 10 carbon atoms.

The aryl group for R⁰² and R⁰³ is not particularly limited, and examples thereof include aryl groups of 6 to 20 carbon atoms in which part or all of the hydrogen atoms may be substituted. The alkyl group for R⁰² and R⁰³ is not particularly limited, and examples thereof include linear, branched or cyclic alkyl groups of 1 to 10 carbon atoms.

Examples of the divalent linking group for W¹ include the same divalent linking groups as those described above for W. The divalent linking group may be linear, branched or cyclic, but is preferably cyclic. Among these, an arylene group having two carbonyl groups, each bonded to the terminal thereof is preferable.

The trivalent linking group for W¹ is preferably an arylene group combined with three carbonyl groups.

In formula (c-2), R⁵″ and R⁶″ each independently represent an aryl group or alkyl group. At least one of R⁵″ and R⁶″ represents an aryl group. It is preferable that both of R⁵″ and R⁶″ represent an aryl group.

As the aryl group for R⁵″ and R⁶″, the same aryl groups as those described above for R¹″ to R³″ can be used.

As the alkyl group for R⁵″ and R⁶″, the same alkyl groups as those described above for R¹″ to R³″ can be used.

It is particularly desirable that both of R⁵″ and R⁶″ represents a phenyl group.

Further, as examples of the organic cation for M⁺, organic cations represented by general formula (c-3) shown below can also be given.

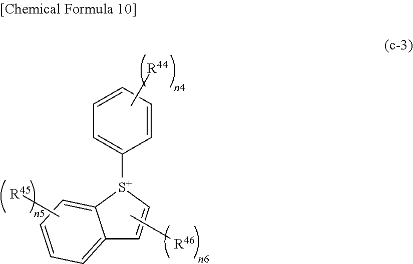

In formulas, each of R⁴⁴ to R⁴⁶ independently represents an alkyl group, an acetyl group, an alkoxy group, a carboxy group, a hydroxy group or a hydroxyalkyl group; each of n₄ and n₅ independently represents an integer of 0 to 3; and n₆ represents an integer of 0 to 2.

With respect to R⁴⁴ to R⁴⁶, the alkyl group is preferably an alkyl group of 1 to 5 carbon atoms, more preferably a linear or branched alkyl group, and most preferably a methyl group, an ethyl group, a propyl group, an isopropyl group, an n-butyl group or a tert-butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably a group in which one or more hydrogen atoms in the aforementioned alkyl group have been substituted with hydroxy groups, and examples thereof include a hydroxymethyl group, a hydroxyethyl group and a hydroxypropyl group.

If there are two or more of an individual R⁴⁴ to R⁴⁶ group, as indicated by the corresponding value of n₄ to n₆, then the two or more of the individual R⁴⁴ to R⁴⁶ group may be the same or different from each other.

n₄ is preferably 0 to 2, and more preferably 0 or 1.

n₅ is preferably 0 or 1, and more preferably 0.

n₆ is preferably 0 or 1, and more preferably 1.

[Structural Units Constituting Polymer 1]

<Structural Unit (a0)>

The structural unit (a0) is a structural unit containing —SO₂-containing cyclic group.

By virtue of using the resist composition containing the polymer including structural unit (a0), the resist composition is capable of improving the adhesion of a resist film to a substrate. Further, the structural unit (a0) contributes to improvement in various lithography properties such as sensitivity, resolution, exposure latitude (EL margin), line width roughness (LWR), line edge roughness (LER) and mask reproducibility.

Here, an “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group.

In the —SO₂— containing cyclic group, the ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings.

The —SO₂ containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

The —SO₂— containing cyclic group preferably has 3 to 30 carbon atoms, more preferably 4 to 20, still more preferably 4 to 15, and most preferably 4 to 12. Herein, the number of carbon atoms refers to the number of carbon atoms constituting the ring skeleton, excluding the number of carbon atoms within a substituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton has been substituted with a —O—SO₂— group and has at least one hydrogen atom removed therefrom.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of the substituent include an alkyl group, an alkoxy group, a halogen atom, a halogenated alkyl group, a hydroxy group, an oxygen atom (═O), —COOR″, —OC(═O)R″, a hydroxyalkyl group and a cyano group (wherein R″ represents a hydrogen atom or an alkyl group).

The alkyl group for the substituent is preferably an alkyl group of 1 to 6 carbon atoms. Further, the alkyl group is preferably a linear alkyl group or a branched alkyl group. Specific examples include a methyl group, ethyl group, propyl group, isopropyl group, n-butyl group, isobutyl group, tert-butyl group, pentyl group, isopentyl group, neopentyl group and hexyl group. Among these examples, a methyl group or an ethyl group is preferable, and a methyl group is particularly desirable.

As the alkoxy group for the substituent, an alkoxy group of 1 to 6 carbon atoms is preferable. Further, the alkoxy group is preferably a linear alkoxy group or a branched alkoxy group. Specific examples of the alkoxy groups include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms. As examples of the halogenated alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ preferably represents a hydrogen atom or a linear, branched or cyclic alkyl group of 1 to 15 carbon atoms. When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxy group.

More specific examples of the —SO₂— containing cyclic group include groups represented by general formulas (3-1) to (3-4) shown below.

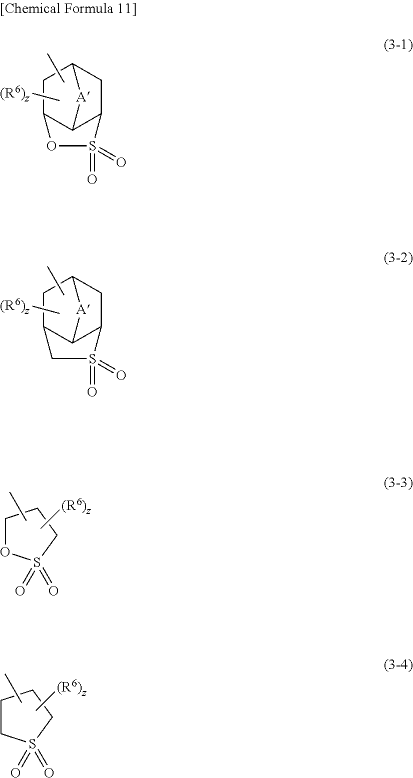

In the formulas, A′ represents an oxygen atom, a sulfur atom or an alkylene group of 1 to 5 carbon atoms which may contain an oxygen atom or a sulfur atom; z represents an integer of 0 to 2; and R⁶ represents an alkyl group, an alkoxy group, a halogenated alkyl group, a hydroxy group, —COOR″, —OC(═O)R″, a hydroxyalkyl group or a cyano group, wherein R″ represents a hydrogen atom or an alkyl group.

In general formulas (3-1) to (3-4) A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms for A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or interposed within the alkyl group. Specific examples of such alkylene groups include —O—CH₂—, —CH₂—O—CH₂—, —S—CH₂— and —CH₂—S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

When z is 2, the plurality of R⁶ may be the same or different from each other.

As the alkyl group, alkoxy group, halogenated alkyl group, —COOR″, —OC(═O)R″ and hydroxyalkyl group for R⁶, the same alkyl groups, alkoxy groups, halogenated alkyl groups, —COOR″, —OC(═O)R″ and hydroxyalkyl groups as those described above as the substituent for the —SO₂— containing cyclic group can be mentioned.

Specific examples of the cyclic groups represented by general formulas (3-1) to (3-4) are shown below. In the formulas shown below, “Ac” represents an acetyl group.

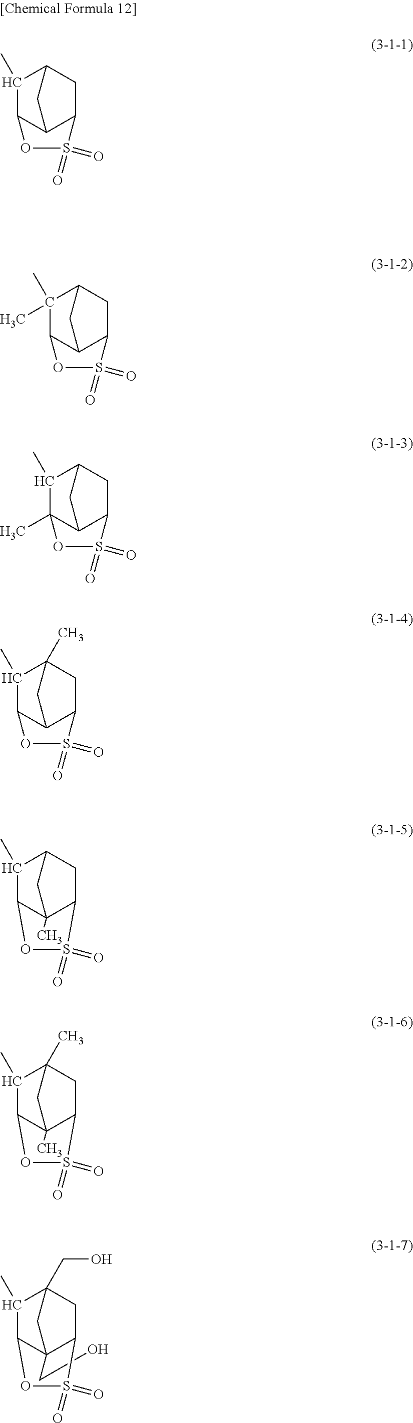

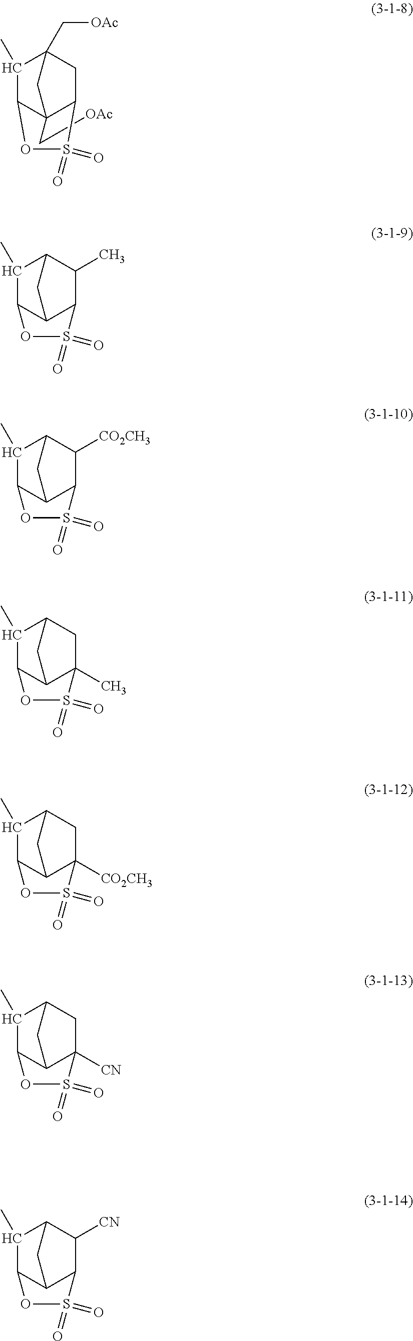

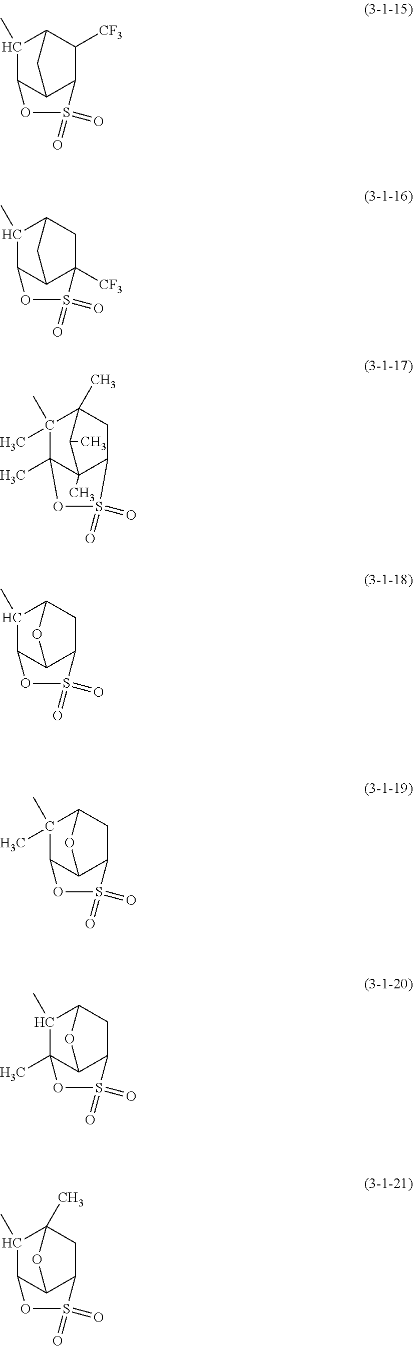

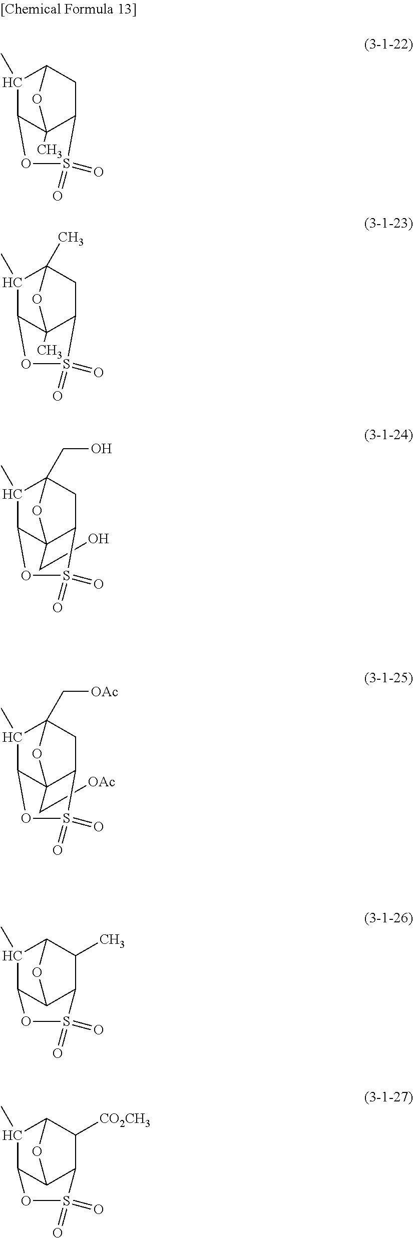

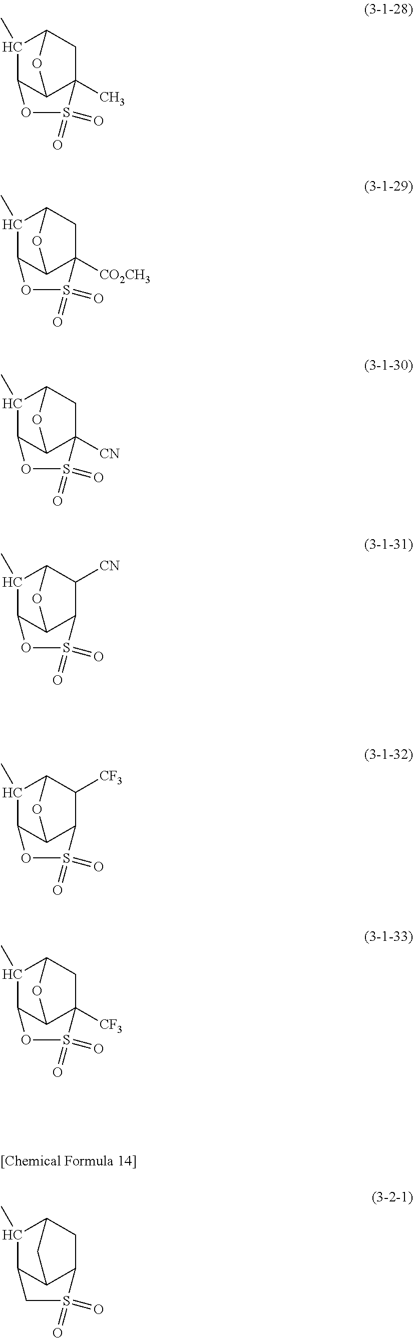

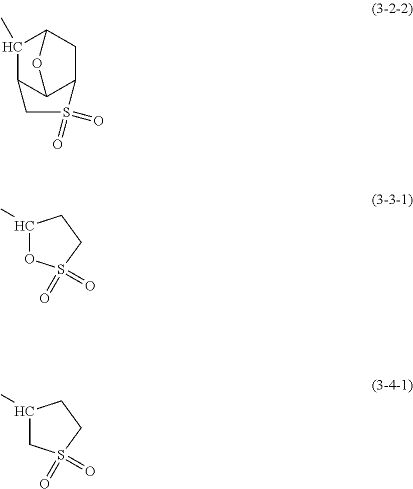

As the —SO₂— containing cyclic group, a group represented by the aforementioned general formula (3-1) is preferable, at least one member selected from the group consisting of groups represented by the aforementioned chemical formulas (3-1-1), (3-1-18), (3-3-1) and (3-4-1) is more preferable, and a group represented by chemical formula (3-1-1) is most preferable.

The structural unit (a0) is a structural unit derived from an acrylate ester and may have the hydrogen atom bonded to the carbon atom on the α-position substituted with a substituent. The term “structural units derived from an acrylic acid ester” will be described later.

More specifically, examples of the structural unit (a0) include structural units represented by general formula (a0-0) shown below.

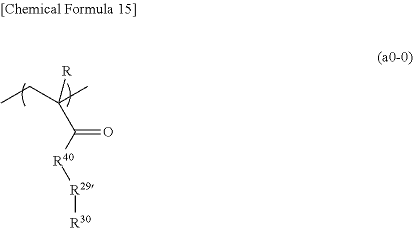

In the formula, R represents a hydrogen atom, an alkyl group of 1 to 5 carbon atoms or a halogenated alkyl group of 1 to 5 carbon atoms; R⁴⁰ represents —O— or —NH—; R³⁰ represents a —SO₂— containing cyclic group; and R²⁹′ represents a single bond or a divalent linking group.

As the alkyl group for R in the formula (a0-0), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In the formula (a0-0), R⁴⁰ represents —O— or —NH—.

In formula (a0-0), R³⁰ is the same those as defined for the aforementioned —SO₂-containing group.

In the formula (a0-0), R²⁹′ may be a single bond or a divalent linking group. R²⁹′ is preferably a divalent linking group, in terms of improving lithographic properties.

As preferable examples of the divalent linking group for R²⁹′, a divalent hydrocarbon group which may have a substituent, and a divalent linking group containing a hetero atom can be given.

(Divalent Hydrocarbon Group which May have a Substituent)

A hydrocarbon group “has a substituent” refers a group in which part or all of the hydrogen atoms within the hydrocarbon group is substituted with a substituent (a group or an atom other than hydrogen).

The hydrocarbon group may be either an aliphatic hydrocarbon group or an aromatic hydrocarbon group.

An “aliphatic hydrocarbon group” refers to a hydrocarbon group that has no aromaticity.

The divalent aliphatic hydrocarbon group as the divalent hydrocarbon group for R²⁹′ may be either saturated or unsaturated. In general, the divalent aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include the same linear or branched alkylene group as those described for X in the formula (I-1).

As the branched aliphatic hydrocarbon group, a branched alkylene group is preferable, and specific examples include the same branched alkylene group as those described for X in the formula (I-1).

The linear or branched aliphatic hydrocarbon group may or may not have a substituent. Examples of the substituent include a fluorine atom, a fluorinated alkyl group of 1 to 5 carbon atoms and an oxygen atom (═O).

The aliphatic hydrocarbon group containing a ring in the structure thereof is the same aliphatic hydrocarbon group containing a ring in the structure thereof as those described above for X in the formula (I-1). Among these, a group in which two hydrogen atoms have been removed from cyclopentane, cyclohexane, adamantane or norbornane is preferable.

The aromatic hydrocarbon group is a hydrocarbon group having an aromatic ring.

The aromatic hydrocarbon group as a divalent hydrocarbon group for R²⁹′ preferably has 3 to 30 carbon atoms, more preferably 5 to 30, still more preferably 5 to 20, still more preferably 6 to 15, and most preferably 6 to 12. Here, the number of carbon atoms within a substituent(s) is not included in the number of carbon atoms of the aromatic hydrocarbon group.

Examples of the aromatic ring in the aromatic hydrocarbon group include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom.

Specific examples of the aromatic hydrocarbon group include a group in which two hydrogen atoms have been removed from the aromatic hydrocarbon ring (arylene group); a group in which one of hydrogen atom of the group in which one hydrogen atom has been removed from the aromatic hydrocarbon group (aryl group) is substituted with an alkylene group (for example, a group in which one hydrogen atom is removed from an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and particularly preferably 1.

The aromatic hydrocarbon group may or may not have a substituent. For example, one or more of the hydrogen atoms bonded to the aromatic hydrocarbon ring in the aromatic hydrocarbon group may be substituted with a substituent. Examples of substituents include an alkyl group, an alkoxy group, a halogen atom, a halogenated alkyl group, a hydroxy group and an oxygen atom (═O).

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

### (Divalent Linking Group Containing a Hetero Atom)

With respect to a “divalent linking group containing a hetero atom” for R²⁹′, the hetero atom is an atom other than carbon and hydrogen, and examples thereof include an oxygen atom, a nitrogen atom, a sulfur atom and a halogen atom.

Examples of the divalent linking group containing a hetero atom include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, C(═O)—, ═N— and a group represented by general formula —Y²¹—O—Y²²—, —[Y²¹—C(═O)—O]_{m′}—Y²²— or —Y²¹—O—C(═O)—Y²² [in the formulas, each of Y²¹ and Y²² independently represents a divalent hydrocarbon group which may have a substituent, O represents an oxygen atom, and m′ represents an integer of 0 to 3].

When R²⁹′ represents —NH—, H may be substituted with a substituent such as an alkyl group, an aryl group (an aromatic group) or the like. The substituent (an alkyl group, an aryl group or the like) preferably has 1 to 10 carbon atoms, more preferably 1 to 8, and particularly preferably 1 to 5.

In the formula —Y²¹—O—Y²²—, —[Y²¹—C(═O)—O]_{m′}—Y²²— or —Y²¹—O—C(═O)—Y²²—, each of Y²¹ and Y²² independently represents a divalent hydrocarbon group which may have a substituent. As the divalent hydrocarbon group, the same “divalent hydrocarbon group which may have a substituent” as those described above for R²⁹′ can be mentioned.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]ₘ′—Y²²—, m′ represents an integer of 0 to 3, preferably an integer of 0 to 2, more preferably 0 or 1, and most preferably 1. Namely, it is particularly desirable that the group represented by the formula —[Y²¹—C(═O)—O]ₘ′—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a hetero atom, a linear group containing an oxygen atom as the hetero atom e.g., a group containing an ether bond or an ester bond is preferable, and a group represented by the aforementioned formula —Y²¹—O—Y²²—, —[Y²¹—C(═O)—O]_{m′}—Y²²— or —Y²¹—O—C(═O)—Y²²— is more preferable.

As the divalent linkage group for R²⁹′, an alkylene group, a divalent aliphatic hydrocarbon group or a divalent linkage group containing a hetero atom is preferable. Among these, an alkylene group or a divalent linking group containing an ester bond (—C(═O)—O—) is preferable.

As the alkylene group, a linear or branched alkylene group is preferable.

As the divalent linking group containing an ester bond, a group represented by general formula: —R²⁰—C(═O)—O— (in the formula, R²⁰ represents a divalent linking group) is particularly desirable. Namely, the structural unit (a0) is preferably a structural unit represented by general formula (a0-0-1) shown below.

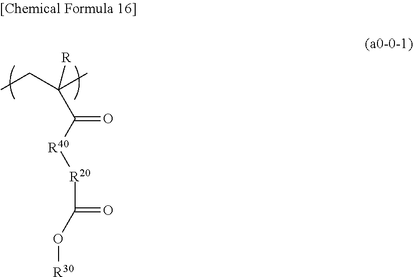

In the formula, R represents a hydrogen atom, an alkyl group of 1 to 5 carbon atoms or a halogenated alkyl group of 1 to 5 carbon atoms; R⁴⁰ represents —O— or —NH—; R²⁰ represents a divalent linking group; and R³⁰ represents an —SO₂— containing cyclic group.

R²⁰ is not particularly limited. For example, the same divalent linking groups as those described for R²⁹′ in general formula (a0-0) can be mentioned.

As the divalent linking group for R²⁰, an alkylene group, a divalent alicyclic hydrocarbon group or a divalent linking group containing a hetero atom is preferable.

As the linear or branched alkylene group, the divalent alicyclic hydrocarbon group and the divalent linking group containing a hetero atom, the same linear or branched alkylene group, divalent alicyclic hydrocarbon group and divalent linking group containing a hetero atom as those described above for preferable examples of R²⁹′ can be mentioned.

Among these, a linear or branched alkylene group, or a divalent linking group containing an oxygen atom as a hetero atom is more preferable.

As the linear alkylene group, a methylene group or an ethylene group is preferable, and a methylene group is particularly desirable.

As the branched alkylene group, an alkylmethylene group or an alkylethylene group is preferable, and —CH(CH₃)—, —C(CH₃)₂— or —C(CH₃)₂CH₂— is particularly desirable.

As the divalent linking group containing a hetero atom, a divalent linking group containing an ether bond or an ester bond is preferable, and a group represented by the aforementioned formulas —Y²¹—O—Y²²—, —[Y²¹—C(═O)—O]_{m′}—Y²²— or —Y²¹—O—C(═O)—Y²²— is more preferable. Y²¹, Y²² and m′ are the same as defined above.

Among these, a group represented by the formula —Y²¹—O—C(═O)—Y²²— is preferable, a group represented by the formula —(CH₂)_{c}—O—C(═O)—(CH₂)_{d}— is particularly desirable. c represents an integer of 1 to 5, and is preferably an integer of 1 to 3, and more preferably an integer of 1 or 2. d represents an integer of 1 to 5, and is preferably an integer of 1 to 3, and more preferably an integer of 1 or 2.

In particular, as the structural unit (a0), a structural unit represented by general formula (a0-0-11) or (a0-0-12) shown below is preferable, and a structural unit represented by general formula (a0-0-12) is more preferable.

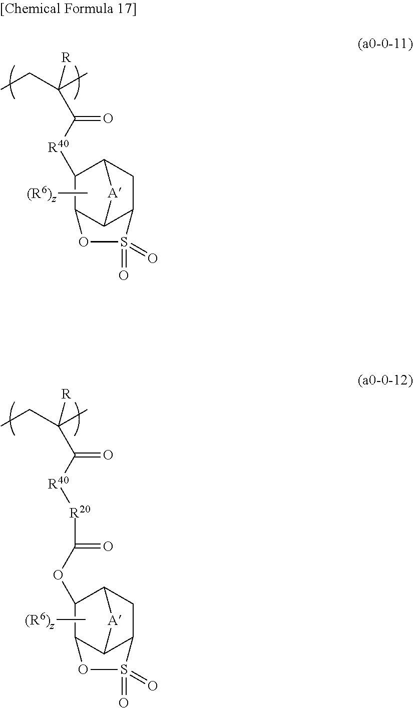

In the formulas, R represents a hydrogen atom, an alkyl group of 1 to 5 carbon atoms, or a halogenated alkyl group of 1 to 5 carbon atoms; R⁴⁰ represents —O— or —NH—; R²⁰ a divalent linking group; A′ represents an oxygen atom, a sulfur atom or an alkylene group of 1 to 5 carbon atoms which may contain an oxygen atom or a sulfur atom; z represents an integer of 0 to 2; and R⁶ represents an alkyl group, an alkoxy group, a halogenated alkyl group, a hydroxy group, —COOR″, —OC(═O)R″, a hydroxyalkyl group or a cyano group, wherein R″ represents a hydrogen atom or an alkyl group.

In general formulas (a0-0-11) and (a0-0-12), R, R⁴⁰, A′, R⁶, z and R²⁰ are the same those as defined above.

In general formula, A′ is preferably a methylene group, an ethylene group, an oxygen atom (—O—) or a sulfur atom (—S—).

As R²⁰ a linear or branched alkylene group or a divalent linking group containing an oxygen atom is preferable. As the linear or branched alkylene group and the divalent linking group containing an oxygen atom represented by R²⁰, the same linear or branched alkylene groups and divalent linking groups containing an oxygen atom as those described above can be mentioned.

As the structural unit represented by general formula (a0-0-12), a structural unit represented by general formula (a0-0-12a) or (a0-0-12b) shown below is particularly desirable.

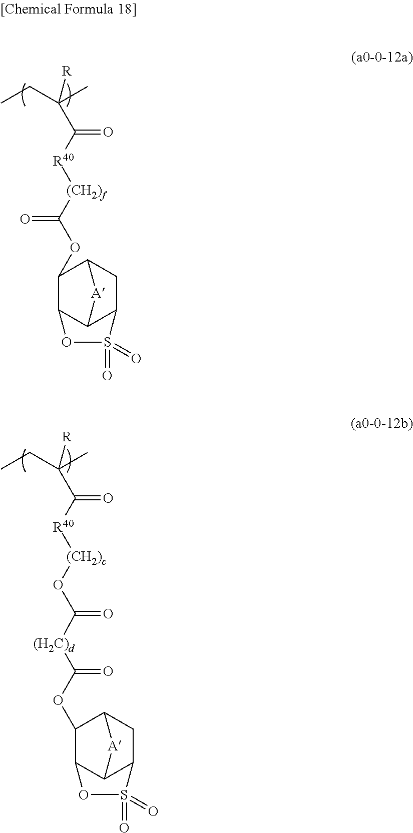

In the formulas, R, R⁴⁰ and A′ are the same as defined above; each of c and d is the same those as defined above; and f represents an integer of 1 to 5 (preferably an integer of 1 to 3).

As the structural unit (a0) contained in the polymer of the first aspect of the present invention, 1 type of structural unit may be used, or 2 or more types may be used.

In the polymer of the first aspect of the present invention, the amount of the structural unit (a0) based on the combined total of all structural units constituting the polymer is preferably 1 to 60 mol %, more preferably 5 to 55 mol %, still more preferably 10 to 50 mol %, and most preferably 15 to 48 mol %.

When the amount of the structural unit (a0) is no less than the lower limit of the above-mentioned range, a resist pattern formed from a resist composition containing the polymer has an excellent shape, and lithography properties such as EL margin, LWR and mask reproducibility can be improved. On the other hand, when the amount of the structural unit (a0) is no more than the upper limit of the above-mentioned range, in the case of using the other structural units, a good balance can be achieved with them.

<Structural Unit (a3)>

The structural unit (a3) is a structural unit containing at least one group selected from the group consisting of —OH, —COOH, —CN, —SO₂NH₂ and —CONH₂.

The structural unit (a3) is a structural unit containing a hydrocarbon group in which part of the hydrogen atoms within the hydrocarbon group is substituted with a polar group consisting of the aforementioned group. The hydrocarbon group may be either an aliphatic hydrocarbon group or an aromatic hydrocarbon group. Among these, the hydrocarbon group is preferably an aliphatic hydrocarbon group.

By virtue of the resist composition containing the polymer including the structural unit (a3), the hydrophilicity of the polymer is enhanced, thereby improving in resolution.

Examples of the aliphatic hydrocarbon group in the hydrocarbon group include linear or branched hydrocarbon groups (preferably alkylene groups) of 1 to 10 carbon atoms, and aliphatic cyclic groups (monocyclic groups and polycyclic groups).

These aliphatic cyclic groups (monocyclic groups and polycyclic groups) can be selected appropriately from the multitude of groups that have been proposed for the resins of resist compositions designed for use with ArF excimer lasers. The aliphatic cyclic group preferably has 3 to 30 carbon atoms, more preferably 5 to 30, still more preferably 5 to 20, particularly preferably 6 to 15, and most preferably 6 to 12. As the aliphatic cyclic group, a group in which two or more hydrogen atoms have been removed from a monocycloalkane or a polycycloalkane such as a bicycloalkane, tricycloalkane or tetracycloalkane can be used. Specific examples include groups in which two or more hydrogen atoms have been removed from a monocycloalkane such as cyclopentane or cyclohexane; and groups in which two or more hydrogen atoms have been removed from a polycycloalkane such as adamantane, norbornane, isobornane, tricyclodecane or tetracyclododecane. The aliphatic cyclic group may or may not have a substituent. Examples of the substituent include an alkyl group of 1 to 5 carbon atoms, a fluorine atom and a fluorinated alkyl group of 1 to 5 carbon atoms.

The aromatic hydrocarbon group in the hydrocarbon group is a hydrocarbon group containing a aromatic ring, and more preferably has 5 to 30 carbon atoms, still more preferably 6 to 20, particularly preferably 6 to 15, and most preferably 6 to 10. Here, the number of carbon atoms within a substituent(s) is not included in the number of carbon atoms of the aromatic hydrocarbon group. Examples of the aromatic ring in the aromatic hydrocarbon group include aromatic hydrocarbon rings such as benzene, biphenyl, fluorene, naphthalene, anthracene and phenanthrene.

Specific examples of the aromatic hydrocarbon group include a group in which two or more hydrogen atom have been removed from the aromatic hydrocarbon ring (arylene group); a group in which one hydrogen atom has been removed from the aromatic hydrocarbon group (aryl group) and in which has one hydrogen atom has been substituted with an alkylene group (for example, a group in which one hydrogen atom is removed from an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and particularly preferably 1.

The aromatic hydrocarbon group may or may not have a substituent. For example, one or more of the hydrogen atoms bonded to the aromatic hydrocarbon ring in the aromatic hydrocarbon group may be substituted with a substituent. Examples of the substituent include an alkyl group, a halogen atom and a halogenated alkyl group.

The alkyl group as the substituent is preferably an alkyl group of 1 to 5 carbon atoms, and a methyl group, an ethyl group, a propyl group, an n-butyl group or a tert-butyl group is most desirable.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

Among these, as the structural unit (a3), a structural unit represented by general formula (a3-1) shown below is preferable.

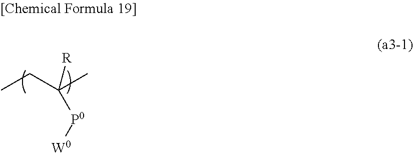

In the formula, R represents a hydrogen atom, an alkyl group of 1 to 5 carbon atoms or a halogenated alkyl group of 1 to 5 carbon atoms; P⁰ represents —C(═O)—O—, —C(═O)—NR⁰— (wherein R⁰ represents a hydrogen atom or an alkyl group of 1 to 5 carbon atoms) or a single bond; and W⁰ represents a hydrocarbon group containing at least one group selected from the group consisting of —OH, —COOH, —CN, —SO₂NH₂ and —CONH₂, and may contain an oxygen atom or a sulfur atom at an arbitrary position.

As the alkyl group for R in the formula (a3-1), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly desirable.

P⁰ in the formula (a3-1) represents —C(═O)—O—, —C(═O)—NR⁰— (wherein R⁰ represents a hydrogen atom or an alkyl group of 1 to 5 carbon atoms) or a single bond. The alkyl group for R⁰ is the same those as defined above for the alkyl group for R.

W⁰ in the formula (a3-1) represents a hydrocarbon group containing at least one group selected from the group consisting of —OH, —COOH, —CN, —SO₂NH₂ and —CONH₂ and may includes an oxygen atom or a sulfur atom at an arbitrary position.

A “hydrocarbon group which have a substituent” refers to a group in which part or all of the hydrogen atoms within the hydrocarbon group is substituted with a substituent.

The hydrocarbon group for W⁰ may be either an aliphatic hydrocarbon group, or an aromatic hydrocarbon group.

Examples of the aliphatic hydrocarbon group for W⁰ include linear or branched hydrocarbon groups (preferably alkylene groups) of 1 to 10 carbon atoms, and aliphatic cyclic groups (monocyclic groups and polycyclic groups), and these definitions are the same as those described above.

The aromatic hydrocarbon group for W⁰ is a hydrocarbon group having an aromatic ring, and these definitions are the same as those described above.

W⁰ may includes an oxygen atom or a sulfur atom at an arbitrary position. The group “may includes an oxygen atom or a sulfur atom at an arbitrary position” refers to a group in which part of the carbon atom constituting the hydrocarbon group or hydrocarbon group having a substituent may be substituted with an oxygen atom or a sulfur atom, or a group in which a hydrogen atom bonded to the hydrocarbon group may be substituted with an oxygen atom or a sulfur atom.

Examples of W⁰ containing an oxygen atom at an arbitrary position are shown below.

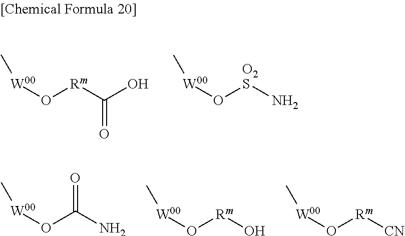

In the formulas, W⁰⁰ represents a hydrocarbon group; and Rm represents an alkylene group of 1 to 5 carbon atoms.

In the formulas, R¹⁰ represents a hydrocarbon group, and the same hydrocarbon group as those described for W⁰ in the formula (a3-1). Among these, W⁰⁰ is preferably an aliphatic hydrocarbon group, more preferably an aliphatic cyclic group (monocyclic group and polycyclic group).

R^{m} is preferably a linear or branched group, preferably an alkylene group of 1 to 3 carbon atoms, and more preferably a methylene group or an ethylene group.

Specific examples of preferable structural units as the structural unit (a3) include structural units represented by general formulas (a3-11) to (a3-13) shown below.

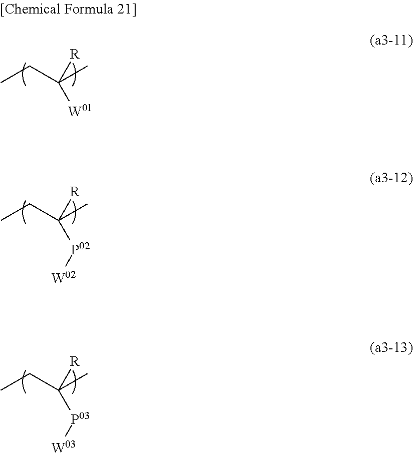

In the formulas, R represents a hydrogen atom, an alkyl group of 1 to 5 carbon atoms or a halogenated alkyl group of 1 to 5 carbon atoms; W⁰¹ is a hydrocarbon group containing at least one group selected from the group consisting of —OH, —COOH, —CN, —SO₂NH₂ and —CONH₂; each of P⁰² and P⁰³ represents —C(═O)—O— or —C(═O)—NR⁰— (R⁰ represents a hydrogen atom or an alkyl group of 1 to 5 carbon atoms); W⁰² is a cyclic hydrocarbon group which contains at least one group selected from the group consisting of —OH, —COOH, —CN, —SO₂NH₂ and —CONH₂, and which may includes an oxygen atom or a sulfur atom at an arbitrary position; and W⁰³ is a linear hydrocarbon group containing at least one group selected from the group consisting of —OH, —COOH, —CN, —SO₂NH₂ and —CONH₂.
(Structural Unit Represented by General Formula (a3-11)

In general formula (a3-11), R is the same as defined for R in general formula (a3-1).

The aromatic hydrocarbon group for W⁰¹ is the same aromatic hydrocarbon group as described for W⁰ in general formula (a3-1).

Specific examples of structural units represented by general formula (a3-11) are shown below. In the formulas shown below, R^{α} represents a hydrogen atom, a methyl group or a trifluoromethyl group.

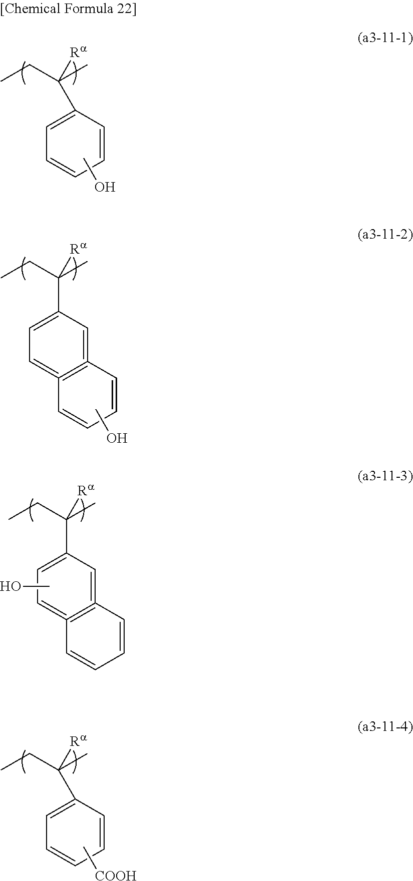

(Structural Unit Represented by General Formula (a3-12)

In general formula (a3-12), R is the same as defined for R in general formula (a3-1).

P⁰² represents —C(═O)—O— or —C(═O)—NR⁰—(wherein R⁰ represents a hydrogen atom or an alkyl group of 1 to 5 carbon atoms), and preferably —C(═O)—O—. The alkyl group for R⁰ is the same alkyl group as defined above for R.

The cyclic hydrocarbon group for W⁰² is the same aliphatic cyclic group (monocyclic group and polycyclic group) and aromatic hydrocarbon group as described for W⁰ in general formula (a3-1).

W⁰² may include an oxygen atom or a sulfur atom at an arbitrary position, and the definition is the same as defined for W⁰ in the formula (a3-1).

Specific examples of structural units represented by general formula (a3-12) are shown below. In the formulas shown below, R^{α} represents a hydrogen atom, a methyl group or a trifluoromethyl group.

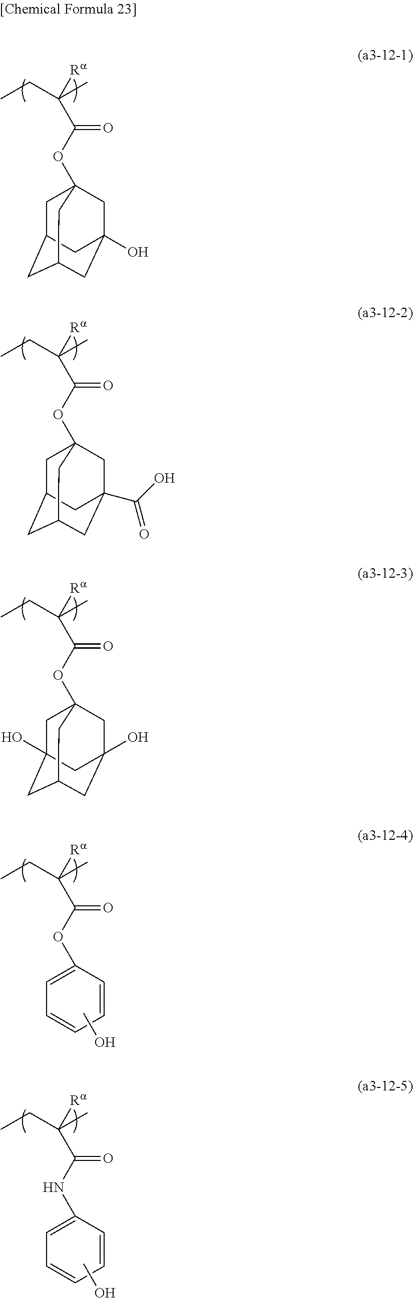

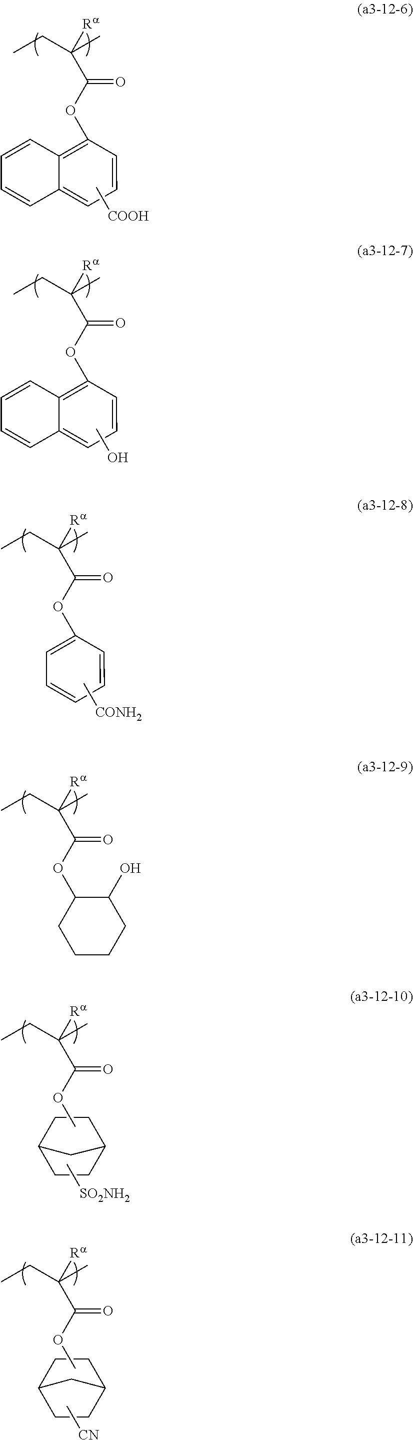

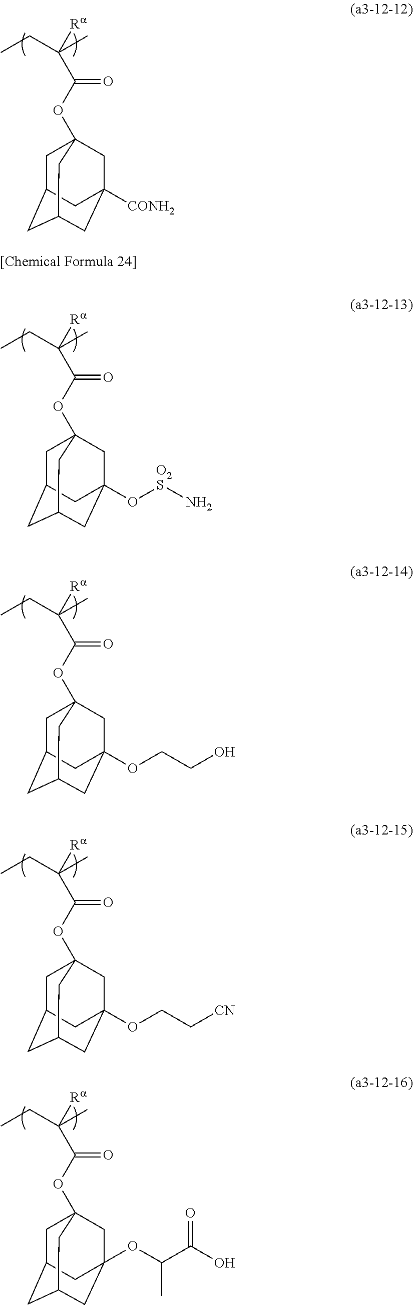

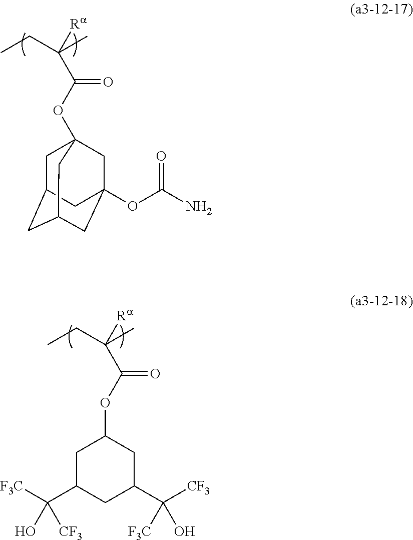

In the formula (a3-1), when the aliphatic hydrocarbon group for W⁰ (hereafter, referred to as polar group-containing aliphatic hydrocarbon group) is a linear or branched hydrocarbon group of 1 to 10 carbon atoms, the structural unit (a3) is preferably a structural unit derived from a hydroxyethyl ester of acrylic acid. On the other hand, when the hydrocarbon group for W⁰ is a polycyclic group, structural units represented by formulas (a3-12-28), (a3-12-29) and (a3-12-30) shown below are preferable.

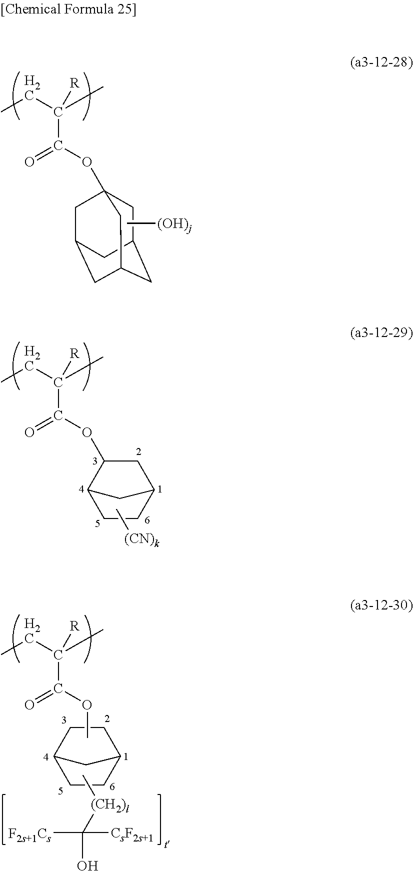

In the formulas, R is as defined above; j is an integer of 1 to 3; k is an integer of 1 to 3; t′ is an integer of 1 to 3; 1 is an integer of 1 to 5; and s is an integer of 1 to 3.

In formula (a3-12-28), j is preferably 1 or 2, and more preferably 1. When j is 2, it is preferable that the hydroxy groups be bonded to the 3rd and 5th positions of the adamantyl group. When j is 1, it is preferable that the hydroxy group be bonded to the 3rd position of the adamantyl group.

j is preferably 1, and it is particularly desirable that the hydroxy group be bonded to the 3rd position of the adamantyl group.

In formula (a3-12-29), k is preferably 1. The cyano group is preferably bonded to 5th or 6th position of the norbornyl group.

In formula (a3-12-30), t′ is preferably 1. l is preferably 1. s is preferably 1. Further, it is preferable that a 2-norbonyl group or 3-norbonyl group be bonded to the terminal of the carboxy group of the acrylic acid. The fluorinated alkyl alcohol is preferably bonded to the 5th or 6th position of the norbornyl group.

(Structural Unit Represented by General Formula (a3-13)

In general formula (a3-13), R is the same as defined for R in general formula (a3-1).

P⁰³ represents —C(═O)—O— or —C(═O)—NR⁰— (wherein R⁰ represents a hydrogen atom or an alkyl group of 1 to 5 carbon atoms), and preferably —C(═O)—O—. The alkyl group for R⁰ is the same alkyl group as defined above for R.

The linear hydrocarbon group for W⁰³ preferably has 1 to 10 carbon atoms, more preferably 1 to 5 carbon atoms, and still more preferably 1 or 3 carbon atoms.

The linear hydrocarbon group for W⁰³ may have a substituent (a) other than —OH, —COOH, —CN, —SO₂NH₂ and —CONH₂. Examples of the substituent (a) include an alkyl group of 1 to 5 carbon atoms, an aliphatic cyclic group (monocyclic group and polycyclic group), a fluorine atom and a fluorinated alkyl group of 1 to 5 carbon atoms. The aliphatic cyclic group for the substituent (a) preferably has 3 to 30 carbon atoms, more preferably 5 to 30, still more preferably 5 to 20, particularly more preferably 6 to 15, and most preferably 6 to 12. As the aliphatic cyclic group, a group in which two or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

In addition, the linear hydrocarbon group for W⁰³ may have a plurality of substituents (a), and the plurality of substituents (a) may be mutually bonded to form a ring, as in the structural unit represented by the general formula (a3-13-a) shown below.

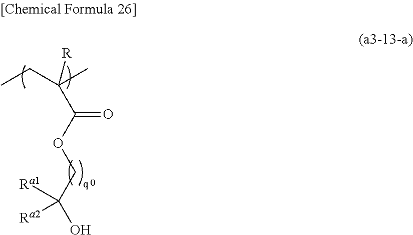

In the formula, R represents a hydrogen atom, an alkyl group of 1 to 5 carbon atoms or a halogenated alkyl group of 1 to 5 carbon atoms; each of R^{a1} and R^{a2} independently represents an alkyl group of 1 to 5 carbon atom, an aliphatic cyclic group (monocyclic group and polycyclic group), a fluorine atom or a fluorinated alkyl group of 1 to 5 carbon atoms, provided that R^{a1} and R^{a2} may be mutually bonded to form a ring; and q⁰ represents an integer of 1 to 4.

In general formula (a3-13-a), R is the same as defined for R in general formula (a3-1).

The aliphatic cyclic group (monocyclic group and polycyclic group) for R^{a1} and R^{a2} is the same aliphatic cyclic group (monocyclic group and polycyclic group) for substituent (a) as described above.

R^{a1} and R^{a2} may be mutually bonded to form a ring. In such a case, a cyclic group is formed from R^{a1}, R^{a2} and the carbon atom having R^{a1} and R^{a2} bonded thereto. The cyclic group may be either a monocyclic group or a polycyclic group. Specific examples include groups in which one or more hydrogen atoms have been removed from a monocycloalkane or polycycloalkane which is exemplified in the explanation of the aliphatic cyclic group (monocyclic group and polycyclic group) for the substituent (a).

q⁰ is preferably 1 or 2, and more preferably 1.

Specific examples of structural units represented by general formula (a3-13) are shown below. In the formulas shown below, R^{α} represents a hydrogen atom, a methyl group or a trifluoromethyl group.

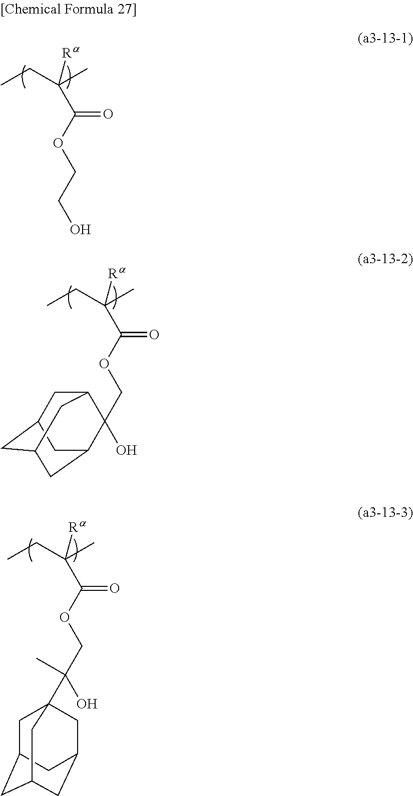

As the structural unit (a3) contained in the polymer of the first aspect of the present invention, 1 type of structural unit may be used, or 2 or more types may be used.

When the polymer of the first aspect of the present invention contains ether the structural unit (a3) or the structural unit (a5), the amount of the structural unit (a3) based on the combined total of all structural units constituting the polymer is preferably 1 to 40 mol %, more preferably 1 to 35 mol %, still more preferably 3 to 30 mol %, and particularly preferably 5 to 25 mol %.

When the amount of the structural unit (a3) is at least as large as the lower limit of the above-mentioned range, the effect of using the structural unit (a3) (such as improvement effect in resolution, lithography properties and pattern shape) can be satisfactorily achieved. On the other hand, when the amount of the structural unit (a3) is no more than the upper limit of the above-mentioned range, a good balance can be achieved with the other structural units.

When the polymer of the first aspect of the present invention contains the structural unit (a0) or when the weight average molecular weight of the polymer is 20,000 or less, the amount of the structural unit (a3) based on the combined total of all structural units constituting the polymer is preferably 5 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

<Structural Unit (a5)>

The structural unit (a5) is a structural unit which generates acid upon exposure.

The structural unit (a5) is not particularly limited as long as it is a structural unit which generates acid upon exposure. However, as the structural unit (a5), a structural unit containing an onium salt structure which generates acid upon exposure is preferred. As the onium salt structure, the same structure as the functional part of the onium salt acid generator which is commonly used in a chemically amplified resist composition can be mentioned. In addition, the strength of the generated acid is not particularly limited, and may be a strong acid which is commonly generated from an acid generator in the resist composition, or may be a weak acid other than the strong acid.

As the structural unit (a5), a structural unit having a group represented by general formula (a5-1) or (a5-2) shown below is desirable.

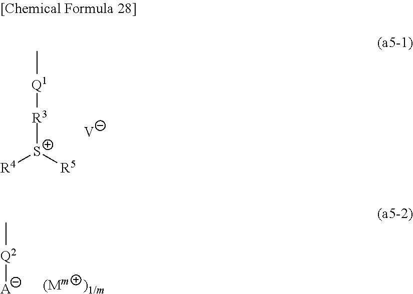

wherein each of Q¹ and Q² independently represents a single bond or a divalent linking group; each of R³, R⁴ and R⁵ independently represents an organic group, provided that R⁴ and R⁵ may be mutually bonded to form a ring with the sulfur atom; V⁻ represents a counteranion; A⁻ represents an organic group containing an anion; M^{m+} represents a countercation; and m represents an integer of 1 to 3.
(Structural Unit Represented by General Formula (a5-1))

In formula (a5-1), Q¹ represents a single bond or a divalent linking group.

Examples of the divalent linking group for Q¹ include the same divalent linking groups as those described above for X in the formula (I-1). In the present invention, Q¹ preferably represents an ester bond [—C(═O)—O—], an ether bond (—O—), an alkylene group, a combination of these, or a single bond.

In general formula (a5-1), each of R³ to R⁵ independently represents an organic group.

The organic group for R³ to R⁵ refers to a group containing a carbon atom, and may further include atoms other than carbon atoms (e.g., a hydrogen atom, an oxygen atom, a nitrogen atom, a sulfur atom, a halogen atom (such as a fluorine atom and a chlorine atom) and the like).

The organic group for R³ is preferably an arylene group or an alkylene group.

Examples of the arylene group for R³ include an arylene group having 6 to 20 carbon atoms in which part or all of the hydrogen atoms of the arylene group may or may not be substituted. For example, the arylene group may or may not be substituted with an alkyl group, an alkoxy group, a halogen atom, a hydroxy group or the like.

The arylene group is preferably an arylene group of 6 to 10 carbon atoms because it can be synthesized at a low cost. Specific examples thereof include a phenylene group and a naphthylene group. Of these, a phenylene group is particularly desirable.

The alkyl group, with which hydrogen atoms of the arylene group may be substituted, is preferably an alkyl group having 1 to 5 carbon atoms, more preferably a methyl group, an ethyl group, a propyl group, an n-butyl group, or a tert-butyl group, and most preferably a methyl group.

The alkoxy group, with which hydrogen atoms of the arylene group may be substituted, is preferably an alkoxy group having 1 to 5 carbon atoms, more preferably a methoxy group, an ethoxy group, an n-propoxy group, an iso-propoxy group, an n-butoxy group or a tert-butoxy group.

The halogen atom, with which hydrogen atoms of the arylene group may be substituted, is preferably a fluorine atom.

Examples of the alkylene group for R³ include an arylene group having 6 to 20 carbon atoms in which part or all of the hydrogen atoms of the alkylene group may or may not be substituted. For example, the alkylene group may or may not be substituted with an alkoxy group, a halogen atom, a hydroxy group or the like. The alkoxy group and the halogen atom are the same groups as defined above.

As the alkylene group, in terms of excellent resolution, a linear alkylene group of 1 to 5 carbon atoms is preferred. Specific examples thereof include a methylene group, an ethylene group, a trimethylene group, a tetramethylene group and a pentamethylene group.

The organic group for R⁴ and R⁵ is not particularly limited, and preferably an aryl group or an alkyl group.

The aryl group and alkyl group for R⁴ and R⁵ are the same as defined above for the aryl groups and alkyl groups as described above for R¹″ to R³″ in the formula (c-1). R⁴ and R⁵ may be mutually bonded to form a ring with the sulfur atom. The ring to be formed is the same ring as described above for a ring in which two of R¹″ to R³″ are mutually bonded to form a ring in the formula (c-1).

In formula (a5-1), V⁻ represents a counteranion.

As the counteranion for V⁻, there is no particular limitation, and any of those conventionally known as anion moiety of an onium salt acid generator can be appropriately selected for use.

Examples for V⁻ include an anion represented by the general formula “R^{4″}SO₃⁻ (wherein R^{4″} represents a linear, branched or cyclic alkyl group which may have a substituent, a halogenated alkyl group, an aryl group or an alkenyl group)”.

R^{4″} in the general formula “R_{4″}SO₃⁻” represents a linear, branched or cyclic alkyl group, a halogenated alkyl group, an aryl group or an alkenyl group.

The linear or branched alkyl group for R⁴″ preferably has 1 to 10 carbon atoms, more preferably 1 to 8 carbon atoms, and most preferably 1 to 4 carbon atoms.

The cyclic alkyl group for R⁴″ preferably has 4 to 15 carbon atoms, more preferably 4 to 10, and most preferably 6 to 10.

When R^{4″} represents an alkyl group, examples for “R^{4″}SO₃⁻” includes alkylsulfonates, such as methanesulfonate, n-propanesulfonate, n-butanesulfonate, n-octanesulfonate, 1-adamantanesulfonate, 2-norbornanesulfonate, d-camphor-10-sulfonate.

The halogenated alkyl group for R^{4″} is a group in which part of all of the hydrogen atoms in the alkyl group have been substituted with a halogen atom. As the alkyl group, an alkyl group of 1 to 5 carbon atoms is preferred. Among these, a linear or branched alkyl group is preferred, and more preferably a methyl group, an ethyl group, a propyl group, an isopropyl group, an n-butyl group, a tert-butyl group, a tert-pentyl group or an isopentyl group. Examples of the halogen atom to substitute a hydrogen atom include a fluorine atom, a chlorine atom, an iodine atom and a bromine atom.

With respect to the halogenated alkyl group, 50 to 100% of the hydrogen atoms in the alkyl group (alkyl group before halogenation) are preferably substituted with the halogen atoms, and all of the hydrogen atoms are more preferably substituted with the halogen atoms.

As the halogenated alkyl group, a fluorinated alkyl group is desirable. The fluorinated alkyl group preferably has 1 to 10 carbon atoms, more preferably 1 to 8 carbon atoms, and most preferably 1 to 4 carbon atoms.

Further, the fluorination ratio of the fluorinated alkyl group (percentage of fluorine atoms within the alkyl group) is preferably from 10 to 100%, more preferably from 50 to 100%, and it is particularly desirable that all hydrogen atoms are substituted with fluorine atoms because the acid strength increases.

Specific examples of the fluorinated alkyl group include a trifluoromethyl group, a heptafluoro-n-propyl group and a nonafluoro-n-butyl group.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X³-Q′- (in the formula, Q⁻ represents a divalent linking group containing an oxygen atom; and X³ represents a hydrocarbon group of 3 to 30 carbon atoms which may have a substituent).

Examples of halogen atoms and alkyl groups include the same halogen atoms and alkyl groups as those described above with respect to the halogenated alkyl group for R⁴″.

Examples of hetero atoms include an oxygen atom, a nitrogen atom, and a sulfur atom.

In the group represented by formula X³-Q′-, Q′ represents a divalent linking group containing an oxygen atom.

Q may contain an atom other than an oxygen atom. Examples of atoms other than oxygen include a carbon atom, a hydrogen atom, a sulfur atom and a nitrogen atom.

Examples of divalent linkage groups containing an oxygen atom include non-hydrocarbon, oxygen atom-containing linkage groups such as an oxygen atom (an ether bond; —O—), an ester bond (—C(═O)—O—), an amido bond (—C(═O)—NH—), a carbonyl group (—C(═O)—) and a carbonate group (—O—C(═O)—O—); and a combination of any of the aforementioned non-hydrocarbon, oxygen atom-containing linkage groups with an alkylene group. To the combination, a sulfonyl group (—SO₂—) may further be linked.

Specific examples of the combinations of the aforementioned non-hydrocarbon, oxygen atom-containing linkage groups with anikylene groups include —R⁹¹—O—, —R⁹²—O—C(═O)—, —C(═O)—O—R⁹³—O—C(═O)—, —SO₂—O—R⁹⁴—O—C(═O)— and —R⁹⁵—SO₂—O—R⁹⁴—O—C(═O)— (in the formulas, R⁹¹ to R⁹⁵ each independently represent an alkylene group.)

The alkylene group for R⁹¹ to R⁹⁵ is preferably a linear or branched alkylene group, and preferably has 1 to 12 carbon atoms, more preferably 1 to 5, and most preferably 1 to 3.

Specific examples of the alkylene group include a methylene group [—CH₂—], alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, an ethylene group [—CH₂CH₂—], alkylethylene groups such as —CH(CH₃)CH₂—, —CH(CH₃)CH(CH₃)—, —C(CH₃)₂CH₂— and —CH(CH₂CH₃)CH₂—, a trimethylene group (n-propylene group) [—CH₂CH₂CH₂—], alkyltrimethylene groups such as —CH(CH₃)CH₂CH₂— and —CH₂CH(CH₃)CH₂—, a tetramethylene group [—CH₂CH₂CH₂CH₂—], alkyltetramethylene groups such as —CH(CH₃)CH₂CH₂CH₂— and —CH₂CH(CH₃)CH₂CH₂—, and a pentamethylene group [—CH₂CH₂CH₂CH₂CH₂—].

Q¹ is preferably a divalent linking group containing an ester linkage or ether linkage, and more preferably a group of —R⁹¹—O—, —R⁹²—O—C(═O)— or —C(═O)—O—R⁹³—O—C(═O)—.

In the group represented by the formula X³-Q′-, the hydrocarbon group for X³ may be either an aromatic hydrocarbon group or an aliphatic hydrocarbon group.

The aromatic hydrocarbon group is a hydrocarbon group having an aromatic ring. The aromatic hydrocarbon group preferably has 3 to 30 carbon atoms, more preferably 5 to 30, still more preferably 5 to 20, still more preferably 6 to 15, and most preferably 6 to 12. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2, and particularly preferably 1.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned heteroatom can be used.

In the latter example, as the substituent for the aromatic hydrocarbon group, an alkyl group, an alkoxy group, a halogen atom, a halogenated alkyl group, a hydroxy group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is most desirable.

The alkoxy group as the substituent for the aromatic hydrocarbon group is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X³ may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X³, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for X³, there is no particular limitation as long as it is an atom other than carbon and hydrogen. Examples of hetero atoms include a halogen atom, an oxygen atom, a sulfur atom and a nitrogen atom.

Examples of the halogen atom include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting a part of the carbon atoms include —O—, —C(═O)—O—, —C(═O)—, —O—C(═O)—O—, —C(═O)—NH—, —NH— (H may be substituted with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxy group, an oxygen atom (═O) and a cyano group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5, still more preferably 2 to 4, and particularly preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group.

The aliphatic cyclic group preferably has 3 to 30 carbon atoms, more preferably 5 to 30, still more preferably 5 to 20, particularly preferably 6 to 15, and most preferably 6 to 12.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

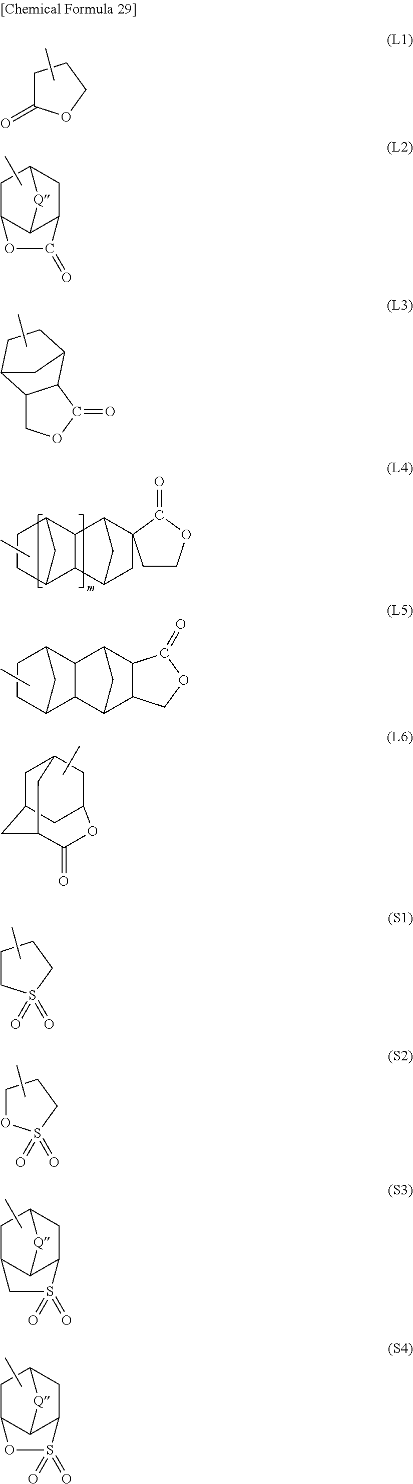

In the formulas, Q″ represents an alkylene group of 1 to 5 carbon atoms, —O—, —S—, —O—R^{94′}— or —S—R⁹⁵′— (R⁹⁴′ and R⁹⁵′ each independently represent an alkylene group of 1 to 5 carbon atoms); and m represents 0 or 1.

As the alkylene group for Q″, R⁹⁴′ and R⁹⁵′, the same alkylene groups as those described above for R⁹¹ to R⁹⁵ can be used.

In these aliphatic cyclic groups, part of the hydrogen atoms bonded to the carbon atoms constituting the ring structure may be substituted with a substituent. Examples of substituents include an alkyl group, an alkoxy group, a halogen atom, a halogenated alkyl group, a hydroxy group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

As the alkoxy group and the halogen atom, the same groups as the substituent groups for substituting part or all of the hydrogen atoms can be used.

In the present invention, as X³, a cyclic group which may have a substituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by the aforementioned formulas (L2) to (L6), (S3) and (S4) are preferable.

Among the above, R⁴″ preferably has X³-Q′- as a substituent.

When the R⁴″ group has X³-Q′- as a substituent, R⁴″ is preferably a group represented by the formula X³-Q-Y³— (in the formula, Q′ and X³ are the same as defined above, and Y³ represents an alkylene group of 1 to 4 carbon atoms which may have a substituent or a fluorinated alkylene group of 1 to 4 carbon atoms which may have a substituent).

In the group represented by the formula X³-Q′-Y³—, as the alkylene group for Y³, the same alkylene group of 1 to 4 carbon atoms as those described above for Q can be used.

As the fluorinated alkylene group, the aforementioned alkylene group in which part or all of the hydrogen atoms has been substituted with fluorine atoms can be used.

Specific examples of Y³ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—, —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)— and —C(CH₃)(CH₂CH₃)—.

As Y³, a fluorinated alkylene group is preferable, and a fluorinated alkylene group in which the carbon atom bonded to the adjacent sulfur atom is fluorinated is particularly desirable. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxy group.

When R⁴″ is a group represented by X³-Q′-Y³—, specific examples of R⁴″-SO₂— includes an anion represented by formulas (b1) to (b9) shown below.

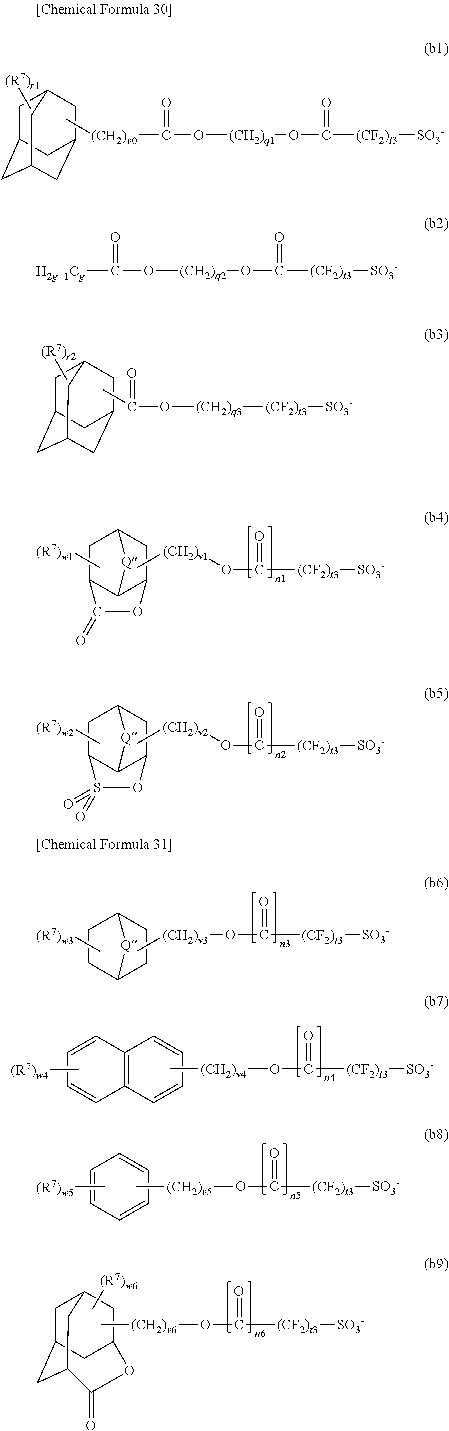

In the formulas, each of q1 and q2 independently represents an integer of 1 to 5; q3 represents an integer of 1 to 12; t3 represents an integer of 1 to 3; each of r1 and r2 independently represents an integer of 0 to 3; g represents an integer of 1 to 20; R⁷ represents a substituent; each of n1 to n6 independently represents 0 or 1; each of v0 to v6 independently represents an integer of 0 to 3; each of w1 to w6 independently represents an integer of 0 to 3; and Q″ is the same as defined above.

As the substituent for R⁷ the same groups as those which the aforementioned aliphatic hydrocarbon group or aromatic hydrocarbon group for X may have as a substituent can be used.

If there are two or more of the R⁷ group, as indicated by the values r1, r2, and w1 to w6 then the two or more of the R⁷ groups may be the same or different from each other.

Moreover, as V⁻ in the formula (a5-1), an anion represented by general formula (b-3) shown below, or an anion represented by general formula (b-4) shown below is also preferable.

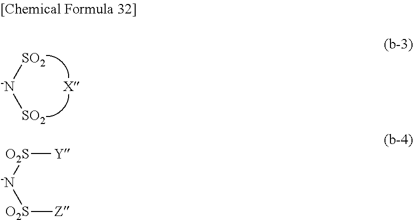

In the formulas, X″ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.

In the formula (b-3), X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

In the formula (b-4), each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved.

The amount of fluorine atoms within the alkylene group or alkyl group, i.e., fluorination ratio, is preferably from 70 to 100%, more preferably from 90 to 100%, and it is particularly desirable that the alkylene group or alkyl group be a perfluoroalkylene or perfluoroalkyl group in which all hydrogen atoms are substituted with fluorine atoms.

As V⁻ in the formula (a5-1), an anion represented by general formula “R^{4″}SO₃⁻” is preferable (in particular, an anion represented by the formulas (b1) to (b9) in which R^{4″} represents X³-Q′-Y³— is preferable).

Specific examples of groups represented by general formula (a5-1) are shown below.

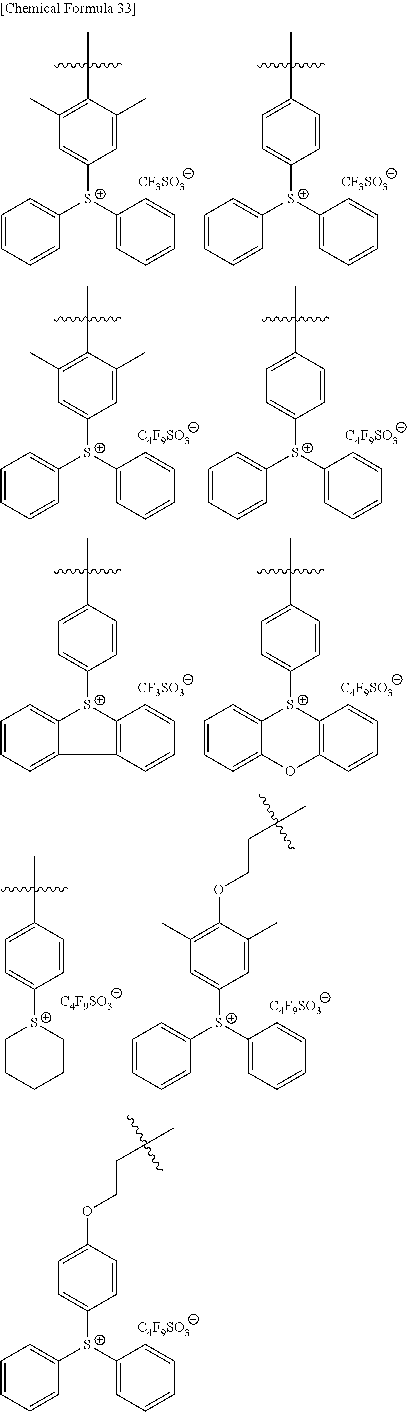

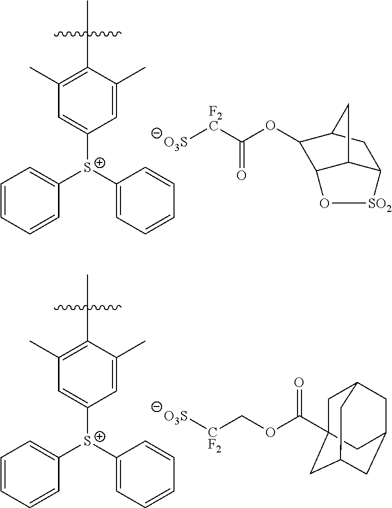

As a structural unit (a5-1) containing a group represented by the formula (a5-1) (hereafter, referred to as “structural unit (a5-1)”), a structural unit represented by the formula (a5-11) shown below is preferable.

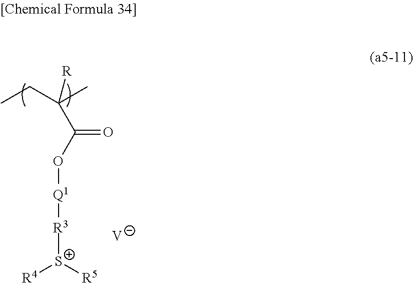

In the formula, R represents a hydrogen atom, an alkyl group of 1 to 5 carbon atoms or a halogenated alkyl group of 1 to 5 carbon atoms; Q¹, R³ to R⁵ and V⁻ are the same as those defined above.

As the alkyl group for R in the formula (a5-11), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In formula (a5-11), Q¹, R³ to R⁵ and V⁻ are the same those as defined above.

(Structural Unit Represented by General Formula (a5-2))

In formula (a5-2), Q² represents a single bond or a divalent linking group. Examples of the divalent linking group for Q² include the same divalent linking groups as those described above for X in the formula (I-1). In the present invention, Q² preferably represents a single bond, a linear or branched alkylene group, an ester bond [—C(═O)—O—] or a combination of these.

In formula (a5-2), A⁻ represents an organic group containing an anion.

The A⁻ is not particularly limited as long as it contains a part which converts into an acid anion and generates acid upon exposure. As for A−, groups which can generate a sulfonic acid anion, a carboxylic acid anion, a sulfonylimide anion, a bis(alkylsulfonyl)imide anion or a tris(alkylsulfonyl)methide anion are preferred.

Among these, as A⁻, groups represented by formulas (a5-2-an1) to (a5-2-an5) shown below are preferred.

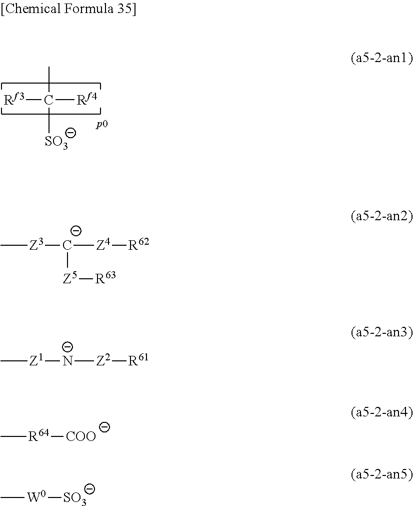

In the formulas, each of R^{f3} and R^{f4} independently represents a hydrogen atom, an alkyl group, a fluorine atom or a fluorinated alkyl group, provided that at least one of R^{f3} and R^{f4} represents a fluorine atom or a fluorinated alkyl group; p0 represents an integer of 1 to 8; Z³ represents —C(═O)—O—, —SO₂— or a hydrocarbon group which may have a substituent; each of Z⁴ and Z⁵ independently represents —C(═O)— or —SO₂—; each of R⁶² and R⁶³ independently represents a hydrocarbon group which may have a fluorine atom; Z¹ represents —C(═O)—, —SO₂—, —C(═O)—O— or a single bond; Z² repesents —C(═O)— or —SO₂—; R⁶¹ represents a hydrocarbon group which may have a fluorine atom; R⁶⁴ represents a hydrocarbon group which may have a fluorine atom; and W⁰ represents a hydrocarbon group of 1 to 30 carbon atoms which may have a substituent, provided that the carbon adjacent to S has no fluorine atom as a substituent.

In the formula (a5-2-an1), each of R^{f3} and R^{f4} independently represents a hydrogen atom, an alkyl group, a fluorine atom or a fluorinated alkyl group, provided that at least one of R^{f3} and R^{f4} represents a fluorine atom or a fluorinated alkyl group.

The alkyl group for R^{f3} and R^{f4} is preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{f3} and R^{f4} is preferably a group in which part or all of the hydrogen atoms within the aforementioned alkyl group for R¹³ and R^{f4} have been substituted with a fluorine atom.

Each of R^{f3} and R^{f4} is preferably a fluorine atom or a fluorinated alkyl group.

In formula (a5-2-an1), p0 represents an integer of 1 to 8, preferably an integer of 1 to 4, and more preferably 1 or 2.

In formula (a5-2-an2), Z³ represents —C(═O)—O—, —SO₂— or a hydrocarbon group which may have a substituent. As the hydrocarbon group which may have a substituent for Z³, examples thereof include the same divalent hydrocarbon groups which may have a substituent as described above in relation to the divalent linking group for X in the formula (I-1). Among these, as Z³, —SO₂— is preferable.

In the formula (a5-2-an2), each of Z⁴ and Z⁵ independently represents —C(═O)— or —SO₂—, at least one of them preferably represents —SO₂—, and both of them more preferably represents —SO₂—.

Each of R⁶² and R⁶³ independently represents a hydrocarbon group which may have a fluorine atom, and the same group as the hydrocarbon group which may have a fluorine atom for R⁶¹ shown below can be mentioned.

In formula (a5-2-an3), Z¹ represents —C(═O)—, —SO₂—, —C(═O)—O— or a single bond. When Z¹ represents a single bond, it is preferable that N⁻ does not directly bond to —C(═O)—on the other side to which Z² is bonded (that is, the left side in the formula).

In the formula (a5-2-an3), Z² represents —C(═O)— or —SO₂—, and preferably —SO₂—.

R⁶¹ represents a hydrocarbon group which may have a fluorine atom. As the hydrocarbon group for R⁶¹, an alkyl group, a monovalent aliphatic hydrocarbon group, an aryl group and an aralkyl group can be mentioned.

The alkyl group for R⁶¹ preferably has 1 to 8 carbon atoms, more preferably 1 to 6 carbon atoms, and still more preferably 1 to 4 carbon atoms, and may be either linear or branched. Specific examples include a methyl group, an ethyl group, a propyl group, a butyl group, a hexyl group and an octyl group.

The monovalent alicyclic hydrocarbon group for R⁶¹ preferably has 3 to 20 carbon atoms, more preferably 3 to 12 carbon atoms, and may be polycyclic or monocyclic. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The aryl group for R⁶¹ preferably has 6 to 18 carbon atoms, more preferably 6 to 10 carbon atoms, and a phenyl group is particularly preferable.

As the aralkyl group for R⁶¹, a group in which an alkylene grope of 1 to 8 carbon atoms and an aryl group for R⁶¹ are bonded can be mentioned. The aralkyl group is a group in which an alkylene group of 1 to 6 carbon atoms and an aryl group for R⁶¹ are bonded is more preferable, and a group in which an alkylene group of 1 to 4 carbon atoms and an aryl group for R⁶¹ are bonded is particularly preferable.

The hydrocarbon group for R⁶¹ is preferably a group in which part or all of the hydrogen atoms of the hydrocarbon group is substituted with a fluorine atom, and more preferably a group in which 30 to 100% of the hydrogen atoms of the hydrocarbon group is substituted with a fluorine atom. Among these, a perfluoroalkyl group in which all of the hydrogen atoms of the alkyl group are substituted with a fluorine atom is particularly desirable.

In the formula (a5-2-an4), R⁶⁴ represents a hydrocarbon group which may have a fluorine atom. As the hydrocarbon group for R⁶⁴, an alkylene group, a divalent alcyclic hydrocarbon group, a group in which one or more hydrogen atoms have been removed from an aryl group and a group in which one or more hydrogen atom have been removed from an aralkyl group.

Specific examples of the hydrocarbon group for R⁶⁴ include a group in which one or more hydrogen atom have been removed from the hydrocarbon groups exemplified in the explanation of R⁶¹ (an alkyl group, a monovalent alicyclic hydrocarbon group, an aryl group and an aralkyl group).

The hydrocarbon group for R⁶⁴ is preferably a group in which part or all of the hydrogen atoms of the hydrocarbon group is substituted with a fluorine atom, and more preferably a group in which 30 to 100% of the hydrogen atoms of the hydrocarbon group is substituted with a fluorine atom.

In formula (a5-2-an5), W⁰ represents a hydrocarbon group of 1 to 30 carbon atoms which may have a substituent,

The hydrocarbon group of 1 to 30 carbon atoms for W⁰ which may have a substituent may be either an aliphatic hydrocarbon group or an aromatic hydrocarbon group, and the same aliphatic hydrocarbon groups and aromatic hydrocarbon groups as aliphatic hydrocarbon groups and aromatic hydrocarbon groups defined as a divalent linking group for X in the formula (I-1) can be used.

Among these, as the hydrocarbon group for W⁰ which may have a substituent, an aliphatic cyclic group which may have a substituent is preferable, and a group in which two or more hydrogen atoms have been removed from adamantane, norbornane, isobornane, tricyclodecane, tetracyclododecane or camphor (which may have a substituent) is more preferable.

When A⁻ contains a group represented by formula (a5-2-an1), (a5-2-an2), or (a5-2-an3) in which Z¹ represents —C(═O)—O— or a single bond, it is possible to generate a relatively strong acid such as a fluorinated sulfonate anion and a carbanion from the polymer upon exposure.

On the other hand, when A⁻ contains a group represented by formula (a5-2-an4), (a5-2-an5), or (a5-2-an3) in which Z¹ represents —C(═O)— or a —SO₂—, it is possible to generate a relatively weak acid such as a sulfonate anion and a carboxylate anion from the polymer upon exposure.

In the polymer of the first aspect of the present invention, it is possible to generate acid having a desired acid strength from the structural unit (a5) as described above. Therefore, when the polymer is used in a resist composition, the function of the acid generated from the structural unit (a5) in the resist composition can be suitably determined, and A⁻ can also be selected according to the desired function.

For example, when the structural unit (a5) has the same role as an acid generator which is usually used in a resist composition, it is preferable to select A⁻ which generates a strong acid.

Also, for example, when the structural unit (a5) has the same role as a quencher (quencher to trap a strong acid by salt-exchange with the strong acid which is generated from the acid generator) which is usually used in a resist composition, it is preferable to select A⁻ which generates a weak acid.

Here, strong acids and weak acids are determined in view of a relationship with the activation energy of the acid decomposition group which is decomposed by the action of acid and is included in the structural unit (a1) described below and a relationship with the acid strength of the acid generator used in combination with these acids. Therefore, the aforementioned “relatively weak acid” cannot always be used as a quencher.

In formula (a5-2), M^{m+} represents a countercation, and m represents an integer of 1 to 3.

As the counteranion for M^{m+}, an onium cation is preferably used.

Examples of the onium cation for M^{m+} include a sulfonium cation, an iodonium cation, a phosphonium cation, a diazonium cation, an ammonium cation and a pyridinium cation. Among these, cations represented by the aforementioned formulas (c-1) to (c-3) are preferable, and cations represented by the aforementioned formula (c-1-1) to (c-1-32) are more preferable.

In the present invention, as the structural unit containing a group represented by the formula (a5-2) (hereafter, referred to as “structural unit (a5-2)”), a structural unit selected from the groups represented by formulas (a5-2-11) to (a5-2-13), (a5-2-21) to (a5-2-25), (a5-2-31) to (a5-2-32), (a5-2-41) to (a5-2-44) and (a5-2-51) to (a5-2-53) is desirable.

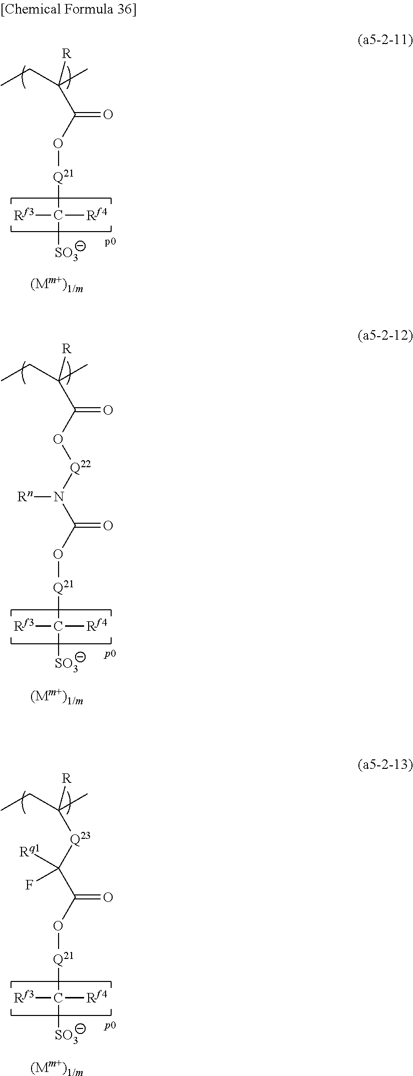

In the formulas, R, R^{f3}, R^{f4}, p0 and (M^{m+})_{1/m} are the same as those defined above; each of Q²¹ independently represents a single bond or a divalent linking group; Q²² represents a divalent linking group; Q²³ represents a group containing —O—, —CH₂—O— or —C(═O)—O—; R^{q1} represents a fluorine atom or a fluorinated alkyl group; and Rⁿ represents a hydrogen atom or an alkyl group of 1 to 5 carbon atoms.

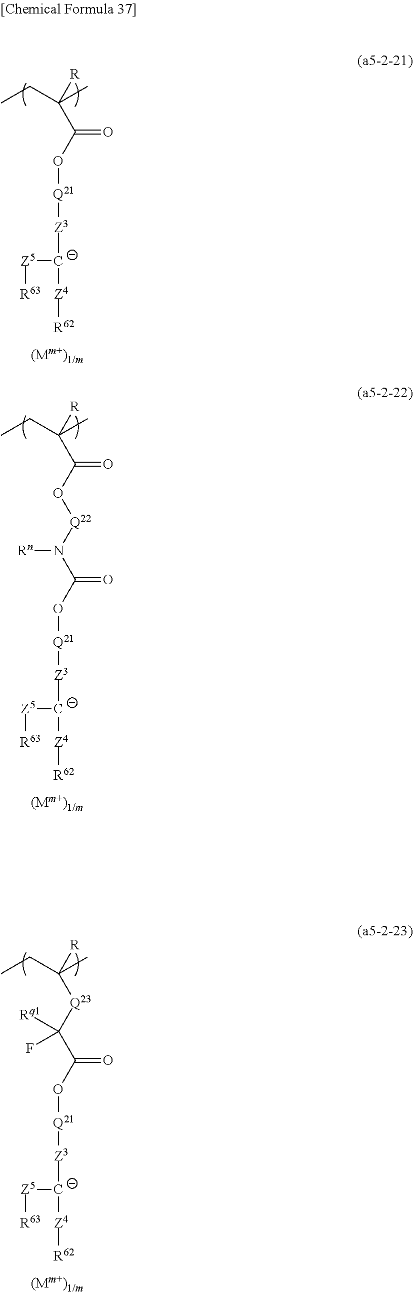

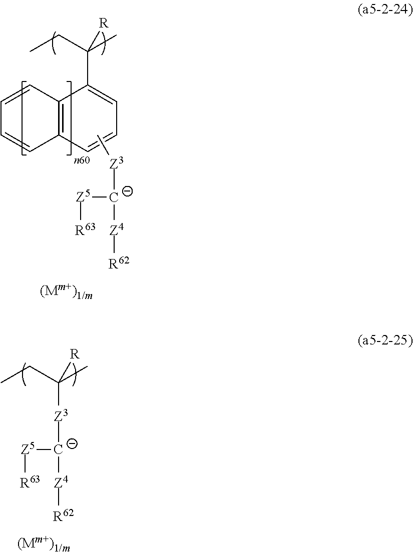

In the formulas, R, Q²¹ to Q²³, Z³ to Z⁵, R⁶², R⁶³, Rⁿ, R^{q1}, and (M^{m+})_{1/m} are the same as those defined above; and n60 represents an integer of 0 to 3.

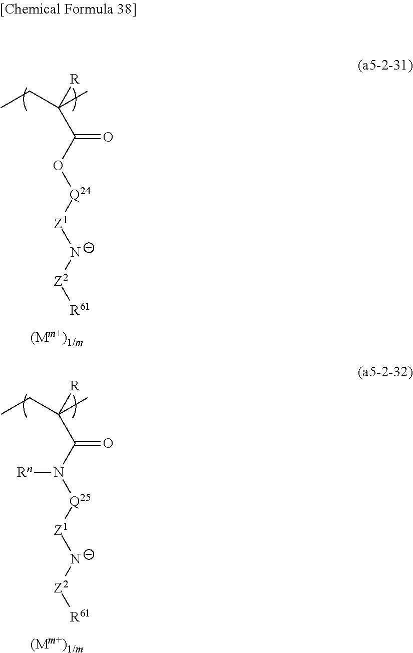

In the formulas, R, Z¹, Z², Rⁿ and (M^{m+})_{1/m} are the same as those defined above; and each of Q²⁴ and Q²⁵ independently represents a single bond or a divalent linking group.

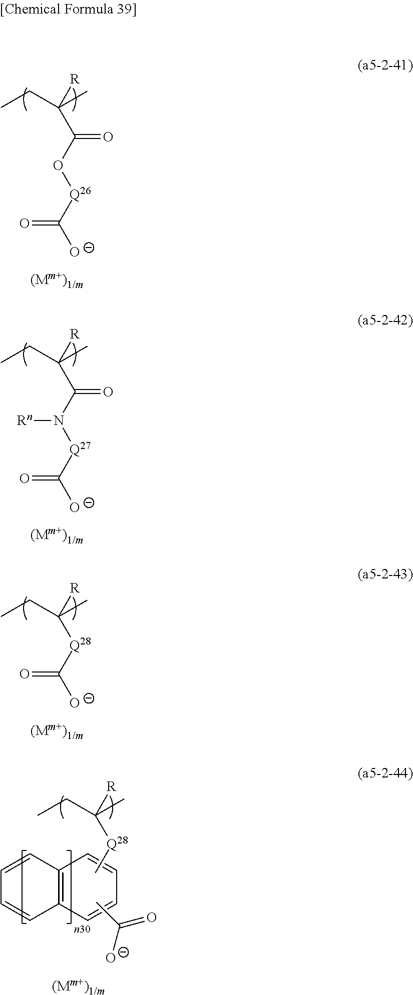

In the formulas, Rⁿ and (M^{m+})_{1/m} are the same as those defined above; each of Q²⁶ to Q²⁸ independently represents a single bond or a divalent linking group; and n30 represents an integer of 0 to 3.

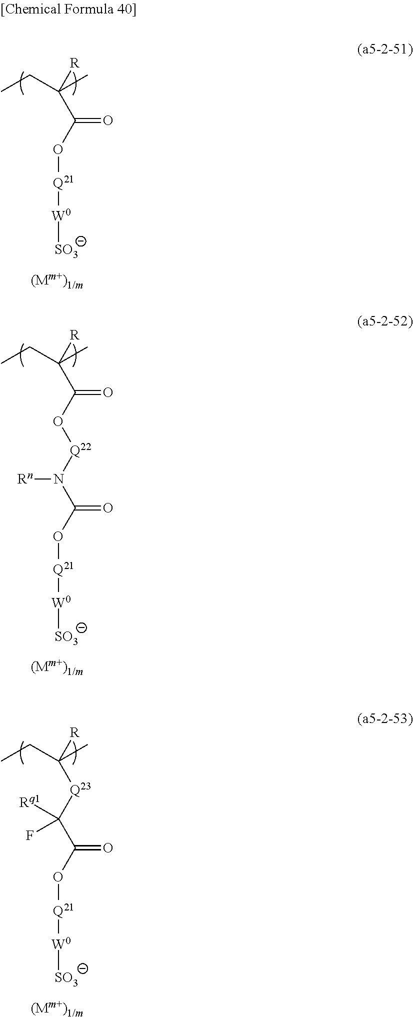

In the formulas, R, Q²¹ to Q²³, W⁰, R^{q1}, Rⁿ and (M^{m+})_{1/m} are the same as those defined above.

In the formulas (a5-2-11) to (a5-2-13), R, R^{f3}, R^{f4}, p0 and (M^{m+)}_{1/m} are the same as those defined above, and Q²¹ represents a single bond or a divalent linking group. Examples of the divalent linking group for Q²¹ include the same divalent linking groups as those described above for X in the formula (I-1).

In particular, as Q²¹, the same linear or branched alkylene group, a cyclic aliphatic hydrocarbon group, an aromatic hydrocarbon group or a divalent linking group containing a hetero atom as described for X is preferable; a linear or branched alkylene group, a combination of a linear or branched alkylene group with a divalent linking group containing a hetero atom, a combination a cyclic aliphatic hydrocarbon group with a divalent linking group containing a hetero atom or a combination of an aromatic hydrocarbon group and a divalent linking group containing a hetero atom is more preferable; a linear or branched alkylene group, a combination of a linear or branched alkylene group with an ester bond [—C(═O)—O—] or a combination of a divalent alicyclic hydroarbon group with an ester bond [—C(═O)—O—] is particularly preferable; and a linear or branched alkylene group or a combination of a linear or branched alkylene group with an ester bond [—C(═O)—O—] is most preferable.

In formula (a5-2-12), Q²² represents a divalent linking group, and examples thereof include the same divalent linking groups as those described above for X in the aforementioned formula (I-1). Among these, a linear or branched alkylene group, a cyclic aliphatic hydrocarbon group or a divalent aromatic hydrocarbon group for X is preferable, a linear alkylene group is more preferable, and a methylene group or ethylene group is most preferable.

In the formula (a5-2-12), Rⁿ represents a hydrogen atom or an alkyl group of 1 to 5 carbon atoms. As the alkyl group of 1 to 5 carbon atoms, the same alkyl groups of 1 to 5 carbon atoms as those described above for R can be used. As Rⁿ a hydrogen atom or a methyl group is preferable.

In the formula (a5-2-13), Q²³ represents a group containing —O—, —CH₂—O— or —C(═O)—O—.

Specific examples of Q²³ include a group constituted of —O—, —CH₂—O— or —C(═O)—O—; and a group constituted of a divalent hydrocarbon group which may have a substituent, —O—, —CH₂—O— or —C(═O)—O—.

As the divalent hydrocarbon group which may have a substituent, examples thereof include the same divalent hydrocarbon groups which may have a substituent as described above in relation to the divalent linking group for X in the formula (I-1). Among these examples, as the “divalent hydrocarbon group” for Q¹, an aliphatic hydrocarbon group is preferable, and a linear or branched alkylene group is more preferable.

Q²³ is preferably a group constituted of —C(═O)—O— and a divalent hydrocarbon group which may have a substituent, more preferably a group constituted of —C(═O)—O— and an aliphatic hydrocarbon group, and most preferably a group constituted of —C(═O)—O— and a linear or branched alkylene group.

As a specific example of the group for Q²³, a group represented by general formula (Q²³-1) shown below can be given.

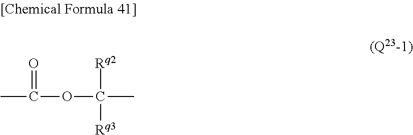

In the formula (Q²³-1), each of R^{q2} and R^{q3} independently represents a hydrogen atom, an alkyl group or a fluorinated alkyl group, and R^{q2} and R^{q3} may be mutually bonded to form a ring.

In the formula (Q²³-1), the alkyl group for R^{q2} and R^{q3} may be linear, branched or cyclic, and is preferably linear or branched.

The linear or branched alkyl group is preferably a linear or branched alkyl group of 1 to 5 carbon atoms, more preferably a methyl group or an ethyl group, and most preferably an ethyl group.

The cyclic alkyl group preferably has 4 to 15 carbon atoms, more preferably 4 to 12, and most preferably 5 to 10. Specific examples include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, dicyclodecane, tricyclodecane or tetracyclododecane. Among these examples, a group in which one or more hydrogen atoms have been removed from adamantane is preferable.

The fluorinated alkyl group for R^{q2} and R^{q3} is an alkyl group in which part or all of the hydrogen atoms have been substituted with a fluorine atom.

In the fluorinated alkyl group, the alkyl group prior to being substituted with a fluorine atom may be linear, branched or cyclic, and examples thereof include the same alkyl groups as those described above for R^{q2} and R^{q3}.

R^{q2} and R^{q3} may be mutually bonded to form a ring. As the ring which is formed from R^{q2}, R^{q3} and the carbon atom having R^{q2} and R^{q3} bonded thereto can be mentioned as a group in which two hydrogen atoms have been removed from a monocycloalkane or a polycycloalkane described above for the aforementioned cyclic alkyl group, preferably a 4- to 10-membered ring, and more preferably a 5- to 7-membered ring.

Among these examples, R^{q2} and R^{q3} preferably represent a hydrogen atom or an alkyl group.

In the formula (a5-2-13), R^{q1} represents a fluorine atom or a fluorinated alkyl group.

With respect to the fluorinated alkyl group for R^{q1}, the alkyl group prior to being fluorinated may be linear, branched or cyclic.

The linear or branched alkyl group preferably has 1 to 5 carbon atoms, more preferably 1 to 3 carbon atoms, and most preferably 1 or 2 carbon atoms.

The cyclic alkyl group preferably has 4 to 15 carbon atoms, more preferably 4 to 12, and still more preferably 5 to 10. Specific examples include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, dicyclodecane, tricyclodecane or tetracyclododecane.

In the fluorinated alkyl group, the percentage of the number of fluorine atoms based on the total number of hydrogen atoms and fluorine atoms (fluorination ratio (%)) is preferably 30 to 100%, and more preferably 50 to 100%. The higher the fluorination ratio is, the higher the hydrophobicity of the resist film becomes.

Among these, as R^{q11}, a fluorine atom is preferable.

In the formulas (a5-2-21) to (a5-2-25), R, Q²¹ to Q²³, Z³ to Z⁵, R⁶², R⁶³, Rₙ and R^{q1}, (M^{m+)}_{1/m} are the same as those defined above.

In general formula (a5-2-24), n60 represents an integer of 0 to 3, preferably 0 or 1.

In the formulas (a5-2-31) and (a5-2-32), R, Z¹, Z², Rₙ and (M^{m+)}_{1/m} are the same as those defined above, and each of Q²⁴ and Q²⁵ independently represents a single bond or a divalent linking group.

Examples of the divalent linking group for Q²⁴ and Q²⁵ include the same divalent linking groups as those described above for X in the formula (I-1). As described above, when Z¹ represents a single bond, the terminal of Q²⁴ and Q²⁵ bonded to Z¹ is not preferably —C(═O)—. As the divalent linking group for Q²⁴ and Q²⁵, a linear or branched alkylene group, a cyclic aliphatic hydrocarbon group or a divalent linking group containing a hetero atom is particularly desirable. Among these, a linear or branched alkylene group and a cyclic aliphatic hydrocarbon group are preferable, and a linear alkylene group and a cyclic aliphatic hydrocarbon group are more preferable.

In the formulas (a5-2-41) to (a5-2-44), Rₙ and (M^{m+})_{1/m} are the same as those defined above, and each of Q²⁶ to Q²⁸ independently represents a single bond or a divalent linking group. Q²⁶ to Q²⁸ are the same as Q²⁴ to Q²⁵.

In general formula (a5-2-44), n30 represents an integer of 0 to 3, preferably 0 or 1.

In the formulas (a5-2-51) to (a5-2-53), R, Q²¹ to Q²³, W⁰, R^{q1} and Rⁿ(M^{m+})_{1/m} are the same as those defined above.

Specific examples of the structural unit (a5-2) are shown below. In the formulas shown below, R^{α} represents a hydrogen atom, a methyl group or a trifluoromethyl group, and (M^{m+})_{1/m} is the same as those defined above.

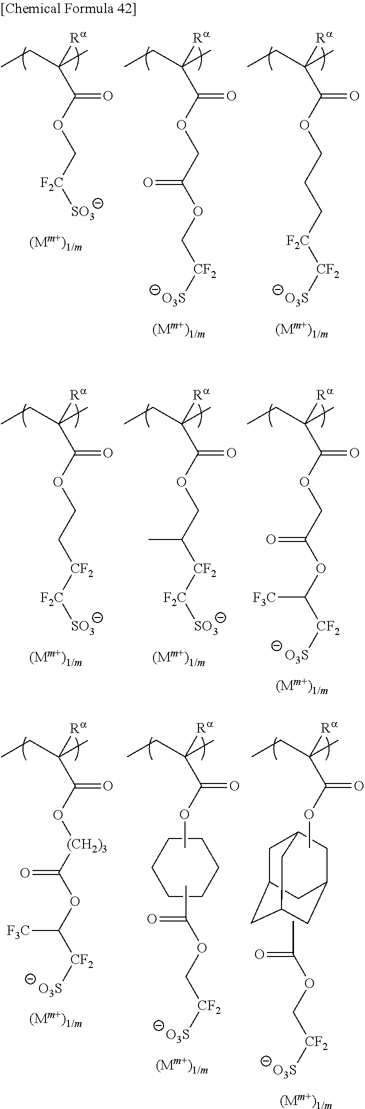

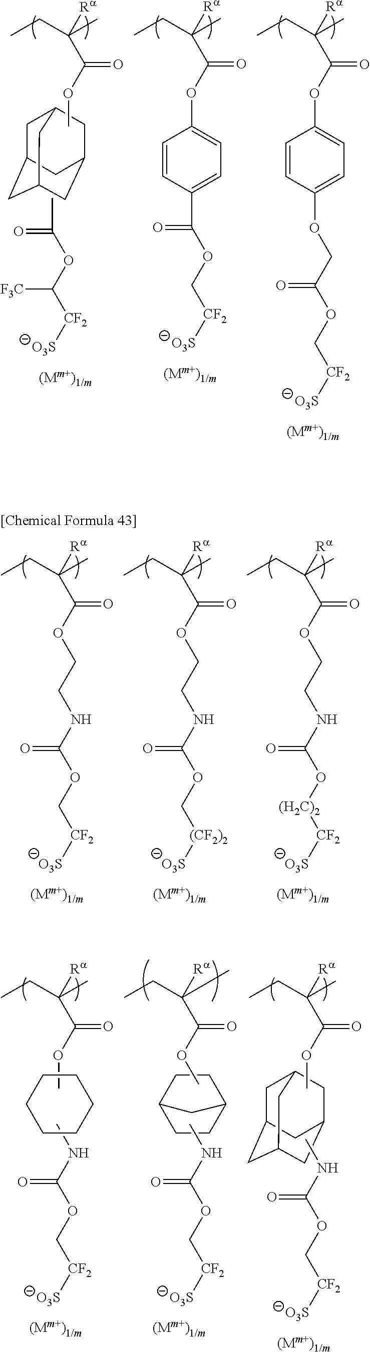

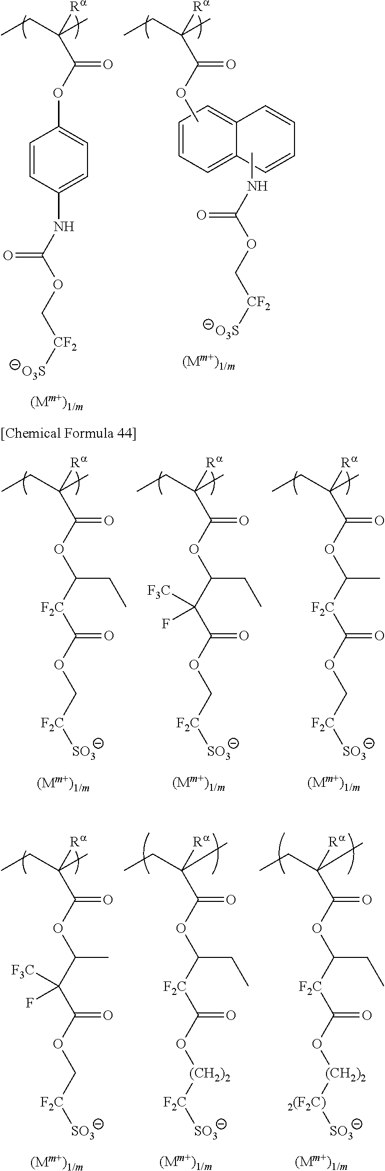

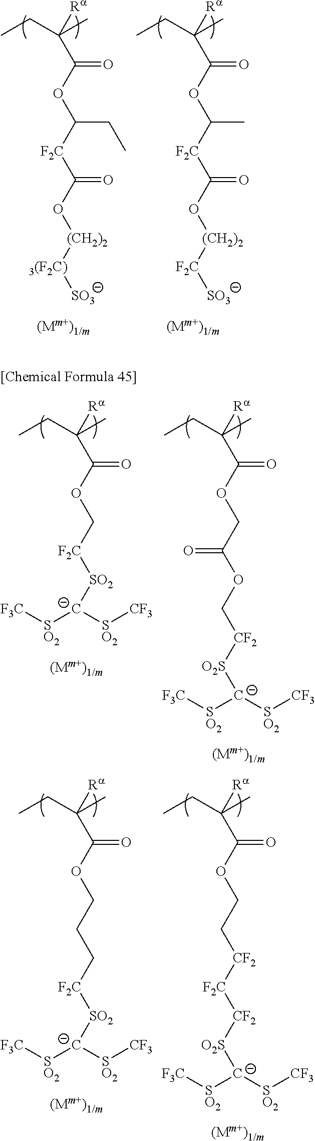

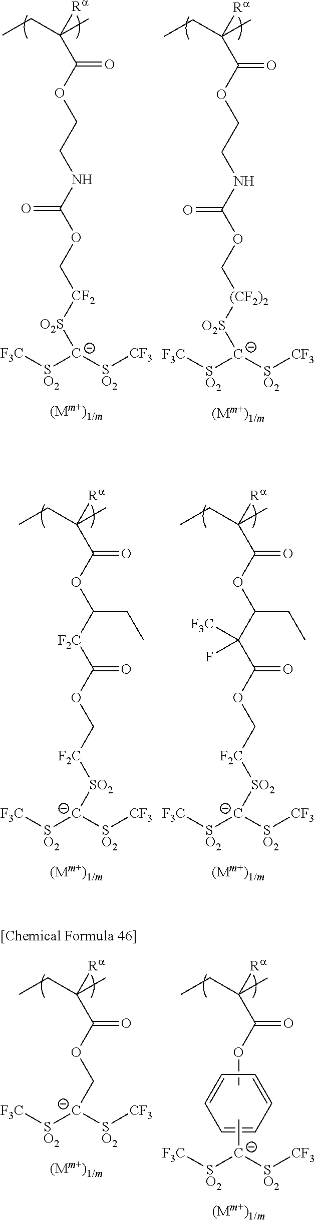

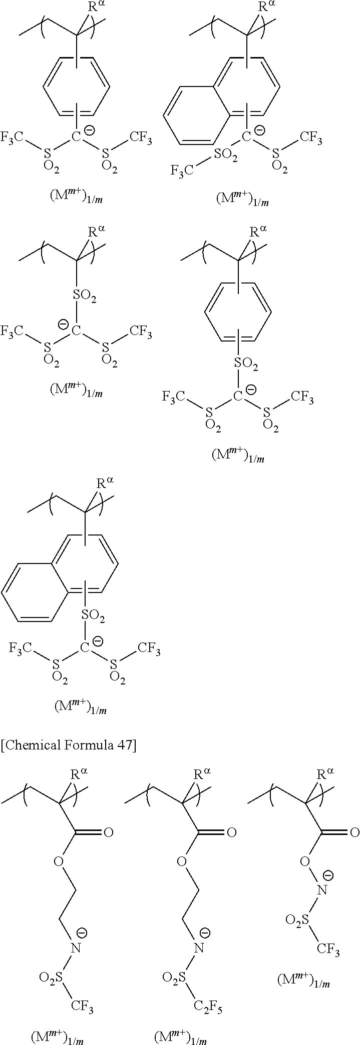

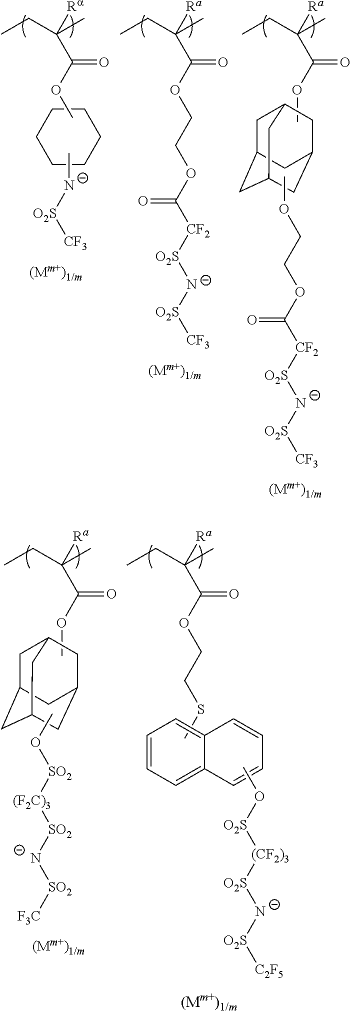

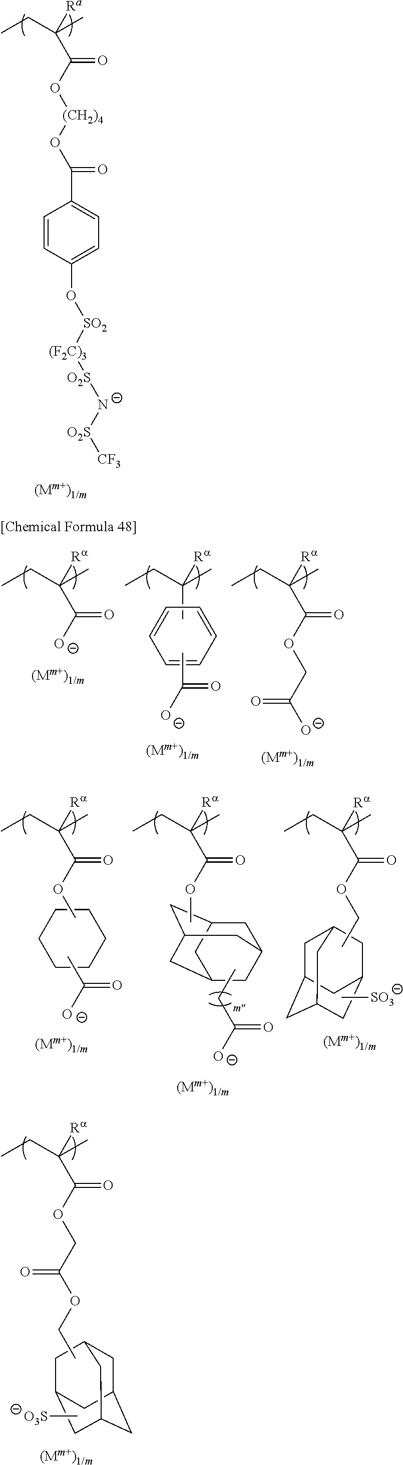

As the structural unit (a5) contained in the polymer of the first aspect of the present invention, 1 type of structural unit may be used, or 2 or more types may be used.

In the polymer of the first aspect of the present invention, the amount of the structural unit (a5) based on the combined total of all structural units constituting the polymer is preferably 1 to 40 mol %, more preferably 1 to 35 mol %, still more preferably 3 to 30 mol %, and particularly preferably 5 to 25 mol %.

When the weight average molecular weight of the polymer is 20,000 or less, the amount of the structural unit (a5) based on the combined total of all structural units constituting the polymer is preferably 1 to 40 mol %, more preferably 1 to 35 mol %, still more preferably 2 to 30 mol %, and particularly preferably 2 to 25 mol %.

When the amount of the structural unit (a5) is at least as large as the lower limit of the above-mentioned range, the effect of using the structural unit (a5) (such as improvement effect in resolution, lithography properties and pattern shape) can be satisfactorily achieved. On the other hand, when the amount of the structural unit (a5) is no more than the upper limit of the above-mentioned range, a good balance can be achieved with the other structural units.

### <Other Structural Units>

<Structural unit (a1)>

In the polymer of the first aspect of the present invention, it is preferable to include a structural unit (a1) containing an acid decomposable group which exhibits increased polarity by the action of acid, in addition to at least one of the structural unit selected from the group consisting of the structural unit (a0), the structural unit (a3) and the structural unit (a5).

The term “acid decomposable group” refers to a group in which at least a part of the bond within the structure thereof is cleaved by the action of acid generated from the anion part on the terminal of the main chain, the structural unit (a5) or the component (B) upon exposure.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H). Among these, a polar group containing —OH in the structure thereof (hereafter, referred to as “OH-containing polar group”) is preferable, a carboxy group or a hydroxy group is more preferable, and a carboxy group is particularly desirable.

Specific examples of an acid decomposable group include a group in which the aforementioned polar group has been protected with an acid dissociable group (such as a group in which the hydrogen atom of the OH-containing polar group has been protected with an acid dissociable group) can be given.

An “acid dissociable group” is a group in which at least the bond between the acid dissociable group and the adjacent carbon atom is cleaved by the action of acid generated from the anion part on the terminal of the main chain, the structural unit (a5) or the component (B) upon exposure. It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group which exhibits a higher polarity than that of the acid dissociable group is generated, thereby increasing the polarity. As a result, the polarity of the entire polymer is increased. When the polarity of the polymer is increased, the solubility of the polymer in a developing solution is relatively changed. When the developing solution is an alkali developing solution, the solubility of the polymer is increased. On the other hand, when the developing solution is a developing solution containing an organic solvent (that is, organic developing solution), the solubility of the polymer is decreased.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxy group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

The term “aliphatic branched” refers to a branched structure having no aromaticity. The “aliphatic branched, acid dissociable group” is not limited to be constituted of only carbon atoms and hydrogen atoms (not limited to hydrocarbon groups), but is preferably a hydrocarbon group. Further, the “hydrocarbon group” may be either saturated or unsaturated, but is preferably saturated.

As an example of the aliphatic branched, acid dissociable group, for example, a group represented by the formula —C(R⁷¹)(R⁷²)(R⁷³) can be given. (in the formula, each of R⁷¹ to R⁷³ independently represents a linear alkyl group of 1 to 5 carbon atoms). The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly desirable.

The term “aliphatic cyclic group” refers to a monocyclic group or polycyclic group that has no aromaticity.

In the “aliphatic cyclic group-containing acid dissociable group”, the “aliphatic cyclic group” may or may not have a substituent. Examples of the substituent include an alkyl group of 1 to 5 carbon atoms, an alkoxyl group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

The aliphatic cyclic group preferably has 3 to 30 carbon atoms, more preferably 5 to 30, still more preferably 5 to 20, particularly preferably 6 to 15, and most preferably 6 to 12. As the monocyclic aliphatic cyclic group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic aliphatic cyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane. In these aliphatic cyclic groups, part of the carbon atoms constituting the ring may be replaced with an ethereal oxygen atom (—O—).

Examples of aliphatic cyclic group-containing acid dissociable groups include

(i) a monovalent aliphatic cyclic group in which a substituent (a group or an atom other than hydrogen) is bonded to the carbon atom on the ring skeleton to which an atom adjacent to the acid dissociable group (e.g., “—O—” within “—C(═O)—O— group”) is bonded to form a tertiary carbon atom; and

(ii) a group which has a branched alkylene group containing a tertiary carbon atom, and a monovalent aliphatic cyclic group to which the tertiary carbon atom is bonded. In the group (i), as the substituent bonded to the carbon atom to which an atom adjacent to the acid dissociable group on the ring skeleton of the aliphatic cyclic group, an alkyl group can be mentioned. Examples of the alkyl group include the same groups as those represented by R¹⁴ in formulas (1-1) to (1-9) described later.

Specific examples of the group (i) include groups represented by general formulas (1-1) to (1-9) shown below.

Specific examples of the group (ii) include groups represented by general formulas (2-1) to (2-6) shown below.

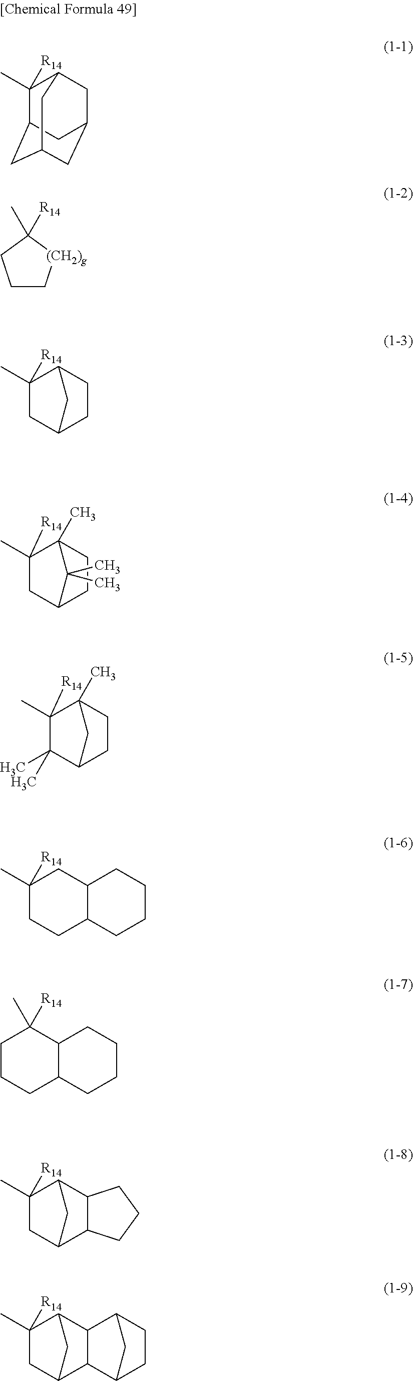

In the formulas above, R¹⁴ represents an alkyl group; and g represents an integer of 0 to 8.

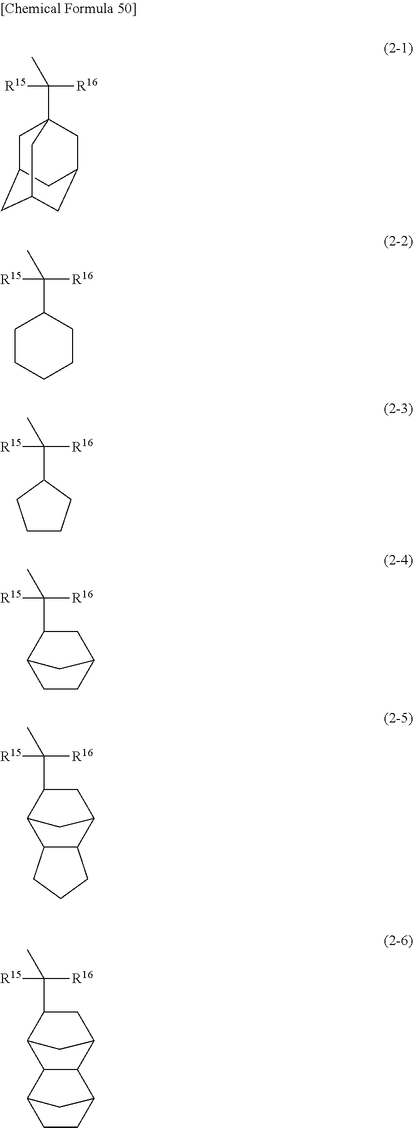

In the formulas above, each of R¹⁵ and R¹⁶ independently represents an alkyl group.

In formulas (1-1) to (1-9), the alkyl group for R¹⁴ may be linear, branched or cyclic, and is preferably linear or branched.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is most desirable.

g is preferably an integer of 0 to 3, more preferably 1 to 3, and still more preferably 1 or 2.

In formulas (2-1) to (2-6), as the alkyl group for R¹⁵ and R¹⁶, the same alkyl groups as those for R¹⁴ can be used.

In formulas (1-1) to (1-9) and (2-1) to (2-6), part of the carbon atoms constituting the ring may be replaced with an ethereal oxygen atom (—O—).

Further, in formulas (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxy group or hydroxy group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxy group or a hydroxy group.

Examples of acetal-type acid dissociable groups include groups represented by general formula (p1) shown below.

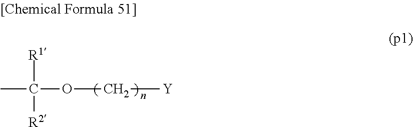

In the formula, R¹′ and R²²′ each independently represent a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1), n is preferably an integer of 0 to 2, more preferably 0 or 1, and most preferably 0.

As the alkyl group for R¹′ and R²′, the same alkyl groups as those described above the alkyl groups as the substituent on the α-position of the aforementioned alkylester can be used, although a methyl group or ethyl group is preferable, and a methyl group is particularly desirable.

In the present invention, it is preferable that at least one of R¹ and R²′ be a hydrogen atom. That is, it is preferable that the acid dissociable group (p1) is a group represented by general formula (p1-1) shown below.

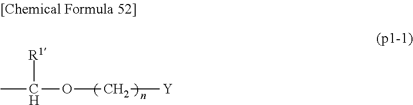

In the formula, R^{h}, n and Y are the same as defined above.

As the alkyl group for Y, the same alkyl groups as those described above for the substituent which may be bonded to the carbon atom on the α-position of the aforementioned alkylester can be mentioned.

As the aliphatic cyclic group for Y, any of the aliphatic monocyclic/polycyclic groups which have been proposed for conventional ArF resists and the like can be appropriately selected for use. For example, the same aliphatic cyclic groups described above in connection with the “acid dissociable group containing an aliphatic cyclic group” can be used.

Further, as the acetal-type, acid dissociable group, groups represented by general formula (p2) shown below can also be used.

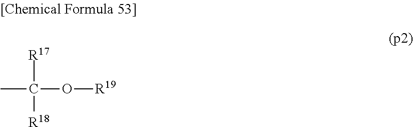

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the R¹⁷ group is bonded to the R¹⁹ group to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, the same aliphatic cyclic group as those described above, such as groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and the R¹⁹ group may be bonded to the R¹⁷ group.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4 to 7-membered ring, and more preferably a 4 to 6-membered ring. Specific examples of the cyclic group include tetrahydropyranyl group and tetrahydrofuranyl group.

In the polymer of the first aspect of the present invention, examples of the structural unit (a1) include a structural unit (a11) which derived from an acrylate ester which may have the hydrogen atom bonded to the carbon atom on the α-position substituted with a substituent and contains an acid decomposable group which exhibits increased polarity by the action of acid, a structural unit (a12) in which at least part of the hydrogen atoms of the hydroxy group in a structural unit derived from a hydroxystyrene or derivative thereof is protected with a substituent containing an acid decomposable group, and a structural unit (a13) in which at least part of the hydrogen atom of —C(═O)—OH in a structural unit derived from a vinylbenzoic acid or derivative thereof is protected with a substituent containing an acid decomposable group.

In the present descriptions and claims, the term “structural unit derived from an acrylate ester” refers to a structural unit which is formed by cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

An “acrylate ester” refers to an acrylate ester having a hydrogen atom bonded to the carbon atom on the α position. The substituent bonded to the carbon atom on the α-position is a group or atom other than a hydrogen atom. Examples of the substituent bonded to the carbon atom on the α-position include an alkyl group of 1 to 5 carbon atoms, a halogenated alkyl group of 1 to 5 carbon atoms and a hydroxyalkyl group of 1 to 5 carbon atoms. A carbon atom on the α-position of an acrylate ester refers to the carbon atom bonded to the carbonyl group, unless specified otherwise.

In the present specification, an acrylate ester in which the hydrogen atom bonded to the carbon atom on the α position has been substituted with a substituent is referred to as an “α-substituted acrylate ester”. Further, acrylate esters and α-substituted acrylate esters are collectively referred to as “(α-substituted) acrylate ester”.

As the alkyl group for the substituent at the α-position in the α-substituted acrylate ester, a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group at the α-position include groups in which part or all of the hydrogen atoms of the aforementioned alkyl group for the substituent at the α-position are substituted with halogen atoms. Examples of the halogen atom include a fluorine atom, a chlorine atom, a bromine atom and an iodine atom, and a fluorine atom is particularly preferred.

Specific examples of the hydroxy alkyl group for the substituent at the α-position include groups in which part or all of the hydrogen atoms of the aforementioned “alkyl group for the substituent at the α-position” are substituted with hydroxy group.

It is preferable that a hydrogen atom, an alkyl group of 1 to 5 carbon atoms or a halogenated alkyl group of 1 to 5 carbon atoms is bonded to the α-position of the acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

A “structural unit derived from a hydroxystyrene or hydroxystyrene derivatives” refers to a structural unit that is formed by the cleavage of the ethylenic double bond of a hydroxystyrene or derivative thereof.

The term “hydroxystyrene derivatives” includes compounds in which the hydrogen atom at the α-position of a hydroxystyrene has been substituted with a substituent such as an alkyl group and a halogenated alkyl group, and includes derivatives thereof. A carbon atom on the α-position refers to the carbon atom bonded to the benzene ring, unless specified otherwise.

A “structural unit derived from a vinylbenzoic acid or vinylbenzoic acid derivatives” refers to a structural unit that is formed by the cleavage of the ethylenic double bond of a vinylbenzoic acid or derivative thereof.

The term “vinylbenzoic acid derivatives” includes compounds in which the hydrogen atom at the α-position of a vinylbenzoic acid has been substituted with a substituent such as an alkyl group and a halogenated alkyl group, and includes derivatives thereof. A carbon atom on the α-position refers to the carbon atom bonded to the benzene ring, unless specified otherwise.
Structural Unit (a11)

Specific examples of the structural unit (a11) include a structural unit represented by general formula (a11-0-1) shown below and a structural unit represented by general formula (a11-0-2) shown below.

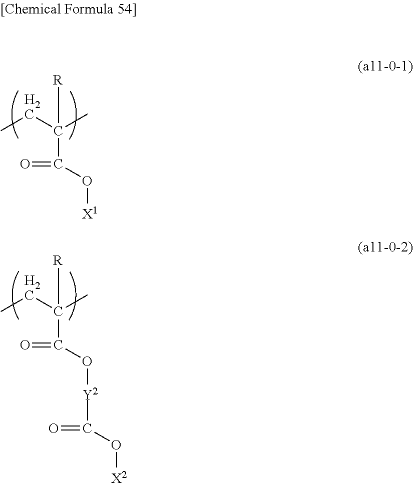

In the formulas, R represents a hydrogen atom, an alkyl group of 1 to 5 carbon atoms or a halogenated alkyl group of 1 to 5 carbon atoms; X¹ represents an acid dissociable group; Y² represents a divalent linking group; and X² represents an acid dissociable group.

In general formula (a11-0-1), the alkyl group and the halogenated alkyl group for R are respectively the same as defined for the alkyl group and the halogenated alkyl group for the substituent which may be bonded to the carbon atom on the α-position of the aforementioned α-substituted acrylate ester. R is preferably a hydrogen atom, an alkyl group of 1 to 5 carbon atoms or a fluorinated alkyl group of 1 to 5 carbon atoms, and most preferably a hydrogen atom or a methyl group.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a11-0-2), R is the same as defined above.

X² is the same as defined for X¹ in general formula (a11-0-1).

The divalent linking group for Y² is not particularly limited, and preferable examples thereof include a divalent hydrocarbon group which may have a substituent and a divalent linking group containing a hetero atom.

A hydrocarbon “has a substituent” means that part or all of the hydrogen atoms within the hydrocarbon group is substituted with a substituent (a group or an atom other than hydrogen).

The hydrocarbon group may be either an aliphatic hydrocarbon group or an aromatic hydrocarbon group.

An “aliphatic hydrocarbon group” refers to a hydrocarbon group that has no aromaticity.

The divalent aliphatic hydrocarbon group as the divalent hydrocarbon group for R² may be either saturated or unsaturated. In general, the divalent aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include the same linear or branched alkylene group as those described for X in the formula (I-1).

As the branched aliphatic hydrocarbon group, a branched alkylene group is preferable, and specific examples include the same branched alkylene group as those described for X in the formula (I-1).

The linear or branched aliphatic hydrocarbon group may or may not have a substituent. Examples of the substituent include a fluorine atom, a fluorinated alkyl group of 1 to 5 carbon atoms and an oxygen atom (═O).

The aliphatic hydrocarbon group containing a ring in the structure thereof is the same aliphatic hydrocarbon group containing a ring in the structure thereof as those described above for X in the formula (I-1). Among these, a group in which two hydrogen atoms have been removed from cyclopentane, cyclohexane, adamantane or norbornane is preferable.

The aromatic hydrocarbon group is a hydrocarbon group having an aromatic ring.

Examples of the aromatic hydrocarbon group as a divalent hydrocarbon group for Y² include the same divalent aromatic hydrocarbon group as those described above for X in the formula (I-1).

With respect to a “divalent linking group containing a hetero atom” for Y², a hetero atom is an atom other than carbon and hydrogen, and examples thereof include an oxygen atom, a nitrogen atom, a sulfur atom and a halogen atom.

As the divalent linking group containing a hetero atom, the same divalent linking group containing a hetero atom as those described for X in the formula (I-1) is preferable, and a group represented by the aforementioned formula —(CH₂)_{a′}—C(═O)—O—(CH₂)_{b′}— is more preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group for Y², a linear or branched alkylene group, a divalent alicyclic hydrocarbon group or a divalent linking group containing a hetero atom is particularly desirable. Among these, a linear or branched alkylene group or a divalent linking group containing a hetero atom is more preferable.

Specific examples of the structural unit (a11) include structural units represented by general formulas (a1-1) to (a1-4) shown below.

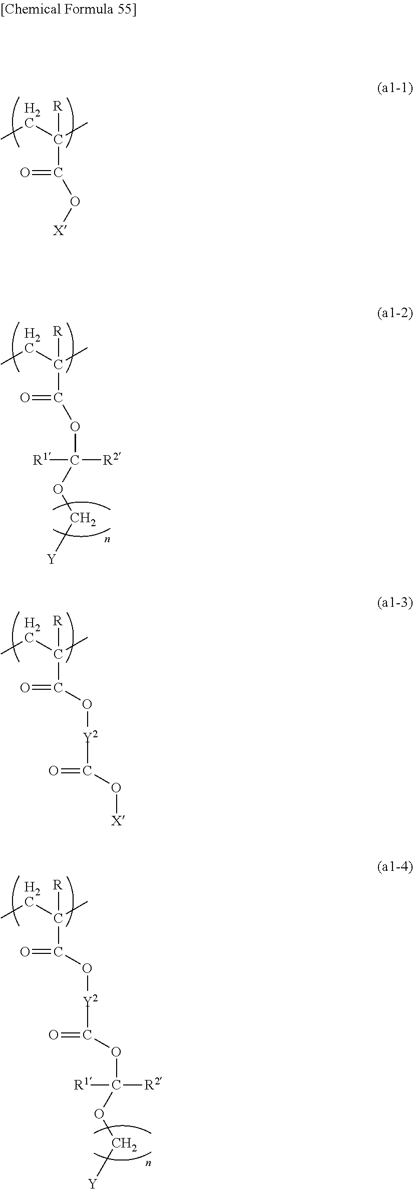

In the formulas, R, R¹′, R²′, n, Y and Y² are the same as defined above; and X′ represents a tertiary alkyl ester-type acid dissociable group.

In the formulas, the tertiary alkyl ester-type acid dissociable group for X′ include the same tertiary alkyl ester-type acid dissociable groups as those described above.

As R¹′, R²′, n and Y are respectively the same as defined for R¹′, R²′, n and Y in general formula (p1) described above in connection with the “acetal-type acid dissociable group”.

Y² is the same as defined for Y² in general formula (a11-0-2).

Specific examples of structural units represented by general formulas (a1-1) to (a1-4) are shown below.

In the formulas shown below, R^{α} represents a hydrogen atom, a methyl group or a trifluoromethyl group.

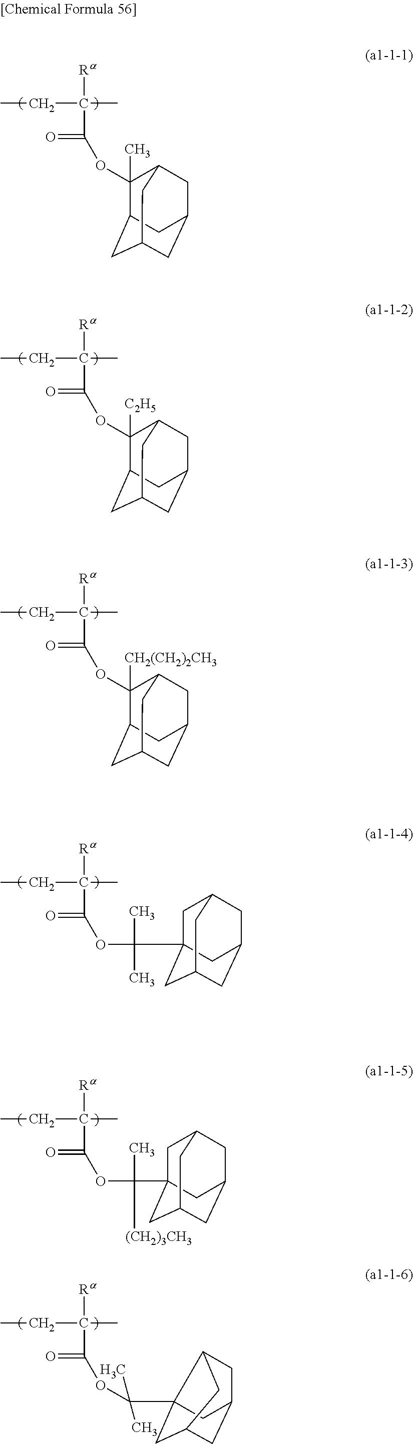

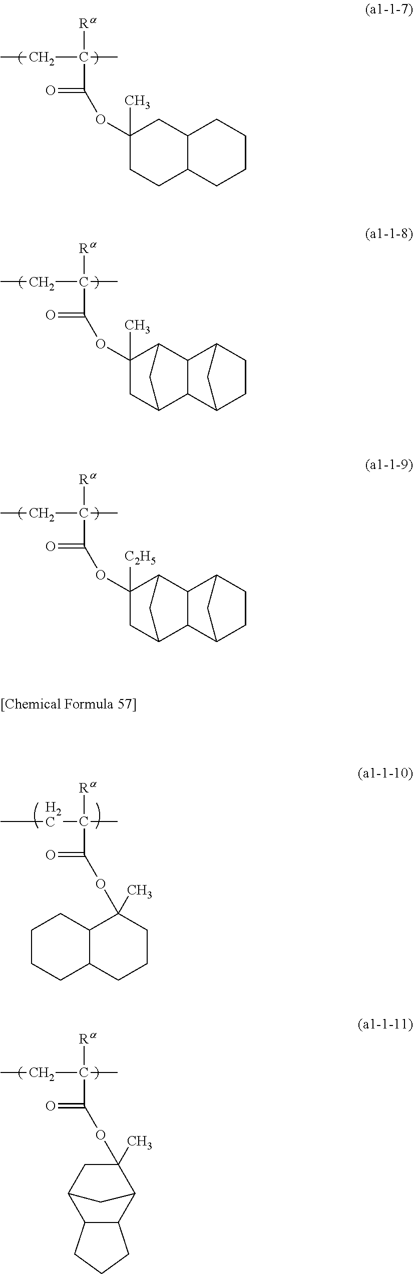

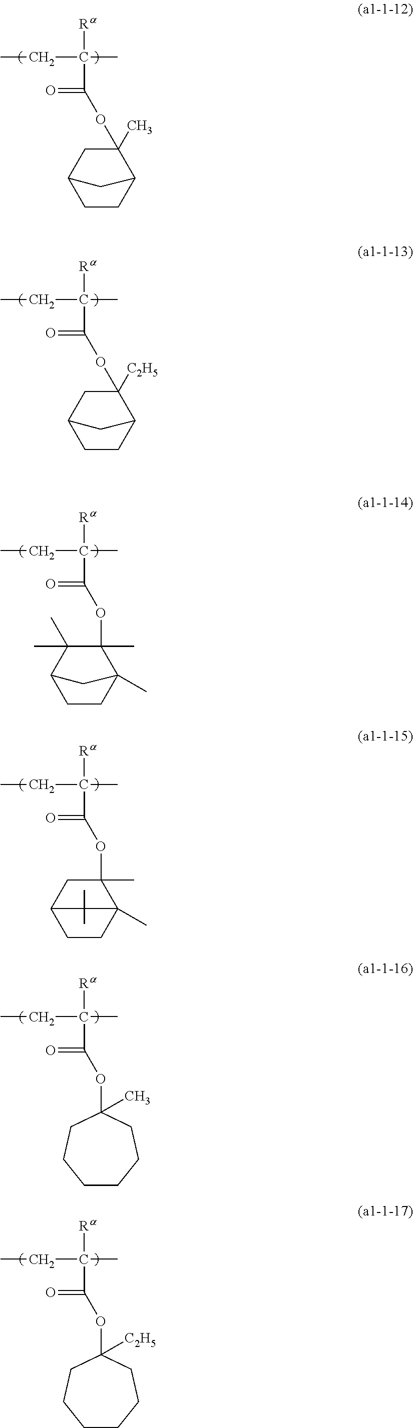

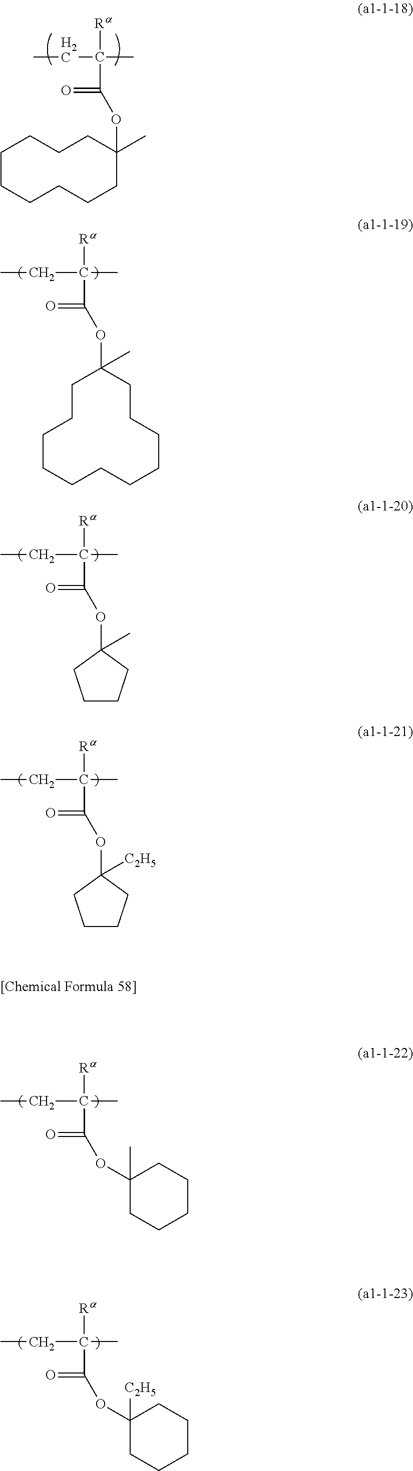

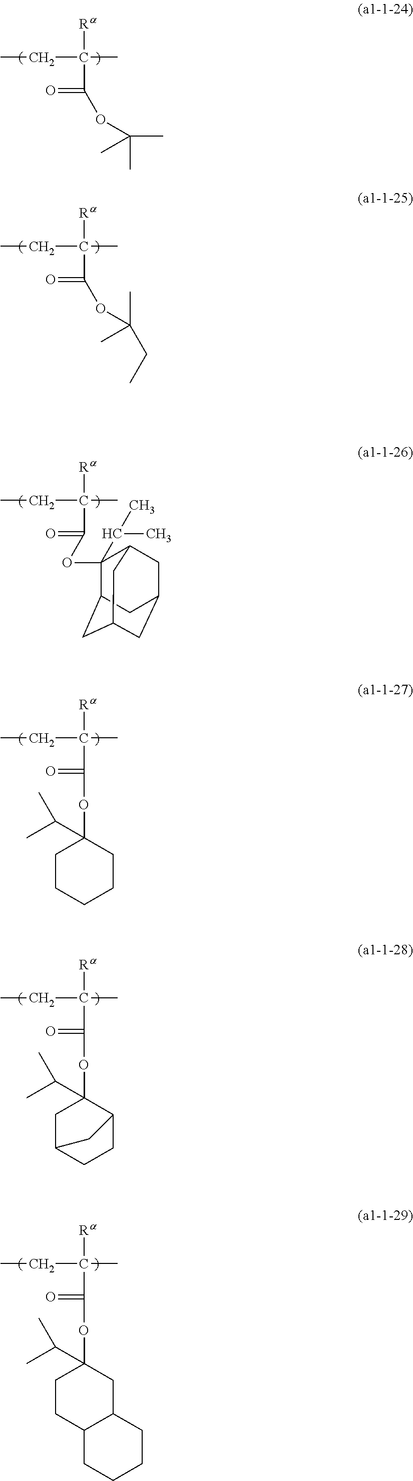

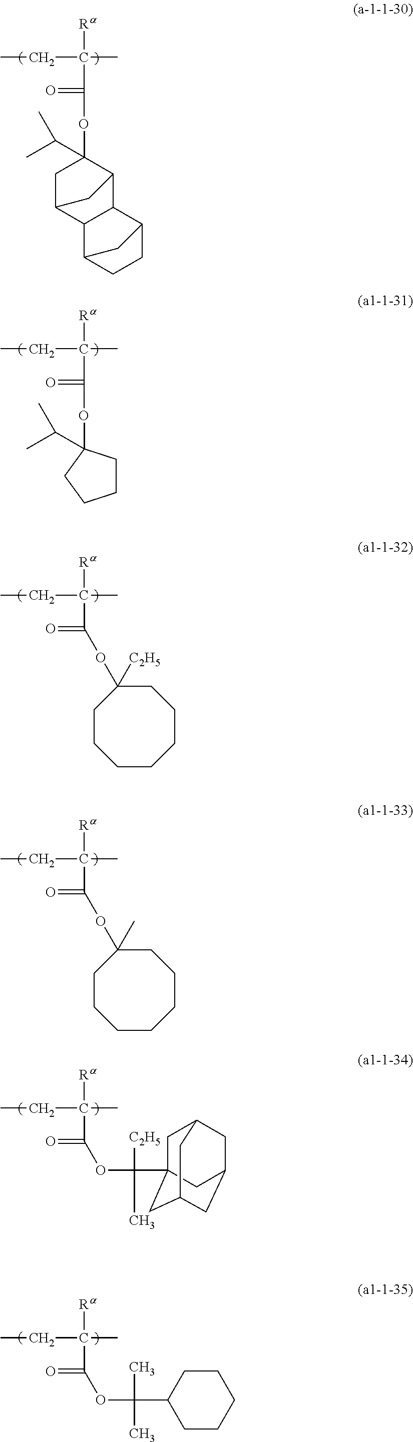

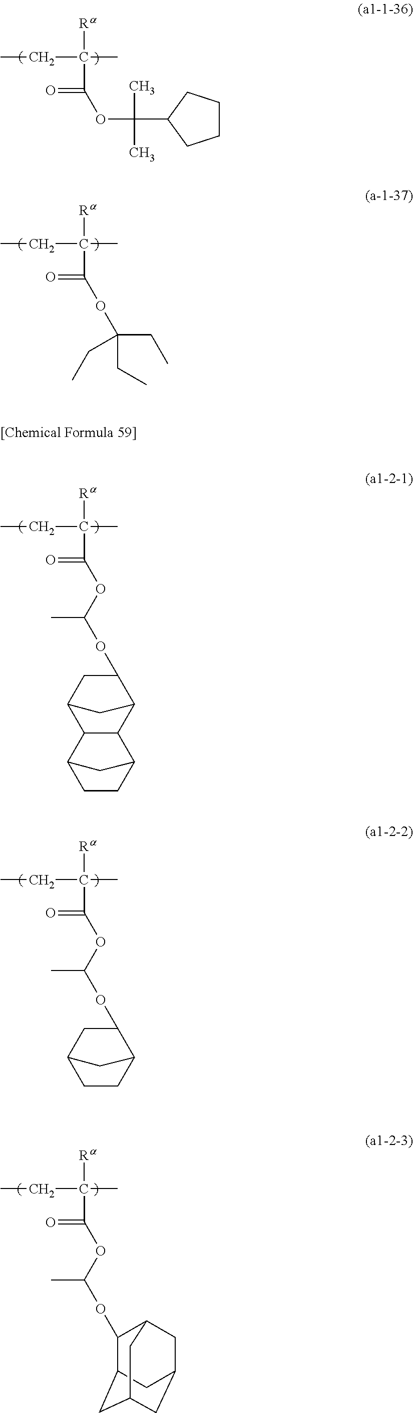

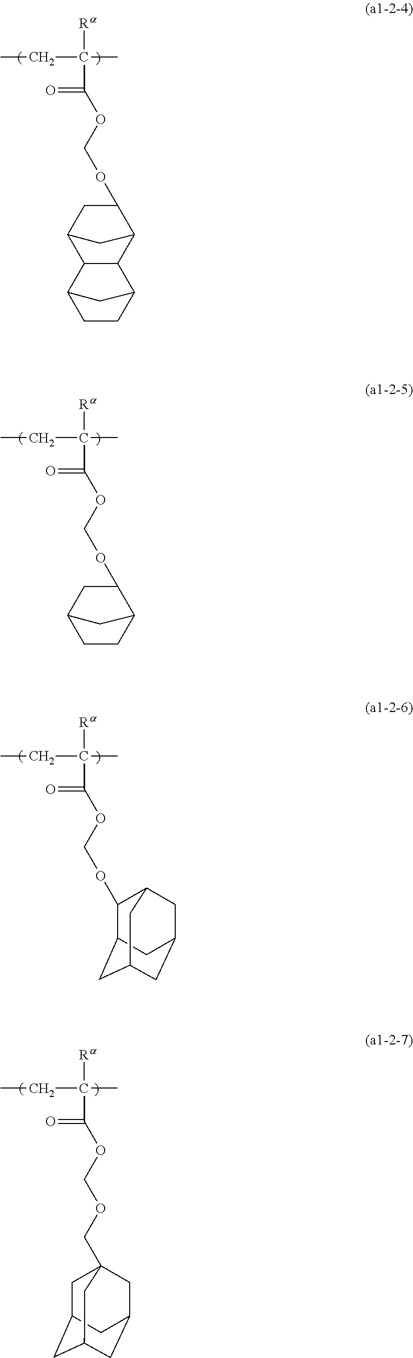

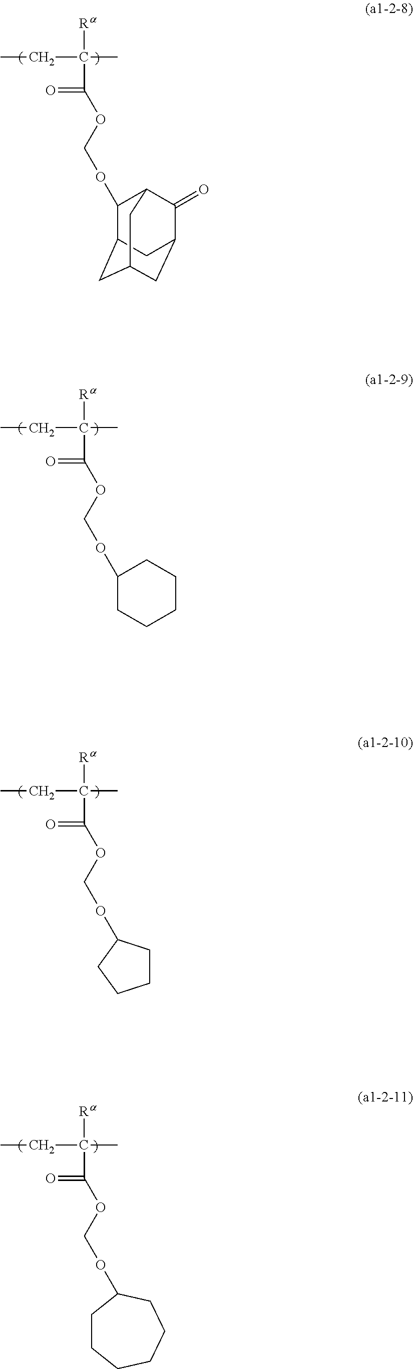

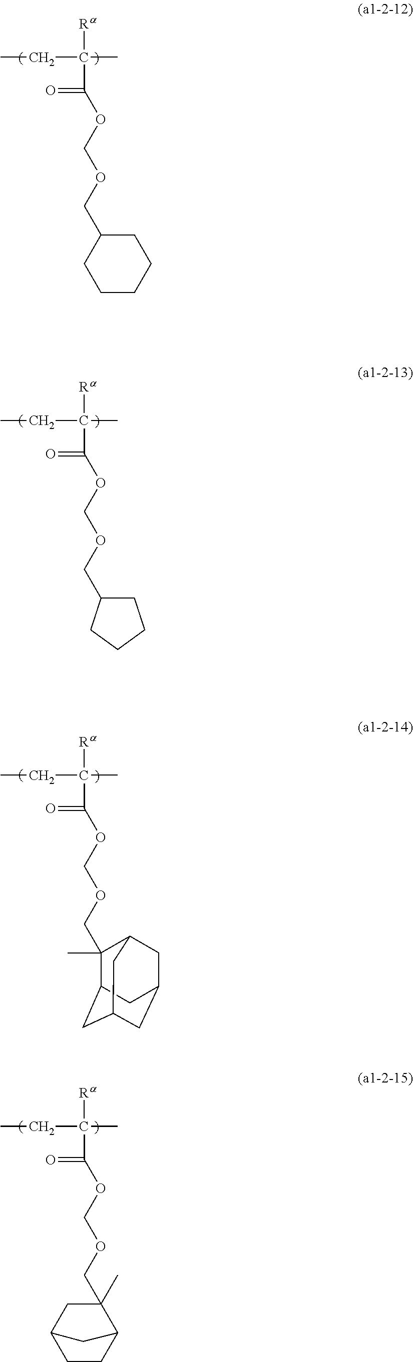

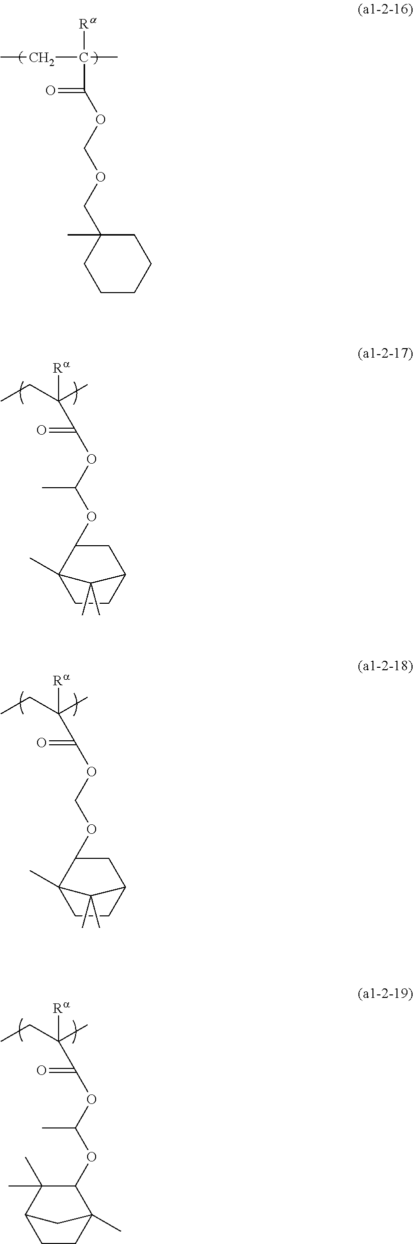

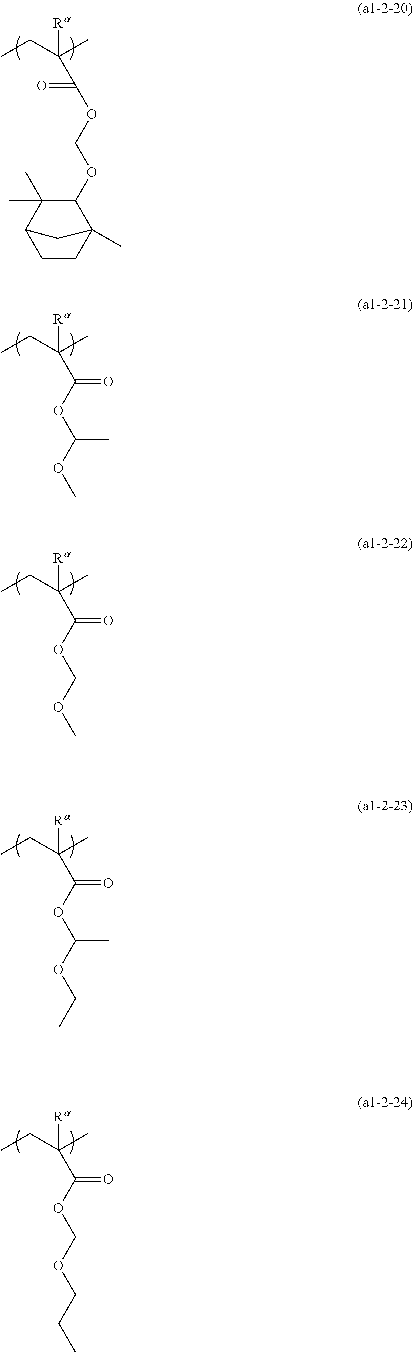

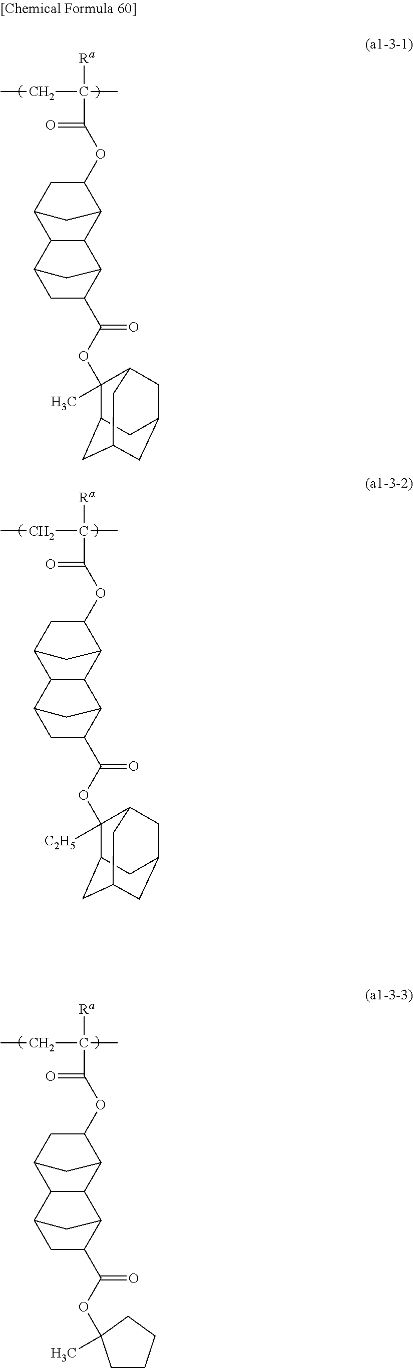

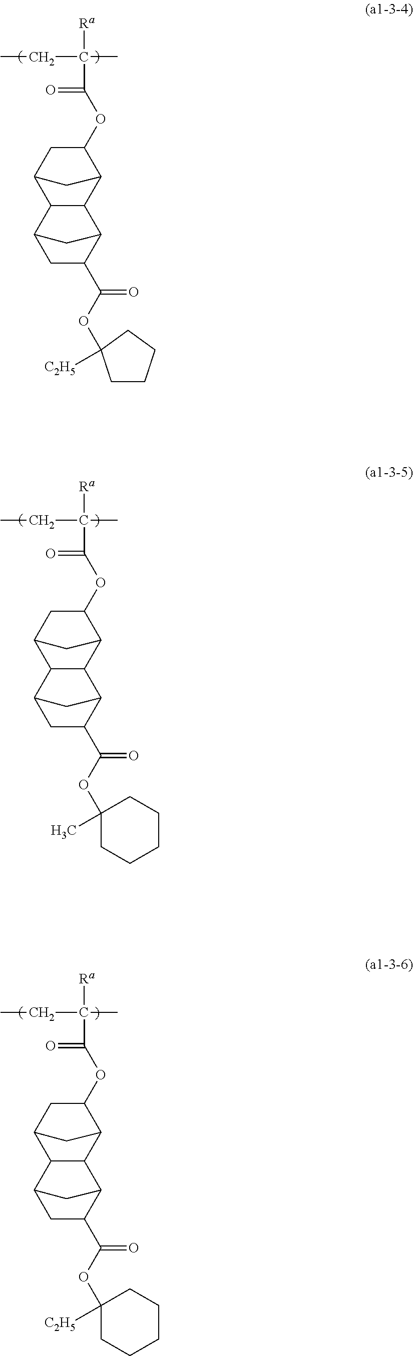

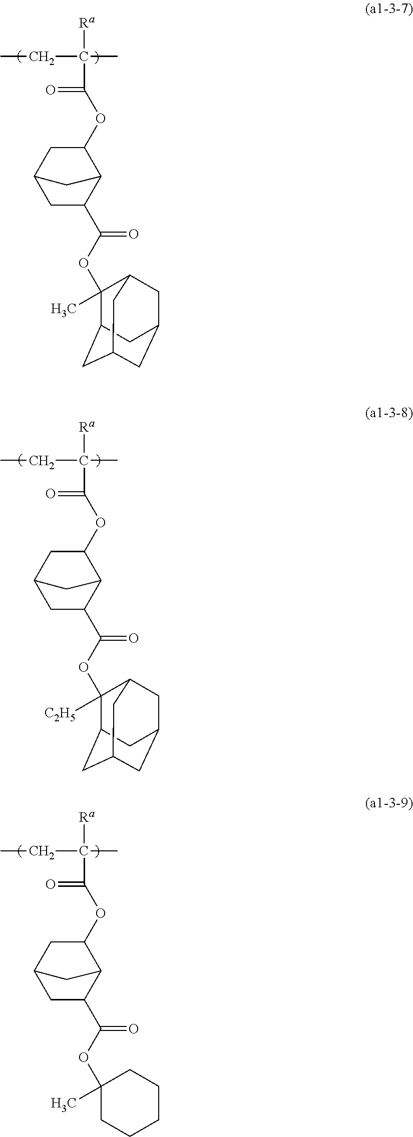

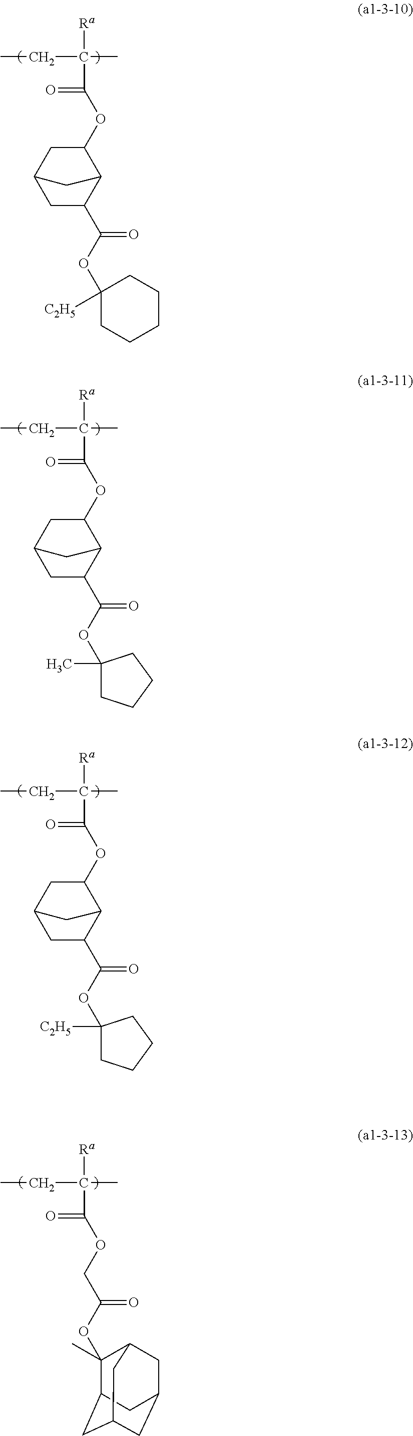

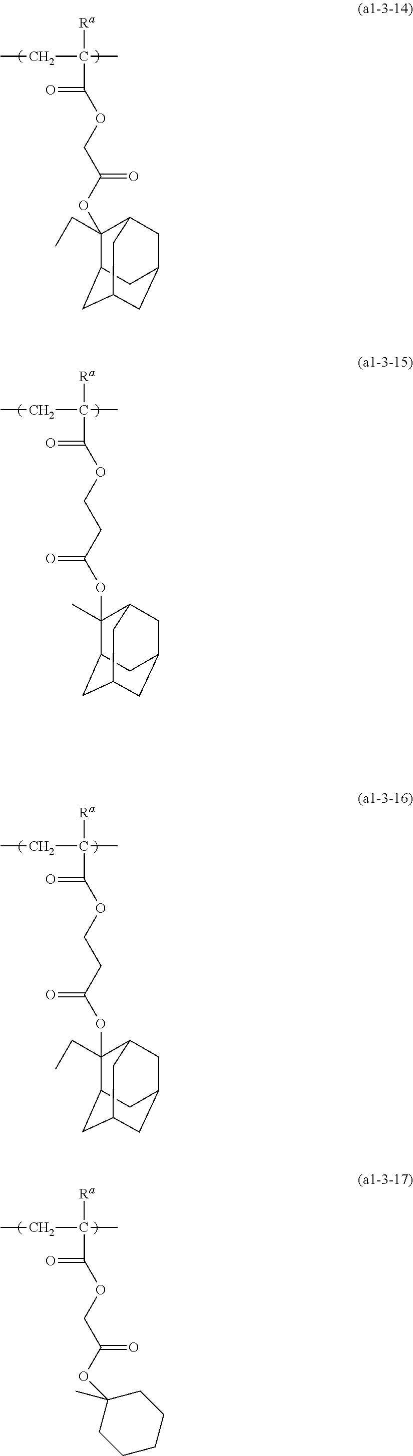

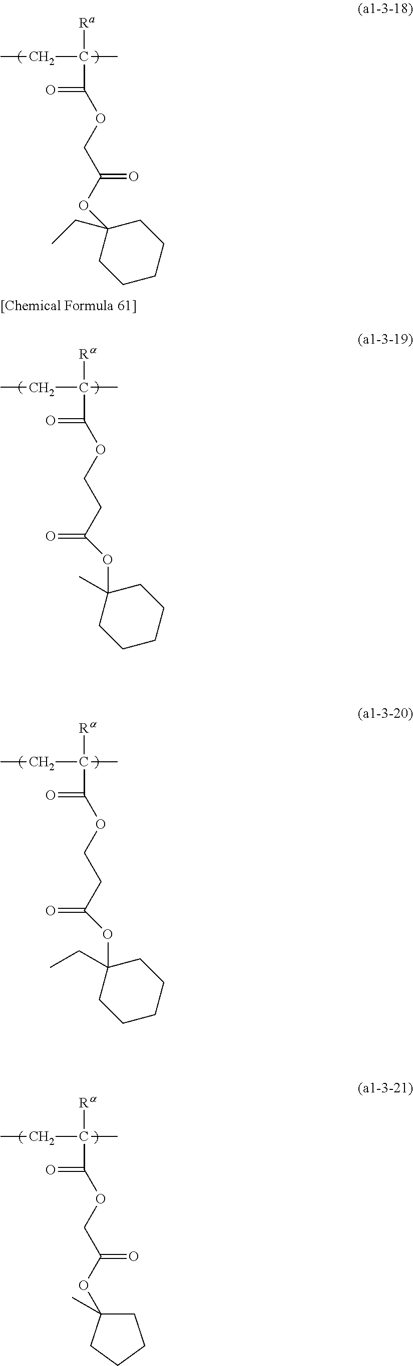

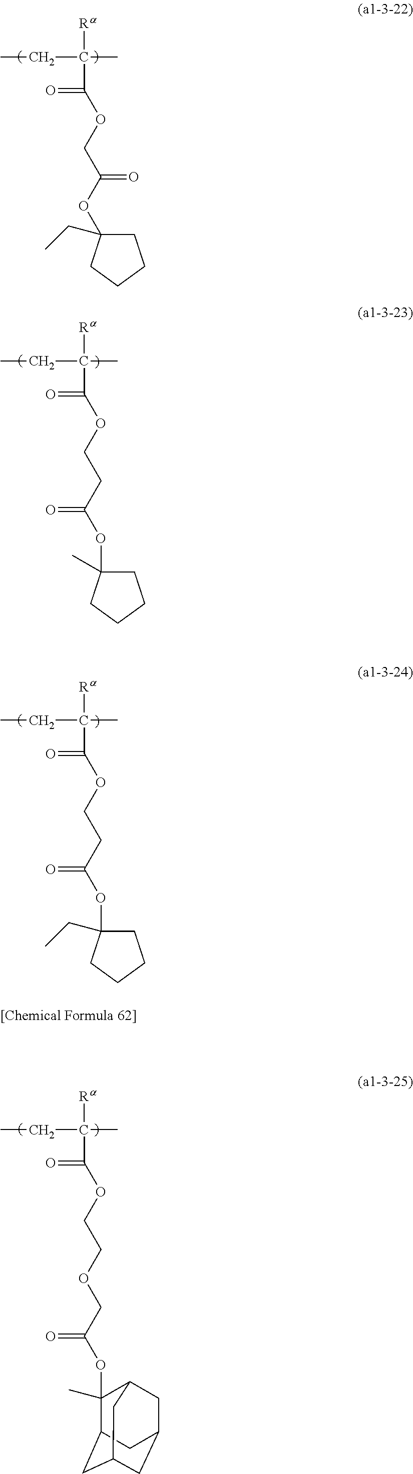

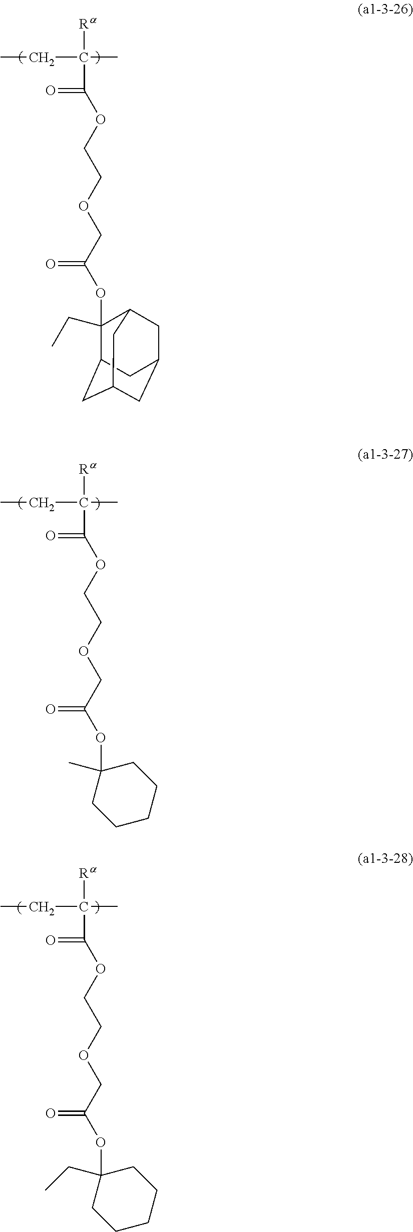

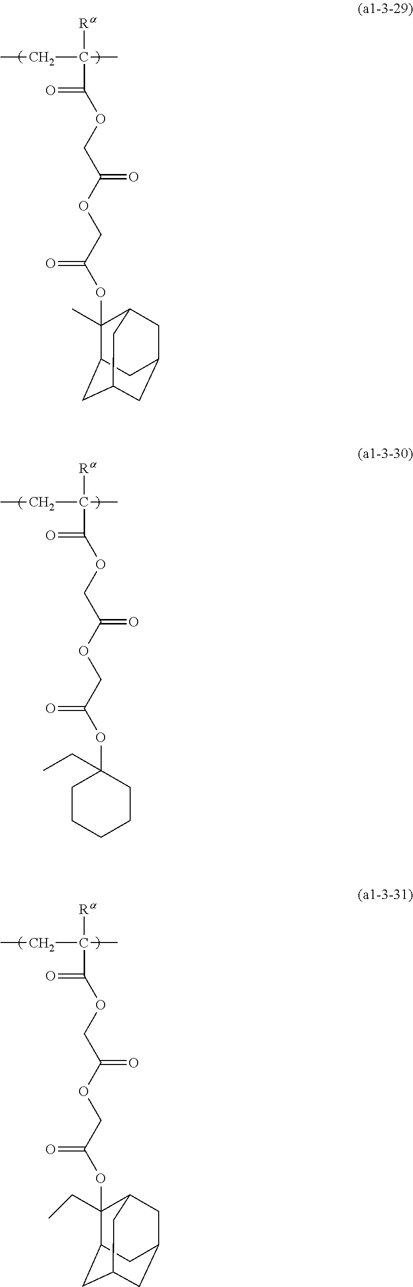

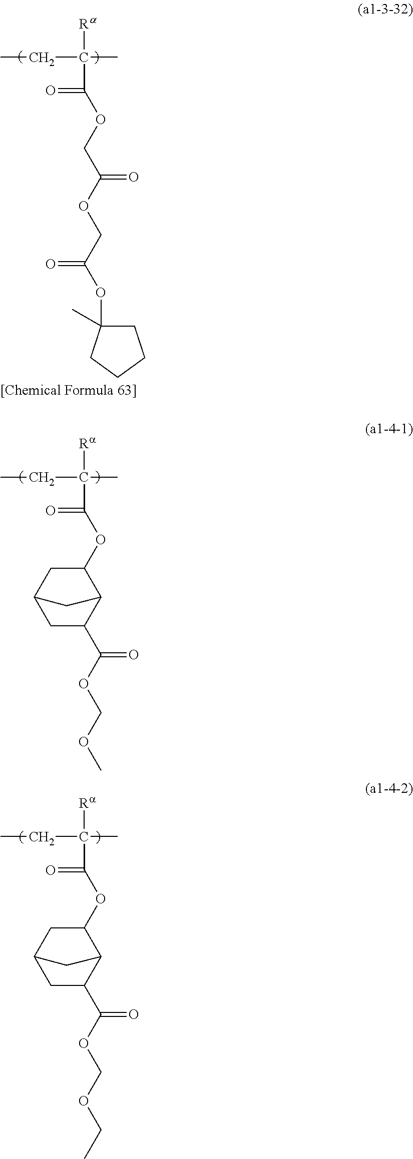

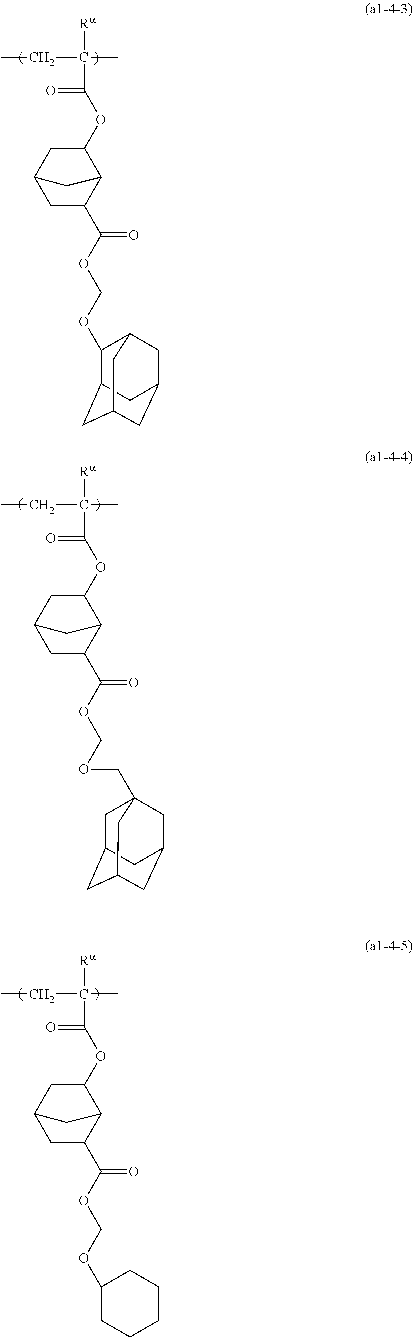

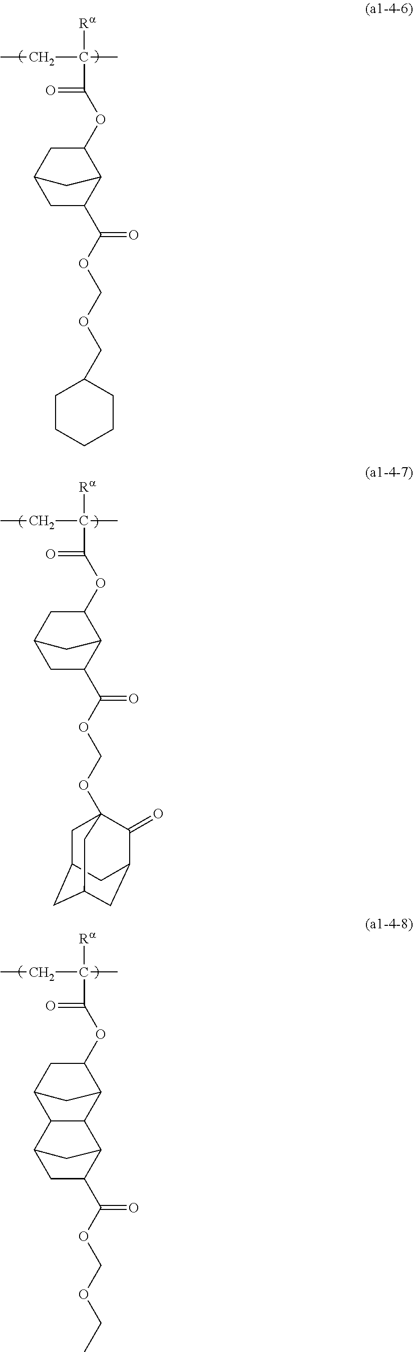

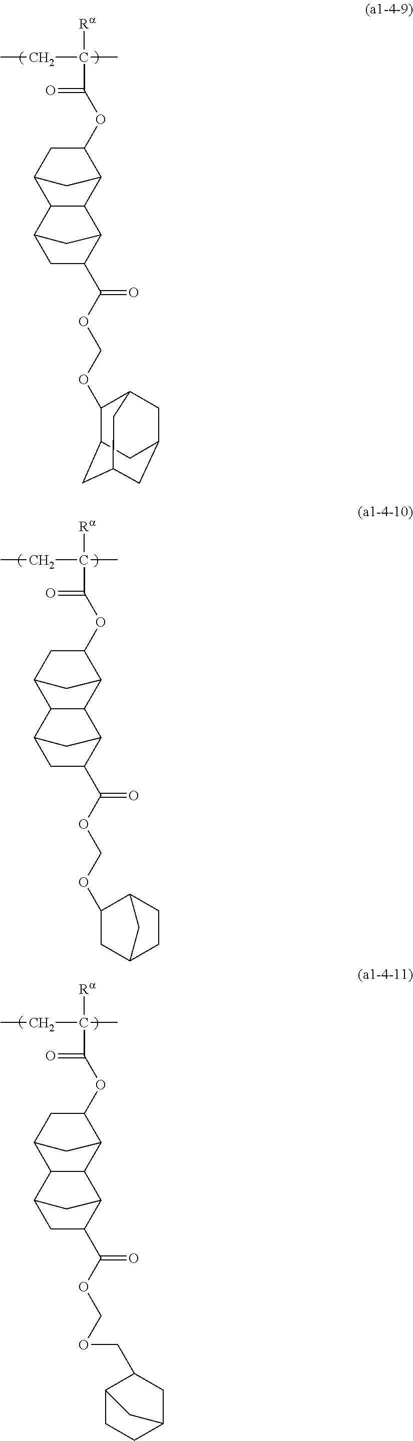

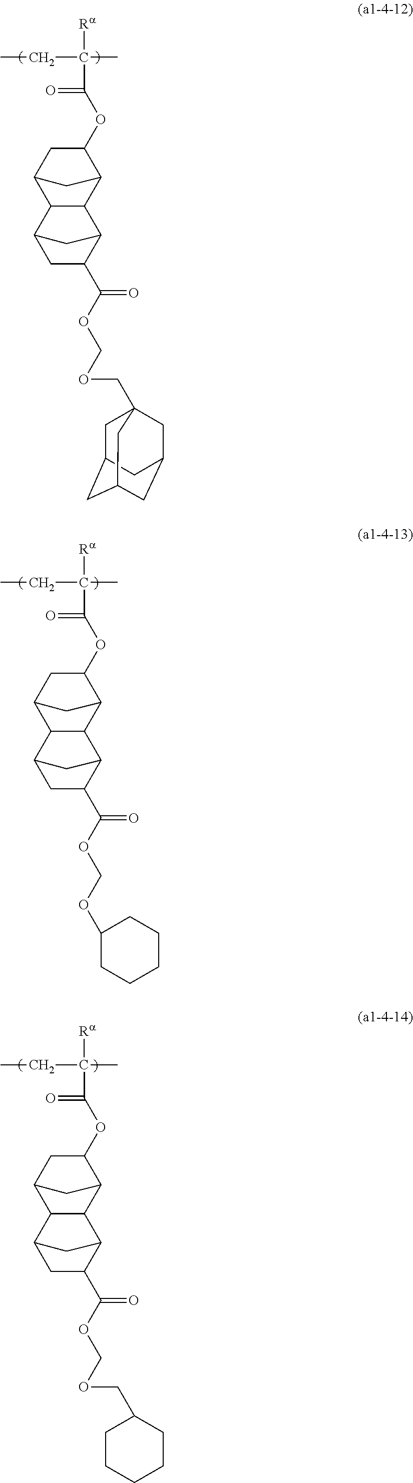

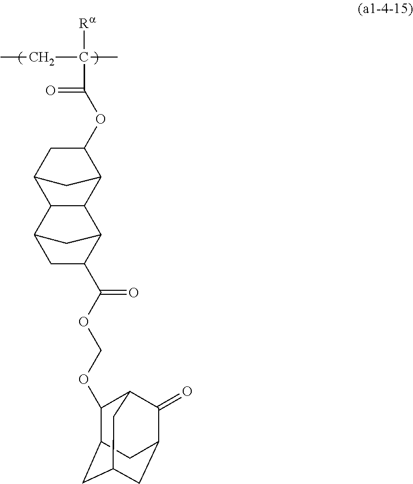

In the present invention, as the structural unit (a11), it is preferable to include at least one structural unit selected from the group consisting of a structural unit represented by general formula (a11-0-11) shown below, a structural unit represented by general formula (a11-0-12) shown below, a structural unit represented by general formula (a11-0-13) shown below, a structural unit represented by general formula (a11-0-14) shown below, a structural unit represented by general formula (a11-0-15) shown below and a structural unit represented by general formula (a11-0-2) shown below.

Among these, it is more preferable to include at least one structural unit selected from the group consisting of a structural unit represented by general formula (a11-0-11) shown below, a structural unit represented by general formula (a11-0-12) shown below, a structural unit represented by general formula (a11-0-13) shown below, a structural unit represented by general formula (a11-0-14) shown below and a structural unit represented by general formula (a11-0-15) shown below.

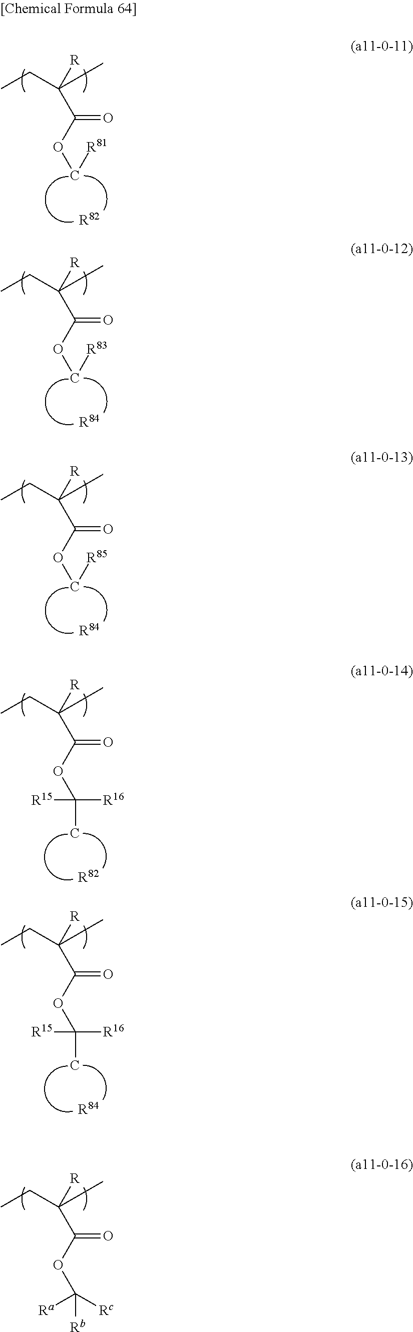

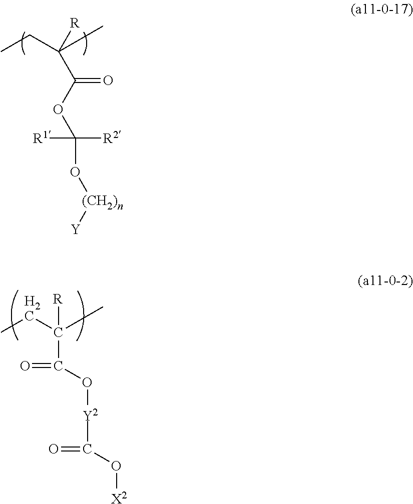

In the formulas, R represents a hydrogen atom, an alkyl group of 1 to 5 carbon atoms or a halogenated alkyl group of 1 to 5 carbon atoms; R⁸¹ represents an alkyl group; R⁸² represents a group which forms an aliphatic monocyclic group with the carbon atom to which R⁸² is bonded; R⁸³ represents a branched alkyl group; R⁸⁴ represents a group which forms an aliphatic polycyclic group with the carbon atom to which R⁸⁴ is bonded; R⁸⁵ represents a linear alkyl group of 1 to 5 carbon atoms; each of R¹⁵ and R¹⁶ independently represents an alkyl group; each of Ra, Rb and Rc represents an alkyl group of 1 to 5 carbon atoms; R¹′ and R²′ each independently represent a hydrogen atom or an alkyl group of 1 to 5 carbon atoms; n represents an integer of 0 to 3; and Y represents an alkyl group of 1 to 5 carbon atoms or an aliphatic cyclic group. Y² represents a divalent linking group; and X² represents an acid dissociable group.

In the formulas, R, Y² and X² are the same as defined above.

In general formula (a11-0-11), as the alkyl group for R⁸¹, the same alkyl groups as those described above for R¹⁴ in formulas (1-1) to (1-9) can be used, a methyl group, an ethyl group or an isopropyl group is preferable.

As the aliphatic monocyclic group formed by R⁸² and the carbon atoms to which R⁸² is bonded, the same aliphatic cyclic groups as those described above for the aforementioned tertiary alkyl ester-type acid dissociable group and which are monocyclic can be used. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and particularly preferably a 5- or 6-membered ring.

The monocycloalkane may or may not have part of the carbon atoms constituting the ring replaced with an ether bond (—O—).

Further, the monocycloalkane may have a substituent such as an alkyl group of 1 to 5 carbon atoms, a fluorine atom or a fluorinated alkyl group of 1 to 5 carbon atoms.

As an examples of R⁸² constituting such an aliphatic cyclic group, an alkylene group which may have an ether bond (—O—) interposed between the carbon atoms can be given.

Specific examples of structural units represented by general formula (a11-0-11) include structural units represented by the aforementioned formulas (a1-1-16) to (a1-1-23), (a1-1-27) and (a1-1-31). Among these, a structural unit represented by general formula (a1-1-02) shown below which inclusive the structural units represented by the aforementioned formulas (a1-1-16), (a1-1-17), (a1-1-20) to (a1-1-23), (a1-1-27) and (a1-1-31) is preferable. Further, a structural unit represented by general formula (a11-1-02′) shown below is also preferable.

In the formulas, h represents an integer of 1 to 4, and is preferably 1 or 2.

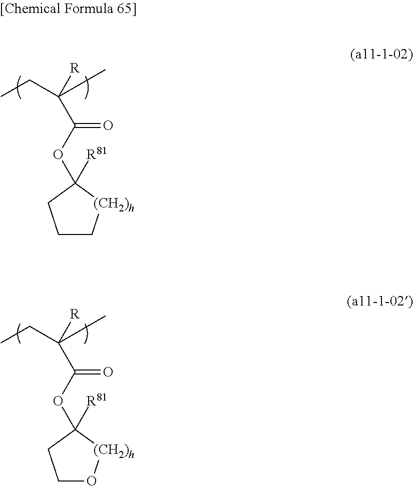

In the formulas, R and R⁸¹ are the same as defined above; and h represents an integer of 1 to 4.

In general formula (a11-0-12), as the branched alkyl group for R⁸³, the same alkyl groups as those described above for R¹⁴ in formulas (1-1) to (1-9) which are branched can be used, and an isopropyl group is particularly desirable.

As the aliphatic polycyclic group formed by R⁸⁴ and the carbon atoms to which R⁸⁴ is bonded, the same aliphatic cyclic groups as those described above for the aforementioned tertiary alkyl ester-type acid dissociable group and which are polycyclic can be used.

Specific examples of structural units represented by general formula (a11-0-12) include structural units represented by the aforementioned formulas (a1-1-26) and (a1-1-28) to (a1-1-30).

As the structural unit (a11-0-12), a structural unit in which the aliphatic polycyclic group formed by R⁸⁴ and the carbon atom to which R⁸⁴ is bonded is a 2-adamantyl group is preferable, and a structural unit represented by the aforementioned formula (a1-1-26) is particularly desirable.

In general formula (a11-0-13), R and R⁸⁴ are the same as defined above.

As the linear alkyl group for R⁸⁵, the same linear alkyl groups as those described above for R¹⁴ in the aforementioned formulas (1-1) to (1-9) can be mentioned, and a methyl group or an ethyl group is particularly desirable.

Specific examples of structural units represented by general formula (a11-0-13) include structural units represented by the aforementioned formulas (a1-1-1) (a1-1-2) and (a1-1-7) to (a1-1-15) which were described above as specific examples of the structural unit represented by general formula (a1-1).

As the structural unit (a11-0-13), a structural unit in which the aliphatic polycyclic group formed by R⁸⁴ and the carbon atom to which R⁸⁴ is bonded is a 2-adamantyl group is preferable, and a structural unit represented by the aforementioned formula (a1-1-1) or (a1-1-2) is particularly desirable.

As the aliphatic polycyclic group formed by R⁸⁴ and the carbon atom to which R⁸⁴ is bonded is preferably a group in which one or more hydrogen atoms have been removed from tetracyclododecane, and a structural unit represented by the aforementioned formulas (a1-1-8), (a1-1-9) or (a1-1-30) is also desirable.

In general formula (a11-0-14), R and R⁸² are the same as defined above. R¹⁵ and R¹⁶ are the same as defined for R¹⁵ and R¹⁶ in the general formulas (2-1) to (2-6).

Specific examples of structural units represented by general formula (a11-0-14) include structural units represented by the aforementioned formulas (a1-1-35) and (a1-1-36) which were described above as specific examples of the structural unit represented by general formula (a1-1).

In general formula (a11-0-15), R and R⁸⁴ are the same as defined above. R¹⁵ and R¹⁶ are the same as defined for R¹⁵ and R¹⁶ in the general formulas (2-1) to (2-6).

Specific examples of structural units represented by general formula (a11-0-15) include structural units represented by the aforementioned formulas (a1-1-4) to (a1-1-6) and (a1-1-34) which were described above as specific examples of the structural unit represented by general formula (a1-1).

In genera formula (a11-0-16), R is the same as defined above.

Each of Ra, Rb and Rc represents an alkyl group of 1 to 5 carbon atoms, and a methyl group or ethyl group is preferable, and all of Ra, Rb and R particularly preferably represent the same groups.

Specific examples of structural units represented by general formula (a11-0-16) include structural units represented by the aforementioned formulas (a1-1-24), (a1-1-25) and (a1-1-37) which were described above as specific examples of the structural unit represented by general formula (a1-1).

In the formula (a11-0-17), R¹′, R²′, n and Y are the same as defined above.

At least one of R¹′ and R²′ is preferably a hydrogen atom, and both of them are particularly preferably hydrogen atoms.

n is preferably 0 or 2, and most preferably 0.

Y is preferably an aliphatic cyclic group, and examples thereof include the aliphatic cyclic group as described in the aliphatic cyclic group-containing acid dissociable group. Among these, a group in which one or more hydrogen atoms have been removed from the polycycloalkane is more preferable.

Examples of structural units represented by general formula (a11-0-2) include structural units represented by the aforementioned formulas (a1-3) and (a1-4), and a structural unit represented by formula (a1-3) is preferable.

As a structural unit represented by general formula (a11-0-2), those in which Y² is a group represented by the aforementioned formula -A-O-B- or -A-C(═O)—O-B- is particularly desirable. Each of A and B independently represents a divalent hydrocarbon group which may have a substituent, and is the same as defined above for A and B.

Preferable examples of such structural units include a structural unit represented by general formula (a1-3-01) shown below, a structural unit represented by general formula (a1-3-02) shown below, and a structural unit represented by general formula (a1-3-03) shown below.

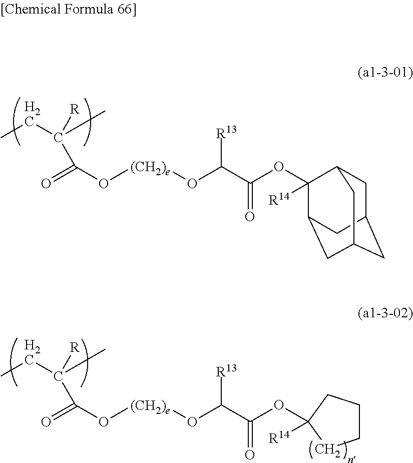

In the formulas, R is the same as defined above; R¹³ represents a hydrogen atom or a methyl group; R¹⁴ represents an alkyl group; e represents an integer of 1 to 10; and n′ represents an integer of 0 to 3.

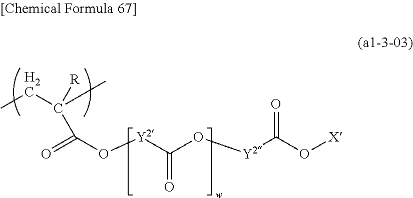

In the formula, R is as defined above; each of Y²′ and Y²″ independently represents a divalent linking group; X′ represents an acid dissociable group; and w represents an integer of 0 to 3.

In general formulas (a1-3-01) and (a1-3-02) R¹³ is preferably a hydrogen atom.

R¹⁴ is the same as defined for R¹⁴ in the aforementioned formulas (1-1) to (1-9).

e is preferably an integer of 1 to 8, more preferably 1 to 5, and most preferably 1 or 2.

n′ is preferably 1 or 2, and most preferably 2.

Specific examples of structural units represented by general formula (a1-3-01) include structural units represented by the aforementioned formulas (a1-3-25) and (a1-3-26).

Specific examples of structural units represented by general formula (a1-3-02) include structural units represented by the aforementioned formulas (a1-3-27) and (a1-3-28).

In general formula (a1-3-03), as the divalent linking group for Y²′ and Y²″, the same groups as those described above for Y² in general formula (a1-3) can be used.

As Y²′, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As Y²″, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As the acid dissociable group for X′, the same groups as those described above can be used. X′ is preferably a tertiary alkyl ester-type acid dissociable group, more preferably the aforementioned group (i) in which a substituent is bonded to the carbon atom to which an atom adjacent to the acid dissociable group is bonded to on the ring skeleton to form a tertiary carbon atom. Among these, a group represented by the aforementioned general formula (1-1) is particularly desirable.

w represents an integer of 0 to 3, preferably an integer of 0 to 2, more preferably 0 or 1, and most preferably 1.

As the structural unit represented by general formula (a1-3-03), a structural unit represented by general formula (a1-3-03-1) or (a1-3-03-2) shown below is preferable, and a structural unit represented by general formula (a1-3-03-1) is particularly desirable.

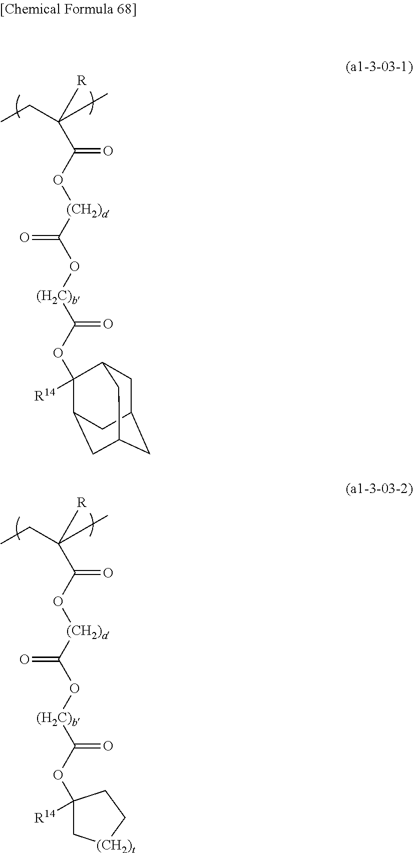

In the formulas, R and R¹⁴ are the same as defined above; a′ represents an integer of 1 to 10; b′ represents an integer of 1 to 10; and t represents an integer of 0 to 3.

In general formulas (a1-3-03-1) and (a1-3-03-2), a′ is the same as defined above, and is preferably an integer of 1 to 8, more preferably 1 to 5, and particularly preferably 1 or 2.

b′ is the same as defined above, m and is preferably an integer of 1 to 8, particularly preferably 1 to 5, and most preferably 1 or 2.

t is preferably an integer of 1 to 3, and most preferably 1 or 2.

Specific examples of structural units represented by general formula (a1-3-03-1) or (a1-3-03-2) include structural units represented by the aforementioned formulas (a1-3-29) to (a1-3-32).

Furthermore, as the structural unit (a11), a structural unit (a1-5) represented by general formula (a1-5) shown below is also preferable. By including the structural unit (a1), the residual film ratio at the exposed portions and the etching resistance can be improved.

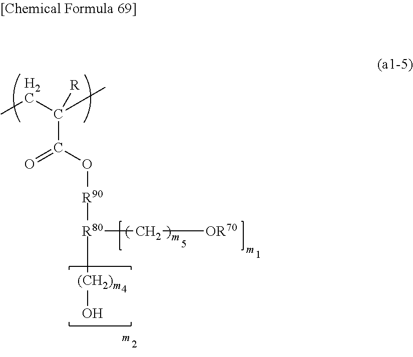

In the formula, R represents a hydrogen atom, an alkyl group of 1 to 5 carbon atoms or a halogenated alkyl group of 1 to 5 carbon atoms; OR⁷⁰ represents an acid decomposable group; R⁸⁰ represents an aliphatic hydrocarbon group which may have a substituent: R⁹⁰ represents a single bond or a divalent linking group; m₁ represents an integer 1 to 3; m₂ represents an integer of 0 to 2, provided that m₁+m₂=1 to 3; and each of m₄ and m₅ independently represents an integer of 0 to 3.

In general formula (a1-5), the alkyl group and the halogenated alkyl group for R are respectively the same as defined for the alkyl group and the halogenated alkyl group for the substituent which may be bonded to the carbon atom on the α-position of the aforementioned substituted acrylate ester.

R is preferably a hydrogen atom, an alkyl group of 1 to 5 carbon atoms or a fluorinated alkyl group of 1 to 5 carbon atoms, and most preferably a hydrogen atom or a methyl group.

Examples of the acid decomposable group for OR⁷⁰ in the formula (a1-5) include groups in which the hydrogen atom of the alcoholic hydroxy group has been substituted with an acid dissociable group.

An “acid dissociable group” is a group in which at least the bond between the acid dissociable group and the adjacent carbon atom is cleaved by the action of acid generated from the anion part on the terminal of the main chain, the structural unit (a5) or the component (B) upon exposure. In the present invention, it is necessary that the acid dissociable group exhibits a lower hydrophilicity than the alcoholic hydroxy group generated by the dissociation of the acid dissociable group. Namely, by substituting the hydrogen atom of the alcoholic hydroxy group with an acid dissociable group, when the acid dissociable group is dissociated, the alcoholic hydroxy group is formed, thereby increasing the hydrophilicity. As a result, the hydrophilicity of the entire polymer is increased, so that the solubility of the polymer in a developing solution is changed. When the developing solution is an alkali developing solution, the solubility is increased. On the other hand, when the developing solution is a developing solution containing an organic solvent (organic developing solution), the solubility is decreased.

The acid dissociable group is not particularly limited, and any of the groups that have been conventionally proposed as acid dissociable groups for the base resins of chemically amplified resists can be used. For example, the same groups as those described above for acid decomposable groups can be used.

In particular, as the acid dissociable group, in terms of improving in solubility of the polymer used for a resist composition either in an organic solvent (resist solvent), or in an organic developing solution and the like, a tertiary alkyl group-containing acid dissociable group or an acetal-type acid dissociable group is preferable.

### (Tertiary Alkyl Group-Containing Acid Dissociable Group)

The term “tertiary alkyl group” refers to an alkyl group having a tertiary carbon atom. The term “alkyl group” refers to a monovalent saturated hydrocarbon group, and includes chain-like (linear or branched) alkyl groups and cyclic alkyl groups.

The term “tertiary alkyl group-containing acid dissociable group” refers to an acid dissociable group which includes a tertiary alkyl group in the structure thereof. The tertiary alkyl group-containing acid dissociable group may be either constituted of only a tertiary alkyl group, or constituted of a tertiary alkyl group and an atom or group other than a tertiary alkyl group.

Examples of the “atom or group other than a tertiary alkyl group” which constitutes the tertiary alkyl group-containing group with a tertiary alkyl group include a carbonyloxy group, a carbonyl group, an alkylene group and an oxygen atom (—O—).

As the tertiary alkyl group-containing acid dissociable group, a tertiary alkyl group-containing acid dissociable group which does not have a ring structure, and a tertiary alkyl group-containing acid dissociable group which has a ring structure can be mentioned.

“A tertiary alkyl group-containing acid dissociable group which does not have a ring structure” is an acid dissociable group which has a branched tertiary alkyl group as the tertiary alkyl group, and has no ring in the structure thereof.

As the branched tertiary alkyl group, for example, a group represented by general formula (I) shown below can be mentioned.

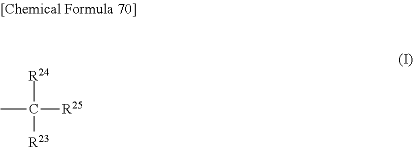

In formula (I), each of R²³ to R²⁵ independently represents a linear or branched alkyl group. The number of carbon atoms within the alkyl group is preferably from 1 to 5, and more preferably from 1 to 3.

Further, in the group represented by general formula (I), the total number of carbon atoms is preferably from 4 to 7, more preferably from 4 to 6, and most preferably 4 or 5.

Preferable examples of the group represented by general formula (I) include a tert-butyl group and a tert-pentyl group, and a tert-butyl group is more preferable.

Examples of tertiary alkyl group-containing acid dissociable groups which do not have a ring structure include the aforementioned branched tertiary alkyl group; a tertiary alkyl group-containing, chain-like alkyl group in which the aforementioned branched tertiary alkyl group is bonded to a linear or branched alkylene group; a tertiary alkyloxycarbonyl group which has the aforementioned branched tertiary alkyl group as the tertiary alkyl group; and a tertiary alkyloxycarbonylalkyl group which has the aforementioned branched tertiary alkyl group as the tertiary alkyl group.

As the alkylene group within the tertiary alkyl group-containing, chain-like alkyl group, an alkylene group of 1 to 5 carbon atoms is preferable, an alkylene group of 1 to 4 carbon atoms is more preferable, and an alkylene group of 2 carbon atoms is the most desirable.

As a chain-like tertiary alkyloxycarbonyl group, for example, a group represented by general formula (II) shown below can be mentioned.

In general formula (II), R²³ to R²⁵ are the same as defined for R²³ to R²⁵ in general formula (I).

As the chain-like tertiary alkyloxycarbonyl group, a tert-butyloxycarbonyl group (t-boc) and a tert-pentyloxycarbonyl group are preferable.

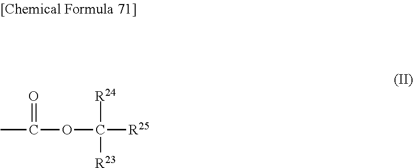

As a chain-like tertiary alkyloxycarbonylalkyl group, for example, a group represented by general formulas (III-1) or (III-2) shown below can be mentioned.

In general formulas (III-1) and (III-2), R²³ to R²⁵ are the same as defined for R²³ to R²⁵ in general formula (I).

m₆ represents an integer of 1 to 3, and is preferably 1 or 2.

R³′ represents an alkyl group of 1 to 5 carbon atoms, and a methyl group or ethyl group is preferable, and a methyl group is particularly desirable.

As the chain-like tertiary alkyloxycarbonylalkyl group, a tert-butyloxycarbonylmethyl group and a tert-butyloxycarbonylethyl group are preferable.

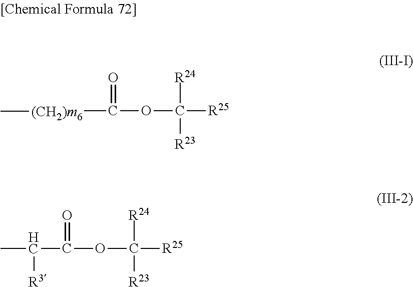

Among these, as the tertiary alkyl group-containing acid dissociable group which does not have a ring structure, in terms of the contrast to the organic developing solution prior to and after exposure, a tertiary alkyloxycarbonyl group or a tertiary alkyloxycarbonylalkyl group is preferable, a tertiary alkyloxycarbonyl group is more preferable, and a tert-butyloxycarbonyl group (t-boc) is most preferable.

A “tertiary alkyl group-containing acid dissociable group” which has a ring structure is an acid dissociable group which contains a tertiary carbon atom and a ring in the structure thereof.

In the tertiary alkyl group-containing acid dissociable group which has a ring structure, the ring structure preferably has 4 to 12 carbon atoms which constitute the ring, more preferably 5 to 10 carbon atoms, and most preferably 6 to 10 carbon atoms.

The ring structure is preferably an aliphatic cyclic group. The term “aliphatic cyclic group” refers to a monocyclic group or polycyclic group that has no aromaticity.

The aliphatic cyclic group may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

As such aliphatic cyclic groups, groups in which one or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated alkyl group, may be used. Specific examples of aliphatic cyclic hydrocarbon groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. In these aliphatic cyclic hydrocarbon groups, part of the carbon atoms constituting the ring may be replaced with an ethereal oxygen atom (—O—).

As the tertiary alkyl group within the tertiary alkyl group-containing acid dissociable group which has a ring structure, for example, a group [1] or [2] described below can be mentioned.

[1] A tertiary alkyl group in which a tertiary carbon atom is formed on the ring skeleton of a monovalent aliphatic cyclic group by an alkyl group being bonded to a carbon atom which is bonded to an atom adjacent to the tertiary alkyl group.

[2] A tertiary alkyl group which has a monovalent aliphatic cyclic group and an alkylene group having a tertiary carbon atom (branched alkylene group), and the tertiary carbon atom is bonded to an atom adjacent to the tertiary alkyl group.

In the group [1] or [2], as the monovalent aliphatic cyclic group, the same aliphatic cyclic groups as those described above for the ring structure can be used.

In the group [1], the alkyl group bonded to the aliphatic cyclic group may be linear, branched or cyclic, and is preferably linear or branched.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is most desirable.

Specific examples of the group [1] include groups represented by general formulas (1-1) to (1-9) shown below.

Specific examples of the group [1] include groups represented by general formulas (2-1) to (2-6) shown below.

Examples of tertiary alkyl group-containing acid dissociable groups which have a ring structure include the aforementioned tertiary alkyl group having a ring structure; a tertiary alkyloxycarbonyl group having the aforementioned tertiary alkyl group having a ring structure; and an alkyloxycarbonylalkyl group having the aforementioned tertiary alkyl group having a ring structure.

Examples of the alkyl group having a ring structure include those represented by the aforementioned formula [1] or [2].

Specific examples of the tertiary alkyloxycarbonyl group include groups represented by the aforementioned general formula (II) in which —C(R²³)(R²⁴)(R²⁵) moiety has been substituted with a tertiary alkyl group having a ring structure.

Specific examples of the tertiary alkyloxycarbonylalkyl group include groups represented by the aforementioned general formulas (III-1) and (III-2) in which —C(R²³)(R²⁴)(R²⁵) moiety has been substituted with a tertiary alkyl group having a ring structure.

Among these, as the tertiary alkyl group-containing acid dissociable group, a group represented by the general formula (II) (particularly preferably tert-butyloxycarbonyl group (t-boc) and a group in which —C(R²³)(R²⁴)(R²⁵) has been substituted with a tertiary alkyl group having a ring structure are preferable.

### (Acetal-Type Acid Dissociable Group)

In an acetal-type acid dissociable group, when acid is generated upon exposure, the generated acid acts to break the bond between the acetal-type acid dissociable group and the oxygen atom to which the acetal-type, acid dissociable group is bonded.

Examples of the acetal-type acid dissociable group include the same acetal-type acid dissociable groups as those described above.

In the structural unit represented by the formula (a1-5), when R⁷⁰ represents an acetal-type acid dissociable group, Preferable examples for —OR⁷⁰ include a methoxymethoy group, an ethoxymethoxy group, an n-butoxymethoxy group, a cyclohexyloxymethoxy group, an adamantyloxymethoxy group, a 1-ethoxyethoxy group, a 1-n-butoxyethoxy group, a 1-cyclohexyloxyethoxy group, a 1-adamatyloxyethoxy group.

In formula (a1-5), R⁸⁰ represents an aliphatic hydrocarbon group which may have a substituent.

An “aliphatic hydrocarbon group” refers to a hydrocarbon group that has no aromaticity.

The aliphatic hydrocarbon group for R⁸⁰ may be either a saturated aliphatic hydrocarbon group, or an unsaturated aliphatic hydrocarbon group. Further, the aliphatic hydrocarbon group may be linear, branched or cyclic.

An aliphatic hydrocarbon group “may have a substituent” means that part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for R⁸⁰ there is no particular limitation as long as it is an atom other than carbon and hydrogen. Examples of the halogen atom include a fluorine atom, a chlorine atom, an iodine atom and a bromine atom.

The substituent group containing a hetero atom may consist of a hetero atom, or may be a group containing a hetero atom and a group or atom other than a hetero atom. Specific examples thereof include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms constituting the aliphatic hydrocarbon group include an alkoxy group, a halogen atom, a halogenated alkyl group, a hydroxy group, an oxygen atom (═O), a cyano group and an alkyl group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

Examples of the alkyl group include alkyl groups of 1 to 5 carbon atoms such as a methyl group, an ethyl group, a propyl group, an n-butyl group and a tert-butyl group.

When R⁸⁰ represents a linear or branched aliphatic hydrocarbon group, the linear or branched aliphatic hydrocarbon group preferably has 1 to 10 carbon atoms, more preferably 1 to 5, and most preferably 1 to 3. Specific examples of preferable linear or branched aliphatic hydrocarbon group include chain-like alkylene groups.

When R⁸⁰ represents a cyclic aliphatic hydrocarbon group (aliphatic cyclic group), the basic ring of the “aliphatic cyclic group” exclusive of substituents (aliphatic ring) is not limited to be constituted from only carbon and hydrogen (not limited to hydrocarbon rings), and the ring (aliphatic ring) may contain a hetero atom (e.g., an oxygen atom or the like) in the structure thereof. Further, the “hydrocarbon ring” may be either saturated or unsaturated, but is preferably saturated.

The aliphatic cyclic group may be either a polycyclic group or a monocyclic group. Examples of aliphatic cyclic groups include groups in which two or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated alkyl group. Specific examples include groups in which two or more hydrogen atoms have been removed from a monocycloalkane such as cyclopentane or cyclohexane; and groups in which two or more hydrogen atoms have been removed from a polycycloalkane such as adamantane, norbornane, isobornane, tricyclodecane or tetracyclododecane.

Further examples of the aliphatic cyclic group include groups in which two or more hydrogen atoms have been removed from tetrahydrofuran or tetrahydropyran which may or may not be substituted with a lower alkyl group, a fluorine atom or a fluorinated alkyl group.

The aliphatic cyclic group within the structural unit (a1-5) is preferably a polycyclic group, and a group in which two or more hydrogen atoms have been removed from adamantane is particularly desirable.

In the formula (a1-5), the divalent linking group for R⁹⁰ is not particularly limited, and preferable examples thereof include a divalent hydrocarbon group which may have a substituent and a divalent linking group containing a hetero atom.

As examples of the divalent hydrocarbon group which may have a substituent and the divalent linking group containing a hetero atom for R⁹⁰, the same groups as those described above for the divalent hydrocarbon group which may have a substituent and the divalent linking group containing a hetero atom in relation to R²⁹′ in general formula (a0-0) can be given.

As the divalent linking group for R⁹⁰, an alkylene group, a divalent alicyclic hydrocarbon group or a divalent linking group containing a hetero atom is particularly desirable. Among these, a linear or branched alkylene group or a divalent linking group containing a hetero atom is more preferable.

As the divalent linking group containing a hetero atom, a linear group containing an oxygen atom as the hetero atom e.g., a group containing an ether bond or an ester bond is preferable, and a group represented by the aforementioned formula —Y²¹—O—Y²²—, —[Y²¹—C(═O)—O]_{m′}—Y²²— or —Y²¹—O—C(═O)—Y²²— is more preferable. Each of Y²¹ and Y²² independently represents a divalent hydrocarbon group which may have a substituent, and is the same as those defined above for Y²¹ and Y²². m′ represents an integer of 0 to 3.

In general formula (a1-5), m₁ represents an integer of 1 to 3, and m₂ represents an integer of 0 to 2, provided that m₁+m₂=1 to 3.

m₁ is preferably 1 or 2.

m₂ is preferably 0.

m₁+m₂ is preferably 1 or 2.

m₄ represents an integer of 0 to 3, preferably 0 or 1, and more preferably 0.

m₅ represents an integer of 0 to 3, preferably 0 or 1, and more preferably 0.

As the structural unit (a1-5), a structural unit represented by the aforementioned general formula (a0-1) in which R⁹⁰ is a single bond or a linear alkylene group of 1 to 3 carbon atoms is preferable. That is, a structural unit represented by general formula (a1-51) is preferable.

Among these, a structural unit represented by general formula (a1-511), (a1-512) or (a1-513) shown below is preferable.

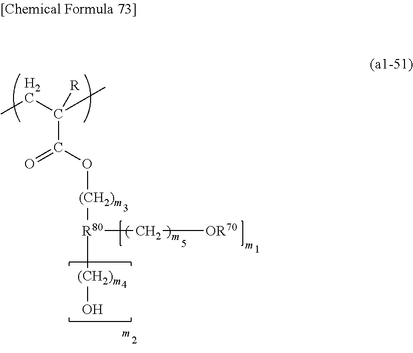

In formula (a1-51), R, OR⁷⁰, R⁸⁰, m₁, m₂, m₄ and m₅ are the same as defined above; and m₃ represents an integer of 0 to 3.

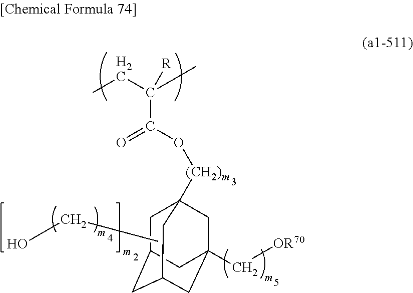

In the formula, R, OR⁷⁰, m₂, m₃, m₄ and m₅ are the same as defined above.

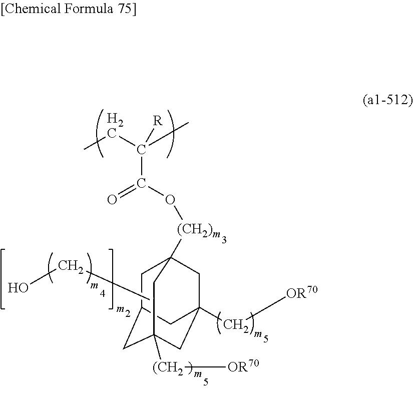

In the formula, R, OR⁷⁰, m₂, m₃, m₄ and m₅ are the same as defined above.

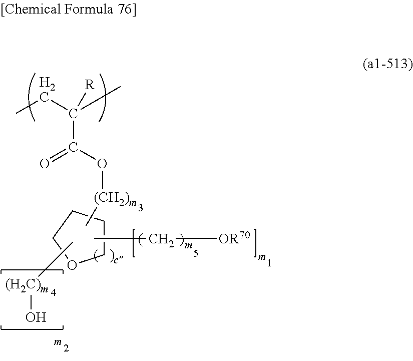

In the formula, R, OR⁷⁰, m₁, m₂, m₃, m₅ and mare the same as defined above. and c″ represents an integer of 1 to 3.

In formula (a1-51), m₃ is an integer of 0 to 3, preferably 0 or 1, and more preferably 0.

In formula (a1-513), c″ is an integer of 1 to 3, preferably 1 or 2, and more preferably 1.

When m₃ represents 0 in formula (a1-513), the oxygen atom on the terminal of the carbonyloxy group within the acrylate ester is preferably not bonded to the carbon atom which is bonded to the oxygen atom within the cyclic group. That is, when m₃ represents 0, it is preferable that there are at least two carbon atoms present between the terminal oxygen atom and the oxygen atom within the cyclic group (excluding the case where the number of such carbon atom is one (i.e., the case where an acetal bond is formed)).

Specific examples of structural units represented by general formula (a1-5) are shown below.

In the formulas shown below, R^{α} represents a hydrogen atom, a methyl group or a trifluoromethyl group.

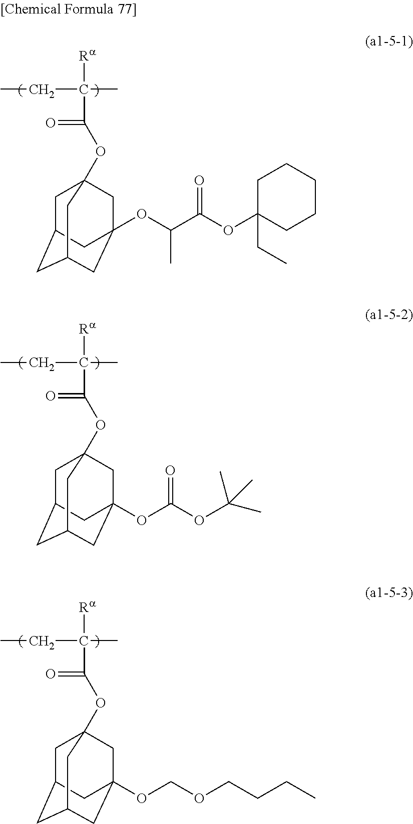

—Structural Unit (a12) and Structural Unit (a13)

In the present specification, the structural unit (a12) is a structural unit in which at least part of the hydrogen atoms of the hydroxy group in a structural unit derived from a hydroxystyrene or derivative thereof is protected with a substituent containing an acid decomposable group.

In addition, a structural unit (a13) is a structural unit in which at least part of the hydrogen atom of —C(═O)—OH in a structural unit derived from a vinylbenzoic acid or vinylbenzoic acid derivatives is protected with a substituent containing an acid decomposable group.

In the structural unit (a12) and structural unit (a13), preferable examples of the substituent containing an acid decomposable group include the aforementioned tertiary alkyl ester-type acid dissociable groups and acetal-type acid dissociable groups.

As the structural unit (a1) contained in the polymer of the first aspect of the present invention, 1 type of structural unit may be used, or 2 or more types may be used.

Among these, as the structural unit (a1), a structural unit (a11) derived from an acrylate ester which may have the hydrogen atom bonded to the carbon atom on the α-position substituted with a substituent is preferred.

In the polymer of the first aspect of the present invention, the amount of the structural unit (a1) based on the combined total of all structural units constituting the polymer is preferably 15 to 70 mol %, more preferably 15 to 60 mol % and still more preferably 20 to 55 mol %.

When the amount of the structural unit (a1) is at least as large as the lower limit of the above-mentioned range, a pattern can be easily formed using a resist composition containing the polymer, and various lithography properties such as sensitivity, resolution, LWR and the like are improved. On the other hand, when the amount of the structural unit (a1) is no more than the upper limit of the above-mentioned range, a good balance can be achieved with the other structural units.

When the polymer of the first aspect of the present invention contains at least two types of structural units (a1), a combination of at least two structural units having the aforementioned tertiary alkyl ester-type acid dissociable group is preferable, more preferably a combination of at least two structural units having the aforementioned group which has a tertiary carbon atom on the ring structure of a cyclic alkyl group. Among these, a combination of the structural unit having the group which has “a tertiary carbon atom on the ring structure of a cyclic alkyl group” in which the ring structure is a monocyclic group with the structural unit having the aforementioned group which has “a tertiary carbon atom on the ring structure of a cyclic alkyl group” in which the ring structure is a polycyclic group is particularly preferable. Specific examples thereof include a combination a structural unit represented the general formula (a11-0-11) with a structural unit represented by the general formula (a11-0-12).

The polymer of the first aspect of the present invention may also have a structural unit other than the above-mentioned structural units (a0), (a3), (a5) and (a1), as long as the effects of the present invention are not impaired.

As such a structural unit, any other structural unit which cannot be classified as the aforementioned structural units can be used without any particular limitation, and any of the multitude of conventional structural units used within resist resins for ArF excimer lasers or KrF excimer lasers (and particularly for ArF excimer lasers) can be used.

Examples of the other structural unit include a structural unit (a2) derived from an acrylate ester which may have the hydrogen atom bonded to the carbon atom on the α-position substituted with a substituent and contains a lactone-containing cyclic group, and a structural unit (a4) derived from an acrylate ester which may have the hydrogen atom bonded to the carbon atom on the α-position substituted with a substituent and contains a non-acid-dissociable aliphatic polycyclic group.

As a polymer according to the first aspect of the present invention, a polymer which contains an anion part which generates acid upon exposure on at least one terminal of the main chain, and the structural unit (a5), and preferably further contains the structural unit (a1) is preferable.

Examples of the polymer include a polymer in which the main chain consists of the repeating structure of the structural unit (a5) and structural unit (a1); a polymer in which the main chain consists of the repeating structure of the structural unit (a5), structural unit (a1) and structural unit (a0); and a polymer in which the main chain consists of the repeating structure of the structural unit (a5), structural unit (a1), structural unit (a0) and structural unit (a3).

Specific examples of the polymer include a polymer containing a group represented by the general formula (I-1-1) on the terminal of the main chain, and a structural unit represented by the formula (a5-1), (a5-2-11) to (a5-2-13), (a5-2-31) or (a5-2-43), a structural unit represented by the general formula (a11-0-12), a structural unit represented by the general formula (a0-0-12) and a structural unit represented by the general formula (a3-12); and a polymer containing a group represented by the general formula (I-1-1) on the terminal of the main chain, and a structural unit represented by the general formula (a5-1) or (a5-2-11) to (a5-2-13), a structural unit represented by the general formula (a11-0-12) and a structural unit represented by the general formula (a0-0-12).

As a polymer according to the first aspect of the present invention, a polymer which contains an anion part which generates acid upon exposure on at least one terminal of the main chain, and at least one of the structural unit selected from the group consisting of the structural unit (a0), the structural unit (a3) and the structural unit (a5), and which has the weight average molecular weight of the polymer of 20,000 or less is preferable. The polymer is preferably a polymer which exhibits increased polarity by the action of acid, and particularly preferably a polymer containing the structural unit (a1).

Preferable examples of the polymer include a polymer in which the main chain consists of the repeating structure of the structural unit (a1) and structural unit (a2); a polymer in which the main chain consists of the repeating structure of the structural unit (a1), structural unit (a2) and structural unit (a3); and

a polymer in which the main chain consists of the repeating structure of the structural unit (a1), structural unit (a2), structural unit (a3) and structural unit (a0).

Specifically, preferable examples of the polymer include a polymer containing a group represented by the general formula (I-1-1) at the terminal of the main chain, a structural unit represented by the general formula (a2-1) and a structural unit represented by the general formula (a11-0-11); a polymer containing a group represented by the general formula (1-1-1) at the terminal of the main chain, a structural unit represented by the general formula (a2-1), a structural unit represented by the general formula (a11-0-17) and a structural unit represented by the general formula (a2-12-28); a polymer containing a group represented by the general formula (I-1-1) at the terminal of the main chain, a structural unit represented by the general formula (a0-0-12), a structural unit represented by the general formula (a11-0-12) and a structural unit represented by the general formula (a3-12-28); a polymer containing a group represented by the general formula (I-1-1) at the terminal of the main chain, a structural unit represented by the general formula (a0-0-12), a structural unit represented by the general formula (a11-0-12), a structural unit represented by the general formula (a3-12-28) and a structural unit represented by the general formula (a5-11); a polymer containing a group represented by the general formula (I-1-1) at the terminal of the main chain, a structural unit represented by the general formula (a0-0-12), a structural unit represented by the general formula (a11-0-12), a structural unit represented by the general formula (a3-12-28) and a structural unit represented by the general formula (a5-2-11); a polymer containing a group represented by the general formula (I-1-1) at the terminal of the main chain, a structural unit represented by the general formula (a0-0-12), a structural unit represented by the general formula (a11-0-12), a structural unit represented by the general formula (a3-12-28) and a structural unit represented by the general formula (a5-2-12); a polymer containing a group represented by the general formula (I-1-1) at the terminal of the main chain, a structural unit represented by the general formula (a0-0-12), a structural unit represented by the general formula (a11-0-12), a structural unit represented by the general formula (a3-12-28) and a structural unit represented by the general formula (a5-2-13); a structural unit containing a group represented by the general formula (I-1-1) at the terminal of the main chain, a structural unit represented by the general formula (a0-0-12), a structural unit represented by the general formula (a11-0-12), a structural unit represented by the general formula (a3-12-28) and a structural unit represented by the general formula (a5-2-31); a polymer containing a group represented by the general formula (I-1-1) at the terminal of the main chain, a structural unit represented by the general formula (a0-0-12), a structural unit represented by the general formula (a11-0-12), a structural unit represented by the general formula (a3-12-28) and a structural unit represented by the general formula (a5-2-43); and a polymer containing a group represented by the general formula (I-1-1) at the terminal of the main chain, a structural unit represented by the general formula (a0-0-12), a structural unit represented by the general formula (a11-0-12), a structural unit represented by the general formula (a3-12-28), a structural unit represented by the general formula (a5-2-11) and a structural unit represented by the general formula (a5-2-31).

The weight average molecular weight (Mw) (the polystyrene equivalent value determined by gel permeation chromatography) of the polymer of the first aspect of the present invention is not particularly limited, and is preferably 1,000 to 50,000, more preferably 1,500 to 30,000, still more preferably 20,000 or less, and still more preferably 3,000 to 20,000, further preferably 2,000 to 20,000, particularly preferably 4,000 to 17,000 and most preferably 5,000 to 14,000.

When the weight average molecular weight of the polymer is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

When the weight average molecular weight of the polymer is 20,000 or less, various lithography properties such as sensitivity, exposure latitude, mask reproducibility, reduced roughness and the like and pattern shape become excellent, and the polymer exhibits a satisfactory solubility in a resist solvent.

On the other hand, when the weight average molecular weight of the polymer is at least as large as the lower limit, excellent lithography properties can be more reliably achieved, because the softening point of the resin can be sufficiently secured, and the dry etching resistance and the cross-sectional shape of the resist pattern become excellent.

Here, the weight average molecular weight of the polymer is the weight average molecular weight in terms of the polystyrene equivalent value determined by gel permeation chromatography (GPC).

Further, the dispersity (Mw/Mn) of the polymer of the first aspect of the present invention is preferably 1.0 to 5.0, more preferably 1.0 to 3.0, and most preferably 1.2 to 2.5. Here, Mn is the number average molecular weight.

When the dispersity of the polymer is within the range, excellent lithography properties can be more reliably achieved.

[Structural Units Constituting Polymer 2]

The main chain containing an anion part on at least one terminal thereof is not particularly limited, and a main chain which is formed by the cleavage of the ethylenic double bond (C═C) is preferable.

That is, the polymer is composed of a structural unit derived from a compound containing an ethylenic double bond.

Here, the “structural unit derived from a compound containing an ethylenic double bond” refers to a structural unit in which the ethylenic double bond of the compound containing an ethylenic double bond is cleaved to form a single bond.

Examples of the compound containing an ethylenic double bond include an acrylate or ester thereof which may have the hydrogen atom bonded to the carbon atom on the α-position substituted with a substituent, an acrylamide or derivative thereof which may have the hydrogen atom bonded to the carbon atom on the α-position substituted with a substituent, a stylene or derivative thereof which may have the hydrogen atom bonded to the carbon atom on the α-position substituted with a substituent, a vinylnaphthalene or derivative thereof which may have the hydrogen atom bonded to the carbon atom on the α-position substituted with a substituent, a cycloolefine or derivative thereof, a vinyl sulfonate ester and the like.

Among these, an acrylate or ester thereof which may have the hydrogen atom bonded to the carbon atom on the α-position substituted with a substituent, an acrylamide or derivative thereof which may have the hydrogen atom bonded to the carbon atom on the α-position substituted with a substituent, a stylene or derivative thereof which may have the hydrogen atom bonded to the carbon atom on the α-position substituted with a substituent, or a vinylnaphthalene or derivative thereof which may have the hydrogen atom bonded to the carbon atom on the α-position substituted with a substituent is preferable, and an acrylate ester which may have the hydrogen atom bonded to the carbon atom on the α-position substituted with a substituent is more preferable.

An “acrylate ester” refers to a compound in which the terminal hydrogen atom of the carboxy group of acrylic acid (CH₂═CH—COOH) has been substituted with an organic group.

In the present specification, an acrylate ester in which the hydrogen atom bonded to the carbon atom on the α-position has been substituted with a substituent is referred to as an “α-substituted acrylate ester”. Further, acrylate esters and α-substituted acrylate esters are collectively referred to as “(α-substituted) acrylate ester”.

Examples of the substituent bonded to the carbon atom on the α-position of the α-substituted acryl ester include an alkyl group of 1 to 5 carbon atoms, a halogenated alkyl group of 1 to 5 carbon atoms and a hydroxyalkyl group. With respect to the structural unit derived from an acrylate ester, the α-position (the carbon atom on the α-position) refers to the carbon atom having the carbonyl group bonded thereto, unless specified otherwise.

Examples of the halogen atom as the substituent at the α-position include a fluorine atom, a chlorine atom, a bromine atom and an iodine atom.

Specific examples of the alkyl group of 1 to 5 carbon atoms for the substituent at the α-position include linear or branched alkyl groups such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group of 1 to 5 carbon atoms as a substituent on the α-position include groups in which part or all of the hydrogen atoms of the aforementioned alkyl group of 1 to 5 carbon atoms are substituted with halogen atoms.

Examples of the halogen atom include a fluorine atom, a chlorine atom, a bromine atom and an iodine atom, and a fluorine atom is particularly preferred.

Specific examples of the halogenated alkyl group of 1 to 5 carbon atoms as a substituent on the α-position include groups in which part or all of the hydrogen atoms of the aforementioned alkyl group of 1 to 5 carbon atoms are substituted with halogen atoms.

In the present invention, it is preferable that a hydrogen atom, an alkyl group of 1 to 5 carbon atoms or a halogenated alkyl group of 1 to 5 carbon atoms is bonded to the α-position of the (α-substituted) acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most preferred.

The organic group in (α-substituted) acrylate ester is not particularly limited. Examples thereof include an acid dissociable group as those described for the structural unit (f2) below and a characteristic group-containing group which contains a characteristic group such as acid dissociable group in the structure thereof. Examples of the characteristic group-containing group include a group in which a divalent linking group is bonded to the characteristic group. Examples of the divalent linking group include the same divalent linking groups as those described for Y² in the formula (f1-0-2) described later.

Examples of the “acrylamide and derivative thereof” include an acryl amide which may have the hydrogen atom bonded to the carbon atom on the α-position substituted with a substituent (hereafter, referred to as (α-substituted) acrylamide) and a compound in which one or both of hydrogen atoms on the terminal of the amino group within the α-substituted) acrylamide is substituted with a substituent.

As the substituent which may be bonded to the carbon atom on the α-position of an acrylamide is substituted, or derivatives thereof, the same substituents as those described above for the substituent to be bonded to the carbon atom on the α-position of an α-substituted acrylate ester can be mentioned.

As the substituent with which one or both of hydrogen atoms on the terminal of the amino group within (α-substituted) acrylamide is substituted, an organic group is preferable. The organic group is not particularly limited, and examples thereof include the same groups as described for the organic groups within (α-substituted) acrylate ester.

Examples of the compound in which one or both of hydrogen atom on the terminal of the (α-substituted) acrylamide is substituted with a substituent include a compound in which a group —C(═O)—O— bonded to the carbon atom on the α-position of the α-substituted) acrylate ester is replaced by a group —C(═O)—N(R^{b})— [in the formula, R^{b} represents a hydrogen atom or an alkyl group of 1 to 5 carbon atoms].

In the formula, the alkyl group for R^{b} is preferably a linear or branched alkyl group.

The “styrene and derivative thereof” may have the hydrogen atom bonded to the carbon atom on the α-position substituted with a substituent, and examples thereof include a styrene which may have the hydrogen atom bonded to the benzene ring substituted with a substituent other than the hydroxy group (hereafter, referred to as (α-substituted)styrene), a hydroxystyrene which may have the hydrogen atom bonded to the carbon atom on the α-position substituted with a substituent and may have a hydrogen atom bonded to the benzene ring substituted with a substituent other than a hydroxy group (hereafter, referred to as (α-substituted)hydroxystyrene), a compound in which a hydrogen atom of hydroxy group of (α-substituted)hydroxystyrene is substituted with an organic group, a vinylbenzoic acid which may have the hydrogen atom bonded to the carbon atom on the α-position substituted with a substituent and may have a hydrogen atom bonded to the benzene ring substituted with a substituent other than a hydroxy group and carboxy group (hereafter, referred to as (α-substituted)vinylbenzoic acid), and a compound in which a hydrogen atom of carboxy group of (α-substituted)vinylbenzoic acid is substituted with an organic group.

A hydroxystyrene is a compound which has one vinyl group and at least one hydroxy group bonded to a benzene ring. The number of hydroxy groups bonded to the benzene ring is preferably 1 to 3, and most preferably 1. The bonding position of the hydroxy group on the benzene ring is not particularly limited. When the number of the hydroxy group is 1, a para (4th) position against the bonding position of the vinyl group is preferable. When the number of the hydroxy groups is an integer of 2 or more, an arbitrary combination of the bonding positions can be adopted.

The vinylbenzoic acid is a compound in which one vinyl group is bonded to the benzene ring within the benzoic acid.

The bonding position of the vinyl group on the benzene ring is not particularly limited.

As the substituent which may be bonded to the carbon atom on the α-position of a stylene or derivatives thereof, the same substituents as those described above for the substituent to be bonded to the carbon atom on the α-position of the α-substituted acrylate ester can be mentioned.

The substituent other than a hydroxy group or carboxy group which may be bonded to the benzene ring of an styrene or derivative thereof is not particularly limited, and examples thereof include a halogen atom, an alkyl group of 1 to 5 carbon atoms and a halogneated alkyl group of 1 to 5 carbon atoms. Examples of the halogen atom include a fluorine atom, a chlorine atom, a bromine atom and an iodine atom, and a fluorine atom is particularly preferred.

The organic group within a compound in which the hydrogen atom of the hydroxy group within the (α-substituted) hydroxystyrene is substituted with an organic group is not particularly limited, and examples thereof include the same groups as described for the organic groups within (α-substituted) acrylate ester.

The organic group within a compound in which the hydrogen atom of the carboxy group within the (α-substituted) vinylbenzoic acid is substituted with an organic group is not particularly limited, and examples thereof include the same organic groups as those described for the organic group within (α-substituted) acrylate ester.

The “vinylnaphthalene and derivative thereof” may have the hydrogen atom bonded to the carbon atom on the α-position substituted with a substituent, and examples thereof include a vinylnaphthalene which may have the hydrogen atom bonded to the naphthalene ring substituted with a substituent other than the hydroxy group (hereafter, referred to as (α-substituted) vinyl naphthalene), a vinyl(hydroxynaphthalene) which may have the hydrogen atom bonded to the carbon atom on the α-position substituted with a substituent and may have a hydrogen atom bonded to the naphthalene ring substituted with a substituent other than a hydroxy group (hereafter, referred to as (α-substituted) vinyl(hydroxynaphthalene) and a compound in which a hydrogen atom of hydroxy group within (α-substituted) vinyl(hydroxynaphthalene) is substituted with a substituent.

A vinyl(hydroxynaphthalene) is a compound which has one vinyl group and at least one hydroxy group bonded to a naphthalene ring. The vinyl group may be bonded to the 1st or 2nd position of the naphthalene ring. The number of hydroxy groups bonded to the naphthalene ring is preferably 1 to 3, and particularly preferably 1. The bonding position of the hydroxy group on the naphthalene ring is not particularly limited. When the vinyl group is bonded to the 1st or 2nd position of the naphthalene ring, the hydroxy group is preferably bonded to either one of the 5th to 8th position of the naphthalene ring. In particular, when the number of hydroxy group is 1, the hydroxy group is preferably bonded to either one of the 5th to 7th position of the naphthalene ring, and more preferably the 5th or 6th position. When the number of the hydroxy groups is an integer of 2 or more, an arbitrary combination of the bonding positions can be adopted.

As the substituent which may be bonded to the carbon atom on the α-position of a vinylnaphthalene or derivatives thereof, the same substituents as those described above for the substituent to be bonded to the carbon atom on the α-position of an α-substituted acrylate ester can be mentioned.

As the substituent which may be bonded to the naphthanlene ring of the vinylnaphthalene or derivative thereof, the same substituents as those described above for the substituent other than a hydroxy group which may be bonded to the benzene ring of the (α-substituted) styrene can be mentioned.

The organic group within a compound in which the hydrogen atom of the hydroxy group within the (α-substituted) vinyl(hydroxystyrene) is substituted with an organic group is not particularly limited, and examples thereof include the same organic groups as those described for the organic group within (α-substituted) acrylate ester.

Specific examples of the structural unit derived from the (α-substituted) acrylic acid or ester thereof include a structural unit represented by the general formula (I) shown below.

Specific examples of the structural unit derived from the (α-substituted) acrylamide or derivative thereof include a structural unit represented by the general formula (II) shown below.

Specific examples of the structural unit derived from the (α-substituted) styrene or derivative thereof include a structural unit represented by the general formula (III) shown below.

Specific examples of the structural unit derived from the (α-substituted) vinylnaphthalene or derivative thereof include a structural unit represented by the general formula (IV) shown below.

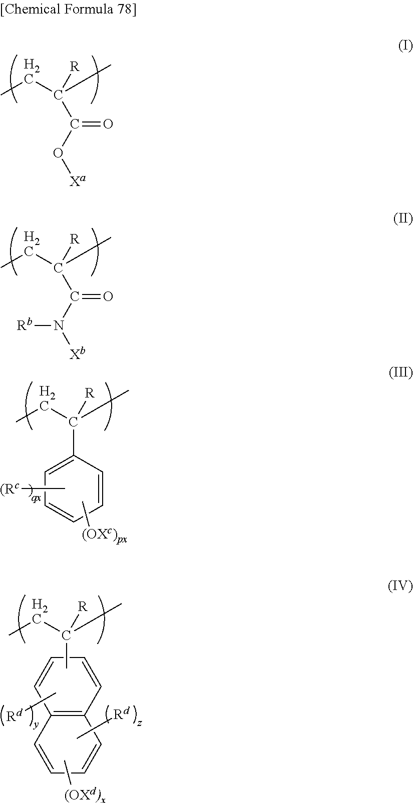

In the formulas, R represents a hydrogen atom, an alkyl group of 1 to 5 carbon atoms or a halogenated alkyl group of 1 to 5 carbon atoms; X^{a} to X^{d} each independently represents a hydrogen atom or an organic group; R^{b} represents a hydrogen atom or an alkyl group of 1 to 5 carbon atoms; each of R^{c} and R^{d} independently represents a halogen atom, —COOX^{c} (wherein, X^{c} represents a hydrogen atom or an organic group), an alkyl group of 1 to 5 carbon atoms or a halogenated alkyl group of 1 to 5 carbon atoms; px represents an integer of 0 to 3, and qx represents an integer of 0 to 5, provided that px+qx ═0 to 5, and when qx is an integer of 2 or more, the plurality of R^{c} may be the same or different from each other; x represents an integer of 0 to 3; y represents an integer of 0 to 3; and z represents an integer of 0 to 4, with the provision that x+y+z=0 to 7, when y+z is an integer of 2 or more, the plurality of R^{d} group may be the same or different from each other.
<Structural Unit (f1)>

The structural unit (f1) contained in the polymer of the fourth aspect of the present invention is a structural unit containing a fluorine atom. The structural unit (f1) is not particularly limited as long as it has a fluorine atom in the structure thereof, and a structural unit derived from a compound containing an ethylenic double bond is preferred. As the compound containing an ethylenic double bond and the structural unit derived from thereof, the same compounds and structural units as those described above can be mentioned.

Among these, as the structural unit (f1), a structural unit represented by general formula (f1-1) shown below is preferable.

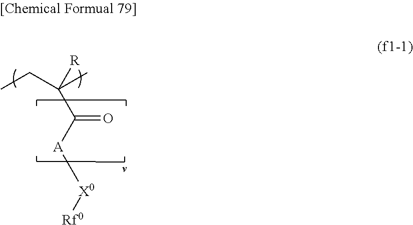

In the formula, R represents a hydrogen atom, an alkyl group of 1 to 5 carbon atoms or a halogenated alkyl group of 1 to 5 carbon atoms; A represents —O— or —NH—; X⁰ represents a single bond or a divalent linking group; Rf⁰ represents an organic group, provided that at least one of X⁰ and Rf⁰ has a fluorine atom; and v represents 0 or 1.

In formula (f1-1), R represents a hydrogen atom, an alkyl group of 1 to 5 carbon atoms or a halogenated alkyl group of 1 to 5 carbon atoms. The alkyl group of 1 to 5 carbon atoms or halogenated alkyl group of 1 to 5 carbon atoms for R are the same as the alkyl group of 1 to 5 carbon atoms or halogenated alkyl group of 1 to 5 carbon atoms as described above for a substituent on the α-position.

In particular, as R, a hydrogen atom or a methyl group is preferable.

In the formula (f1-1), A represents —O— or —NH—, and —O— is preferable.

In the formula (f1-1), v represents 0 or 1. In the present invention, when v is 0, —C—(═O)-A- represents a single bond.

In formula (f1-1), X⁰ represents a single bond or a divalent linking group.

As the divalent linking group for X⁰, for example, a divalent hydrocarbon group which may have a substituent and a divalent linking group containing a hetero atom can be mentioned, and examples thereof include the same group as the divalent hydrocarbon group which may have a substituent and the divalent linking group containing a hetero atom for X. The divalent linking group for X⁰ may or may not have an acid dissociable group in the structure thereof. As the acid dissociable group, the same acid dissociable groups as those described later in relation to the structural unit (f2) an be mentioned.

As X⁰, a single bond or a divalent linking group containing a hetero atom is preferable, and a single bond or a divalent linking group containing —C(═O)—O— is more preferable.

More specifically, as the divalent linking group for X⁰, when v is 0, a combination of a divalent aromatic hydrocarbon group which may have a substituent with a divalent linking group containing —O—C(═O)— is preferable, and a combination of —O—C(═O)— with a group in which one hydrogen atom of the phenyl group or naphthyl group which may have a substituent is removed therefrom, or a combination of these groups with a linear alkylene group is particularly preferable.

As the divalent linking group for X⁰ when v is 1, a combination of a divalent hydrocarbon group which may have a substituent with a divalent linking group containing —O—C(═O)— is preferable, and a combination of —O—C(═O)— with either an aliphatic hydrocarbon group or an aromatic hydrocarbon group which may have a substituent is particularly preferable. In addition, a combination of these groups with an ether bond (—O—) is also preferable.

When X⁰ represents a divalent linking group, X⁰ may or may not have a fluorine atom. When X⁰ represents a single bond, or when the divalent linking group for X⁰ does not have a fluorine atom, the organic group for Rf⁰ described later has a fluorine atom.

In formula (f1-1), Rf⁰ represents an organic group.

The organic group for Rf⁰ may be an organic group containing a fluorine atom or an organic group which does not contain a fluorine atom. When X⁰ represents a single bond, or when the divalent linking group for X⁰ does not have a fluorine atom, the organic group for Rf⁰ contains a fluorine atom. An “organic group having a fluorine atom” refers to an organic group in which part or all of the hydrogen atoms have been substituted with a fluorine atom.

Preferable examples of the organic group for Rf⁰ include a hydrocarbon group which may have a fluorine atom. The hydrocarbon group which may have a fluorine atom may be an aliphatic hydrocarbon group or an aromatic hydrocarbon group.

As the organic group for Rf⁰, a linear, branched, or cyclic alkyl group can be mentioned.

The linear or branched alkyl group preferably has 1 to 15 carbon atoms, more preferably 1 to 10 carbon atoms, still more preferably 1 to 8 carbon atoms, and most preferably 1 to 5 carbon atoms.

The cyclic alkyl group preferably has 4 to 15 carbon atoms, more preferably 4 to 10 carbon atoms, still more preferably 6 to 10 carbon atoms, and most preferably 5 to 7 carbon atoms.

The aromatic hydrocarbon group for Rf⁰ preferably has 5 to 30 carbon atoms, more preferably 5 to 20, still more preferably 6 to 15, most preferably 6 to 12, particularly preferably 6 to 15, and a phenyl group or a naphthyl group is particularly desirable.

The alkyl group and aromatic hydrocarbon group are preferably substituted with a fluorine atom. The fluorinated alkyl group and fluorinated aromatic hydrocarbon group preferably have 50% or more of the hydrogen atoms thereof fluorinated, more preferably 50% or more, and most preferably all of the hydrogen atoms thereof fluorinated.

In addition, the alkyl group and the aromatic hydrocarbon group may be substituted with a substituent other than a fluorine atom. Examples of substituent other than a fluorine atom include a hydroxy group, a chlorine atom, a bromine atom, an iodine atom and an alkoxy group of 1 to 5 carbon atoms. In addition, the cyclic alkyl group and the aromatic hydrocarbon group may be substituted with an alkyl group of 1 to 5 carbon atoms. The alkyl group of 1 to 5 carbon atoms is the same alkyl group of 1 to 5 carbon atoms as described above for a substituent at α-position.

Preferable examples of the structural units represented by general formula (f1-1) include structural units represented by general formulas (f1-11) to (f1-14) shown below.

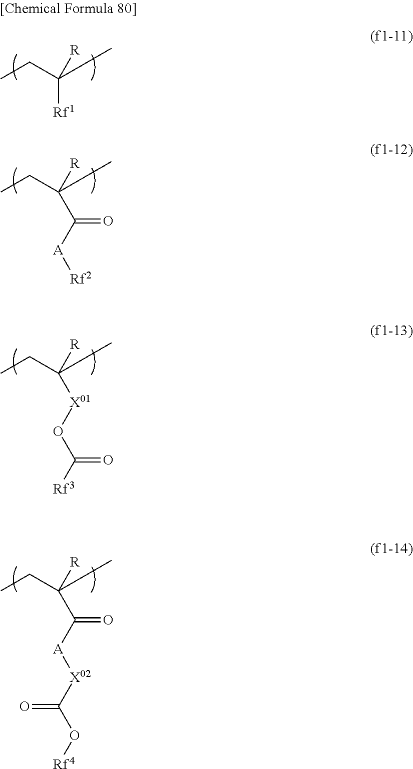

In the formulas, Rf¹ to Rf² represent an organic group containing a fluorine atom; A is the same as defined above; each of X⁰¹ to X⁰² represents a divalent linking group; and Rf³ to Rf⁴ represents an organic group which may have a fluorine atom, provided that at least one of X⁰¹ or Rf³, and at least one of X⁰² and Rf⁴ have a fluorine atom.

In formula (f1-11), Rf⁴ represents an organic group containing a fluorine atom, and is preferably an aromatic hydrocarbon group containing a fluorine atom. Examples of the fluorinated aromatic hydrocarbon group include groups in which part or all of the hydrogen atoms within the aromatic hydrocarbon group for Rf⁰ has been substituted with a fluorine atom.

In formula (f1-12), A is the same as defined above. Rf² represents an organic group containing a fluorine atom, and is preferably a cyclic alkyl group containing a fluorine atom or an aromatic hydrocarbon group containing a fluorine atom. Examples of the cyclic alkyl group containing a fluorine atom and the fluorinated aromatic hydrocarbon group include groups in which part or all of the hydrogen atoms within the cyclic alkyl group and the aromatic hydrocarbon group for Rf⁰ has been substituted with a fluorine atom.

In general formula (f1-13), X⁰¹ represents a divalent linking group, and the same groups as those described above for X⁰ can be used.

Among these, as X⁰¹, the divalent aromatic hydrocarbon group which may have a substituent is preferable, and a group in which one or more hydrogen atoms have been removed from phenyl group or naphthyl group which may have a substituent is preferable.

As the substituent, a fluorine atom and an alkoxy group of 1 to 6 carbon atoms are preferable. When X⁰¹ contains no fluorine atom, Rf³ has a fluorine atom.

In general formula (f1-13), Rf³ represents an organic group which may have a fluorine atom, and is the same organic groups as described above for Rf⁰. As Rf³, a linear or branched alkyl group which may have a fluorine atom is preferable, and preferably has 1 to 5 carbon atoms.

In formula (f1-14), A is the same as defined above. X⁰² represents a divalent linking group, and the same groups as those described above for X⁰ can be used.

As X⁰², a divalent aliphatic hydrocarbon group which may have a substituent, an aromatic hydrocarbon group which may have a substituent, an ether bond (—O—), or a combination thereof is preferable.

As the substituent, a fluorine atom and an alkoxy group of 1 to 5 carbon atoms are preferable. When X⁰² contains no fluorine atom, Rf⁴ has a fluorine atom.

In general formula (f1-14), Rf⁴ represents an organic group which may have a fluorine atom, and is the same defined for Rf³.

When the pattern formation is conducted using a resist composition containing the polymer of the fourth aspect of the present invention by an alkali development, Rf⁴ in the formula (f1-14) is preferably a base dissociable group. The base dissociable group for Rf⁴ is not particularly limited as long as Rf⁴ is a hydrocarbon group which may have a substituent, and preferably has a fluorine atom.

In the present invention, the term “base dissociable group” refers to a group that is decomposable (—O-Rf⁴ is dissociated) by the action of an alkali developing solution. The expression “decomposable in an alkali developing solution” means that the group is decomposable by the action of an alkali developing solution (preferably decomposable by action of a 2.38% by weight aqueous solution of tetramethylammonium hydroxide (TMAH) at 23° C.), and exhibits increased alkali solubility in the alkali developing solution. The reason for this is that the ester bond [—C(═O)—O—Rf⁴] is decomposed (hydrolyzed) by the action of a base (alkali developing solution), thereby forming a hydrophilic group [—C(═O)—OH] (—O—Rf⁴ is dissociated).

The structural unit (f1) having a hydrophilicity prior to exposure is converted into a structural unit having a hydrophilicity after exposure, and therefore, the water tracking ability during immersion exposure is improved, and defects after exposure is reduced. Hence, the polymer containing a structural unit (f1) which contains a base dissociable group according to the first aspect of the present invention is useful for a resist composition for immersion exposure.

Specific examples of structural units represented by general formulas (f1-11) to (f1-14) are shown below. In the formula, R^{β} represents a hydrogen atom or a methyl group;

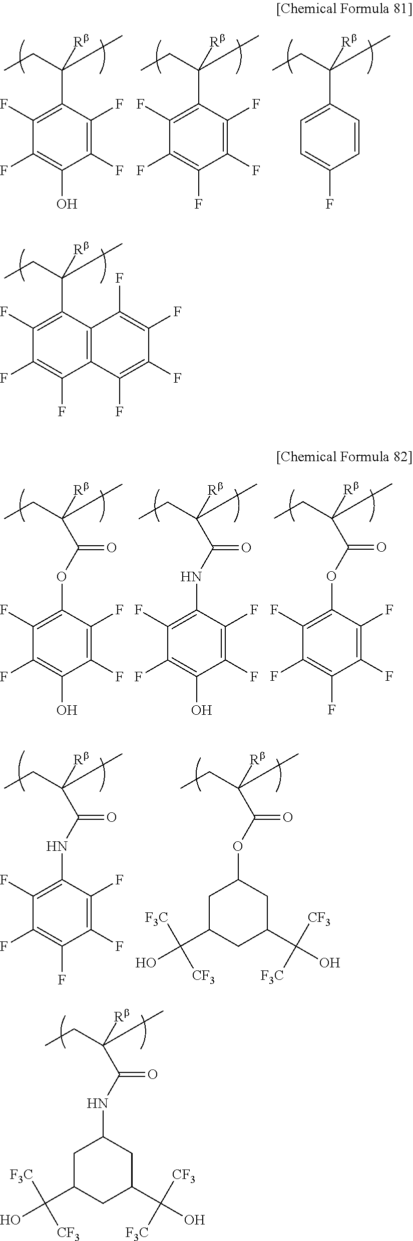

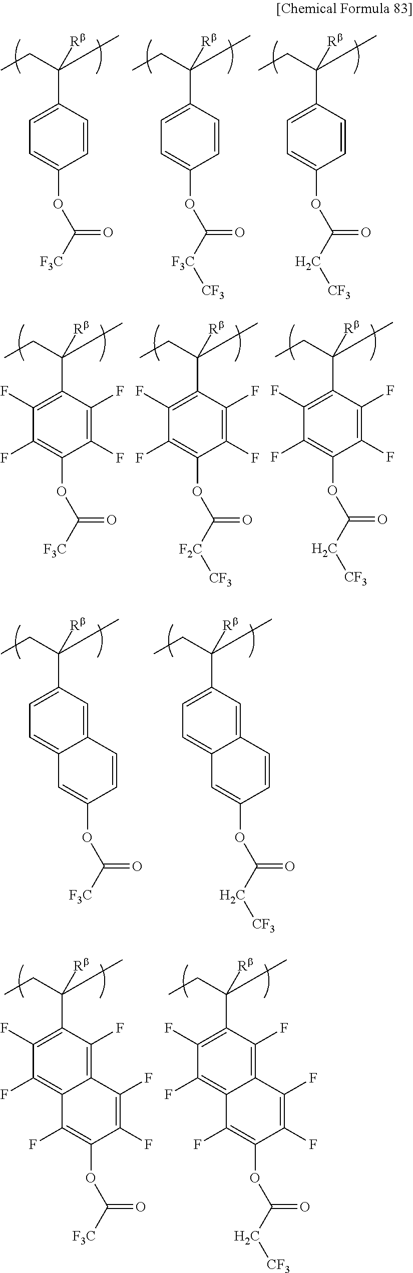

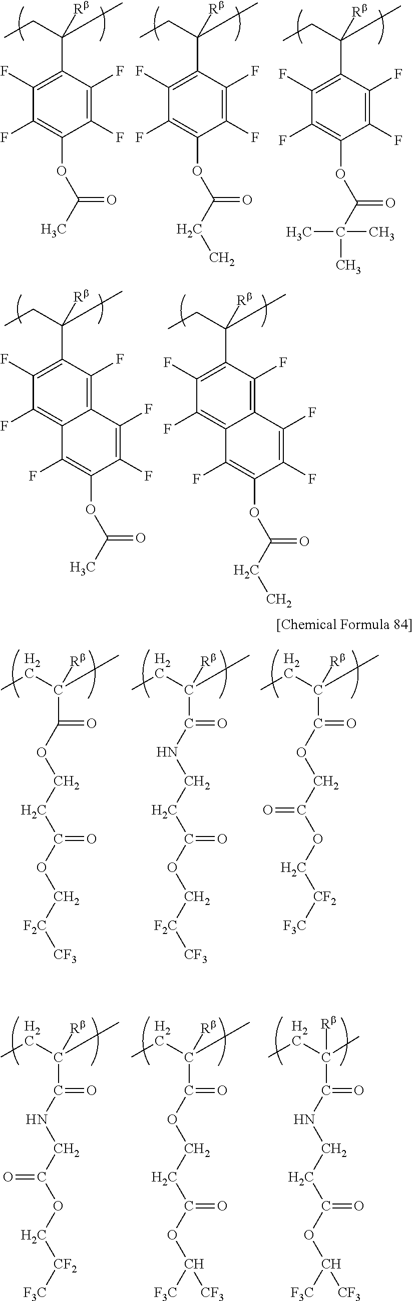

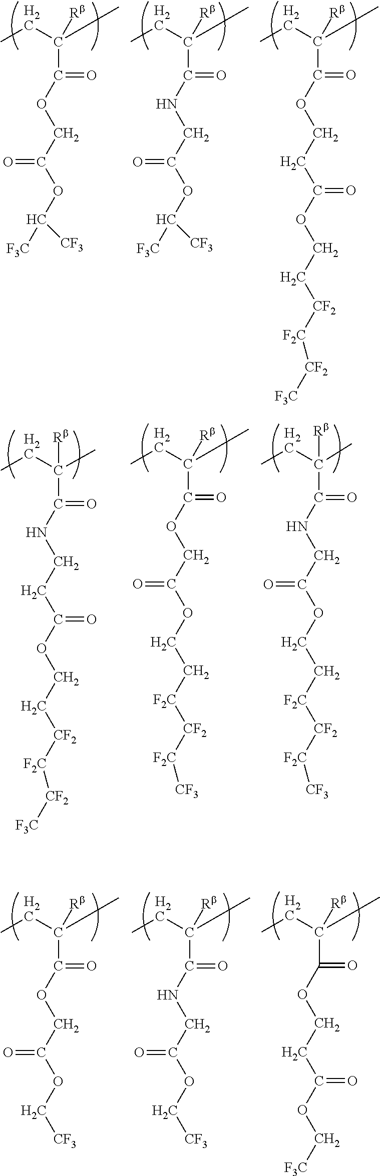

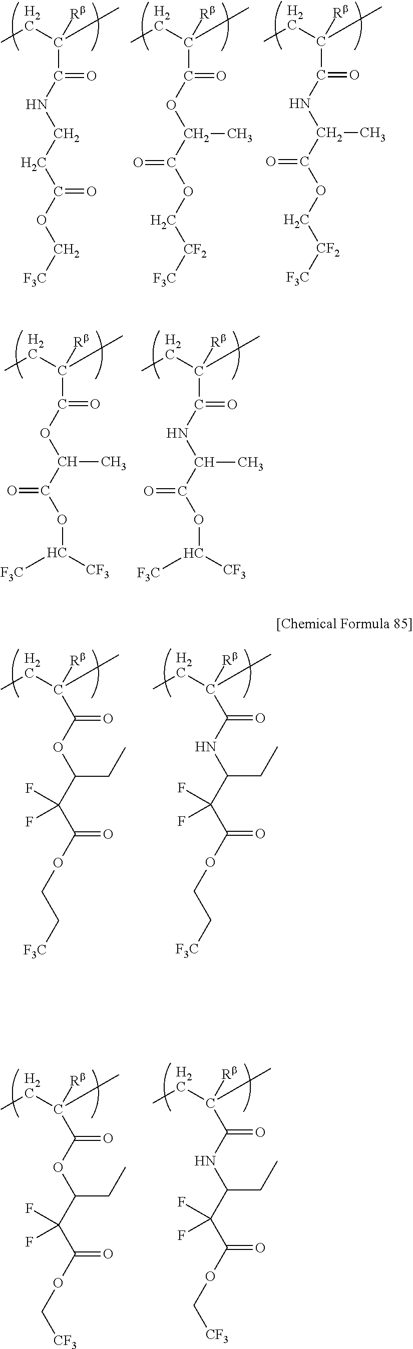

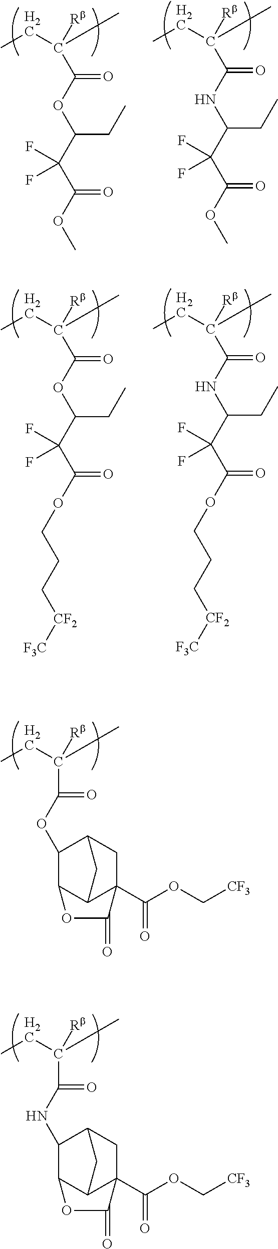

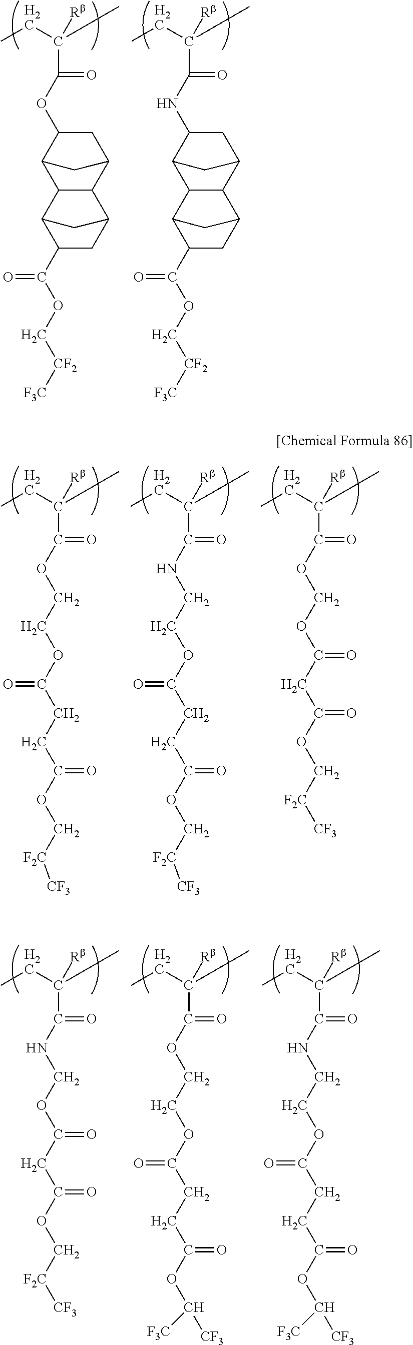

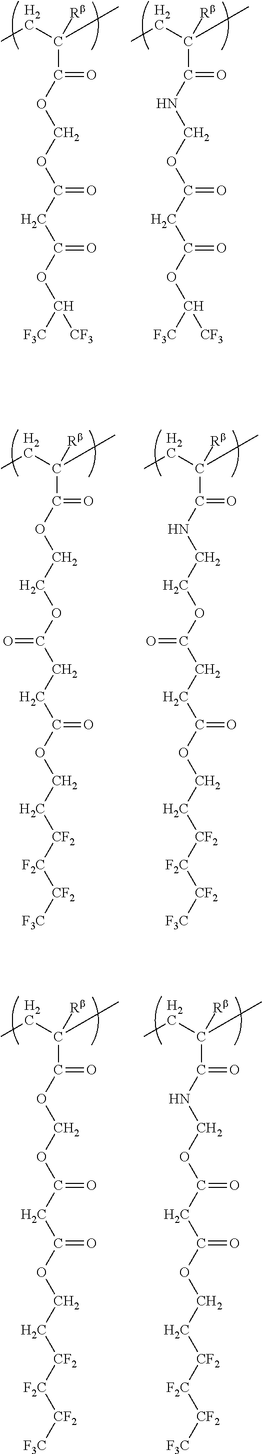

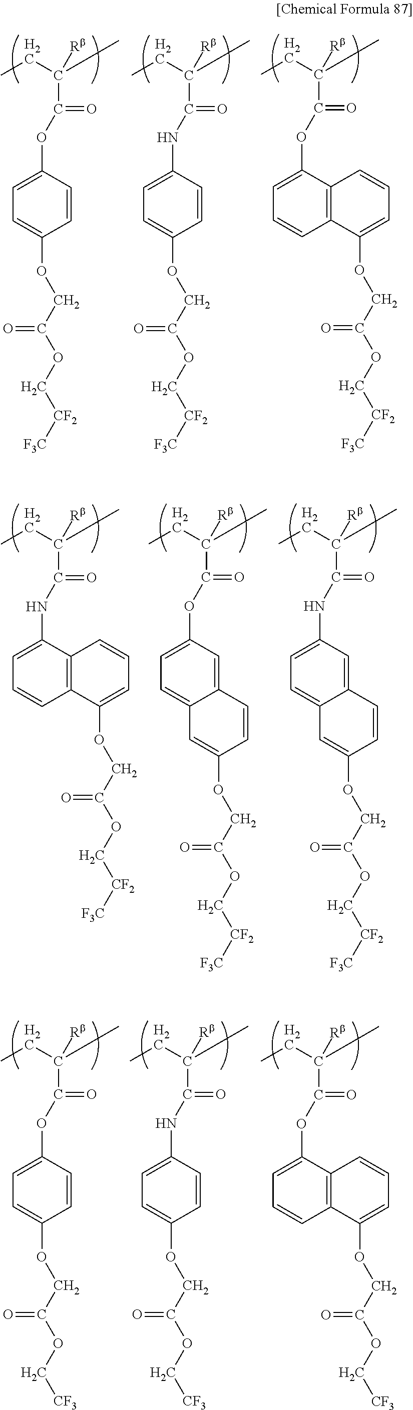

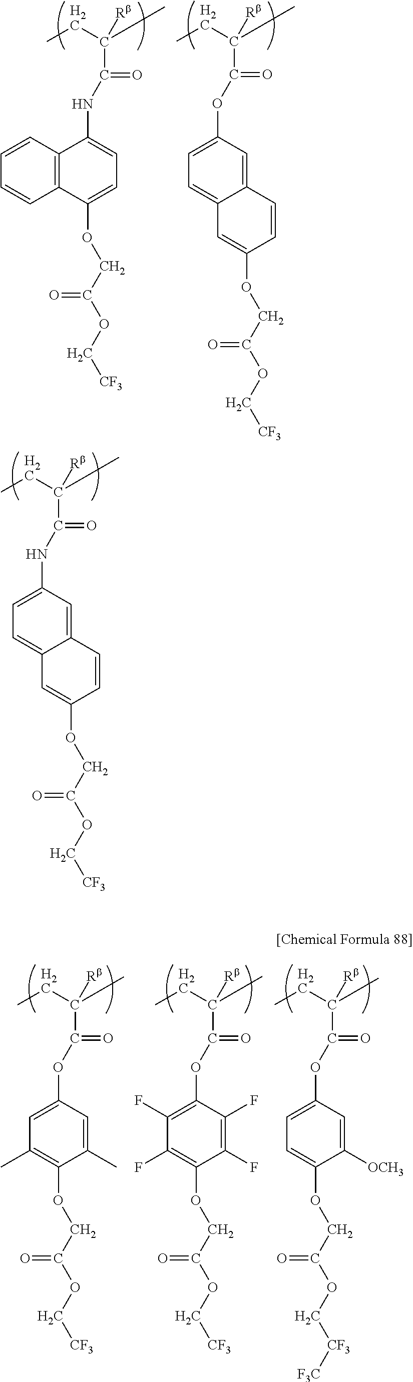

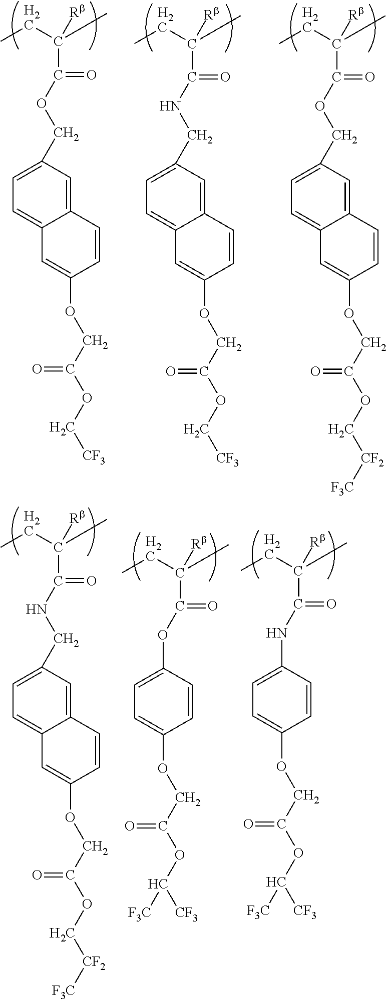

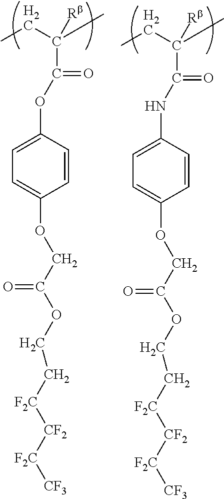

As the structural unit (f1), at least one structural unit selected from the group consisting of structural units represented by general formulas (f1-11) to (f1-14) are preferable, and a structural unit represented by general formula (f1-14) is particularly desirable.

As the structural unit (f1) contained in the polymer of the fourth aspect of the present invention, 1 type of structural unit may be used, or 2 or more types may be used.

In the polymer of the fourth aspect of the present invention, the amount of the structural unit (f1) based on the combined total of all structural units constituting the polymer is preferably 10 mol % or more, more preferably 30 mol % or more, still more preferably 50 mol % or more and may be 100 mol % (homopolymer). By ensuring that the amount of the structural unit (f1) is at least as large as the lower limit of the above-mentioned range, it is possible to impart water repellency to the surface of the resist film, and it is possible to form an excellent pattern in immersion exposure.

When the component (F1) contains a structural unit other than the structural unit (f1), the upper limit of the amount of the structural unit (f1) is preferably 95 mol %, and more preferably 85 mol %.

### <Other Structural Units>

<Structural Unit (f2)>

In the polymer of the fourth aspect of the present invention, it is preferable to include a structural unit (f2) containing an acid decomposable group which exhibits increased polarity by the action of acid, in addition to the structural unit (f1).

As the structural unit (f2), the same as the structural unit (a1) can be mentioned.

As the structural unit (f2) contained in the polymer of the fourth aspect of the present invention, 1 type of structural unit may be used, or 2 or more types may be used.

Among these, as the structural unit (f2), a structural unit (f21) derived from an acrylate ester which may have the hydrogen atom bonded to the carbon atom on the α-position substituted with a substituent is preferred. As the structural unit (f21), the same structural units as the structural unit (a11) can be mentioned.

When the polymer of the fourth aspect of the present invention contains the structural unit (f2), the amount of the structural unit (f2) based on the combined total of all structural units constituting the polymer is preferably 15 to 70 mol %, more preferably 15 to 60 mol % and still more preferably 20 to 55 mol %.

When the amount of the structural unit (f2) is at least as large as the lower limit of the above-mentioned range, a pattern can be easily formed using a resist composition prepared from the polymer, and various lithography properties such as sensitivity, resolution, LWR and the like are improved. On the other hand, when the amount of the structural unit (f2) is no more than the upper limit of the above-mentioned range, a good balance can be achieved with the other structural units.

The polymer of the fourth aspect of the present invention may also have a structural unit other than the above-mentioned structural units (f1) and (f2), as long as the effects of the present invention are not impaired.

As such a structural unit, any other structural unit which cannot be classified as the aforementioned structural units can be used without any particular limitation, and any of the multitude of conventional structural units used within polymers for ArF excimer lasers or KrF excimer lasers (and particularly for ArF excimer lasers) can be used.

The structural unit is not particularly limited as long as it is copolymerizable with the structural unit (f1) or the structural unit (f2), and examples thereof include a structural unit (f3) containing a polar group and which and does not fall under the definition of the aforementioned structural unit (f1).

<Structural Unit (f3)>

The structural unit (f3) is a structural unit containing a polar group and does not fall under the definition of the aforementioned structural unit (f1).

When the structural unit (f3) contains a polar group, the hydrophilicity of the component (A1) is enhanced, thereby contributing to improvement in resolution. Examples of the polar group include —OH, —COOH, —CN, —SO₂NH₂ and —CONH₂. By virtue of having these groups, it is presumed that the hydrophilicity is increased, and defects can be reduced preferably.

As the structural unit (f3), the same as the structural unit (a3) is preferable.

As the structural unit (f3), a structural unit represented by general formula (f3-3-4) shown below can be also used. In the formulas shown above, R^{α} represents a hydrogen atom, a methyl group or a trifluoromethyl group.

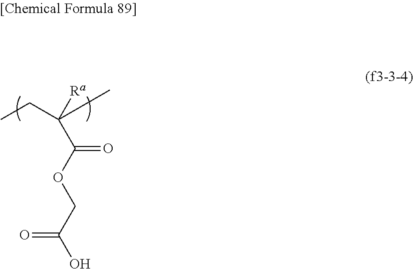

Furthermore, as the structural unit (f3), a structural unit represented by general formula (f3-0′) can be also used.

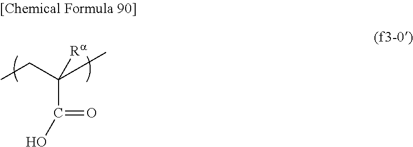

In the formula, is the same as those defined above.

As the structural unit (f3), one type of structural unit may be used alone, or two or more structural units may be used in combination.

When the polymer of the fourth aspect of the present invention includes the structural unit (f3), the amount of the structural unit (f3) based on the combined total of all structural units constituting the component (F) is preferably 1 to 50 mol %, more preferably 5 to 40 mol %, and particularly preferably 10 to 30 mol %. When the amount of the structural unit (f3) is at least as large as the lower limit of the above-mentioned range, the effect of using the structural unit (f3) can be satisfactorily achieved. On the other hand, when the amount of the structural unit (f3) is no more than the upper limit of the above-mentioned range, a good balance can be achieved with the other structural units.

A polymer according to the fourth aspect of the present invention contains an anion part which generates acid upon exposure on at least one terminal of the main chain, and the structural unit (f1). The polymer may also include other structural units such as the structural unit (f2), the structural unit (f3), and the like. When the polymer contains a structural unit other than the structural unit (f1), it is preferable to contain the structural unit (f2).

Examples of the polymer include a polymer which contains a group represented by the general formula (I-1-1) on the terminal of the main chain, and consists of a structural unit represented by the formula (f1-1); and a polymer which contains a group represented by the general formula (I-1-1) on the terminal of the main chain, and consists of a structural unit represented by the general formula (f1-1) and a structural unit represented by the formula (a11-0-11).

More specifically, a polymer consisting of a structural unit represented by the formula (f1-14), and a polymer consisting of a structural unit represented by the formula (f1-14) and a structural unit represented by the formula (a1-1-32) are particularly desirable.

The weight average molecular weight (Mw) (the polystyrene equivalent value determined by gel permeation chromatography) of the polymer of the fourth aspect of the present invention is not particularly limited, but is preferably 1,000 to 80,000, more preferably 5,000 to 60,000, and most preferably 10,000 to 50,000. When the weight average molecular weight of the polymer is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the polymer of the fourth aspect of the present invention is preferably 1.0 to 5.0, more preferably 1.0 to 3.0, and most preferably 1.2 to 2.5. Here, Mn is the number average molecular weight.

### (Production Method of Polymer)

The polymer of the first aspect of the present invention can be obtained, for example, by a radical polymerization or an anionic polymerization, using monomers including at least one monomer which derives at least one structural unit selected from the group consisting of a structural unit (a0), a structural unit (a3) and a structural unit (a5), and using a radical polymerization initiator containing an anion part which generates acid upon exposure.

The polymer of the fourth aspect of the present invention can be obtained, for example, by a radical polymerization or an anionic polymerization, using monomers including at least one monomer which derives a structural unit (f1), and using a radical polymerization initiator containing an anion part which generates acid upon exposure.

As the monomers, commercially available monomers may be used, or the monomers synthesized by a conventional method may be used.

The polymer of the present invention is preferably a radical polymer obtained by radial polymerization using a radical polymerization initiator including a compound represented by general formula (I).

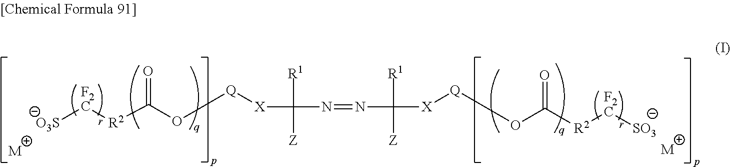

In the formula, R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having —O—C(═O)—, —NH—C(═O)— or —NH—C(═NH)— on at least the terminal bonded to Q; p represents an integer of 0 to 3.

Q represents a hydrocarbon group having a valency of (p+1), provided that, p represents 1, Q may represent a single bond;

R² represents an alkylene group which may have a substituent or an aromatic group which may have a substituent, q represents 0 or 1, and r represents an integer of 0 to 8. M⁺ represents an organic cation. The plurality of R¹, Z, X, p, Q, R², q, r and M⁺ may be the same or different from each other.

In the formula (I), R¹, Z, X, p, Q, R², q, r and M⁺ are respectively the same as R¹, Z, X, p, Q, R², q, r, M⁺ in the formula (I-1), respectively.

As the monomers used in the radical polymerization, any monomers which can be polymerized with a monomer which derives at least one structural unit selected from the group consisting of the structural unit (a0), the structural unit (a3) and the structural unit (a5), or a monomer which derives the structural unit (f1) can be used. These monomers can be appropriately selected according to the polymer to be formed.

The radical polymerization can be conducted by a conventional method, expect that a compound represented by the formula (I) is used as a radical polymerization initiator.

In the radical polymerization, as the radical polymerization initiator, one type may be used alone, or two or more types may be used in combination.

Production examples of the polymer of the present invention are shown below. With respect to the production example described below, a synthetic route in which the monomer represented by the formula (a3-1-0) (the monomer derives the structural unit represented by the formula (a3-1); hereafter, referred to as “monomer (a3-1-0)”) is subjected to a radical polymerization using a radical polymerization initiator composed of the compound represented by the formula (I) (hereafter, referred to as “radical polymerization initiator (I)”) is schematically described. However, the synthetic route of the polymer is not limited to the following production examples. For example, a monomer represented by formula (a0-0-0) (monomer which derives the structural unit represented by formula (a0-0); hereafter, referred to as “monomer (a0-0-0)”), a monomer represented by formula (a11-0-01) (monomer which derives the structural unit represented by formula (a11-0-01); hereafter, referred to as “monomer (a11-0-1)”), a monomer represented by formula (a5m) (hereafter, referred to as “monomer (a5m)”) or a monomer represented by formula (f1-1m) (hereafter, referred to as “monomer (f1-1m)”) may be used, instead of the monomer (a3-1-0).

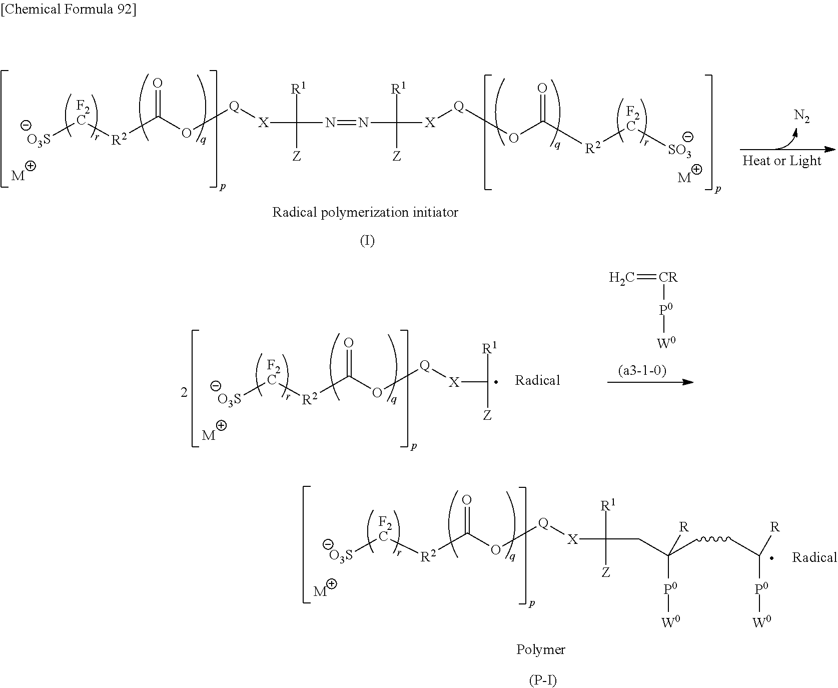

In the formula, R¹, Z, X, p, Q, R², q, r and M⁺ are the same as defined for R¹, Z, X, p, Q, R², q, r and M⁺ in the formula (I-1); and R, P⁰ and W⁰ are the same as defined for R, P⁰ and W⁰ in the formula (a3-1).

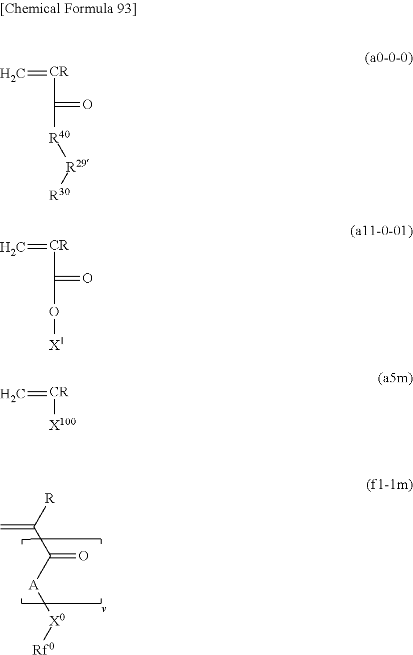

In the formula (a0-0-0), R, R⁴⁰, R³⁰ and R²⁹′ are the same as defined for R, R⁴⁰, R³⁰ and R²⁹′ in the formula (a0-0-0). In the formula (a11-0-01), R, X¹ are the same as defined for R and X¹ in the formula (a11-0-1). In the formula (a5m), X¹⁰⁰ represents a characteristic group which is capable of generating an acid upon exposure. In the formula (f1-1m), A, X⁰, Rf⁰, and v are the same as defined for A, X⁰, Rf⁰ and v in the formula (f1-1).

In the formula (a5m), X¹⁰⁰ represents a characteristic group which is capable of generating an acid upon exposure. Examples thereof include a combination of a divalent linking group with a group represented by the formula (a5-1) or (a5-2). As the divalent linking group, the same groups as those for X in the formula (I-1) can be used, and —C(═O)O— or a divalent aromatic hydrocarbon group is preferable.

In the synthetic route, the radical polymerization initiator (I) is decomposed by the action of heat or light, thereby generating nitrogen gas (N₂) and a carbon radical.

Next, the carbon radical acts on the monomer (a3-1-0), and the polymerization of monomers (a3-1-0) is proceeded, thereby obtaining the polymer (P-I).

The resulting polymer (P-I) contains an anion part which generates acid upon exposure on at least one terminal of the main chain. The “anion part which generates acid upon exposure” is a residue derived from a radical polymerization initiator (I) (aforementioned terminal group (I-1)).

In addition, the polymer preferably has a weight average molecular weight of 20,000 or less.

In order to control the weight average molecular weight of the polymer to 20,000 or less, during the polymerization, the used amount of the radical polymerization initiator (I), the reaction solvent, the polymerization temperature and the concentration of the polymerization solution can be appropriately adjusted.

As the radial polymerization initiator (I), a compound represented by any one of general formulas (I1) to (I5) shown below is preferable.

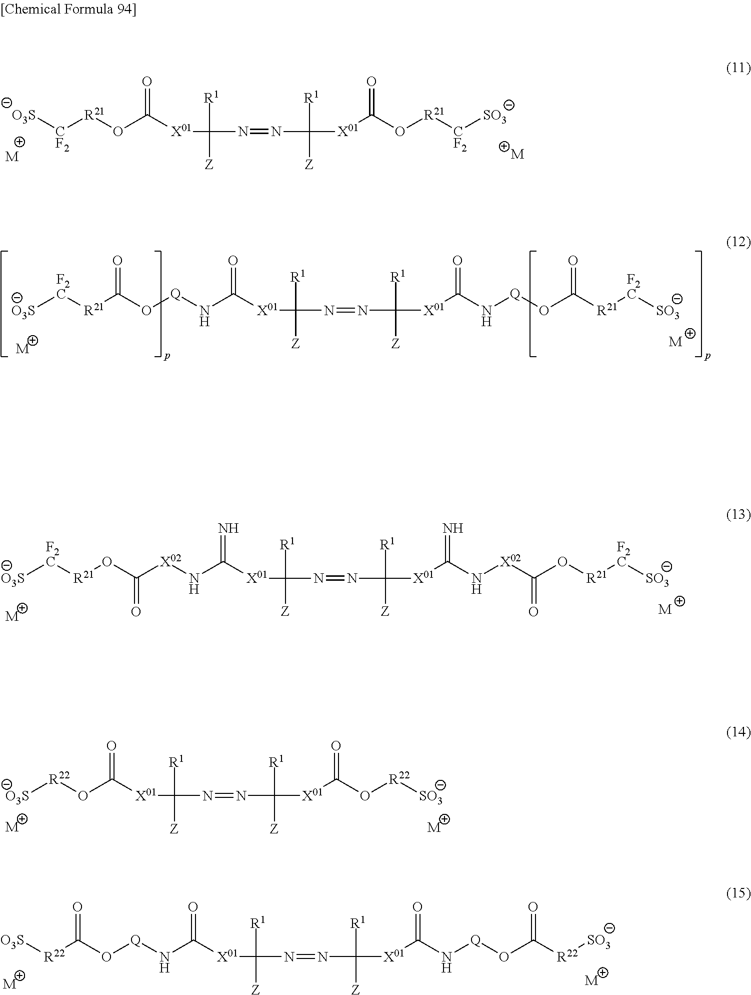

In the formulas, R¹, Z, Q, p and M⁺ are the same as defined above; X⁰¹ represents a single bond or an alkylene group which may have a substituent; R²¹ represents a single bond or an alkylene group which may have a substituent; X⁰² represents an alkylene group which may have a substituent; and R²² represents an aromatic group which may have a substituent, and provided that the plurality of R¹, Z, Q, p, M⁺, X⁰¹, R²¹, X⁰² and R²² may be the same or different from each other.

In the formulas (I1) to (I5), R¹, Z, X⁰¹, Q, p and M⁺ are respectively the same as R¹, Z, X⁰¹, Q, p and M⁺ in the formulas (I-1-1) to (I-1-5), respectively.

In general formulas (I1) and (I3), R²¹ is the same as defined for R²¹ in general formulas (I-1-1) and (I-1-3).

In general formula (I3), X⁰² is the same as defined for X⁰² in general formula (I-1-3).

In general formulas (I4) and (I5), R²² is the same as defined for R²² in general formulas (I-1-4) and (I-1-5).

Specific examples of compounds represented by general formulas (I1) to (I5) are shown below. In the following formulas, M⁺ is the same as defined above.

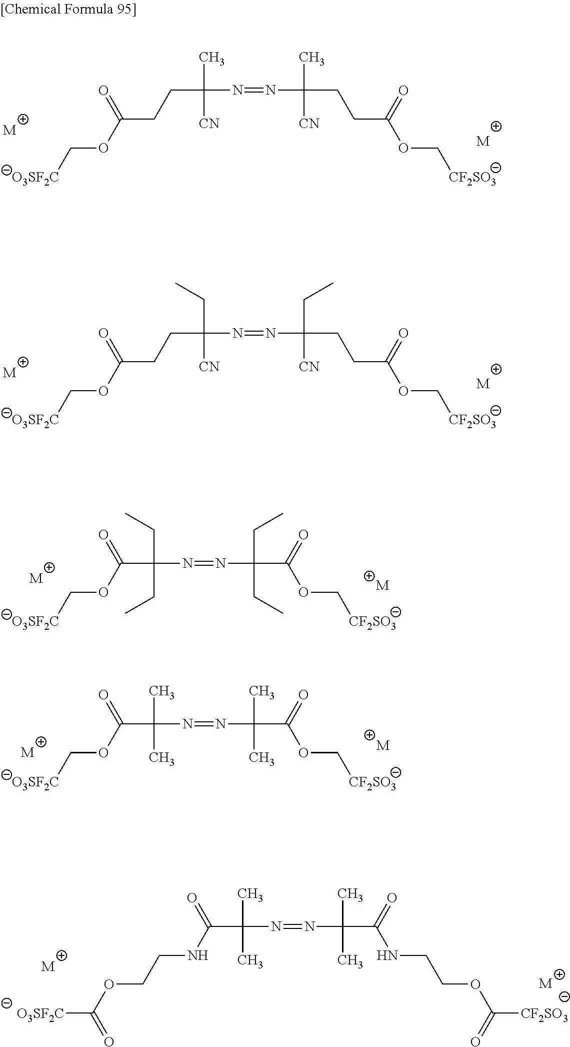

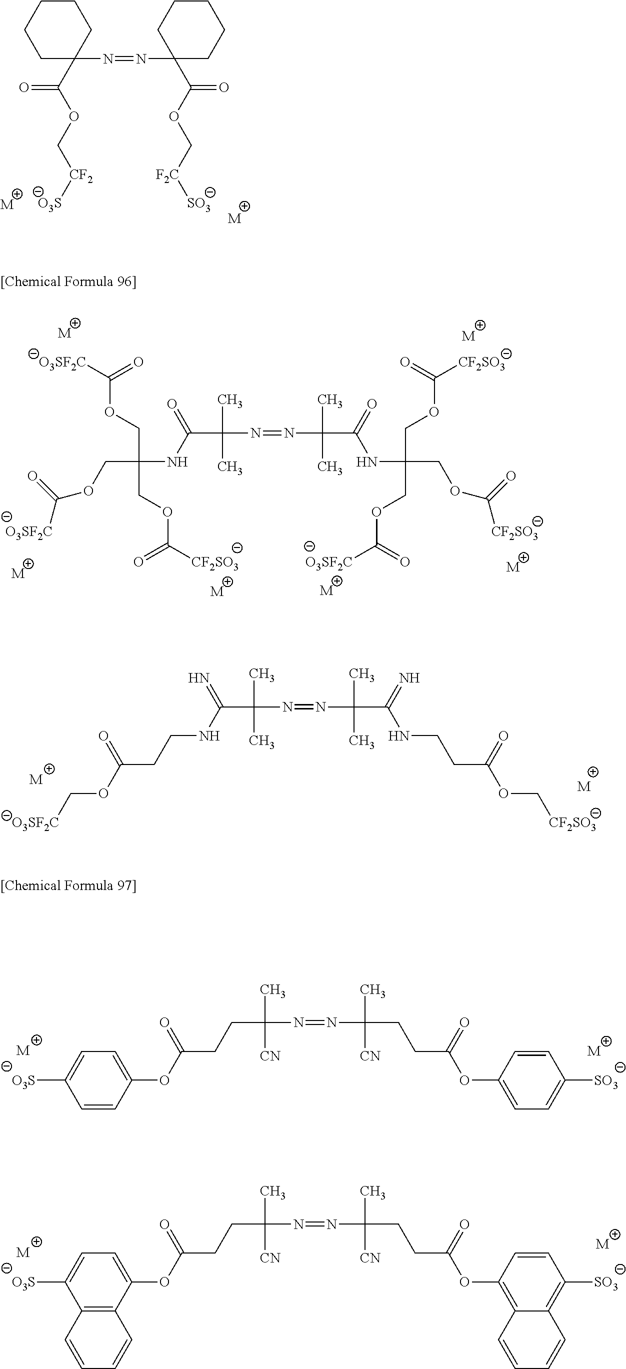

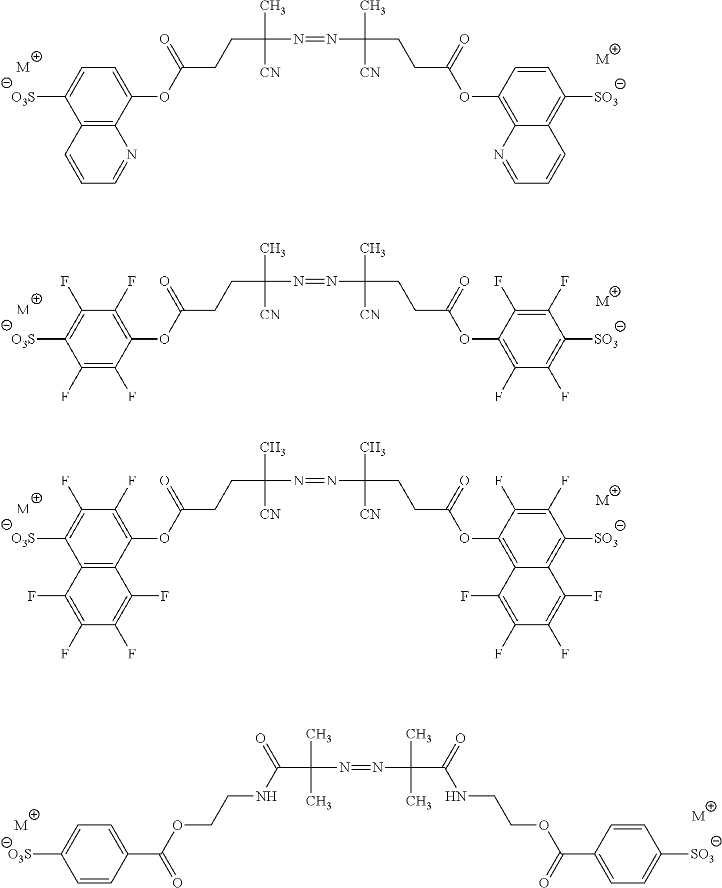

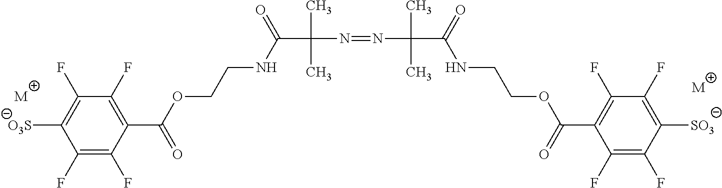

Among these, as the radical polymerization initiator (I), a compound represented by any one of the formulas (I1) to (I5) is preferable, and a compound represented by the formula (I1) is particularly preferable.

In addition, as the organic cation for M⁺, an organic cation represented by any one of aforementioned formulas (c-1) to (c-3) is preferable, and an organic cation represented by the aforementioned formula (c-1) is particularly preferable.

The production method of the radical polymerization initiator (I) is not particularly limited, although a method containing a step of reacting a compound represented by general formula (i-1) shown below (hereafter referred to as “compound (i-1)”) to a compound represented by general formula (i-2) shown below (hereafter referred to as “compound (i-2)”) can be preferably used.

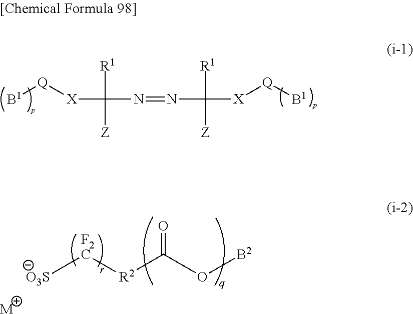

In the formulas, R¹, Z, X, Q, p, q, R², r and M⁺ are the same as defined above; and each of B¹ and B² independently represents H or OH, provided that the plurality of R¹, Z, X, p, Q and B¹ may be the same or different from each other.

In the formula (i-1), when the terminal of Q bonded to B¹ is an oxygen atom, or when Q represents a single bond and the terminal of Q bonded to B¹ is an oxygen atom, B¹ is preferably H. On the other hand, the terminal of Q bonded to B¹ is not an oxygen atom, or when Q represents a single bond and the terminal of Q bonded to B¹ is not an oxygen atom, B¹ is preferably OH.

In the formula (i-2), when q represents 1, B² is preferably H. On the other hand, q represents 0, B² is preferably OH.

As the compound (i-1) and the compound (i-2), commercially available compounds may be used, or synthesized compounds may be used.

Examples of the method for reacting the compound (i-1) with the compound (i-2) to obtain the radical polymerization initiator (I) include a method containing reacting the compound (i-1) with the compound (i-2) in an organic solvent in the presence of a condensation agent and base, followed by washing the reaction mixture thereby collecting the reaction product.

Examples of the condensation agent used in the reaction include compounds containing carbodiimide groups, such as diisopropylcarbodiimide. These compounds may be used individually or in a combination of two or more. The amount of the condensation agent is preferably 0.01 to 10 moles, per 1 mole of the compound (i-2).

Examples of the base used in the reaction include potassium carbonate, tertiary amines such as triethylamine and aromatic amines such as pyridine. These bases may be used individually or in a combination of two or more. The amount of the base is preferably 0.01 to 10 moles, per 1 mole of the compound (i-2).

As the organic solvent used in the reaction, chlorinated hydrocarbon solvents such as dichloromethane is preferred. The amount of the organic solvent is preferably 0.5 to 100 parts by weight, and more preferably 0.5 to 20 parts by weight, relative to the amount of the compound (i-2). As the organic solvent, one type may be used alone, or two or more types may be used in combination.

In general, when p represents 1, the amount of the compound (i-2) used in the reaction is preferably 0.5 to 5 moles per 1 mole of the compound (i-1), and more preferably 0.8 to 4 moles per 1 mole of the compound (i-1).

The reaction time in the aforementioned reaction varies depends on the reactivity of the compounds (i-1) and (i-2), the reaction temperature or the like. However, in general, the reaction time is preferably 1 to 80 hours, and more preferably 3 to 60 hours.

The reaction temperature in the aforementioned reaction is preferably 20 to 200° C., and more preferably 20 to 150° C.

After the reaction is completed, the radical polymerization initiator (I) in the reaction solution may be separated and purified. The separation and purification can be conducted by a conventional method, and for example, any one of concentration, solvent extraction, distillation, crystallization, recrystallization and chromatography can be used alone, or two or more of these methods may be used in combination.

The structure of the radical polymerization initiator (I) obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

As an another method of producing the polymer of the present invention, examples include a method in which a polymer (precursor polymer) having a group represented by the following formula (I-01) on at least one terminal of the main chain is obtained using a radical polymerization initiator (I0) represented by the general formula (I0) shown below, and a group “—(OCO)_{q}—R²—(CF₂)ᵣ—SO₃⁻M⁺ (wherein q, R², r and M⁺ are the same as those defined above)” is induced on the terminal of the main chain of the precursor polymer (substituted the hydrogen atom on the terminal of the main chain with the group). As the compound (I-01), conventional compounds can be used.

Inducing “—(OCO)_{q}—R²—(CF₂)ᵣ—SO₃⁻M⁺” can be conducted by a conventional method. For example, it can be conducted by a method including reacting a precursor polymer with a compound (i-02) represented by general formula (i-02) shown below. The reaction can be conducted in the same manner as the method of reacting the compound (i-1) with the compound (i-2) as described above.

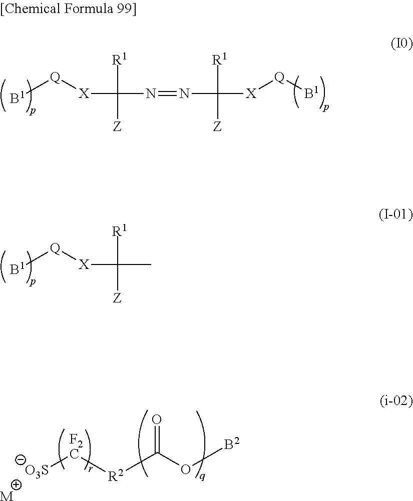

In the formulas, R¹, Z, X, Q, p, q, R², r, M⁺ and B¹, B² are the same as defined above.

With respect to the polymer of the present invention as described above, by virtue of containing an anion part which generates acid upon exposure on at least one terminal of the main chain, the polymer of the present invention is capable of generating an acid upon exposure. For example, by virtue of the sulfonium salt part at the end of the group represented by the general formula (I-1) (terminal group (I-1)), sulfonic acid is generated upon exposure.

In addition, by virtue of containing the structural unit (a3) which contains at least one group selected from the group consisting of —OH, —COOH, —CN, —SO₂NH₂ and —CONH₂, the hydrophilicity of the polymer can be enhanced. In the resist composition containing the polymer, the polymer contributes to favorable improvements in the resolution, and various lithography properties and pattern shape can be improved.

Further, with respect to the polymer according to the first aspect of the present invention, by virtue of including the structural unit (a0) containing a —SO₂— containing cyclic group, the adhesion of a resist film formed by a resist composition containing the polymer to a substrate can be enhanced. In addition, it is presumed that there is a large interaction between the structural unit (a0) and an acid-generator component in the resist composition, and therefore, by virtue of containing the structural unit (a0), the acid-generator component is likely to be uniformly distributed in the resist film.

In addition, with respect to the polymer according to the first aspect of the present invention, by virtue of including the structural unit (a5) which generates acid upon exposure is contained in the polymer, acid is generated from the structural unit (a5) as well as the terminal of the main chain upon exposure. Therefore, the polymer is capable of improving the acid-generating ability.

Further, with respect to the polymer according to the first aspect of the present invention, by virtue of having a weight average molecular weight of 20,000 or less, as compared to the polymer having the weight average molecular weight of greater than 20,000, the solubility in a solvent is enhanced, because the interaction between polymers is relatively weak, therefore a glass transition temperature tends to be low.

Moreover, with respect to the polymer according to the fourth aspect of the present invention, by virtue of containing the structural unit (f1) containing a fluorine atom, the polymer itself has water repellency.

Therefore, the polymers of the present invention are useful as a resin for a resist composition, and particularly useful as a base component for the chemically amplified resist composition.

The polymer of the first aspect of the present invention is useful for a resist composition. There are no particular limitations on the resist composition containing the polymer, although a chemically amplified resist composition including a base component that exhibits changed solubility in an alkali developing solution under the action of acid, and an acid generator component that generates acid upon exposure is preferred.

The polymer according to the first aspect of the present invention is useful as a base component for the chemically amplified resist composition, or as an additive component which is arbitrarily blended into a resist component, and use as a base component is particularly preferable.

There are no particular limitations on the resist composition containing the polymer according to the fourth aspect of the present invention, although a chemically amplified resist composition including a base component that exhibits changed solubility in an alkali developing solution under the action of acid is ideal. Among these, it is particularly suitable for use in a chemically amplified resist composition for immersion exposure which requires water repellency during exposure.

The polymer according to the fourth aspect of the present invention is useful as a base component for the chemically amplified resist composition, or as an additive component which is blended into a resist component, and use as a resist component is particularly preferable.

### <<Resist Composition>>

The resist composition of the present invention contains the polymer of the present invention. The resist film formed from the resist composition has a function of generating an acid upon exposure.

In addition, by virtue of including the polymer of the present invention in the resist film, it is possible to form a pattern using the components which exhibits a changed solubility under action of acid, even if the resist composition does not additionally contain an acid-generator component. On the other hand, when the resist composition contains an acid-generator component other than the polymer of the present invention, the sensitivity thereof is further improved, as compared to a resist composition which does not contain the polymer of the present invention.

The resist composition of the present invention may be either a negative resist composition or a positive resist composition.

In the present specification, a resist composition which forms a positive pattern by dissolving and removing the exposed portions is called a positive resist composition, and a resist composition which forms a negative pattern by dissolving and removing the unexposed portions is called a negative resist composition.

In addition, the resist composition of the present invention, may be either a non-chemically amplified type or a chemically amplified type. In particular, the resist composition of the present invention contains a polymer which generates acid from the terminal of the main chain or from the terminal of the side chain (the terminal of the structural unit (a5)). Therefore, the resist composition of the present invention is preferably a chemically amplified resist composition. In addition, the chemically amplified resist composition is preferable because it can form a resist pattern with high sensitivity and high resolution.

As a chemically amplified composition, a composition including a base material component that exhibits a changed solubility in a developing solution under the action of acid and an acid-generator component that generates acid upon exposure is generally used.

The resist composition according to the second aspect of the present invention contains a base component (A) which exhibits changed solubility in a developing solution under action of acid, and generates acid upon exposure. The resist composition may or may not contain an acid-generator component other than the component (A).

The resist composition according to the fourth aspect of the present invention contains a fluorine-containing polymeric compound component (F) which generates acid upon exposure. The resist composition may or may not contain an acid-generator component other than the component (F).

When the resist composition is subjected to a selective exposure, acid is generated from an acid-generator component, and the solubility of the base component in a developing solution is changed by the action of the acid. As a result, in the formation of a resist pattern, when a resist film formed from the resist composition is subjected to selective exposure, at the exposed portions of the resist film, the solubility in the alkali developing solution is changed (In the case of positive resist composition, the solubility is increased. In the case of negative resist composition, the solubility is decreased), whereas the solubility in the alkali developing solution at the unexposed portions of the resist film remains unchanged. Therefore, by developing the resist film after exposure, a resist pattern can be formed.

As described above, in the chemically amplified resist composition, a base component which exhibits changed solubility in a developing solution under action of acid is generally used.

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed. The “organic compound having a molecular weight of 500 or more” which can be used as a base component is broadly classified into non-polymers and polymers. In general, as a non-polymer, any of those which have a molecular weight in the range of 500 to less than 4,000 is used. Hereafter, a non-polymer having a molecular weight in the range of 500 to less than 4,000 is referred to as a low molecular weight compound. As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

### <<Resist Composition 1>>

The resist composition according to the second aspect of the present invention may contain the polymer according to the first aspect of the present invention as a base component (A) which exhibits changed solubility in a developing solution under action of acid, or may contain the polymer of the first aspect of the present invention in addition to other resin constituting the base component. That is, when the polymer according to the first aspect is used in the resist composition according to the second aspect, the polymer according to the first aspect of the present invention may be either a polymer which exhibits increased solubility in a developing solution under the action of acid, or other polymer.

The polymer according to the first aspect of the present invention used in the resist composition according to the present invention is preferably a polymer which exhibits increased solubility in a developing solution under the action of acid, and which is useful for a base component.

As described above, the polymer according to the first aspect of the present invention contains an anion part which generates acid upon exposure on at least one terminal of the main chain. In addition, in the case of the polymer exhibits a changed solubility in a developing solution under the action of acid, the anion part on the terminal of the main chain, the generating-acid part which generates acid on the terminal of the side chain (the terminal of the structural unit (a5)) and the part which contributes to change the solubility under the action of acid (specific examples includes the structural unit (a1)) are uniformly distributed within the resist film, and at the exposed portions, acid is uniformly generated from the polymer thereby changing the solubility of the polymer itself by the action of the acid. As a result, excellent lithography properties can be achieved.

That is, the resist composition according to the second aspect of the present invention preferably contains a base component (A) which exhibits changed solubility in a developing solution under action of acid, and generates acid upon exposure (hereafter, referred to as “component (A)”), and which contains the polymer according to the first aspect of the present invention.

The resist composition according to the second aspect of the present invention preferably contains the base component (A) and an acid generator component (B) which generates acid upon exposure (provided that the base component (A) is excluded) (hereafter, referred to as “component (B)”), and which contains the polymer according to the first aspect of the present invention.

Next, the resist composition containing the polymer according to the first aspect of the present invention as a component (A) will be described.

### <Component (A)>

In the case where the resist composition according to the second aspect of the present invention is a “negative resist composition for alkali developing process” to form a negative pattern in an alkali developing process, for example, as the component (A), a base component that is soluble in an alkali developing solution is used, and a cross-linking agent is blended in the negative resist composition.

In the negative resist composition for alkali developing process, when acid is generated from the polymer according to the first aspect of the present invention contained in the component (A) upon exposure, the action of the generated acid causes cross-linking between the base component and the cross-linking agent, and the cross-linked portion becomes insoluble in an alkali developing solution. Therefore, in the formation of a resist pattern, by conducting selective exposure to a resist film formed by applying the negative resist composition onto a substrate, the exposed portions become insoluble in an alkali developing solution, whereas the unexposed portions remain soluble in an alkali developing solution, and hence, a resist pattern can be formed by alkali developing.

Generally, as the component (A) used for a negative resist composition for alkali developing process, a resin that is soluble in an alkali developing solution (hereafter, referred to as “alkali-soluble resin”) is used.

Examples of the alkali soluble resin include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin which has a sulfonamide group and may have the hydrogen atom bonded to the carbon atom on the α-position substituted with a substituent or polycycloolefin resin having a sulfoneamide group, as disclosed in U.S. Pat. No. 6,949,325; an acrylic resin which may have the hydrogen atom bonded to the carbon atom on the α-position substituted with a substituent, and which has a fluorinated alcohol, as disclosed in Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable, because a resist pattern can be formed with minimal swelling.

Here, the term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the cross-linking agent, typically, an amino-based cross-linking agent such as a glycoluril having a methylol group or a alkoxymethyl group, or a melamine-based cross-linking agent is preferable, as it enables formation of a resist pattern with minimal swelling. The amount of the cross-linking agent added is preferably within a range from 1 to 50 parts by weight, relative to 100 parts by weight of the alkali-soluble resin.

In the case where the resist composition of the second aspect of the present invention is a resist composition which forms a positive pattern in an alkali developing process and a negative pattern in a solvent developing process, it is preferable to use a base component (A0) (hereafter, referred to as “component (A0)”) which exhibits increased polarity by the action of acid, as a component (A). By using the component (A0), since the polarity of the base component changes prior to and after exposure, an excellent development contrast can be obtained not only in an alkali developing process, but also in a solvent developing process.

More specifically, in the case of applying an alkali developing process, the component (A0) is substantially insoluble in an alkali developing solution prior to exposure, but when acid is generated from the polymer according to the first aspect of the present invention contained in the component (A) upon exposure, the polarity of the base component is increased by the action of the acid, thereby increasing the solubility of the component (A0) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A0) exhibits high solubility in an organic developing solution prior to exposure, and when acid is generated from the polymer according to first aspect of the present invention contained in the component (A) upon exposure, the polarity of the component (A0) is increased by the action of the generated acid, thereby decreasing the solubility of the component (A0) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the resist composition of the first aspect of the present invention, the component (A) is preferably a base component which exhibits increased polarity by the action of acid (i.e., a component (A0)). That is, the resist composition of the first aspect of the present invention is preferably a chemically amplified resist composition which becomes a positive type in the case of an alkali developing process, and a negative type in the case of a solvent developing process.

In particular, in the resist composition according to the first aspect of the present invention, the component (A) preferably contains a component (A1) which consists of the polymer according to the first aspect of the present invention and exhibits increased polarity by the action of acid (hereafter, referred to as “component (A1)”).

[Component (A1)]

The component (A1) is a polymer which contains an anion part which generates acid upon exposure on at least one terminal of the main chain, and at least one of the structural unit selected from the group consisting of the structural unit (a0), the structural unit (a3) and the structural unit (a5), and exhibits increased polarity by the action of acid.

Among these, as the component (A1), a copolymer (A1-1-3) which contains an anion part which generates acid upon exposure on at least one terminal of the main chain, the structural unit (a3) and the structural unit (a1) (hereafter, referred to as “component (A1-1-3)”), and a copolymer (A1-1-0) which contains an anion part which generates acid upon exposure on at least one terminal of the main chain, the structural unit (a0) and the structural unit (a1) (hereafter, referred to as “component (A1-1-0)”) are preferable.

As the component (A1), a component (A1-1-3) further containing the structural unit (a0) is preferable.

As the component (A1), a component (A1-1-0) further containing the structural unit (a3) is preferable.

As the component (A1), a component (A1-1-3) may include an other structural unit (such as the aforementioned structural units (a2) and (a4)) as well as the structural unit (a0), or may include an other structural unit instead of the structural unit (a0).

The explanation of the component (A1-1-3) is the same as the explanation of the aforementioned “copolymer which contains an anion part which generates acid upon exposure on at least one terminal of the main chain, the structural unit (a3) and the structural unit (a1)” for the polymer according to the first aspect of the present invention.

As the component (A1), a component (A1-1-0) may also include an other structural unit (such as the aforementioned structural units (a2) and (a4)) as well as the structural unit (a3) or may include an other structural unit instead of the structural unit (a3).

The explanation of the component (A1-1-0) is the same as the explanation of the aforementioned “copolymer which contains an anion part which generates acid upon exposure on at least one terminal of the main chain, the structural unit (a0) and the structural unit (a1)” for the polymer according to the first aspect of the present invention.

Among these, as the component (A1), a copolymer which contains an anion part which generates acid upon exposure on at least one terminal of the main chain, the structural unit (a5) and the structural unit (a1) (hereafter, referred to as “component (A1-1-5)”) is preferred.

As the component (A1), a component (A1-1-5) further containing the structural unit (a0) is preferable.

As the component (A1), a component (A1-1-5) further containing the structural unit (a3) is preferable.

As the component (A1), a component (A1-1-5) may include an other structural unit (such as the aforementioned structural units (a2) and (a4)) with the structural unit (a0) or may include an other structural unit instead of the structural unit (a0).

The explanation of the component (A1-1-5) is the same as the explanation of the aforementioned “copolymer which contains an anion part which generates acid upon exposure on at least one terminal of the main chain, the structural unit (a5) and structural unit (a1)” for the polymer according to the first aspect of the present invention.

[Component (A2)]

In the resist composition according to the second aspect of the present invention, the component (A) may contain a base component which exhibits changed solubility in a developing solution under action of acid, and which does not fall under the definition of the component (A1) (hereafter, referred to as “component (A2)”).

Examples of the component (A2) include low molecular weight compounds that have a molecular weight of at least 500 and less than 2,500, contains a hydrophilic group, and also contains an acid dissociable group described above in connection with the component (A1).

Specific examples include compounds containing a plurality of phenol skeletons in which a part of the hydrogen atoms within hydroxy groups have been substituted with the aforementioned acid dissociable groups.

Examples of the component (A2) include low molecular weight phenolic compounds in which a portion of the hydroxy group hydrogen atoms have been substituted with an aforementioned acid dissociable group, and these types of compounds are known, for example, as sensitizers or heat resistance improvers for use in non-chemically amplified g-line or i-line resists.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers and tetramers of formalin condensation products of phenols such as phenol, m-cresol, p-cresol and xylenol. Needless to say, the low molecular weight phenol compound is not limited to these examples. In particular, a phenol compound having 2 to 6 triphenylmethane skeletons is preferable in terms of resolution and LWR.

Also, there are no particular limitations on the acid dissociable group, and suitable examples include the groups described above.

In addition as a component (A2), a resin component which does not fall under the definition of the aforementioned component (A1) is preferably used. The resin component which does not fall under the definition of the component (A1) is a polymer other than the polymer according to the first aspect of the present invention. For example, a polymer which is produced using a conventional radical polymerization initiator other than the radical polymerization initiator (I), instead of using the radical polymerization initiator (I) can be mentioned. The composition of the polymer is not particularly limited, and preferable examples thereof include a polymer containing the structural units (a3), (a1), (a0) and (a2), a polymer containing the structural units (a1), (a2), (a3) and (a0), and a polymer containing the structural units (a5), (a1), (a0), (a2) and (a3).

As the component (A2), one type of resin may be used, or two or more types of resins may be used in combination.

In the resist composition of the second aspect of the present invention, as the component (A), one type may be used, or two or more types may be used in combination.

In the resist composition of the second aspect of the present invention, the amount of the component (A) can be appropriately adjusted depending on the thickness of the resist film to be formed, and the like.

### <<Resist Composition 2>>

The resist composition according to the fifth aspect of the present invention may contain the polymer according to the fourth aspect of the present invention as a base component (A) which exhibits changed solubility in a developing solution under action of acid, or may contain the polymer of the fourth aspect of the present invention in addition to other resin constituting the base component.

That is, in the case where the polymer according to the fourth aspect is used in the resist composition according to the fifth aspect, the polymer according to the fourth aspect of the present invention may be either a polymer which exhibits increased solubility in a developing solution under the action of acid, or other polymer.

In particular, with respect to the polymer according to the fourth aspect of the present invention which is used in the resist composition according to the fifth aspect of the present invention, by virtue of the structural unit (f1) containing a fluorine atom, it is presumed that the polymer is localized in the vicinity of the surface of the resist film. Therefore, the polymer is preferably used as an additive component which is added into a resist component as well as a base component. In the case where the polymer is used as an additive component, the polymer may be either a polymer which exhibits changed solubility in a developing solution under action of acid or a polymer which does not exhibit changed solubility in a developing solution under action.

The resist composition according to the fifth aspect of the present invention contains a fluorine-containing polymeric compound component (F) which generates acid upon exposure (hereafter, referred to as “component (F)”), and the component (F) preferably contains the polymer according to the fourth aspect of the present invention. The resist composition according to the fifth aspect of the present invention includes a base component (A) which exhibits changed solubility in an alkali developing solution under action of acid (hereafter, referred to as “component (A)”), an acid-generator component (B) which generates acid upon exposure (provided that the base component (A) is excluded) (hereafter, referred to as “component (B)”) and the component (F), and the component (F) preferably contains the polymer according to the fourth aspect of the present invention.

Next, the resist composition containing the polymer of the fourth aspect of the present invention as a component (F) will be described below.

### <Component (F)>

The component (F) is a fluorine-containing polymeric compound unit which generates acid upon exposure.

The explanation of the component (F) is the same as the explanation of the aforementioned “copolymer which contains an anion part which generates acid upon exposure on at least one terminal of the main chain, the structural unit (f1) containing a fluorine atom” for the polymer according to the fourth aspect of the present invention.

As described above, the component (F) contains a fluorine atom. Therefore, in a resist film is formed from the resist composition according to the fifth aspect of the present invention, the component (F) can be unevenly distributed in the vicinity of the surface of the resist film.

As the component (F), one type of resin may be used, or two or more types of resins may be used in combination.

The amount of the component (F) relative to 100 parts by weight of the component (A) is preferably within a range from 0.3 to 20 parts by weight, more preferably from 0.3 to 15 parts by weight, and still more preferably from 0.5 to 10 parts by weight. When the component (F) is within the above-mentioned range, an effect of reducing defects and a good balance can be achieved with the other lithography properties.

### <Component (A)>

In the case where the resist composition of the fifth aspect of the present invention is a “negative resist composition for alkali developing process” which forms a negative pattern in an alkali developing process, for example, as the component (A), a base component that is soluble in an alkali developing solution is used, and a cross-linking agent is blended in the negative resist composition.

In the negative resist composition for alkali developing process, when acid is generated from the polymer according to the fourth aspect of the present invention contained in the component (A) upon exposure, the action of the generated acid causes cross-linking between the base component and the cross-linking agent, and the cross-linked portion becomes insoluble in an alkali developing solution. Therefore, in the formation of a resist pattern, by conducting selective exposure to a resist film formed by applying the negative resist composition onto a substrate, the exposed portions become insoluble in an alkali developing solution, whereas the unexposed portions remain soluble in an alkali developing solution, and hence, a resist pattern can be formed by alkali developing.

Generally, as the component (A) used for a negative resist composition for alkali developing process, a resin that is soluble in an alkali developing solution (hereafter, referred to as “alkali-soluble resin”) is used.

Examples of the alkali soluble resin include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin which has a sulfonamide group and may have the hydrogen atom bonded to the carbon atom on the α-position substituted with a substituent or a polycycloolefin resin having a sulfoneamide group, as disclosed in U.S. Pat. No. 6,949,325; an acrylic resin which may have the hydrogen atom bonded to the carbon atom on the α-position substituted with a substituent, and which has a fluorinated alcohol, as disclosed in U.S. Pat. No. 6,949,325, Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable, because a resist pattern can be formed with minimal swelling.

Here, the term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the cross-linking agent, typically, an amino-based cross-linking agent such as a glycoluril having a methylol group or alkoxymethyl group, or a melamine-based cross-linking agent is preferable, in terms of forming a resist pattern with minimal swelling. The amount of the cross-linking agent added is preferably within a range from 1 to 50 parts by weight, relative to 100 parts by weight of the alkali-soluble resin.

In the case where the resist composition of the fifth aspect of the present invention is a resist composition which forms a positive pattern in an alkali developing process and a negative pattern in a solvent developing process, it is preferable to use a base component (A0) (hereafter, referred to as “component (A0)”) which exhibits increased polarity by the action of acid. By using the component (A0), since the polarity of the base component changes prior to and after exposure, an excellent development contrast can be obtained not only in an alkali developing process, but also in a solvent developing process.

More specifically, in the case of an alkali developing process, the component (A0) is substantially insoluble in an alkali developing solution prior to exposure, but when acid is generated from the polymer according to the fourth aspect of the present invention contained in the component (A) upon exposure, the polarity of the base component is increased by the action of the acid, thereby increasing the solubility of the component (A0) in an alkali developing solution. Therefore, in the formation of a resist pattern, by conducting selective exposure to a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A0) exhibits high solubility in an organic developing solution prior to exposure, and when acid is generated from the polymer according to fourth aspect of the present invention contained in the component (A) upon exposure, the polarity of the component (A0) is increased by the action of the generated acid, thereby decreasing the solubility of the component (A0) in an organic developing solution. Therefore, in the formation of a resist pattern, by conducting selective exposure to a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the resist composition of the fifth aspect of the present invention, the component (A) is preferably a base component which exhibits increased polarity by the action of acid (i.e., a component (A0)). That is, the resist composition of the fifth aspect of the present invention is preferably a chemically amplified resist composition which becomes a positive type in the case of an alkali developing process, and a negative type in the case of a solvent developing process.

The component (A0) may be a resin component (A1′) that exhibits increased polarity under the action of acid (hereafter, frequently referred to as “component (A1′)”), or may be a low molecular weight material (A2′) that exhibits increased polarity under the action of acid (hereafter, frequently referred to as “component (A2′)”), or a mixture thereof.

[Component (A1′)]

As the component (A1′), a resin component (base resin) typically used as a base component for a chemically amplified resist composition can be used alone, or two or more of such resin components can be mixed together.

In the resist composition of the fifth aspect of the present invention, it is preferable that the component (A′) includes a structural unit (a1′) containing an acid decomposable group that exhibits increased polarity by the action of acid.

The component (A1) preferably includes, at least one structural unit (a2′) selected from the group consisting of a structural unit derived from an acrylate ester which may have the hydrogen atom bonded to the carbon atom on the α-position substituted with a substituent and contains an —SO₂— containing cyclic group, and a structural unit derived from an acrylate ester which may have the hydrogen atom bonded to the carbon atom on the α-position substituted with a substituent and contains a lactone-containing cyclic group, in addition to the structural unit (a1).

Furthermore, the component (A1′) preferably includes a structural unit (a3′) containing a polar group, as well as the structural unit (a1′), or as well as the structural unit (a1′) and the structural unit (a2′).

<Structural Unit (a1′)>

The structural unit (a1′) is a structural unit containing an acid decomposable group which exhibits increased polarity by the action of an acid, and the same structural unit as described above for the structural unit (a1) can be mentioned.

Among these, as the structural unit (a1′), a structural unit represented by the formula (a1-1) or (a1-2), and a structural unit represented by the formula (a1-1-2), (a1-1-26) or (a1-2-6) is particularly desirable.

In the component (A1′), as the structural unit (a1′), one type of structural unit may be used, or two or more types may be used in combination.

In the component (A1′), the amount of the structural unit (a1′) based on the combined total of all structural units constituting the component (A1′) is preferably 5 to 90 mol %, more preferably 10 to 85 mol %, and still more preferably 15 to 80 mol %. When the amount of the structural unit (a1′) is at least as large as the lower limit of the above-mentioned range, a pattern can be easily formed using a resist composition prepared from the component (A1′). On the other hand, when the amount of the structural unit (a1′) is no more than the upper limit of the above-mentioned range, a good balance can be achieved with the other structural units.

<Structural Unit (a2′)>

The structural unit (a2′) is at least one structural unit selected from the group consisting of a structural unit derived from an acrylate ester which may have the hydrogen atom bonded to the carbon atom on the α-position substituted with a substituent and contains an —SO₂— containing cyclic group (hereafter, referred to as “structural unit (a2^{S})”), and a structural unit derived from an acrylate ester which may have the hydrogen atom bonded to the carbon atom on the α-position substituted with a substituent and contains a lactone-containing cyclic group (hereafter, referred to as “structural unit (a2^{L})”).

By virtue of the structural unit (a2′) containing a —SO₂— containing cyclic group or a lactone-containing cyclic group, a resist composition containing the polymer of the fourth aspect of the present invention is capable of improving the adhesion of a resist film to a substrate, and increasing the compatibility with the developing solution which contains water (especially in the case of alkali developing process), thereby contributing to improvement of lithography properties.

<Structural Unit (a2^{S})>

The structural unit (a2^{S}) is a structural unit derived from an acrylate ester which may have the hydrogen atom bonded to the carbon atom on the α-position substituted with a substituent and contains an —SO₂— containing cyclic group.

As the structural unit (a2^{S}), the same as the structural unit (a0) can be mentioned.

<Structural Unit (a2^{L})>

The structural unit (a2^{L}) is a structural unit derived from an acrylate ester which may have the hydrogen atom bonded to the carbon atom on the α-position substituted with a substituent and contains a lactone-containing cyclic group.

As the structural unit (a2^{L}), the same as the structural unit (a2) can be mentioned.

In the component (A1′), as the structural unit (a2′), one type of structural unit may be used, or two or more types may be used in combination. For example, as the structural unit (a2′), either a structural unit (a2^{S}), or a structural unit (a2^{L}) may be used alone, or a combination of these structural units may be used, and at least the structural unit (a2^{S}) is preferably used. Further, as the structural unit (a2^{S}) or the structural unit (a2^{L}), either a single type of structural unit may be used, or two or more types may be used in combination.

In the component (A1′), the amount of the structural unit (a2′) based on the combined total of all structural units constituting the component (A1′) is preferably 1 to 80 mol %, more preferably 10 to 70 mol %, still more preferably 10 to 65 mol %, and most preferably 10 to 60 mol %.

When the amount of the structural unit (a2′) is at least as large as the lower limit of the above-mentioned range, the effect of using the structural unit (a2′) can be satisfactorily achieved. On the other hand, when the amount of the structural unit (a2′) is no more than the upper limit of the above-mentioned range, a good balance can be achieved with the other structural units, and various lithography properties such as DOF and CDU and pattern shape can be improved.

<Structural Unit (a3′)>

The structural unit (a3′) is a structural unit having a polar group, and the same one as the structural unit (f3) can be mentioned. As the structural unit (a3′), the same as the structural unit (a3) is preferably used.

Among these, as the structural unit (a3′), the structural unit represented by the formula (a3-12) is preferable, and the structural unit represented by the formula (a3-12-1) is particularly desirable.

In the component (A1′), as the structural unit (a3′), one type of structural unit may be used, or two or more types may be used in combination.

In the component (A1′), the amount of the structural unit (a3′) based on the combined total of all structural units constituting the component (A1′) is preferably 1 to 40 mol %, more preferably 1 to 35 mol %, still more preferably 3 to 30 mol %, and most preferably 5 to 25 mol %. When the amount of the structural unit (a3′) is at least as large as the lower limit of the above-mentioned range, the effect of using the structural unit (a3) (such as improvement effect in resolution, lithography properties and pattern shape) can be satisfactorily achieved. On the other hand, when the amount of the structural unit (a3) is no more than the upper limit of the above-mentioned range, a good balance can be achieved with the other structural units.

### (Other Structural Units)

The component (A1′) may also have a structural unit other than the above-mentioned structural units (a1′) to (a3′) (hereafter, referred to as “structural unit (a4′)”), as long as the effects of the present invention are not impaired.

The structural unit (a4′) is not particularly limited as long as the structural unit (a4′) can not classified into one of the above structural units (a1′) to (a3′), and any of the multitude of conventional structural units used within resist resins for ArF excimer lasers or KrF excimer lasers (and particularly for ArF excimer lasers) can be used.

Preferable examples of the structural unit (a4′) include a structural unit derived from an acrylate ester which contains a non-acid-dissociable aliphatic polycyclic group and may have the hydrogen atom bonded to the carbon atom on the α-position substituted with a substituent, a structural unit derived from a styrene monomer and a structural unit derived from a vinylnaphthalene monomer. Examples of this polycyclic group include the same groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

As the structural unit (a4′), the same as the structural unit (a4) can be mentioned.

In the component (A1′), as the structural unit (a4′), one type of structural unit may be used, or two or more types may be used in combination.

When the structural unit (a4′) is included in the component (A1′), the amount of the structural unit (a4′) based on the combined total of all structural units constituting the component (A1′) is preferably 1 to 20 mol %, more preferably 1 to 15 mol %, and still more preferably 1 to 10 mol %.

The component (A1′) is preferably a polymer containing the structural unit (a1′).

Examples of such copolymers include a copolymer consisting of the structural units (a1′) and (a2′), a copolymer consisting of the structural units (a1′) and (a3′), and a copolymer consisting of the structural units (a1′), (a2′) and (a3′).

In particular, preferable examples of the component (A1′) include a copolymer containing a structural unit represented by the general formulas (a1-1-2), (a1-1-26) or (a1-2-6) and a structural unit represented by the general formula (a0-0-12a), or a copolymer containing a structural unit represented by the general formulas (a1-1-2), (a1-1-26) or (a1-2-6), a structural unit represented by the general formula (a0-0-12a) and a structural unit represented by the general formula (a3-12-1).

In the fifth aspect according to the present invention, the component (A1′) may contain an anion part which generates acid upon exposure on at least one terminal of the main chain, as well as the polymer according to the fourth aspect of the present invention. Here, as the “anion part which generates acid upon exposure”, the same anion parts as those described above in the aforementioned polymer of the present invention can be mentioned.

In the fifth aspect according to the present invention, the component (A1′) may be the same as the component (A1) contained in the resist composition according to the second aspect of the present invention.

The component (A1′) containing an anion part which generates acid upon exposure on at least one terminal of the main chain can be produced in the similar manner as the aforementioned method of producing the polymer. Specifically, the component (A1′) can be obtained by polymerization such as a radical polymerization or an anion polymerization of monomers which derive structural units (for example, structural units (a1), (a2′) and (a3′)) constituting the component (A1′) using a polymerization initiator represented by the formula (I).

In the fifth aspect according to the present invention, by using the component (A1′) containing an anion part which generates acid upon exposure on at least one terminal of the main chain, in addition to the component (F), an acid is also generated from the terminal of the main chain of the component (A1′), and the acid-generating ability is preferably improved.

In addition, the component (A1′) exhibits a changed solubility in a developing solution under the action of acid. In the formed resist film, the anion part on the terminal of the main chain and the part which contributes to change the solubility under the action of acid (specific examples includes the structural unit (a1′)) are uniformly distributed within the resist film, and the solubility of the component (A1′) itself is changed by the action of acid which is uniformly generated from the component (A1′) at exposed portions. As a result, excellent lithography properties can be achieved.

The weight average molecular weight (Mw) (the polystyrene equivalent value determined by gel permeation chromatography) of the component (A1′) is not particularly limited, but is preferably 1,000 to 50,000, more preferably 1,500 to 30,000, and most preferably 2,000 to 20,000. When the weight average molecular weight of the component (A1′) is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (A1′) is preferably 1.0 to 5.0, more preferably 1.0 to 3.0, and most preferably 1.2 to 2.5. Here, Mn is the number average molecular weight.

In the component (A), as the component (A1′), one type may be used, or two or more types of resins may be used in combination.

In the component (A), the amount of the component (A1′) based on the total weight of the component (A) is preferably 25% by weight or more, more preferably 50% by weight or more, still more preferably 75% by weight or more, and may be even 100% by weight. When the amount of the component (A1) is 25% by weight or more, various lithography properties are improved.

[Component (A2′)]

In the resist composition of the fifth aspect of the present invention, the component (A) may contain “a base component which exhibits changed solubility in a developing solution under action of acid” which does not fall under the definition of the component (A1′) (hereafter, referred to as “component (A2′)”).

Examples of the component (A2′) include low molecular weight compounds that have a molecular weight within the range from at least 500 to less than 4,000, contains a hydrophilic group, and also contains an acid dissociable group described above in connection with the component (A1). Specific examples include compounds containing a plurality of phenol skeletons in which a part of the hydrogen atoms within hydroxy groups have been substituted with the aforementioned acid dissociable groups.

As the component (A2′), the same compounds as those described above for the component (A2) may be used. As the component (A2′), one type of resin may be used, or two or more types of resins may be used in combination.

In the resist composition of the fifth aspect of the present invention, as the component (A), one type may be used, or two or more types of resins may be used in combination.

In the resist composition of the fifth aspect of the present invention, the amount of the component (A) can be appropriately adjusted depending on the thickness of the resist film to be formed, and the like.

### <Optional Components>

[Component (B)]

The resist composition of the present invention may further include an acid-generator component (B) which generates acid upon exposure.

When the resist composition of the present invention includes the component (B), as the component (B), there is no particular limitation, and any of the known acid generators used in conventional chemically amplified resist compositions can be used. Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

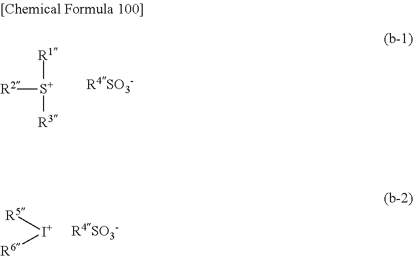

In the formulas above, R¹″ to R³″, R⁵″ and R⁶″ each independently represent an aryl group or alkyl group, wherein two of R¹″ to R³″ may be mutually bonded to form a ring with the sulfur atom; and R⁴″ represents an alkyl group, a halogenated alkyl group, an aryl group or an alkenyl group which may have a substituent, with the provision that at least one of R¹″ to R³″ represents an aryl group, and at least one of R⁵″ and R⁶″ represents an aryl group.

R¹″ to R³″ in general formula (b-1), and R⁵″ to R⁶″ in general formula (b-2) are each the same as defined for R¹″ to R³″ in the formula (c-1) and R⁵″ to R⁶″ in the formula (c-2).

In formulas (b-1) and (b-2), R⁴″ represents an alkyl group, a halogenated alkyl group, an aryl group or an alkenyl group which may have a substituent.

R⁴″ is the same as defined for R⁴″ in V⁻ explained above in relation to the aforementioned formula (a5-1).

Examples of the substituent in R⁴″ include a halogen atom, a hetero atom, an alkyl group, and a group represented by the formula X³-Q¹- (in the formula, Q¹ represents a divalent linking group containing an oxygen atom; and X³ represents a hydrocarbon group of 3 to 30 carbon atoms which may have a substituent). The substituent is the same as defined for the substituent which may be contained in R⁴″ in V⁻ explained in relation to the general formula (a5-1).

In the group represented by formula X³-Q¹-, Q¹ represents a divalent linking group containing an oxygen atom.

Q¹″ is the same as defined for Q′ in X³-Q′- explained above in relation to the aforementioned formula (a5-1).

With respect to the group represented by X³-Q¹-, X³ is the same group as defined for X³ in the group represented by X³-Q′- explained above in relation to the aforementioned formula (a5-1).

In the present invention, R⁴″ preferably has X³-Q¹- as a substituent. In this case, R⁴″ is preferably a group represented by formula X³-Q¹-Y¹⁰— [wherein Q¹ and X³ are the same as defined above; and Y¹⁰ represents an alkylene group of 1 to 4 carbon atoms which may have a substituent, or a fluorinated alkylene group of 1 to 4 carbon atoms which may have a substituent]. These groups are the same group as defined for Y³ in the group represented by X³-Q′-Y³—.

Specific examples of suitable onium salt acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenyl sulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts is replaced by an alkyl sulfonate, such as methanesulfonate, n-propanesulfonate, n-butanesulfonate, n-octanesulfonate, 1-adamantanesulfonate, 2-norbornanesulfonate or d-camphor-10-sulfonate; or replaced by an aromatic sulfonate, such as benzenesulfonate, perfluorobenzenesulfonate or p-toluenesulfonate.

Furthermore, onium salts in which the anion moiety of these onium salts are replaced by an anion moiety represented by any one of formulas (b1) to (b9) shown below can be used.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may be also used.

Furthermore, as an onium salt-based acid generator, a sulfonium salt having a cation moiety represented by general formula (c-3) shown below may be used. The anion moiety of the sulfonium salt having a cation moiety represented by general formula (c-3) is not particularly limited, and the same anion moieties for onium salt-based acid generators which have been proposed may be used. Examples of such anion moieties include fluorinated alkylsulfonate ions such as anion moieties (R⁴″SO₃⁻) of onium salt-based acid generators represented by the general formula (b-1) or (b-2); and anion moieties represented by general formula (b-3) or (b-4) shown above.

In the present description, an oximesulfonate-based acid generator is a compound having at least one group represented by general formula (B-1) shown below, and has a feature of generating acid by irradiation. Such oximesulfonate acid generators are widely used for a chemically amplified resist composition, and can be appropriately selected.

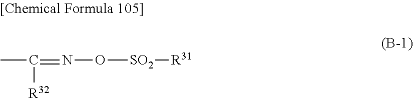

In the formula, each of R³¹ and R³² independently represents an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a substituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of halogen atoms include fluorine atoms, chlorine atoms, bromine atoms and iodine atoms, and fluorine atoms are particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. As the alkyl group or aryl group for R³², the same alkyl groups or aryl groups as those described above for R³¹ can be used.

As R³², a cyano group, an alkyl group of 1 to 8 carbon atoms having no substituent or a fluorinated alkyl group of 1 to 8 carbon atoms is particularly desirable.

Preferable examples of the oxime sulfonate-based acid generator include compounds represented by general formula (B-2) or (B-3) shown below.

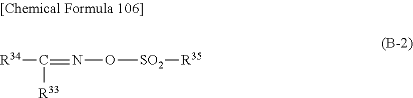

In the formula, R³³ represents a cyano group, an alkyl group having no substituent or a halogenated alkyl group; R³⁴ represents an aryl group; and R³⁵ represents an alkyl group having no substituent or a halogenated alkyl group.

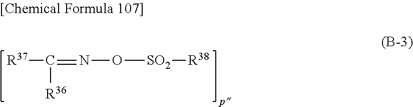

In the formula (B-3), R³⁶ represents a cyano group, an alkyl group having no substituent or a halogenated alkyl group; R³⁷ represents a divalent or trivalent aromatic hydrocarbon group; and R³⁸ represents an alkyl group having no substituent or a halogenated alkyl group. and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenantryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propyl sulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 86) may be preferably used.

Furthermore, as preferable examples, the following can be used.

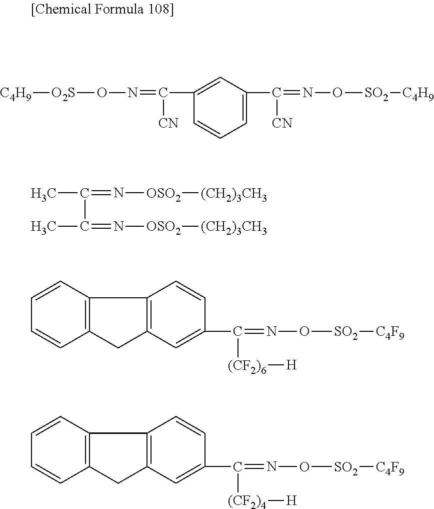

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used. Furthermore, as poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be mentioned.

As the component (B), one type of acid generator may be used, or two or more types of acid generators may be used in combination.

When the resist composition in the present invention contains the component (B), as the component (B), it is preferable to use an onium salt having a fluorinated alkylsulfonate ion as the anion moiety.

When the resist composition of the present invention contains the component (B), the amount of the component (B) relative to 100 parts by weight of the component (A) is preferably 0.5 to 50 parts by weight, and more preferably 1 to 40 parts by weight. When the amount of the component (B) is within the above-mentioned range, formation of a resist pattern can be satisfactorily performed. Further, by virtue of the above-mentioned range, a uniform solution can be obtained and the storage stability becomes satisfactory.

[Component (D)]

The resist composition of the present invention may contain a basic-compound component (D) (hereafter referred to as “component (D)”) as an optional component.

As the component (D), there is no particular limitation as long as it functions as an acid diffusion control agent, i.e., a quencher which traps the acid generated from the component (A1) and component (B) upon exposure. A multitude of these components (D) have already been proposed, and any of these known compounds may be used.

In the present invention, the component (D) has a function as an acid diffusion control agent, i.e., a quencher which traps the acid generated from the terminal of the main chain of the component (F) and the component (B) upon exposure. In the present invention, a “basic compound” refers to a compound which is basic relative to the terminal of the main chain of the component (F) and the component (B).

In the present invention, the component (D) may be a basic compound (D1) (hereafter, referred to as “component (D1)”) which has a cation moiety and an anion moiety, or a basic compound (D2) (hereafter, referred to as “component (D2)”) which does not fall under the definition of component (D1).

(Component (D1))

In the present invention, it is preferable that the component (D1) include at least one member selected from the group consisting of a compound (d1-1) represented by general formula (d1-1) shown below (hereafter, referred to as “component (d1-1)”), a compound (d1-2) represented by general formula (d1-2) shown below (hereafter, referred to as “component (d1-2)”) and a compound (d1-3) represented by general formula (d1-3) shown below (hereafter, referred to as “component (d1-3)”).

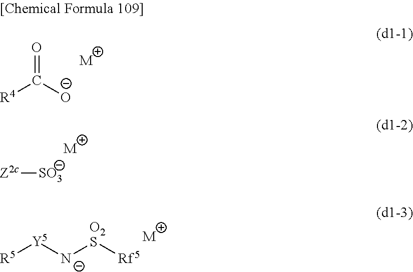

In the formulas, R⁴ represents a hydrocarbon group which may have a substituent; Z^{2c} represents a hydrocarbon group of 1 to 30 carbon atoms which may have a substituent (provided that the carbon adjacent to S has no fluorine atom as a substituent); R⁵ represents an organic group; Y⁵ represents a linear, branched or cyclic alkylene group or an arylene group; Rf⁵ represents a hydrocarbon group containing a fluorine atom; and M⁺ represents an organic cation.

[Component (d1-1)]

Anion Moiety

In formula (d1-1), R⁴ represents a hydrocarbon group which may have a substituent.

The hydrocarbon group for R⁴ which may have a substituent may be either an aliphatic hydrocarbon group or an aromatic hydrocarbon group, and the same aliphatic hydrocarbon groups and aromatic hydrocarbon groups as those described above for the aforementioned X^{c} in the component (B) can be used.

Among these, as the hydrocarbon group for R⁴ which may have a substituent, an aromatic hydrocarbon group which may have a substituent or an aliphatic cyclic group which may have a substituent is preferable, and a phenyl group or a naphthyl group which may have a substituent, or a group in which one or more hydrogen atoms have been removed from a polycycloalkane such as adamantane, norbornane, isobornane, tricyclodecane or tetracyclododecane is more preferable.

As the hydrocarbon group for R⁴ which may have a substituent, a linear or branched alkyl group or a fluorinated alkyl group is also preferable.

The linear or branched alkyl group for R⁴ preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

The fluorinated alkyl group for R⁴ may be either chain-like or cyclic, but is preferably linear or branched.

The fluorinated alkyl group preferably has 1 to 11 carbon atoms, more preferably 1 to 8, and still more preferably 1 to 4. Specific examples include a group in which part or all of the hydrogen atoms constituting a linear alkyl group (such as a methyl group, an ethyl group, a propyl group, a butyl group, a pentyl group, a hexyl group, a heptyl group, an octyl group, a nonyl group or a decyl group) have been substituted with fluorine atom(s), and a group in which part or all of the hydrogen atoms constituting a branched alkyl group (such as a 1-methylethyl group, a 1-methylpropyl group, a 2-methylpropyl group, a 1-methylbutyl group, a 2-methylbutyl group or a 3-methylbutyl group) have been substituted with fluorine atom(s).

The fluorinated alkyl group for R⁴ may contain an atom other than fluorine. Examples of the atom other than fluorine include an oxygen atom, a carbon atom, a hydrogen atom, an oxygen atom, a sulfur atom and a nitrogen atom.

Among these, as the fluorinated alkyl group for R⁴, a group in which part or all of the hydrogen atoms constituting a linear alkyl group have been substituted with fluorine atom(s) is preferable, and a group in which all of the hydrogen atoms constituting a linear alkyl group have been substituted with fluorine atoms (i.e., a perfluoroalkyl group) is more preferable.

Specific examples of preferable anion moieties for the component (d1-1) are shown below.

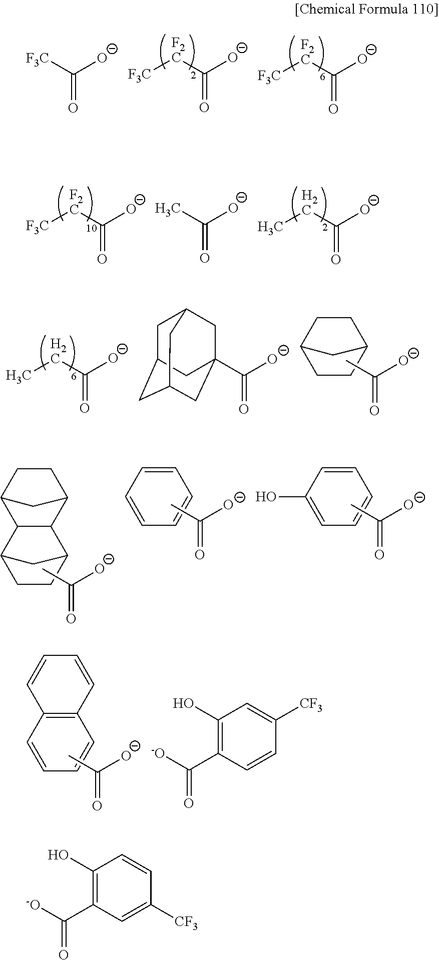

Cation Moiety

In formula (d1-1), M⁺ represents an organic cation. As the organic cation for M⁺, the same groups as those described above for the organic cation for M⁺ in the formula (I-1).

As the component (d1-1), one type of compound may be used, or two or more types of compounds may be used in combination.

[Component (d1-2)]

—Anion Moiety

In formula (d1-2), Z^{2c} represents a hydrocarbon group of 1 to 30 carbon atoms which may have a substituent.

The hydrocarbon group of 1 to 30 carbon atoms for Z^{2c} which may have a substituent may be either an aliphatic hydrocarbon group or an aromatic hydrocarbon group, and the same aliphatic hydrocarbon groups and aromatic hydrocarbon groups as those described above for X as a substituent of R″ in relation to the compound (B) can be used.

Among these, as the hydrocarbon group for Z^{2c} which may have a substituent, an aliphatic cyclic group which may have a substituent is preferable, and a group in which one or more hydrogen atoms have been removed from adamantane, norbornane, isobornane, tricyclodecane, tetracyclododecane or camphor (which may have a substituent) is more preferable.

The hydrocarbon group for Z^{2c} may have a substituent, and the same substituents as those described above for X in the aforementioned component (B) can be used. However, in Z^{2c}, the carbon adjacent to the S atom within SO₃⁻ has no fluorine atom as a substituent. By virtue of SO₃⁻ having no fluorine atom adjacent thereto, the anion of the component (d1-2) becomes an appropriately weak acid anion, thereby improving the quenching ability of the component (D).

Specific examples of preferable anion moieties for the component (d1-2) are shown below.

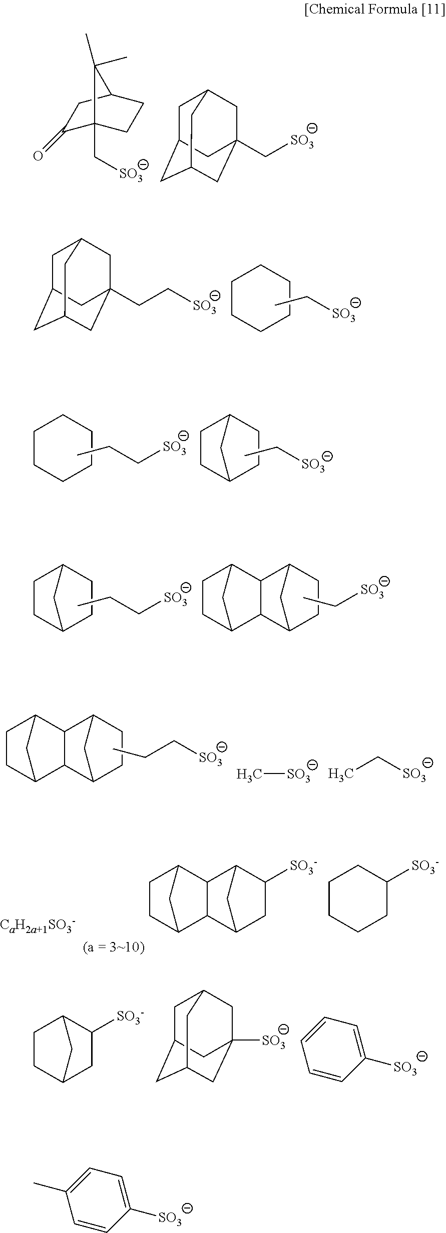

—Cation Moiety

In formula (d1-2), M⁺ is the same as defined for Min the aforementioned formula (d1-1).

As the component (d1-2), one type of compound may be used, or two or more types of compounds may be used in combination.

[Component (d1-3)]

—Anion Moiety

In formula (d1-3), R⁵ represents an organic group.

The organic group for R⁵ is not particularly limited, and examples thereof include an alkyl group, an alkoxy group, —O—C(═O)—C(R^{C2})═CH₂ (wherein, R^{C2} represents a hydrogen atom, an alkyl group of 1 to 5 carbon atoms or a halogenated alkyl group of 1 to 5 carbon atoms) and —O—C(═O)—R^{C3} (R^{C3} represents a hydrocarbon group).

The alkyl group for R⁵ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for R⁵ may be substituted with a hydroxy group, a cyano group or the like.

The alkoxy group for R⁵ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are particularly desirable.

When R⁵ is —O—C(═O)—C(R^{C2})═CH₂, R^{C2} represents a hydrogen atom, an alkyl group of 1 to 5 carbon atoms or a halogenated alkyl group of 1 to 5 carbon atoms.

The alkyl group of 1 to 5 carbon atoms for R^{C2} is preferably a linear or branched alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The halogenated alkyl group for R^{C2} is a group in which part or all of the hydrogen atoms of the aforementioned alkyl group of 1 to 5 carbon atoms has been substituted with halogen atoms. Examples of the halogen atom include a fluorine atom, a chlorine atom, a bromine atom and an iodine atom, and a fluorine atom is particularly preferred.

As R^{C2}, a hydrogen atom, an alkyl group of 1 to 3 carbon atoms or a fluorinated alkyl group of 1 to 3 carbon atoms is preferable, and a hydrogen atom or a methyl group is particularly desirable in terms of industrial availability.

When R⁵ is —O—C(═O)—R^{C3}, R^{C3} represents a hydrocarbon group.

The hydrocarbon group for R^{C3} may be either an aromatic hydrocarbon group or an aliphatic hydrocarbon group. Specific examples of the hydrocarbon group for R^{C3} include the same hydrocarbon groups as those described for X in the component (B).

Among these, as the hydrocarbon group for R^{C3}, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When R^{C3} is an alicyclic group, the resist composition can be satisfactorily dissolved in an organic solvent, thereby improving the lithography properties. Alternatively, when R^{C3} is an aromatic group, the resist composition exhibits an excellent photoabsorption efficiency in a lithography process using EUV or the like as the exposure source, sensitivity and the lithography properties become excellent.

Among these, as R⁵, —O—C(═O)—C(R^{C2}′)═CH₂₂ (wherein, R^{C2}′ represents a hydrogen atom or a methyl group) or —O—C(═O)—R^{C3}″ (wherein, R^{C3}′ represents an aliphatic cyclic group) is preferable.

In formula (d1-3), Y⁵ represents a linear, branched or cyclic alkylene group or an arylene group.

Examples of the linear, branched or cyclic alkylene group or the arylene group for Y⁵ include the “linear or branched aliphatic hydrocarbon group”, “cyclic aliphatic hydrocarbon group” and “aromatic hydrocarbon group” described above as the divalent linking group for Y²² in the aforementioned formula (a1-0-2).

Among these, as Y⁵ an alkylene group is preferable, a linear or branched alkylene group is more preferable, and a methylene group or an ethylene group is still more preferable.

In formula (c1-3), Rf⁵ represents a hydrocarbon group containing a fluorine atom.

The hydrocarbon group containing a fluorine atom for Rf⁵ is preferably a fluorinated alkyl group, and more preferably the same fluorinated alkyl groups as those described above for R⁴.

Specific examples of preferable anion moieties for the component (d1-3) are shown below.

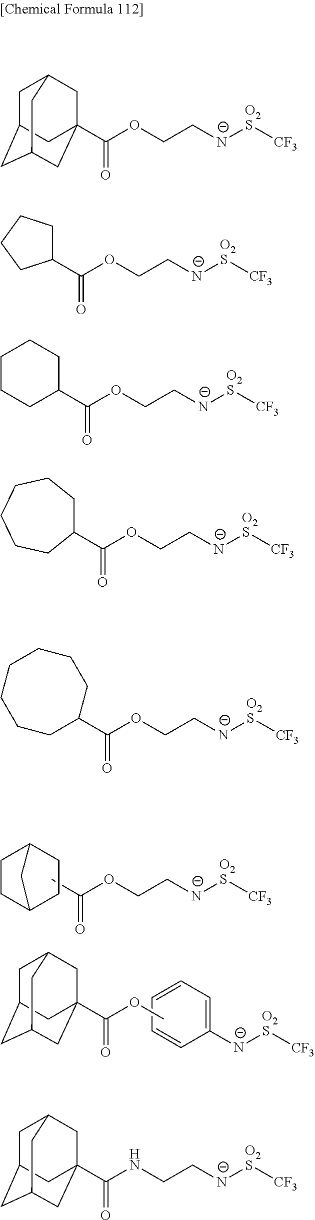

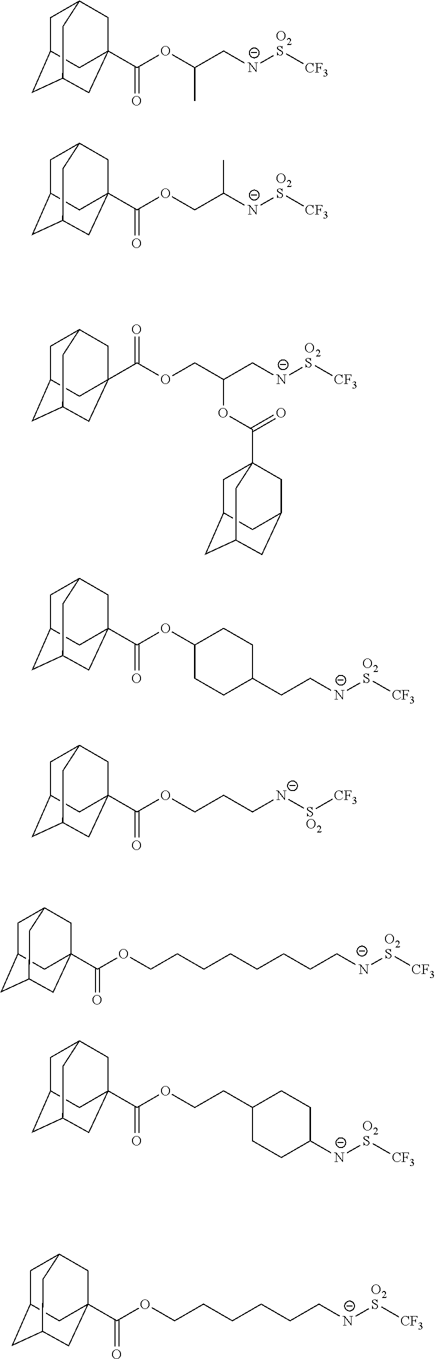

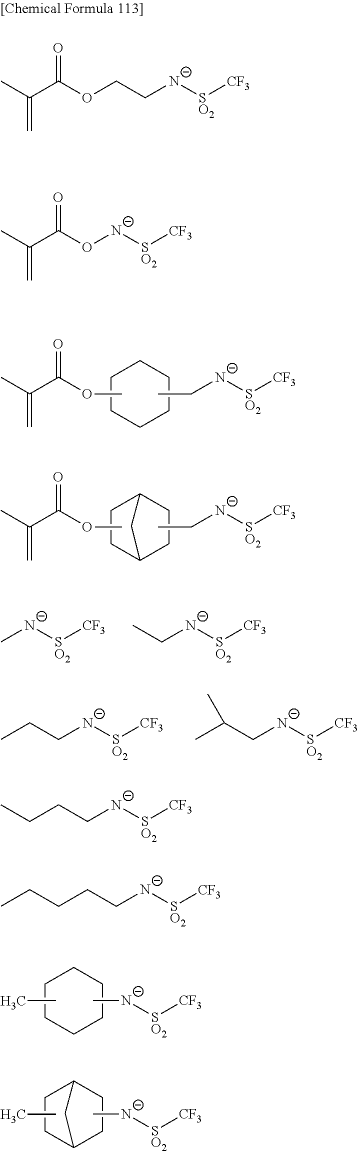

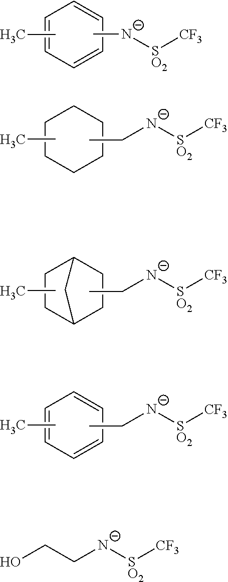

—Cation Moiety

In formula (d1-3), M⁺ is the same as defined for M⁺ in the aforementioned formula (d1-1).

As the component (d1-3), one type of compound may be used, or two or more types of compounds may be used in combination.

The component (D) may contain one of the aforementioned components (d1-1) to (d1-3), or at least two of the aforementioned components (d1-1) to (d1-3). Among these, the component (D) preferably contains the component (d1-2).

The total amount of the components (d1-1) to (d1-3) relative to 100 parts by weight of the component (A) is preferably within a range from 0.5 to 10.0 parts by weight, more preferably from 0.5 to 8.0 parts by weight, still more preferably from 1.0 to 8.0 parts by weight, and particularly preferably from 1.0 to 5.5 parts by weight. When the amount of at least as large as the lower limit of the above-mentioned range, excellent lithography properties and excellent resist pattern shape can be obtained. On the other hand, when the amount of the component (D) is no more than the upper limit of the above-mentioned range, sensitivity can be maintained at a satisfactory level, and throughput becomes excellent.

(Production Method of Components (d1-1) to (d1-3))

In the present invention, the production methods of the components (d1-1) and (d1-2) are not particularly limited, and the components (d1-1) and (d1-2) can be produced by conventional methods.

The production method of the component (d1-3) of the present invention is not particularly limited. For example, in the case where R⁵ in formula (d1-3) is a group having an oxygen atom on the terminal thereof which is bonded to Y⁵, the compound (d1-3) represented by general formula (d1-3) can be produced by reacting a compound (i-1) represented by general formula (i-1) shown below with a compound (i-2) represented by general formula (i-2) shown below to obtain a compound (−3) represented by general formula (i-3), and reacting the compound (i-3) with a compound Z⁻M⁺ having the desired cation M⁺, thereby obtaining the compound (d1-3).

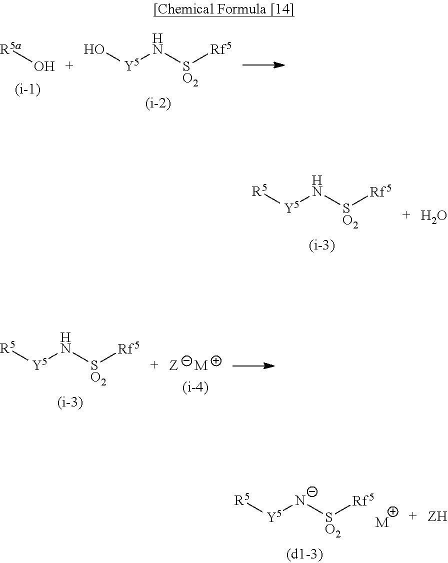

In the formulas, R⁵, Y⁵, Rf⁵ and M⁺ are respectively the same as defined for R⁵, Y⁵, Rf⁰ and M⁺ in the aforementioned general formula (d1-3); R^{5a} represents a group in which the terminal oxygen atom has been removed from R⁵; and Z⁻ represents a counteranion.

Firstly, the compound (i-1) is reacted with the compound (i-2), thereby obtaining the compound (i-3).

In formula (i-1), R^{5a} represents a group in which the terminal oxygen atom has been removed from R⁵. In formula (i-2), Y⁵ and Rf⁵ are the same as those defined above.

As the compound (i-1) and the compound (i-2), commercially available compounds may be used, or the compounds may be synthesized.

The method for reacting the compound (i-1) with the compound (i-2) to obtain the compound (i-3) is not particularly limited, but can be performed, for example, by reacting the compound (i-1) with the compound (i-2) in an organic solvent in the presence of an appropriate acidic catalyst, followed by washing and collecting the reaction mixture.

The acidic catalyst used in the above reaction is not particularly limited, and examples thereof include toluenesulfonic acid and the like. The amount of the acidic catalyst is preferably 0.05 to 5 moles, per 1 mole of the compound (i-2).

As the organic solvent used in the above reaction, any organic solvents which are capable of dissolving the raw materials, i.e., the compound (i-1) and the compound (i-2) can be used, and specific examples thereof include toluene and the like. The amount of the organic solvent is preferably 0.5 to 100 parts by weight, more preferably 0.5 to 20 parts by weight, relative to the amount of the compound (i-1). As the solvent, one type may be used alone, or two or more types may be used in combination.

In general, the amount of the compound (i-2) used in the above reaction is preferably 0.5 to 5 moles per 1 mole of the compound (i-1), and more preferably 0.8 to 4 moles per 1 mole of the compound (i-1).

The reaction time varies depending on the reactivity of the compounds (i-1) and (i-2), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

Next, the obtained compound (i-3) is reacted with the compound (i-4), thereby obtaining the compound (d1-3).

In formula (i-4), M⁺ is the same as defined above, and Z⁻ represents a counteranion.

The method for reacting the compound (i-3) with the compound (i-4) to obtain the compound (d1-3) is not particularly limited, but can be performed, for example, by dissolving the compound (i-3) in an organic solvent and water in the presence of an appropriate alkali metal hydroxide, followed by addition of the compound (i-4) and stirring.

The alkali metal hydroxide used in the above reaction is not particularly limited, and examples thereof include sodium hydroxide, potassium hydroxide and the like. The amount of the alkali metal hydroxide is preferably 0.3 to 3 moles, per 1 mole of the compound (i-3).

Examples of the organic solvent used in the above reaction include dichloromethane, chloroform, ethyl acetate and the like. The amount of the organic solvent is preferably 0.5 to 100 parts by weight, and more preferably 0.5 to 20 parts by weight, relative to the amount of the compound (i-3). As the solvent, one type may be used alone, or two or more types may be used in combination.

In general, the amount of the compound (i-4) used in the above reaction is preferably 0.5 to 5 moles per 1 mole of the compound (i-3), and more preferably 0.8 to 4 moles per 1 mole of the compound (i-3).

The reaction time depends on the reactivity of the compounds (i-3) and (i-4), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

After the reaction is completed, the compound (d1-3) within the reaction mixture may be separated and purified from the reaction mixture. The separation and purification can be conducted by a conventional method. For example, any one of concentration, solvent extraction, distillation, crystallization, recrystallization and chromatography can be used alone, or two or more of these methods may be used in combination.

The structure of the compound (d1-3) obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

[Component (D2)]

It is preferable that the resist composition of the present invention further includes a nitrogen-containing organic compound (D2) (hereafter referred to as the component (D2)) as an optional component.

As the component (D2), there is no particular limitation as long as it functions as an acid diffusion control agent, i.e., a quencher which traps the acid generated from the components (A1) and (B) upon exposure. A multitude of these components (D) have already been proposed, and any of these known compounds may be used.

The component (D2) is not particularly limited, as long as it is a compound which is basic relative to the component (B) and the terminal of the main chain of the component (F), and which functions as an acid diffusion inhibitor and does not fall under the definition of the component (D1). As the component (D2), any of the conventionally known compounds may be selected for use.

Among these, an aliphatic amine, particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine) can be used.

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris {2-(2-methoxyethoxy)ethyl}amine, tris {2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D2), an aromatic amine may be used.

Examples of aromatic amines include aniline, pyridine, 4-dimethylaminopyridine, pyrrole, indole, pyrazole, imidazole and derivatives thereof, diphenylamine, triphenylamine, tribenzylamine, 2,6-diisopropylaniline and N-tert-butoxycarbonylpyrrolidine.

As the component (D2), one type of compound may be used alone, or two or more types compounds may be used in combination.

The component (D2) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

As the component (D), one type of compound may be used, or two or more types of compounds may be used in combination.

When the resist composition of the present invention contains the component (D), the amount of the component (D) relative to 100 parts by weight of the component (A) is preferably within a range from 0.1 to 15 parts by weight, more preferably from 0.3 to 12 parts by weight, and still more preferably from 0.5 to 12 parts by weight. In the case where the amount of the component (D) is at least as large as the lower limit of the above-mentioned range, various lithography properties (such as roughness) of the positive resist composition are improved, when the resist composition is used as a positive resist composition. Further, a resist pattern having an excellent shape can be obtained. On the other hand, in the case where the amount of the component (D) is no more than the upper limit of the above-mentioned range, sensitivity can be maintained at a satisfactory level, and throughput becomes excellent.

[Component (E)]

Furthermore, in the resist composition of the present invention, for preventing any deterioration in sensitivity, and for improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of phosphorous oxo acid derivatives include esters in which a hydrogen atom within the above-mentioned phosphorous oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

As the component (E), salicylic acid is particularly desirable.

As the component (E), one type may be used alone, or two or more types may be used in combination.

The component (E) is typically used in an amount within a range from 0.01 to 5.0 parts by weight, relative to 100 parts by weight of the component (A).

[Component (F′)]

The resist composition of the second aspect of the present invention may further include a fluorine additive (hereafter, referred to as “component (F′)”) for imparting water repellency to the resist film. As the component (F′), for example, a fluorine-containing polymeric compound described in Japanese Unexamined Patent Application, First Publication No. 2010-002870 can be used.

As the component (F′), a polymer having a structural unit represented by general formula (f1-1) shown below can be used. The polymer is preferably a polymer (homopolymer) consisting of a structural unit represented by formula (f1-1) shown below; a copolymer of a structural unit represented by formula (f1-1) shown below and the aforementioned structural unit (a1); or a copolymer of a structural unit represented by formula (f1-1) shown below, a structural unit derived from acrylic acid or methacrylic acid and the aforementioned structural unit (a1). As the structural unit (a1) to be copolymerized with a structural unit represented by the formula (f1-1) shown below, a structural unit represented by the formula (a11-1) is preferable, a structural unit represented by the formula (a11-0-11) is more preferable, a structural unit represented by the formula (a1-1-02) is still more preferable and a structural unit represented by the formula (a1-1-32) is particularly preferable.

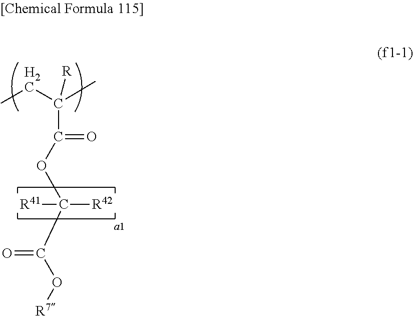

In the formula, R is the same as defined above; each of R⁴¹ and R⁴² independently represents a hydrogen atom, a halogen atom, an alkyl group of 1 to 5 carbon atoms or a halogenated alkyl group of 1 to 5 carbon atoms, provided that the plurality of R⁴¹ to R⁴² may be the same or different from each other; a1 represents an integer of 1 to 5; and R⁷″ represents an organic group containing a fluorine atom.

In formula (f1-1), R is the same as defined above. As R, a hydrogen atom or a methyl group is preferable.

In formula (f1-1), examples of the halogen atom for R⁴¹ and R⁴² include a fluorine atom, a chlorine atom, a bromine atom and an iodine atom, and a fluorine atom is particularly desirable. Examples of the alkyl group of 1 to 5 carbon atoms for R⁴¹ and R⁴² include the same alkyl group of 1 to 5 carbon atoms for R defined above, and a methyl group or an ethyl group is preferable. Specific examples of the halogenated alkyl group of 1 to 5 carbon atoms for R⁴¹ or R⁴² include groups in which part or all of the hydrogen atoms of the aforementioned alkyl groups of 1 to 5 carbon atoms have been substituted with halogen atoms. Examples of the halogen atom include a fluorine atom, a chlorine atom, a bromine atom and an iodine atom, and a fluorine atom is particularly preferred. Among these, R⁴¹ and R⁴² are preferably a hydrogen atom, a fluorine atom or an alkyl group of 1 to 5 carbon atoms, and more preferably a hydrogen atom, a fluorine atom, a methyl group or an ethyl group.

In formula (f1-1), a1 represents an integer of 1 to 5, preferably an integer of 1 to 3, and more preferably 1 or 2.

In formula (f1-1), R⁷″ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and particularly preferably 1 to 10 carbon atoms. The hydrocarbon group having a fluorine atom preferably has 25% or more of the hydrogen atoms within the hydrocarbon group fluorinated, more preferably 50% or more, and most preferably 60% or more, as the hydrophobicity of the resist film during immersion exposure is enhanced.

As R⁷, a fluorinated hydrocarbon group is preferable, more preferably a fluorinated hydrocarbon group of 1 to 5 carbon atoms, and still more preferably a methyl group, CH₂—CF₃, —CH₂—CF₂—CF₃, —CH(CF₃)₂, —CH₂—CH₂—CF₃ and —CH₂—CH₂—CF₂—CF₂—CF₂—CF₃.

The weight average molecular weight (Mw) (the polystyrene equivalent value determined by gel permeation chromatography) of the component (F′) is preferably 1,000 to 50,000, more preferably 5,000 to 40,000, and most preferably 10,000 to 30,000. When the weight average molecular weight of the component (A1) is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F′) is preferably 1.0 to 5.0, more preferably 1.0 to 3.0, and most preferably 1.2 to 2.5.

The component (F′) can be produced by a conventional radical polymerization or the like of the monomers corresponding with each of the structural units, using a radical polymerization initiator such as dimethyl 2,2′-azobis(2-methylpropionate) (V-601) or azobisisobutyronitrile (AIBN). By using a chain transfer agent such as HS—CH₂—CH₂—CH₂—C(CF₃)₂—OH in the polymerization reaction, a —C(CF₃)₂—OH group can be introduced at the terminals of the component (F). Such a copolymer having introduced a hydroxyalkyl group in which part of the hydrogen atoms with an alkyl group have been substituted with fluorine atoms is effective in reducing defects and reducing LER (line edge roughness: unevenness of the side walls of a line pattern).

As the monomers which derive the corresponding structural units, commercially available monomers may be used, or the monomers may be synthesized by a conventional method.

As the component (F′), one type may be used alone, or two or more types may be used in combination.

The component (F′) is typically used in an amount within a range from 0.5 to 10 parts by weight, relative to 100 parts by weight of the component (A).

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

[Component (S)]

The resist composition according to the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These solvents can be used individually, or in combination as a mixed solvent.

Among these, propylene glycol monomethyl ether acetate (PGMEA), propylene glycol monomethyl ether (PGME), cyclohexanone and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

Furthermore, as the component (S), a mixed solvent of PGMEA and cyclohexanone or a mixed solvent of PGMEA, PGME and cyclohexanone is also preferable. The former mixing ratio of such a mixed solvent is preferably PGMEA:cyclohexanone=95-5:10-90, whereas the latter mixing ratio of such a mixed solvent is preferably PGMEA:PGME:cyclohexanone=35-55:20-40:15-35.

The amount of the component (S) is not particularly limited, and is appropriately adjusted to a concentration which enables coating of a coating solution to a substrate. In general, the organic solvent is used in an amount such that the solid content of the resist composition becomes within the range from 1 to 20% by weight, and preferably from 2 to 15% by weight.

The resist composition of the present invention exhibits excellent various lithography properties such as sensitivity, exposure latitude, mask reproducibility, reduced roughness and the like and excellent pattern shape, and is capable of reducing defects. The reason why these effects can be achieved has not been elucidated yet, but is presumed as follows.

The polymer contained in the resist composition of the present invention contains an anion part which generates acid upon exposure on at least one terminal of the main chain. Therefore, it is presumed that acid is generated from the terminal of the polymer at the exposed portions, thereby improving the sensitivity.

In addition, by virtue of the polymer having a group capable of generating acid, the excessive diffusion of generated acid can be suppressed, as compared to the case using only an acid generator component composed of a low molecular weight compound such as those aforementioned as a component (B). In addition, by virtue of the polymer of the first aspect of the present invention having the structural unit (a3) which contains a specific polar group selected from the group consisting of —OH, —COOH, —CN, —SO₂NH₂ and —CONH₂, the hydrophilicity of the polymer can be enhanced.

In addition, there is a large interaction between the structural unit (a0) and an acid-generator component in the resist composition. Therefore, by virtue of the polymer having the structural unit (a0), it is presumed that the acid-generator component is likely to be uniformly distributed in the resist film.

Furthermore, the polymer of the first aspect of the present invention further contains a structural unit (a5) which generates acid upon exposure. Therefore, it is presumed that acid is generated from the terminal of main chain and the terminal of side chain of the polymer at the exposed portions, thereby improving the sensitivity.

In addition, the resist composition includes the polymer according to the first aspect of the present invention having a weight average molecular weight of 20,000 or less, therefore, it is presumed that diffusion of acid can be controlled and the significant reduction of dissolution rate in a developing solution can be suppressed.

Moreover, the polymer according to the fourth aspect of the present invention contains the structural unit (f1) containing a fluorine atom. Therefore, it is presumed that the water repellency is improved and defects can be reduced.

Moreover, the polymer according to the fourth aspect of the present invention contains the structural unit (f1) containing a fluorine atom. Therefore, it is presumed that the structural unit (f1) is distributed in the vicinity of the surface layer of the resist film, and hence, the water repellency is improved and the water tracking ability during immersion exposure is improved.

In addition, the polymer of the fourth aspect of the present invention has a group capable of generating acid. Therefore, it is presumed that the excessive diffusion of generated acid can be suppressed, as compared to the case using only an acid generator component composed of a low molecular weight compound such as those aforementioned as a component (B), and hence, various lithography properties and pattern shape can be improved.

Then, it is presumed that by the synergistic effect of these, various lithography properties and pattern shape can be improved.

Furthermore, in the case where the polymer contained in the resist composition according to the second aspect of the present invention is a component (A1) which exhibits increased polarity by the action of acid, it is presumed that the anion part which generates acid upon exposure on the terminal of the main chain of the component (A1) or the anion part on the side chain (the terminal of the structural unit (a5)) of the component (A1) are uniformly distributed within the resist film, and acid is uniformly generated from the anion part at exposed portions, and hence, the acid decomposable groups within the component (A1) are uniformly dissociated at exposed portions, as a result, the aforementioned effect is particularly achieved. In addition, it is presumed that the component (A1) has an anion part which generates an acid upon exposure and a structural unit (structural unit (a5)) which generates acid upon exposure, the acid which generates from either the anion part or the structural unit (a5) is present in relatively vicinity of the acid decomposable group, and hence, a decomposition reaction of the acid decomposable group by the action of acid is likely to occur, and therefore the aforementioned effect is particularly achieved.

Furthermore, in the case where the polymer contained in the resist composition according to the fifth aspect of the present invention is a component (F) which exhibits increased polarity by the action of acid, that is, in the case where the component (F) includes the structural unit (f2), it is presumed that the anion part which generates acid upon exposure on the terminal of the main chain of the component (F) is uniformly distributed within the resist film, and acid is uniformly generated from the anion part at exposed portions, and hence, the acid decomposable groups within the component (F) are uniformly dissociated at exposed portions, and therefore, the aforementioned effect is particularly achieved.

In addition, it is presumed that the component (F) has an anion part which generates an acid upon exposure, and an acid generated from the anion part is present in relatively vicinity of the acid decomposable group, and hence, a decomposition reaction of the acid decomposable group by the action of acid is likely to occur, and therefore the aforementioned effect is particularly achieved.

### <<Method of Forming a Resist Pattern>>

The method of forming a resist pattern according to the present invention includes: forming a resist film on a substrate using a resist composition of the present invention; conducting exposure of the resist film; and developing the resist film to form a resist pattern.

The method for forming a resist pattern according to the present invention can be performed, for example, as follows.

Firstly, a resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

After conducting selective exposure to the thus formed resist film, either by exposure through a mask having a predetermined pattern formed thereon (mask pattern) using an exposure apparatus such as an ArF exposure apparatus, an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment.

The developing treatment is conducted using an alkali developing solution in the case of an alkali developing process, whereas the developing treatment is conducted using a developing solution containing an organic solvent (organic developing solution) in the case of a solvent developing process.

After the developing treatment, it is preferable to conduct a rinse treatment. The rinse treatment is preferably conducted using pure water in the case of an alkali developing process, whereas the rinse treatment is preferably conducted using a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold. Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV.

The exposure of the resist film can be either a general exposure (dry exposure) conducted in air or an inert gas such as nitrogen, or immersion exposure (liquid immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used, which are capable of dissolving the component (A) (prior to exposure). Specific examples of the organic solvent include polar solvents such as ketone-based solvents, ester-based solvents, alcohol-based solvents, amide-based solvents and ether-based solvents, and hydrocarbon solvents.

If desired, the organic developing solution may have a conventional additive blended. Examples of the additive include surfactants. The surfactant is not particularly limited, and for example, an ionic or non-ionic fluorine surfactant surfactant and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone-based solvents, ester-based solvents, alcohol-based solvents, amide-based solvents and ether-based solvents is used. Among these, at least one solvent selected from the group consisting of hydrocarbon solvents, ketone-based solvents, ester-based solvents, alcohol-based solvents and amide-based solvents is preferable, more preferably at least one solvent selected from the group consisting of alcohol-based solvents and ester-based solvents, and an alcohol-based solvent is particularly desirable.

The rinse treatment (washing treatment) using the rinse liquid can be performed by a conventional rinse method. Examples thereof include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

In the NMR analysis, the internal standard for ¹H-NMR and ¹³C-NMR was tetramethylsilane. The internal standard for ¹⁹F-NMR was hexafluorobenzene (provided that the peak of hexafluorobenzene was regarded as −160 ppm).

### Synthesis Example 1

### Synthesis of Compound Anion-A

Under a nitrogen atmosphere, 28.0 g of ACVA and 36.8 g of Anion-a were added to 280 g of dichloromethane, and the mixture was stirred at room temperature. 27.8 g of diisopropylcarbodiimide was added thereto, followed by stirring for 10 minutes. Then, 2.44 g of dimethylaminopyridine was added thereto as a catalyst, and a reaction was effected for 24 hours at 30° C. 1400 g of t-butyl methyl ether was added to the suspended reaction solution, followed by stirring for 30 minutes, and then the precipitated objective compound was separated by filtration, followed by drying, thereby obtaining 20.8 g of Anion-A.

The obtained compound was analyzed by NMR, and the structure thereof was identified by the following results.

¹H-NMR (400 MHz, DMSO-d6): δ (ppm)=4.61 (dt, 4H, CH2CF2), 2.40-2.65 (m, 8H, CH2CH2), 1.72 (s, 6H, CH3), 1.66 (s, 6H, CH3).

¹⁹F-NMR (376 MHz, DMSO-d6): δ (ppm)=−111.4.

From the results shown above, it was confirmed that Anion-A had a structure shown below.

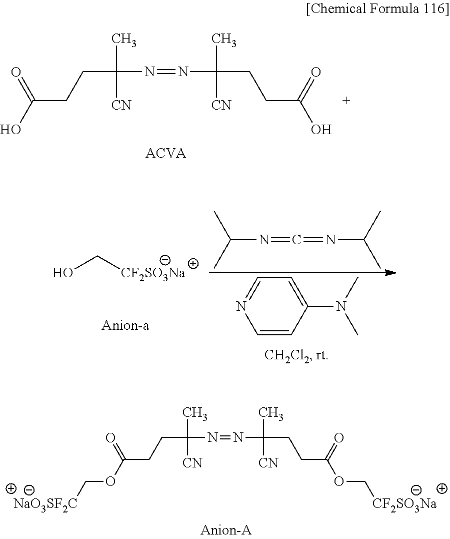

### Synthesis Example 2

### Synthesis of compound (I-A)

10.50 g of TPS—Br, 8.70 g of Anion-A, 155.0 g of dichloromethane and 78.0 g of pure water were added to a beaker, and the mixture was stirred at room temperature for 1 hour. Then, the dichloromethane phase was collected by liquid separation, and repeatedly washed with 78.0 g of pure water. Thereafter, the organic layer was concentrated under reduced pressure, thereby obtaining 13.80 g of a compound (I-A) in the form of a white solid.

The obtained compound was analyzed by NMR, and the structure thereof was identified by the following results.

¹H-NMR (400 MHz, DMSO-d6): δ (ppm)=7.78-7.90 (m, 30H, ArH), 4.61 (dt, 4H, CH2CF2), 2.40-2.65 (m, 8H, CH2CH2), 1.72 (s, 6H, CH3), 1.66 (s, 6H, CH3).

¹⁹F-NMR (376 MHz, DMSO-d6): δ (ppm)=−111.4.

From the results shown above, it was confirmed that compound (I-A) had a structure shown below.

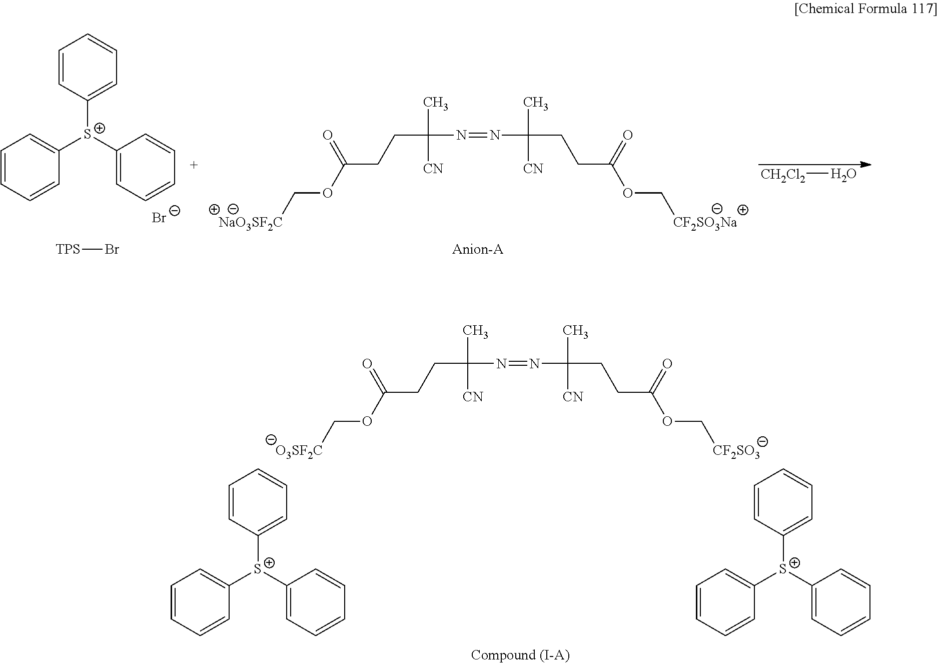

### Synthesis Examples 3 to 55

### Synthesis of Compounds (I-B) to (I-BB)

The same procedure as in Synthesis Example 2 was performed, except that the cation moiety of TPS-Br was changed to a cation moiety (equimolar amount) shown in Tables 1 to 18, respecitively. In this manner, compounds (I-B) to (I-BB) shown in Tables 1 to 18 were obtained.

These compound were analyzed by NMR. The results are shown in Tables 1 to 18.

TABLE 1

| Compound | NMR | Cation | Product |
|---|---|---|---|
| I-B | 1H-NMR (400 MHz, DMSO-d6): δ(ppm) = 8.50 (d, 4H, ArH), 8.37 (d, 4H, ArH), 7.93 (t, 4H, ArH), 7.55-7.75 (m, 14H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ(ppm) = −111.4. | 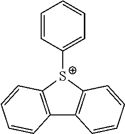 [SMILES: c1ccc(-[s+]2c3ccccc3c3ccccc32)cc1] | 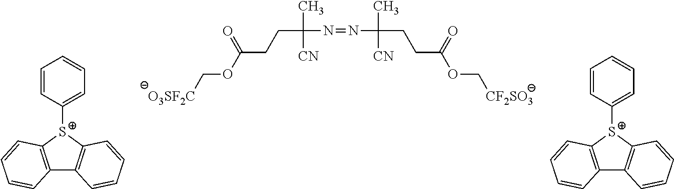 |
| I-C | 1H-NMR (400 MHz, DMSO-d6): δ(ppm) = 7.72-7.84 (m, 24H, ArH), 7.56 (d, 4H, ArH), 4.61 (dt, 4H, CH2CF2), 3.35 (s, 6H, ArCH3), 2.40- 2.65 (m, 8H, CH2CH2), 1.72 (s, 6H, CH3), 1.66 (s, 6H, CH3). 19F-NMR (376 MHz, DMSO-d6): δ(ppm) = −111.4. | 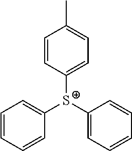 [SMILES: Cc1ccc([S+](c2ccccc2)c2ccccc2)cc1] | 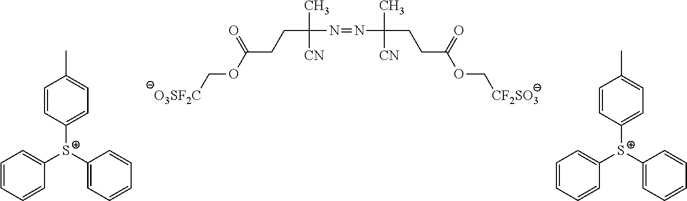 |
| I-D | 1H-NMR (400 MHz, DMSO-d6): δ(ppm) = 7.75-7.86 (m, 20H, ArH), 7.61 (s, 4H, ArH), 4.65 (s, 4H, CH2O), 4.61 (dt, 4H, CH2CF2), 2.40-2.65 (m, 8H, CH2CH2), 2.31 (s, 12H, ArCH3), 1.49-1.97 (m, 36H, Adamantane + CH3). 19F-NMR (376 MHz, DMSO-d6): δ(ppm) = −111.4. | 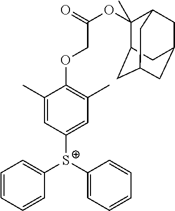 [SMILES: Cc1cc([S+](c2ccccc2)c2ccccc2)cc(C)c1OCC(=O)OC1(C)C2CC3CC(C2)CC1C3] | 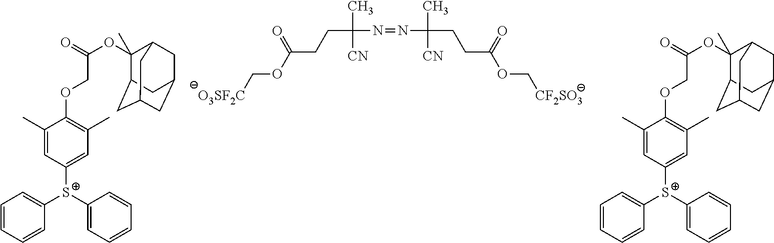 |

TABLE 2

| Compound | NMR | Cation | Product |
|---|---|---|---|
| I-E | 1H-NMR (400 MHz, DMSO-d6): δ(ppm) = 7.76-7.82 (m, 20H, ArH), 7.59 (s, 4H, ArH), 4.61 (dt, 4H, CH2CF2), 4.55 (s, 4H, OCH2), 2.40- 2.65 (m, 8H, CH2CH2), 2.29 (m, 12H, ArCH3), 1.90-1.93 (m, 8H, CH2CH3, cyclopentyl), 1.48-1.75 (m, 24H, CH3 + cyclopentyl), 0.77-0.81 (t, 6H, CH2CH3). 19F-NMR (376 MHz, DMSO-d6): δ(ppm) = −111.4. | 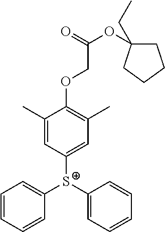 [SMILES: CCC1(OC(=O)COc2c(C)cc([S+](c3ccccc3)c3ccccc3)cc2C)CCCC1] | 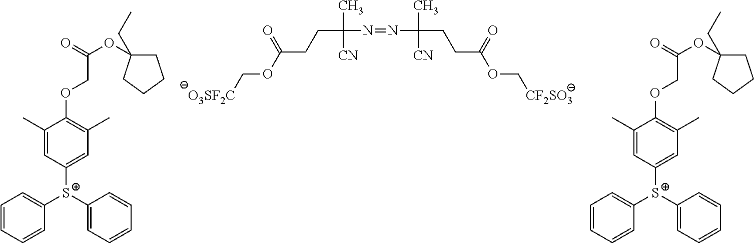 |
| I-F | 1H-NMR (400 MHz, DMSO-d6): δ(ppm) = 7.76-7.82 (m, 20H, ArH), 7.59 (s, 4H, ArH), 4.61 (dt, 4H, CH2CF2), 4.55 (s, 4H, OCH2), 2.40- 2.65 (m, 8H, CH2CH2), 2.29 (m, 12H, ArCH3), 1.90-2.08 (m, 4H, cyclopentyl), 1.48-1.75 (m, 30H, Cp- CH3 + cyclopentyl + CH3). 19F-NMR (376 MHz, DMSO-d6): δ(ppm) = −111.4. | 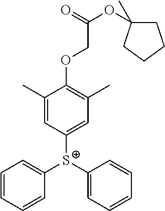 [SMILES: Cc1cc([S+](c2ccccc2)c2ccccc2)cc(C)c1OCC(=O)OC1(C)CCCC1] | 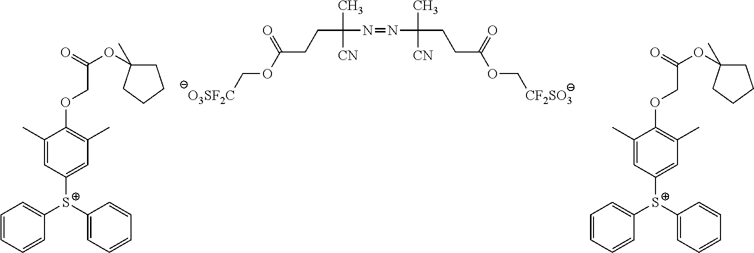 |
| I-G | 1H-NMR (400 MHz, DMSO-d6): δ(ppm) = 10.05 (s, 2H, OH), 7.64- 7.87 (m, 20H, ArH), 7.56 (s, 4H, ArH), 4.61 (dt, 4H, CH2CF2), 2.40- 2.65 (m, 8H, CH2CH2), 2.22 (m, 12H, ArCH3), 1.72 (s, 6H, CH3), 1.66 (s, 6H, CH3). 19F-NMR (376 MHz, DMSO-d6): δ(ppm) = −111.4. | 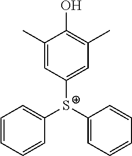 [SMILES: Cc1cc([S+](c2ccccc2)c2ccccc2)cc(C)c1O] | 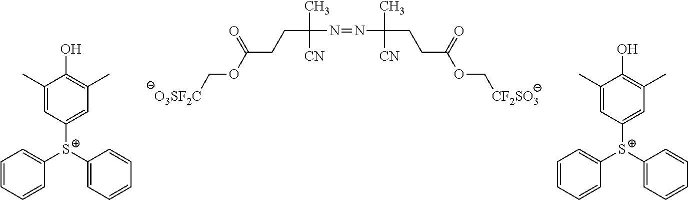 |

TABLE 3

| Compound | NMR | Cation | Product |
|---|---|---|---|
| I-H | 1H-NMR (400 MHz, DMSO-d6): δ(ppm) = 7.71-7.89 (m, 20H, ArH), 7.59 (s, 4H, ArH), 4.61 (dt, 4H, CH2CF2), 4.53 (s, 4H, OCH2), 2.40-2.65 (m, 8H, CH2CH2), 2.30 (s, 12H, ArCH3), 1.72 (s, 6H, CH3), 1.66 (s, CH3). 19F-NMR (376 MHz, DMSO-d6): δ(ppm) = −111.4. | 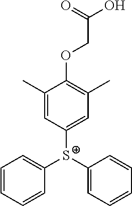 [SMILES: Cc1cc([S+](c2ccccc2)c2ccccc2)cc(C)c1OCC(=O)O] | 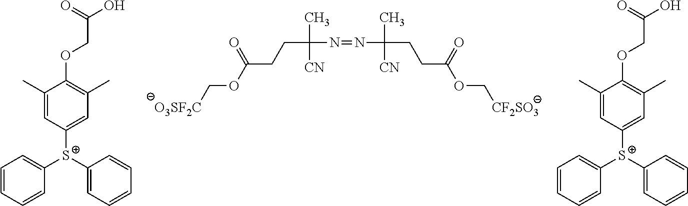 |
| I-I | 1H-NMR (400 MHz, DMSO-d6): δ(ppm) = 7.75-7.86 (m, 20H, ArH), 7.63 (s, 4H, ArH), 4.61 (dt, 4H, CH2CF2), 4.55 (s, 4H, OCH2), 2.40-2.65 (m, 8H, CH2CH2), 2.30 (s, 12H, ArCH3), 1.72 (s, 6H, CH3), 1.66 (s, 6H, CH3), 1.43 (s, 18H, t-Butyl). 19F-NMR (376 MHz, DMSO-d6): δ(ppm) = −111.4. | 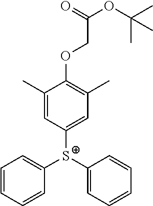 [SMILES: Cc1cc([S+](c2ccccc2)c2ccccc2)cc(C)c1OCC(=O)OC(C)(C)C] | 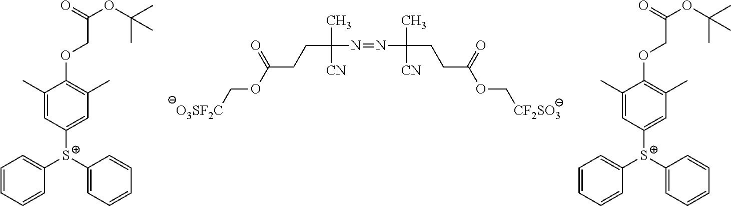 |
| I-J | 1H-NMR (400 MHz, DMSO-d6): δ(ppm) = 7.75-7.87 (m, 20H, ArH), 7.63, (s, 4H, ArH), 4.94 (t, 4H, OCH2CF2), 4.84 (s, 4H, OCH2), 4.61 (dt, 4H, CH2CF2), 2.40-2.65 (m, 8H, CH2CH2), 2.37 (s, 12H, ArCH3), 1.72 (s, 6H, CH3), 1.66 (s, 6H, CH3). 19F-NMR (376 MHz, DMSO-d6): δ(ppm) = −80.4, −111.4, −119.7. | 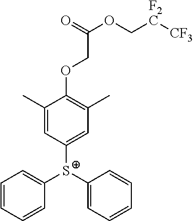 [SMILES: Cc1cc([S+](c2ccccc2)c2ccccc2)cc(C)c1OCC(=O)OCC(F)(F)C(F)(F)F] | 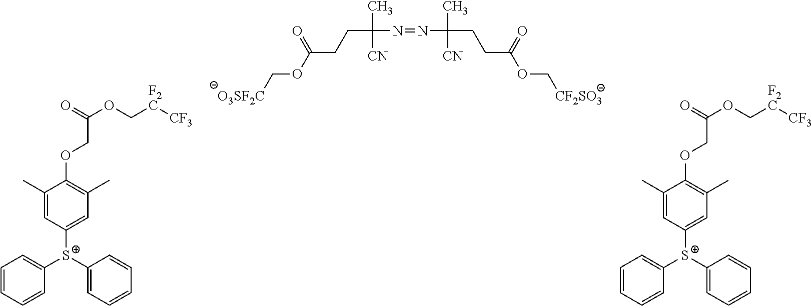 |

TABLE 4

| Com- | | | |
|---|---|---|---|
| pound | NMR | Cation | Product |
| I-K | 1H-NMR (400 MHz, DMSO-d6): δ (ppm) = 7.72-7.83 (m, 20H, ArH), 7.59 (s, 4H, ArH), 4.90 (m, 2H, sultone), 4.63-4.68 (m, 6H, CH2O + sultone), 4.61 (dt, 4H, CH2CF2), 3.83-3.89 (m, 2H, sultone), 3.43 (m, 2H, sultone), 1.75-2.65 (m, 30H, CH2CH2 + sultone + ArCH3), 1.72 (s, 6H, CH3), 1.66 (s, 6H, CH3), 19F-NMR (376 MHz, DMSO-d6): δ (ppm) = −111.4. | 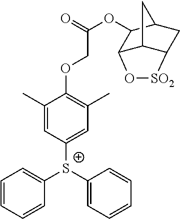 [SMILES: Cc1cc([S+](c2ccccc2)c2ccccc2)cc(C)c1OCC(=O)OC1C2CC3C1OS(=O)(=O)C3C2] | 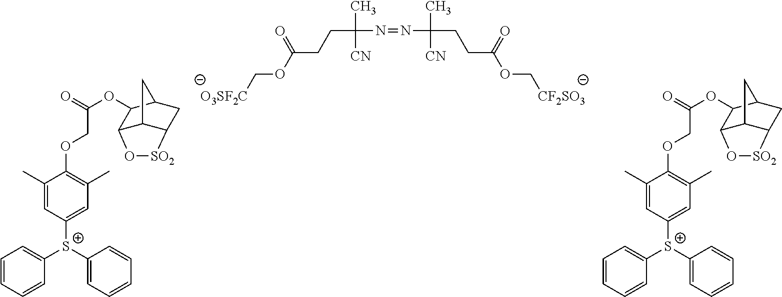 |
| I-L | 1H-NMR (400 MHz, DMSO-d6): δ (ppm) = 7.74-7.84 (m, 20H, ArH), 7.61 (s, 4H, ArH), 5.42 (t, 2H, oxo- norbornane), 4.97 (s, 2H, oxo- norbornane), 4.67-4.71 (m, 8H, OCH2 + oxo-norbornane), 4.61 (dt, 4H, CH2CF2), 2.69-2.73 (m, 2H, oxo-norbomane), 2.40- 2.65 (m, 8H, CH2CH2), 2.32 (s, 12H, ArCH3), 2.06-2.16 (m, 4H, oxo-norbornane), 1.72 (s, 6H, CH3), 1.66 (s, 6H, CH3), 19F-NMR (376 MHz, DMSO-d6): δ (ppm) = −111.4. | 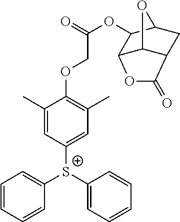 [SMILES: Cc1cc([S+](c2ccccc2)c2ccccc2)cc(C)c1OCC(=O)OC1C2CC3C(=O)OC1C3O2] | 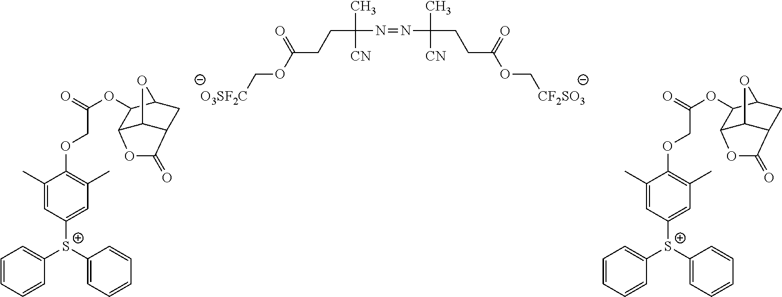 |
| I-M | 1H-NMR (400 MHz, DMSO-d6): δ (ppm) = 7.73-7.85 (m, 20H, ArH), 7.59 (S, 4H, ArH), 4.61 (dt, 4H, CH2CF2), 3.83 (t, 4H, OCH2), 2.40-2.65 (m, 8H, CH2CH2), 2.33 (s, 12H, ArCH3), 1.72 (s, 6H, CH3), 1.66 (s, 6H, CH3), 1.45 (m, 8H, CH2 in n-hexyl), 1.29 (m, 8H, CH2 in n-hexyl), 0.87 (t, 6H, CH3 in n-hexyl), 19F-NMR (376 MHz, DMSO-d6): δ (ppm) = −111.4. | 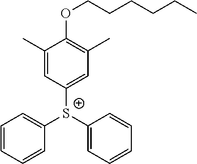 [SMILES: CCCCCCOc1c(C)cc([S+](c2ccccc2)c2ccccc2)cc1C] | 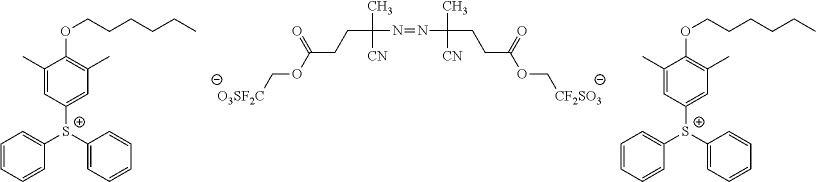 |

TABLE 5

| Com- | | | |
|---|---|---|---|
| pound | NMR | Cation | Product |
| I-N | 1H-NMR (400 MHz, DMSO-d6): δ (ppm) = 8.53 (d, 4H, ArH), 8.27 (d, 4H, ArH), 7.95 (t, 4H, ArH), 7.74 (t, 4H, ArH), 7.20 (s, 2H, ArH), 6.38 (s, 2H, ArH), 4.61 (dt, 4H, CH2CF2), 4.05 (t, 4H, OCH2), 2.40-2.65 (m, 8H, CH2CH2), 1.84 (s, 12H, ArCH3), 1.72 (s, 6H, CH3), 1.69 (quin, 4H, CH2 in n-hexyl), 1.66 (s, 6H, CH3), 1.37 (quin, 4H, CH2 in n-hexyl), 1.24-1.26 (m, 8H, CH2 in n-hexyl), 0.82 (t, 6H, CH3 in n-hexyl), 19F-NMR (376 MHz, DMSO-d6): δ (ppm) = −111.4. | 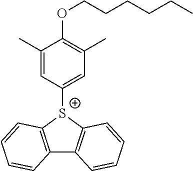 [SMILES: CCCCCCOc1c(C)cc(-[s+]2c3ccccc3c3ccccc32)cc1C] | 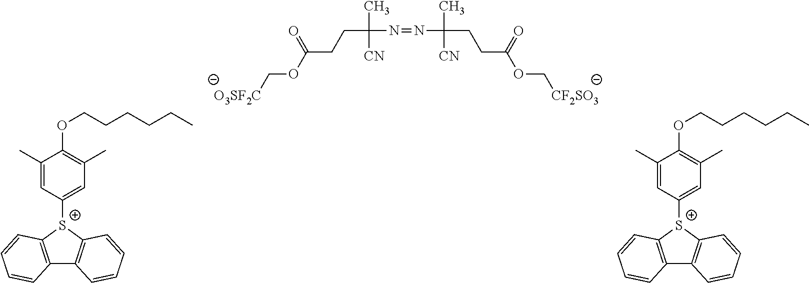 |
| I-O | 1H-NMR (400 MHz, DMSO-d6): δ (ppm) = 7.99-8.01 (d, 4H, ArH), 7.73-7.76 (t, 2H, ArH), 7.58-7.61 (t, 4H, ArH), 5.31 (s, 4H, SCH2C═O), 4.61 (dt, 4H, CH2CF2), 3.49-3.62 (m, 8H, CH2 in tetramethylenesulfide), 2.18-2.65 (m, 16H, CH2S + CH2CH2), 1.72 (s, 6H, CH3), 1.66 (s, 6H, CH3), 19F-NMR (376 MHz, DMSO-d6): δ (ppm) = −111.4. | 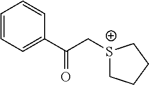 [SMILES: O=C(C[S+]1CCCC1)c1ccccc1] | 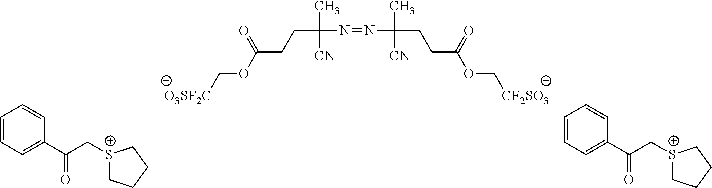 |
| I-P | 1H-NMR (400 MHz, DMSO-d6): δ (ppm) = 8.02-8.05 (m, 4H, ArH), 7.61-7.73 (m, 6H, ArH), 4.61 (dt, 4H, CH2CF2), 3.76-3.86 (m, 8H, SCH2), 2.40-2.65 (m, 8H, CH2CH2), 2.09-2.12 (m, 4H, CH2 in pentamethylenesulfide), 1.84-1.93 (m, 4H, CH2 in pentamethylenesulfide), 1.61-1.72 (m, 16H, CH3 + CH2 in pentamethylenesulfide), 19F-NMR (376 MHz, DMSO-d6): δ (ppm) = −111.4. | 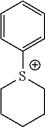 [SMILES: c1ccc([S+]2CCCCC2)cc1] | 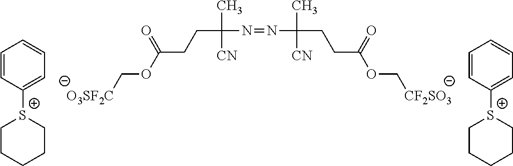 |

TABLE 6

| Compound | NMR | Cation | Product |
|---|---|---|---|
| I-Q | 1H-NMR (400 MHz, DMSO-d6): δ (ppm) = 8.04-8.09 (m, 4H, ArH), 7.69-7.79 (m, 6H, ArH), 4.61 (dt, 4H, CH2CF2), 3.29 (s, 12H, SCH3), 2.40- 2.65 (m, 8H, CH2CH2), 1.72 (s, 6H, CH3), 1.66 (s, 6H, CH3), 19F-NMR (376 MHz, DMSO-d6): δ (ppm) = −111.4. | 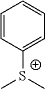 | 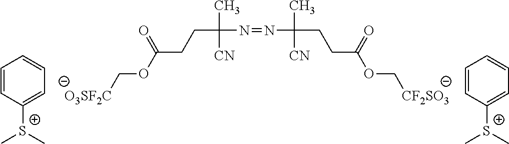 |
| I-R | 1H-NMR (400 MHz, DMSO-d6): δ (ppm) = 8.07 (d, 4H, ArH), 7.81(d, 4H, ArH), 4.61 (dt, 4H, CH2CF2), 4.10 (t, 4H, CH2 in pentamethylenesulfide), 3.59 (d, 4H, CH2 in pentamethylenesulfide), 2.40-2.65 (m, 8H, CH2CH2), 2.20 (d, 4H, CH2 in pentamethylenesulfide), 1.71-2.19 (m, 14H, CH3 + CH2 in pentamethylenesulfide), 1.66 (s, 6H, CH3), 1.23 (s, 18H, t-Bu), 19F-NMR (376 MHz, DMSO-d6): δ (ppm) = −11 1.4. | 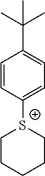 [SMILES: CC(C)(C)c1ccc([S+]2CCCCC2)cc1] | 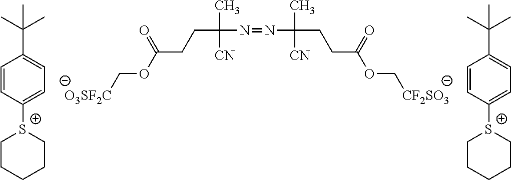 |
| I-S | 1H-NMR (400 MHz, DMSO-d6): δ (ppm) = 7.77-7.89 (m, 20H, ArH), 7.70 (s, 4H, ArH), 5.10 (s, 4H, CH2O), 4.61 (dt, 4H, CH2CF2), 2.40-2.65 (m, 8H, CH2CH2), 2.07-2.19 (m, 18H, CH3O + ArCH3), 1.72 (s, 6H, CH3), 1.66 (s, 6H, CH3), 19F-NMR (376 MHz, DMSO-d6): δ (ppm) = −111.4. | 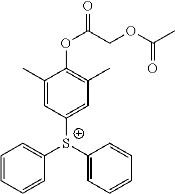 [SMILES: CC(=O)OCC(=O)Oc1c(C)cc([S+](c2ccccc2)c2ccccc2)cc1C] | 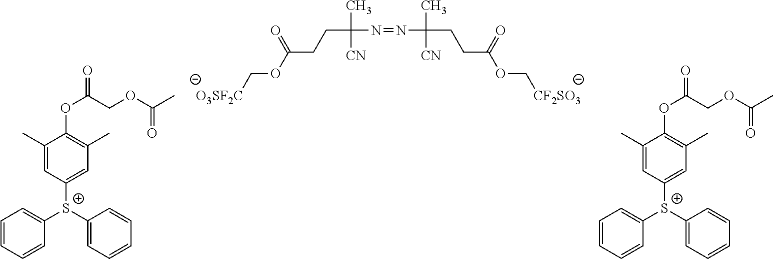 |

TABLE 7

| Com- | | | |
|---|---|---|---|
| pound | NMR | Cation | Product |
| I-T | 1H-NMR (400 MHz, DMSO- d6): δ (ppm) = 7.84 (d, 12H, ArH), 7.78 (d, 12H, ArH), 4.61 (dt, 4H, CH2CF2), 2.40- 2.65 (m, 8H, CH2CH2), 1.72 (s, 6H, CH3), 1.66 (s, 6H, CH3), 1.33 (s, 54H, tBu), 19F- NMR (376 MHz, DMSO- d6): δ (ppm) = −111.4. | 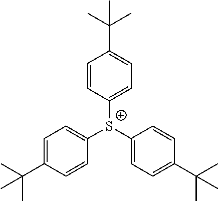 [SMILES: CC(C)(C)c1ccc([S+](c2ccc(C(C)(C)C)cc2)c2ccc(C(C)(C)C)cc2)cc1] | 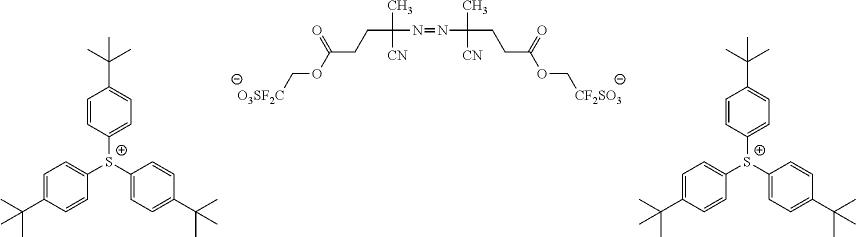 |
| I-U | 1H-NMR (400 MHz, DMSO- d6): δ (ppm) = 7.73- 7.89 (m, 24H, ArH), 4.61 (dt, 4H, CH2CF2), 2.40- 2.65 (m, 8H, CH2CH2), 2.38 (s, 12H, ArCH3), 1.72 (5, 6H, CH3), 1.66 (s, 6H, CH3), 19F- NMR (376 MHz, DMSO- d6): δ (ppm) = −70.2. −111.4. | 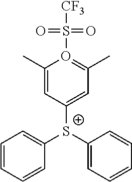 | 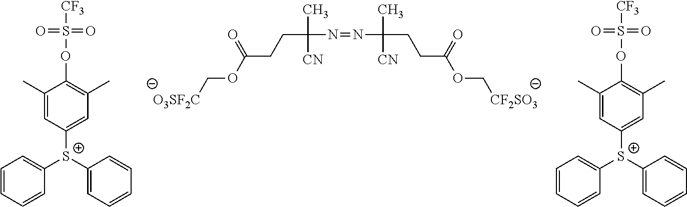 |
| I-V | 1H-NMR (400 MHz, DMSO- d6): δ (ppm) = 7.69- 7.85 (m, 20H, ArH), 7.56 (s, 4H, ArH), 4.75 (s, 8H, OCH2), 4.61 (dt, 4H, CH2CF2), 2.40-2.65 (m, 8H, CH2CH2), 2.31 (s, 12H, ArCH3), 2.19 (m, 4H, Adaman- tane), 1.47- 1.98 (m, 42H, CH3 + Adaman- tane), 19F-NMR (376 MHz, DMSO- d6): δ (ppm) = −111.4. | 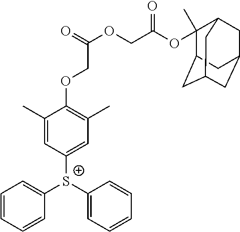 [SMILES: Cc1cc([S+](c2ccccc2)c2ccccc2)cc(C)c1OCC(=O)OCC(=O)OC1(C)C2CC3CC(C2)CC1C3] | 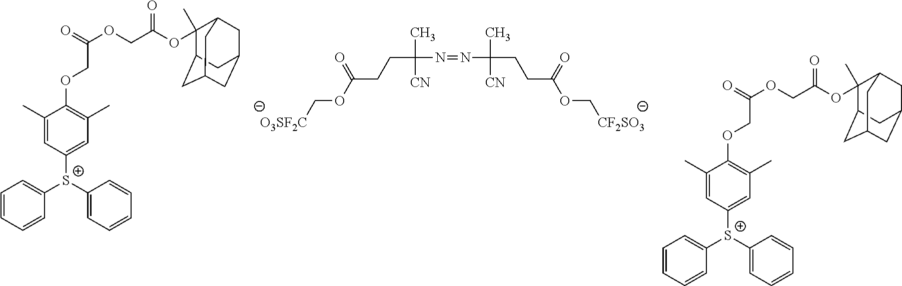 |

TABLE 8

| Com- | | | |
|---|---|---|---|
| pound | NMR | Cation | Product |
| I-W | 1H-NMR (400 MHz, DMSO-d6): δ (ppm) = 7.72-7.84 (m, 20H, ArH), 7.59 (s, 4H, ArH), 4.61 (dt, 4H, CH2CF2), 4.56 (s, 4H, OCH2), 2.40- 2.65 (m, 12H, CH2CH2 + Adamantane), 2.27-2.34 (m, 26H, ArCH3 + Adamantane), 1.94-1.97 (m, 4H, Adamantane), 1.74- 1.79 (m, 4H, Adamantane), 1.72 (s, 6H, CH3), 1.66 (s, 6H, CH3), 19F-NMR (376 MHz, DMSO-d6): δ (ppm) = −111.4. | 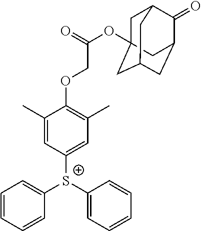 [SMILES: Cc1cc([S+](c2ccccc2)c2ccccc2)cc(C)c1OCC(=O)OC12CC3CC(C1)C(=O)C(C3)C2] | 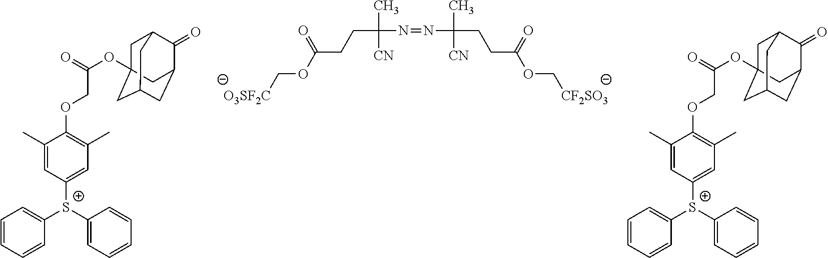 |
| I-X | 1H-NMR (400 MHz, DMSO-d6): δ (ppm) = 7.72-7.84 (m, 20H, ArH), 7.59 (s, 4H, ArH), 4.64 (s, 4H, OCH2), 4.61 (dt, 4H, CH2CF2), 3.70 (s, 6H, OCH3), 2.40-2.65 (m, 8H, CH2CH2), 2.29 (s, 12H, ArCH3), 1.72 (s, 6H, CH3), 1.66 (s, 6H, CH3), 19F-NMR (376 MHz, DMSO-d6): δ (ppm) = −111.4. | 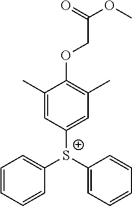 [SMILES: COC(=O)COc1c(C)cc([S+](c2ccccc2)c2ccccc2)cc1C] | 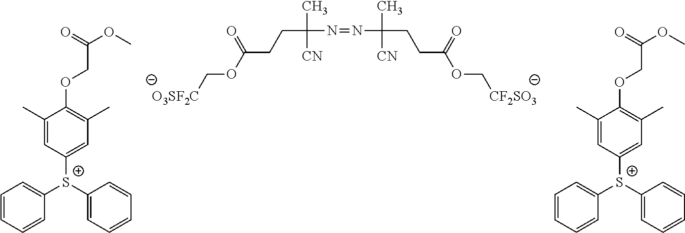 |
| I-Y | 1H-NMR (400 MHz, DMSO-d6): δ (ppm) = 7.78-7.89 (m, 20H, ArH), 7.64 (s, 4H, ArH), 4.61 (dt, 4H, CH2CF2), 3.79 (s, 6H, OCH3), 2.40-2.65 (m, 8H, CH2CH2), 2.32 (s, 12H, ArCH3), 1.72 (s, 6H, CH3), 1.66 (s, 6H, CH3), 19F-NMR (376 MHz, DMSO-d6): δ (ppm) = −111.4. | 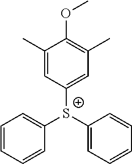 [SMILES: COc1c(C)cc([S+](c2ccccc2)c2ccccc2)cc1C] | 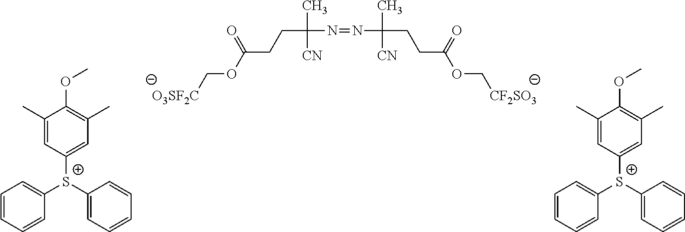 |

TABLE 9

| Com- | | | |
|---|---|---|---|
| pound | NMR | Cation | Product |
| I-Z | 1H-NMR (400 MHz, DMSO-d6): δ (ppm) = 7.76-7.87 (m, 20H, ArH), 7.69 (s, 4H, ArH), 4.61 (dt, 4H, CH2CF2), 2.40-2.65 (m, 8H, CH2CH2), 2.13 (s, 12H, ArCH3), 1.66-2.03 (m, 42H, CH3 + Adamantane), 19F-NMR (376 MHz, DMSO-d6): δ (ppm) = −111.4. | 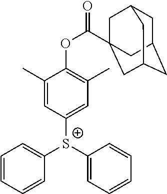 [SMILES: Cc1cc([S+](c2ccccc2)c2ccccc2)cc(C)c1OC(=O)C12CC3CC(CC(C3)C1)C2] | 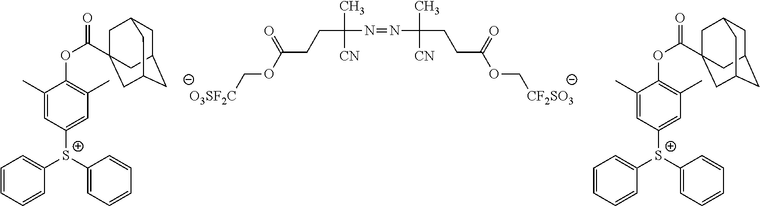 |
| I-AA | 1H-NMR (400 MHz, DMSO-d6): δ (ppm) = 7.79-7.93 (m, 24H, ArH), 4.61 (dt, 4H, CH2CF2), 2.73 (t, 4H, COCH2), 2.40-2.65 (m, 8H, CH2CH2), 2.19 (s, 12H, ArCH3), 1.65- 1.72 (m, 16H, CH3 + CH2 in decanyl), 1.25-1.38 (in, 28H, CH2 in decanyl), 0.85 (t, 6H, CH3 in decanyl), 19F-NMR (376 MHz, DMSO-d6): δ (ppm) = −111.4. | 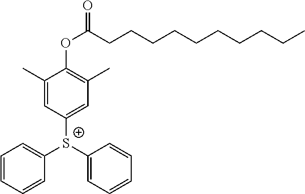 [SMILES: CCCCCCCCCCC(=O)Oc1c(C)cc([S+](c2ccccc2)c2ccccc2)cc1C] | 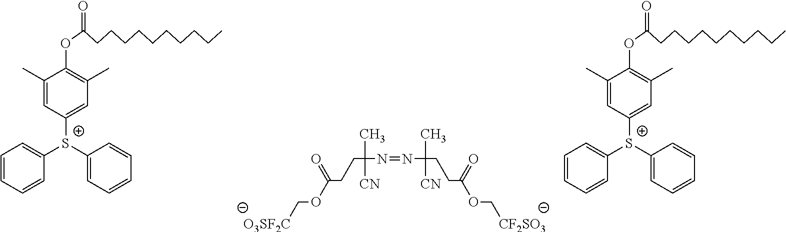 |
| I-AB | 1H-NMR (400 MHz, DMSO-d6): δ (ppm) = 8.76 (s, 2H, ArH), 8.59- 8.64 (m, 2H, ArH), 8.42 (t, 4H, ArH), 8.03-8.19 (m, 10H, ArH), 7.81 (t, 2H, ArH), 7.69 (t, 4H, ArH) 4.61 (dt, 4H, CH2CF2), 2.40-2.65 (m, 8H, CH2CH2), 1.72 (s, 6H, CH3), 1.66 (s, 6H, CH3), 19F-NMR (376 MHz, DMSO- d6): δ (ppm) = −62.1. −111.4. | 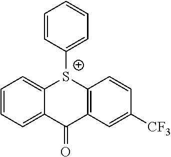 [SMILES: O=c1c2ccccc2[s+](-c2ccccc2)c2ccc(C(F)(F)F)cc12] | 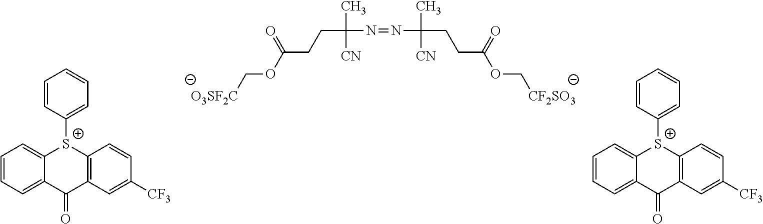 |

TABLE 10

| Compound | NMR | Cation | Product |
|---|---|---|---|
| I-AC | 1H-NMR (400 MHz, DMSO- d6): δ (ppm) = 4.61 (dt, 4H, CH2CF2), 3.36 (t, 12H, CH2 in n-butyl), 2.40-2.65 (m, 8H, CH2CH2), 1.72 (s, 6H, CH3), 1.68 (quintet, 12H, CH2 in n- butyl), 1.66 (s, 6H, CH3), 1.35-1.44 (m, 12H, CH2 in n-butyl), 0.81-0.93 (m, 18H, CH3 in n-butyl), 19F-NMR (376 MHz, DMSO-d6): δ (ppm) = −111.4. | 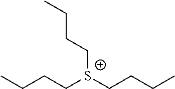 | 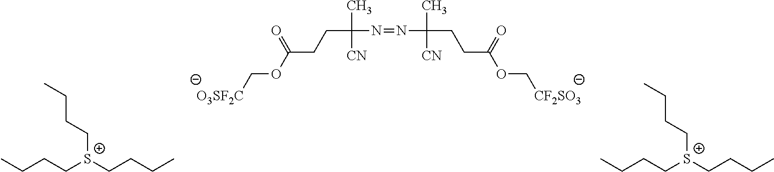 |
| I-AD | 1H-NMR (400 MHz, DMSO- d6): δ (ppm) = 8.29 (d, 8H, ArH), 7.93-8.09 (m, 12H, ArH), 4.61 (dt, 4H, CH2CF2), 2.40-2.65 (m, 8H, CH2CH2), 1.72 (s, 6H, CH3), 1.66 (s, 6H, CH3), 19F-NMR (376 MHz, DMSO-d6): δ (ppm) = −47.9. −111.4. | 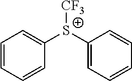 [SMILES: FC(F)(F)[S+](c1ccccc1)c1ccccc1] | 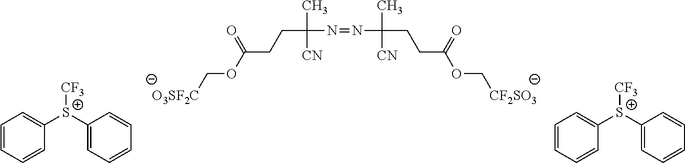 |
| I-AE | 1H-NMR (400 MHz, DMSO-d6): δ (ppm) = 7.90-8.24 (m, 14H, ArH), 4.61 (dt, 4H, CH2CF2), 3.85 (s, 6H, OCH3), 2.42 (s, 12H, ArCH3) 2.40-2.65 (m, 8H, CH2CH2), 1.72 (s, 6H, CH3), 1.66 (s, 6H, CH3), 19F-NMR (376 MHz, DMSO-d6): δ (ppm) = −48.8. −111.4. | 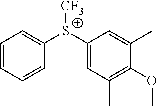 [SMILES: COc1c(C)cc([S+](c2ccccc2)C(F)(F)F)cc1C] | 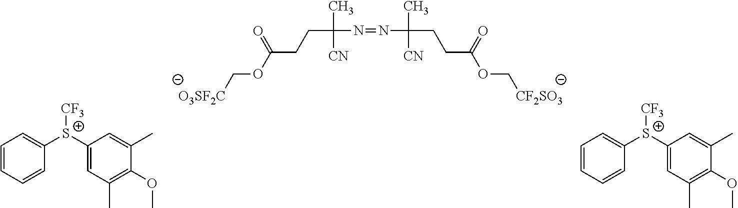 |

TABLE 11

| Compound | NMR | Cation | Product |
|---|---|---|---|
| I-AF | 1H-NMR (400 MHz, DMSO-d6): δ (ppm) = 10.12 (s, 2H, OH), 7.90-8.24 (m, 14H, ArH), 4.61 (dt, 4H, CH2CF2), 2.42 (s, 12H, ArCH3), 2.40-2.65 (m, 8H, CH2CH2), 1.72 (s, 6H, CH3), 1.66 (s, 6H, CH3), 19F-NMR (376 MHz, DMSO- d6): δ (ppm) = −48.2. −111.4. | 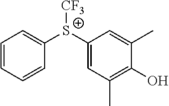 [SMILES: Cc1cc([S+](c2ccccc2)C(F)(F)F)cc(C)c1O] | 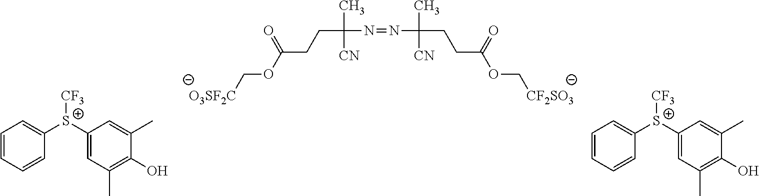 |
| I-AG | 1H-NMR (400 MHz, DMSO- d6): δ (ppm) = 8.49 (d, 4H, ArH), 8.30 (d, 4H, ArH), 7.93 (t, 4H, ArH), 7.73 (t, 4H, ArH), 7.30 (s, 4H, ArH), 4.61 (dt, 4H, CH2CF2), 4.52 (s, 4H, OCH2), 2.40-2.65 (m, 8H, CH2CH2), 2.16-2.24 (m, 16H, ArCH3 + Adamantane), 1.44-1.92 (m, 42H, Adamantane + CH3), 19F-NMR (376 MHz, DMSO-d6): δ (ppm) = −111.4. | 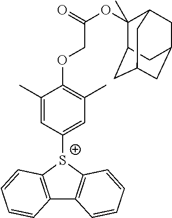 [SMILES: Cc1cc(-[s+]2c3ccccc3c3ccccc32)cc(C)c1OCC(=O)OC1(C)C2CC3CC(C2)CC1C3] | 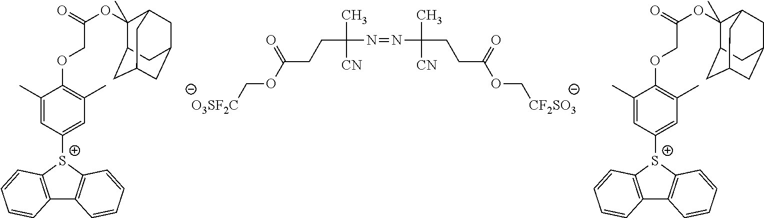 |
| I-AH | 1H-NMR (400 MHz, DMSO- d6): δ (ppm) = 9.73 (br s, 2H, OH), 8.47 ( d, 4H, ArH), 3.24 (d, 4H, ArH), 7.91 (t, 4H, ArH), 7.71 (t, 4H, ArH), 7.18 (s, 4H, ArH), 4.61 (dt, 4H, CH2CF2), 2.40-2.65 (m, 8H, CH2CH2), 2.10 (s, 12H, ArCH3), 1.72 (s, 6H, CH3), 1.66 (s, 6H, CH3), 19F-NMR (376 MHz, DMSO-d6): δ (ppm) = −111.4. | 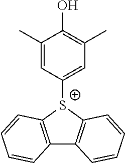 [SMILES: Cc1cc(-[s+]2c3ccccc3c3ccccc32)cc(C)c1O] | 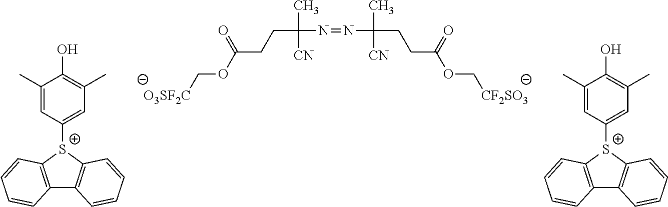 |

TABLE 12

| Com- | | | |
|---|---|---|---|
| pound | NMR | Cation | Product |
| I-AI | 1H-NMR (400 MHz, DMSO-d6): δ (ppm) = 7.75-7.87 (m, 20H, ArH), 7.62 (s, 4H, ArH), 4.61 (dt, 4H, CH2CF2), 3.97 (t, 4H, OCH2), 2.03-2.65 (m, 28H, CH2CH2 + CH2CH2CF2 + ArCH3) 1.72 (s, 6H, CH3), 1.66 (s, 6H, CH3), 19F- NMR (376 MHz, DMSO-d6): δ (ppm) = −78.3. −111.4. −111.6. −121.8. −123.5. | 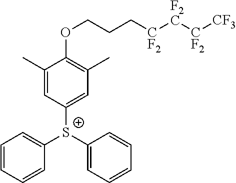 [SMILES: Cc1cc([S+](c2ccccc2)c2ccccc2)cc(C)c1OCCCC(F)(F)C(F)(F)C(F)(F)C(F)(F)F] | 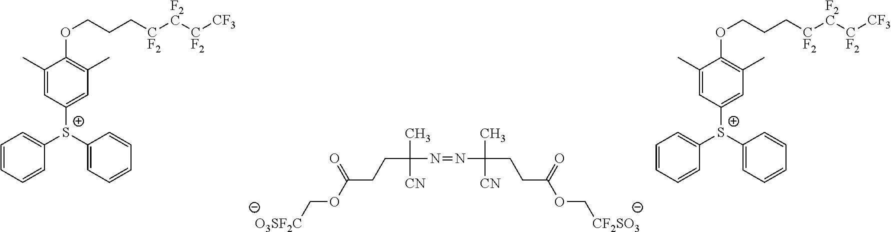 |
| I-AJ | 1H-NMR (400 MHz, DMSO-d6): δ (ppm) = 7.75-7.86 (m, 20H, ArH), 7.60 (s, 4H, ArH), 4.61 (dt, 4H, CH2CF2), 3.87 (t, 4H, OCH2), 2.40-2.65 (m, 12H, CH2CH2 + CH2 in cation), 2.20 (s, 12H, ArCH3), 2.12 (s, 12H, NCH3), 1.86 (t, 4H, NCH2), 1.72 (s, 6H, CH3), 1.66 (s, 6H, CH3), 19F-NMR (376 MHz, DMSO-d6): δ (ppm) = −111.4. | 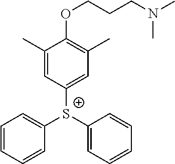 [SMILES: Cc1cc([S+](c2ccccc2)c2ccccc2)cc(C)c1OCCCN(C)C] | 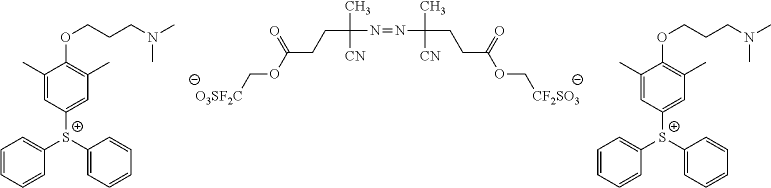 |
| I-AK | 1H-NMR (400 MHz, DMSO-d6): δ (ppm) = 7.77-7.89 (m, 20H, ArH), 7.71 (s, 4H, ArH), 4.61 (dt, 4H, CH2CF2), 2.40-2.65 (m, 12H, CH2CH2 + CH2 − Ad), 2.20 (s, 12H, ArCH3), 1.97 (s, 6H, Adaman- tane), 1.62-1.73 (m, 36H, CH3 + Adaman- tane), 19F-NMR (376 MHz, DMSO-d6): δ (ppm) = −111.4. | 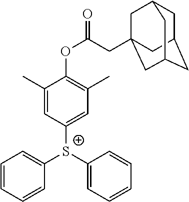 [SMILES: Cc1cc([S+](c2ccccc2)c2ccccc2)cc(C)c1OC(=O)CC12CC3CC(CC(C3)C1)C2] | 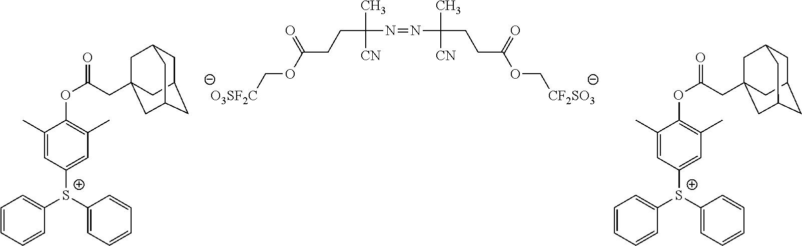 |

TABLE 13

| Compound | NMR | Cation | Product |
|---|---|---|---|
| I-AL | 1H-NMR (400 MHz, DMSO-d6): δ (ppm) = 7.74-7.84 (m, 20H, ArH), 7.61 (s, 4H, ArH), 4.49- 4.66 (m, 12H, CH2CF2 + norbornane + OCH2), 3.24 (m, 2H, norbornane), 2.40-2.65 (m, 12H, CH2CH2 + norbornane), 2.37 (s, 12H, ArCH3), 1.91-2.06 (m, 4H, norbornane), 1.72 (s, 6H, CH3), 1.57-1.67 (m, 10H, CH3 + norbornane), 19F-NMR (376 MHz, DMSO-d6): δ (ppm) = −111.4. | 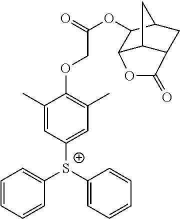 [SMILES: Cc1cc([S+](c2ccccc2)c2ccccc2)cc(C)c1OCC(=O)OC1C2CC3C(=O)OC1C3C2] | 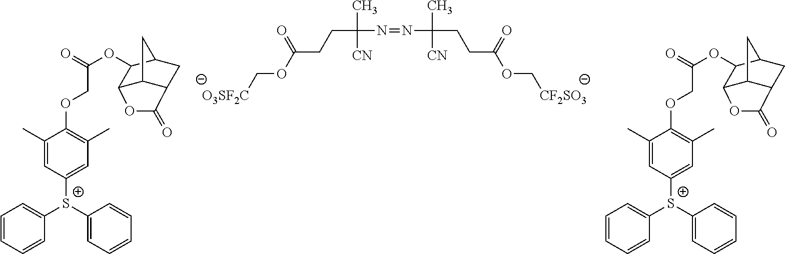 |
| I-AM | 1H-NMR (400 MHz, DMSO-d6): δ (ppm) = 7.80-7.92 (m, 20H, ArH), 7.67 (s, 4H, ArH), 4.66 (s, 4H, OCH2), 4.61 (dt, 4H, CH2CF2), 2.40-2.65 (m, 8H, CH2CH2), 2.37 (s, 12H, ArCH3), 2.13-2.16 (m, 4H, cyclohexyl), 1.93 (q, 4H, CH2 in ethyl), 1.72 (s, 6H, CH3), 1.66 (s, 6H, CH3), 1.14-1.57 (m, 16H, cyclohexyl), 0.84 (t, 6H, CH3 in ethyl), 19F-NMR (376 MHz, DMSO-d6): δ (ppm) = −111.4. | 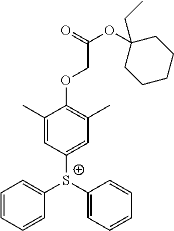 [SMILES: CCC1(OC(=O)COc2c(C)cc([S+](c3ccccc3)c3ccccc3)cc2C)CCCCC1] | 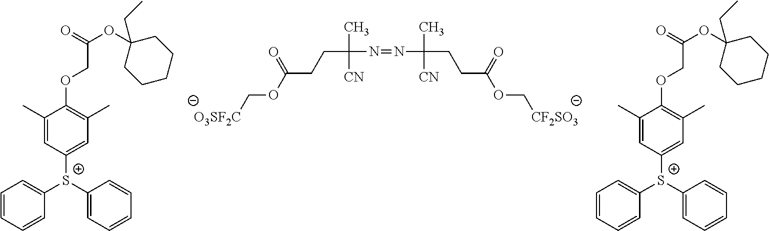 |
| I-AN | 1H-NMR (400 MHz, DMSO-d6): δ (ppm) = 8.44 (d, 2H, ArH), 8.22 (m, 4H, ArH), 7.73-7.89 (m, 26H, ArH), 7.50 (d, 2H, ArH), 4.61 (dt, 4H, CH2CF2), 2.40-2.65 (m, 8H, CH2CH2), 1.72 (s, 6H, CH3), 1.66 (s, 6H, CH3), 19F-NMR (376 MHz, DMSO-d6): δ (ppm) = −111.4. | 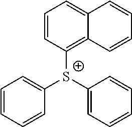 [SMILES: c1ccc([S+](c2ccccc2)c2cccc3ccccc23)cc1] | 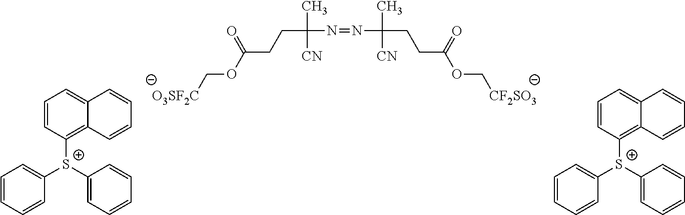 |

TABLE 14

| Compound | NMR | Cation | Product |
|---|---|---|---|
| I-AO | 1H-NMR (400 MHz, DMSO-d6): δ (ppm) = 8.24 (d, 8H, ArH), 7.59 (t, 4H, ArH), 7.47 (t, 8H, ArH), 4.61 (dt, 4H, CH2CF2), 2.40-2.65 (m, 8H,CH2CH2), 1.72 (s, 6H, CH3), 1.66 (s, 6H, CH3), 19F- NMR (376 MHz, DMSO-d6): δ (ppm) = −111.4. | 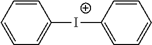 [SMILES: c1ccc([I+]c2ccccc2)cc1] | 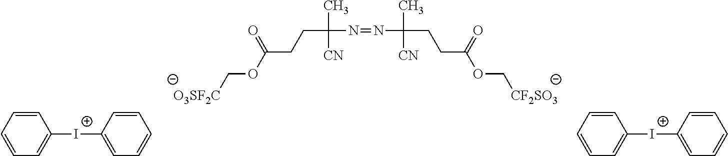 |
| I-AP | 1H-NMR (400 MHz, DMSO-d6): δ (ppm) = 8.55 (d, 4H, ArH), 8.38 (d, 4H, ArH), 8.32 (d, 4H, ArH), 8.03 (d, 4H, ArH), 7.93-7.97 (m, 2H, ArH), 7.82-7.88 (m, 16H, ArH), 7.55 (d, 4H, ArH), 4.61(dt, 4H, CH2CF2), 2.40-2.65 (m, 8H, CH2CH2), 1.72 (s, 6H, CH3), 1.66 (s, 6H, CH3), 19F-NMR (376 MHz, DMSO d6): δ (ppm) = −111.4. | 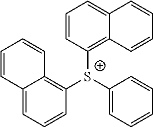 [SMILES: c1ccc([S+](c2cccc3ccccc23)c2cccc3ccccc23)cc1] | 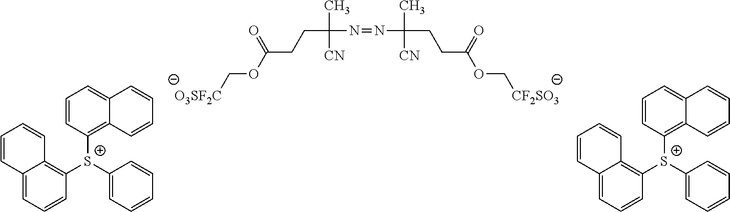 |
| I-AQ | 1H-NMR (400 MHz, DMSO-d6): δ (ppm) = 4.61 (dt, 4H, CH2CF2), 4.46 (s, 4H, CH2(C═O)), 3.38-3.58 (m, 8H, CH2SCH2), 2.40-2.65 (m, 8H, CH2CH2), 1.56- 2.33 (m, 54H, CH3 + Adamantane + CH2CH2 in tetramethylenesulfide), 19F-NMR (376 MHz, DMSO-d6): δ (ppm) = −111.4. | 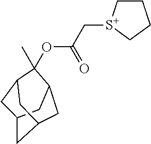 [SMILES: CC1(OC(=O)C[S+]2CCCC2)C2CC3CC(C2)CC1C3] | 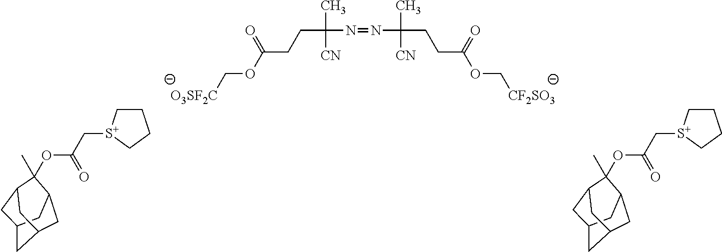 |

TABLE 15

| Com- | | | |
|---|---|---|---|
| pound | NMR | Cation | Product |
| I-AR | 1H-NMR (400 MHz, DMSO-d6): δ (ppm) = 7.75 (s, 4H, Ar), 4.61 (dt, 4H, CH2CF2), 3.91-3.96 (m, 4H, CH2 in tetramethylenesulfide), 3.72-3.79 (m, 4H, CH2 in tetramethylenesulfide), 2.40-2.65 (m, 8H, CH2CH2), 2.29-2.39 (m, 8H, CH2 in tetramethylenesulfide), 1.75-2.19 (m, 42H, ArCH3 + Adamantane), 1.72 (s, 6H, CH3), 1.66 (s, 6H, CH3), 19F-NMR (376 MHz, DMSO-d6): δ (ppm) = −111.4. | 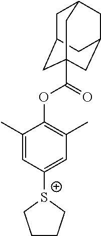 [SMILES: Cc1cc([S+]2CCCC2)cc(C)c1OC(=O)C12CC3CC(CC(C3)C1)C2] | 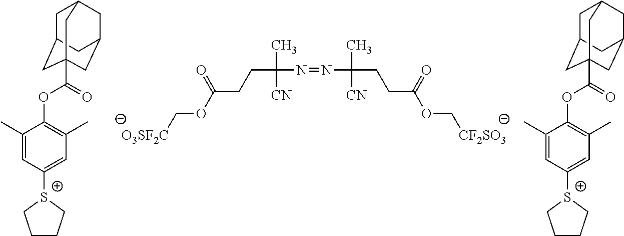 |
| I-AS | 1H-NMR (400 MHz, DMSO-d6): δ (ppm) = 7.82 (m, 4H, ArH), 4.61 (dt, 4H, CH2CF2), 3.73-3.91 (m, 8H CH2 in pentamethylenesulfide), 2.41-2.65 (m, 8H, CH2CH2), 1.56- 2.40 (m, 66H, CH3 + ArCH3 + CH2 in pentamethylenesulfide + Adamantane), 19F-NMR (376 MHz, DMSO-d6): δ (ppm) = −111.4. | 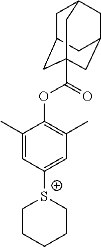 [SMILES: Cc1cc([S+]2CCCCC2)cc(C)c1OC(=O)C12CC3CC(CC(C3)C1)C2] | 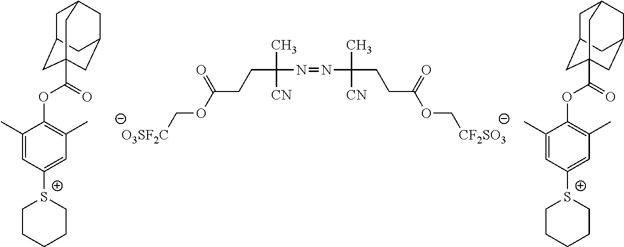 |
| I-AT | 1H-NMR (400 MHz, DMSO-d6): δ (ppm) = 8.23 (d, 8H, ArH), 7.98 (d, 8H, ArH), 4.61 (dt, 4H, CH2CF2), 2.40- 2.65 (m, 8H, CH2CH2), 1.72 (s, 6H, CH3), 1.66 (s, 6H, CH3), 1.37 (s, 36H, t-Butyl), 19F-NMR (376 MHz, DMSO-d6): δ (ppm) = −48.5. −111.4. | 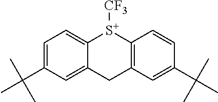 [SMILES: CC(C)(C)c1ccc2c(c1)Cc1cc(C(C)(C)C)ccc1[S+]2C(F)(F)F] | 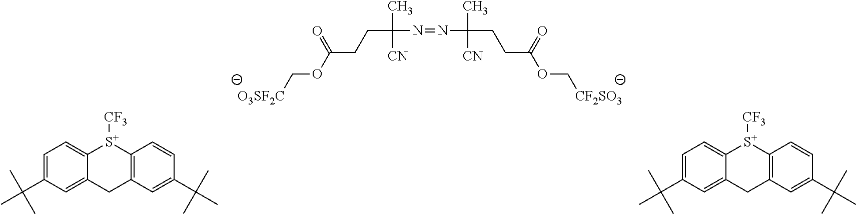 |

TABLE 16

| Compound | NMR | Cation | Product |
|---|---|---|---|
| I-AU | 1H-NMR (400 MHz, DMSO-d6): δ (ppm) = 7.77- 7.98 (m, 20H, ArH), 7.64 (s, 4H, ArH), 4.61 (dt, 4H, CH2CF2), 4.57 (s, 4H, CH2O), 2.42 (s, 12H, ArCH3), 2.40-2.65 (m, 8H, CH2CH2), 2.02- 2.26 (m, 18H, Adamantane), 1.76 (br, 12H, Adamantane), 1.72 (s, 6H, CH3), 1.66 (s, 6H, CH3), 19F-NMR (376 MHz, DMSO-d6): δ (ppm) = −111.4. | 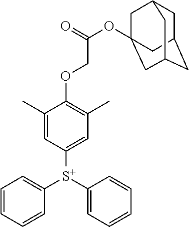 [SMILES: Cc1cc([S+](c2ccccc2)c2ccccc2)cc(C)c1OCC(=O)OC12CC3CC(CC(C3)C1)C2] | 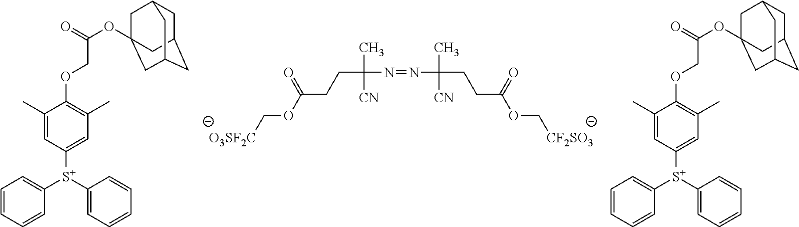 |
| I-AV | 1H-NMR (400 MHz, DMSO- d6): δ (ppm) = 7.77-7.89 (m, 20H, ArH), 7.64 (s, 4H, ArH), 5.70 (t, 2H, CH in GBL), 4.82 (s, 4H, OCH2), 4.61 (dt, 4H, CH2CF2), 4.46-4.30 (m, 4H, GBL), 2.71-2.64 (m, 2H, GBL), 2.40-2.65 (m, 8H, CH2CH2), 2.33-2.24 (m, 14H, ArCH3 + GBL), 1.72 (s, 6H, CH3), 1.66 (s, 6H, CH3), 19F-NMR (376 MHz, DMSO-d6): δ (ppm) = −111.4. | 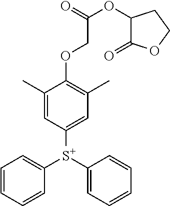 [SMILES: Cc1cc([S+](c2ccccc2)c2ccccc2)cc(C)c1OCC(=O)OC1CCOC1=O] | 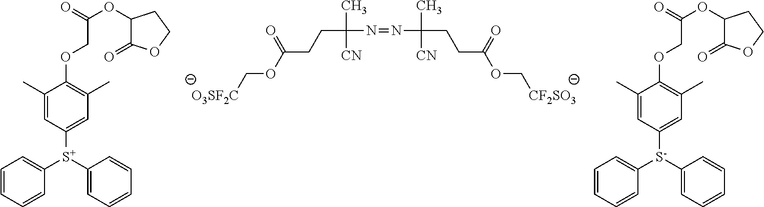 |
| I-AW | 1H-NMR (400 MHz, DMSO- d6): δ (ppm) = 8.28 (d, 4H, ArH), 8.11 (d, 2H, ArH), 7.86 (t, 2H, ArH), 7.63-7.81 (m, 14H, ArH), 4.61 (dt, 4H, CH2CF2), 2.40-2.65 (m, 8H, CH2CH2), 1.72 (s, 6H, CH3), 1.66 (s, 6H, CH3), 19F-NMR (376 MHz, DMSO-d6): δ (ppm) = −111.4. | 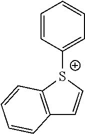 [SMILES: c1ccc(-[s+]2ccc3ccccc32)cc1] | 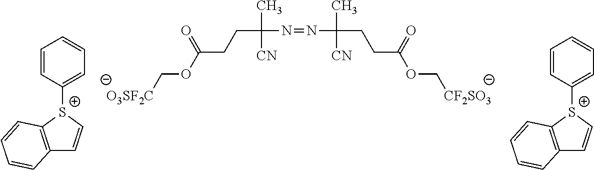 |

TABLE 17

| Com- | | | |
|---|---|---|---|
| pound | NMR | Cation | Product |
| I-AX | 1H-NMR (400 MHz, DMSO-d6): δ (ppm) = 8.05 (d, 4H, ArH), 7.74 (d, 4H, ArH), 4.61 (dt, 4H, CH2CF2), 3.85 (s, 6H, SCH3), 2.40- 2.65 (m, 8H, CH2CH2), 1.72 (s, 6H, CH3), 1.66 (s, 6H, CH3), 1.30 (s, 36H, t-Bu), 19F- NMR (376 MHz, DMSO-d6): δ (ppm) = −111.4. | 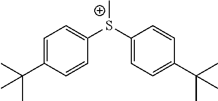 [SMILES: C[S+](c1ccc(C(C)(C)C)cc1)c1ccc(C(C)(C)C)cc1] | 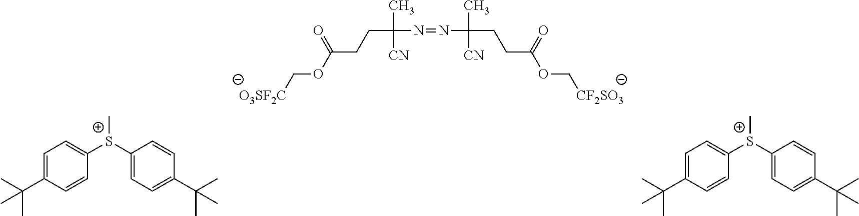 |
| I-AY | 1H-NMR (400 MHz, DMSO-d6): δ (ppm) = 8.41 (m, 4H, ArH), 8.12 (d, 2H, ArH), 7.73-7.93 (m, 4H, ArH), 7.19 (d, 2H, ArH), 5.23 (s, 4H, OCH2), 4.95 (m, 2H, Adamantane), 4.61 (dt, 4H, CH2CF2), 4.03 (m, 4H, CH2S), 3.75 (m, 4H, CH2S), 2.27-2.65 (m, 16H, CH2CH2 + SCH2CH2), 1.42-1.99 (m, 40H, CH3 + Adamantane), 19F-NMR (376 MHz, DMSO-d6): δ (ppm) = −111.4. | 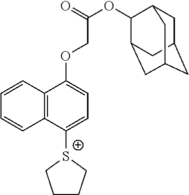 [SMILES: O=C(COc1ccc([S+]2CCCC2)c2ccccc12)OC1C2CC3CC(C2)CC1C3] | 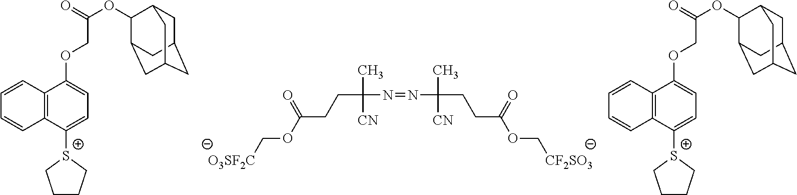 |
| I-AZ | 1H-NMR (400 MHz, DMSO-d6): δ (ppm) = 8.42 (m, 4H, ArH), 8.17 (d, 2H, ArH), 7.78-7.91 (m, 4H, ArH), 7.23 (d, 2H, ArH), 5.26 (s, 4H, CH2), 4.61 (dt, 4H, CH2CF2), 3.75-4.19 (m, 14H, SCH2 + OCH3), 2.29-2.65 (m, 16H, CH2CH2 + SCH2CH2), 1.72 (s, 6H, CH3), 1.66 (s, 6H, CH3), 19F-NMR (376 MHz, DMSO-d6): δ (ppm) = −111.4. | 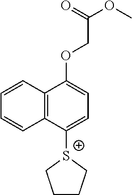 [SMILES: COC(=O)COc1ccc([S+]2CCCC2)c2ccccc12] | 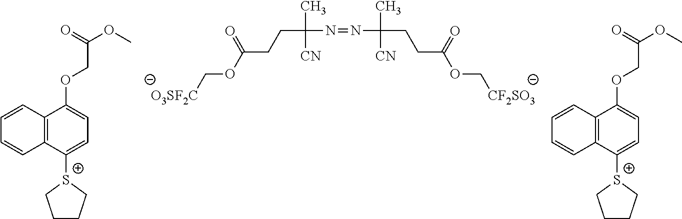 |

TABLE 18

| Compound | NMR | Cation | Product |
|---|---|---|---|
| I-BA | 1H-NMR (400 MHz, DMSO-d6): δ (ppm) = 8.28 (d, 4H, ArH), 8.12 (d, 2H, ArH), 7.88 (t, 2H, ArH), 7.80 (d, 2H, ArH), 7.62-7.74 (m, 10H, ArH), 4.61 (dt, 4H, CH2CF2), 2.40-2.65 (m, 8H, CH2CH2), 1.72 (s, 6H, CH3), 1.66 (s, 6H, CH3), 1.27 (s, 18H, t-Butyl), 19F-NMR (376 MHz, DMSO- d6): δ (ppm) = −111.4. | 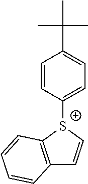 [SMILES: CC(C)(C)c1ccc(-[s+]2ccc3ccccc32)cc1] | 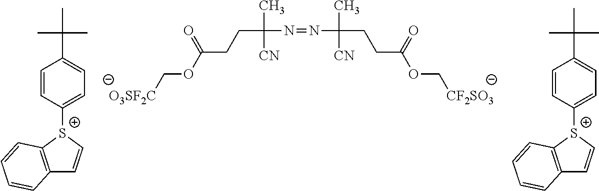 |
| I-BB | 1H-NMR (400 MHz, DMSO-d6): δ (ppm) = 7.76-7.90 (m, 24H, ArH), 4.61 (dt, 4H, CH2CF2), 2.40-2.69 (m, 10H, CH2CH2 + camphane), 2.08-2.26 (m, 16H, ArCH3 + camphane), 1.65-1.72 (m, 14H, CH3 + camphane), 1.19 (s, 6H, CH3 in camphane), 1.09 (s, 6H, CH3 in camphane), 1.04 (s, 6H, CH3 in amphane), 19F-NMR (376 MHz, DMSO-d6): δ (ppm) = −111.4. | 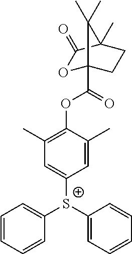 [SMILES: Cc1cc([S+](c2ccccc2)c2ccccc2)cc(C)c1OC(=O)C12CCC(C)(C(=O)O1)C2(C)C] | 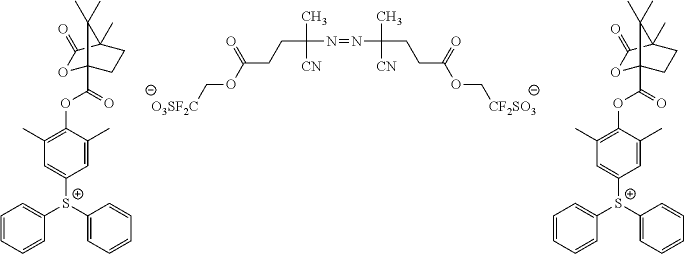 |

### Example 1A

### Synthesis of Polymeric Compound (1A)

In a flask equipped with a thermometer, a reflux tube, a stirrer, and a nitrogen inlet tube, 13.3 g of γ-butyrolactone was added under a nitrogen atmosphere, and the internal temperature was raised to 85° C. while stirring.

4.0 g (12.7 mmol) of the monomer (1A), 6.1 g (23.3 mmol) of the monomer (2A) and 1.5 g (6.5 mmol) of the monomer (3A) were dissolved in 80.6 g of γ-butyrolactone to obtain a solution. Then, 3.34 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer. Thereafter, the precipitated white powder was separated by filtration, followed by washing with a mixed solution of methanol and water and drying under reduced pressure, thereby obtaining 5.8 g of a polymeric compound (1A) as an objective compound.

With respect to the polymeric compound (1A), the weight average molecular weight (Mw) and the dispersity (Mw/Mn) were determined by the polystyrene equivalent value as measured by gel permeation chromatography (GPC). As a result, it was found that the weight average molecular weight was 7,500, and the dispersity was 1.71.

Further, as a result of an analysis by ¹³C-NMR, it was found that the composition of the copolymer (ratio (molar ratio) of the respective structural units within the structural formula) was l/m/n=40/40/20.

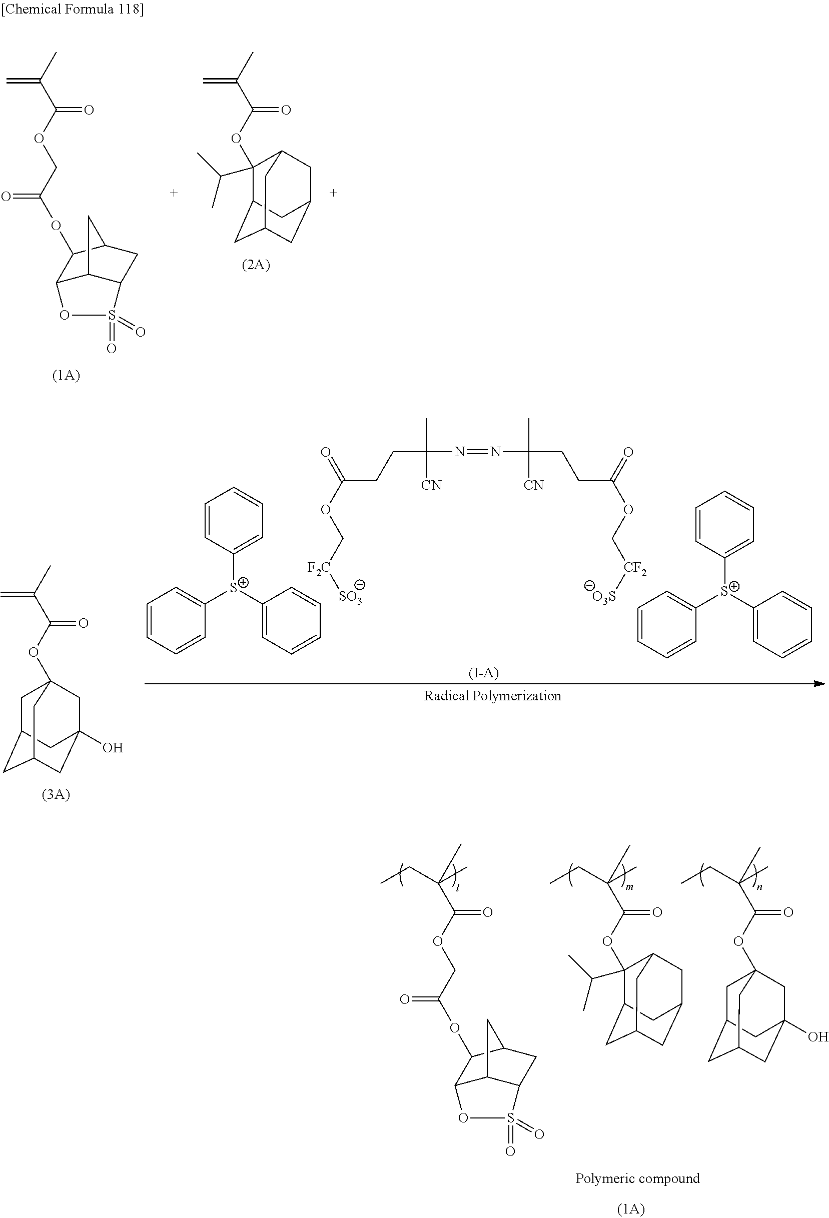

### Examples 2A to 14A

### Synthesis of Polymeric Compounds (2A) to (14A)

Polymeric compounds (2A) to (14A) were produced in the same manner as in Example 1A, except that the following monomers (1A) to (16A) which derive the structural units constituting each polymeric compound were used with a molar ratio indicated in Table 19.

The type of the used polymerization initiator and the weight average molecular weight (Mw) and the molecular weight distribution (Mw/Mn) of the obtained polymeric compounds (2A) to (14A) are shown in Table 19.

### Comparative Example 1A

### Synthesis of Polymeric Compound (15A)

In a flask equipped with a thermometer, a reflux tube, a stirrer, and a nitrogen inlet tube, 13.3 g of γ-butyrolactone was added under a nitrogen atmosphere, and the internal temperature was raised to 85° C. while stirring.

4.0 g (12.7 mmol) of the monomer (1A), 6.1 g (23.3 mmol) of the monomer (2A) and 1.5 g (6.5 mmol) of the monomer (3A) were dissolved in 80.6 g of γ-butyrolactone to obtain a solution. Then, 0.71 g of dimethyl 2,2′-azobis(isobutyrate) (product name: V-601, manufactured by Wako Pure Chemical Industries, Ltd.) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer. Thereafter, the precipitated white powder was separated by filtration, followed by washing with a mixed solution of methanol and water and drying under reduced pressure, thereby obtaining 8.1 g of a polymeric compound (15A) as an objective compound.

With respect to the polymeric compound (15A), the weight average molecular weight (Mw) and the dispersity (Mw/Mn) were determined by the polystyrene equivalent value as measured by gel permeation chromatography (GPC). As a result, it was found that the weight average molecular weight was 6,900, and the dispersity was 1.73.

Further, as a result of an analysis by ¹³C-NMR, it was found that the composition of the copolymer (ratio (molar ratio) of the respective structural units within the structural formula) was l/m/n=40/40/20.

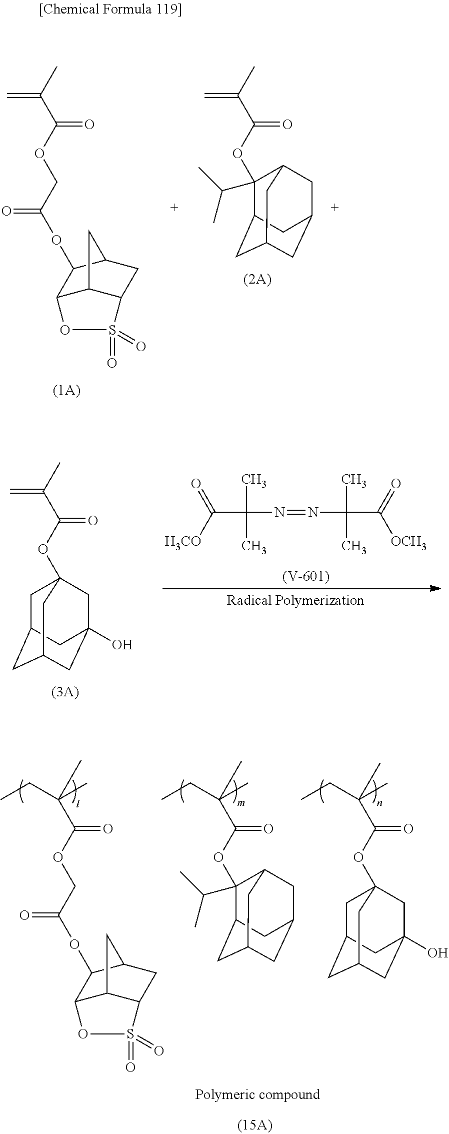

### Comparative Examples 2A to 17A

### Synthesis of Polymeric Compounds (16A) to (28A)

Polymeric compounds (16A) to (28A) were produced in the same manner as in Comparative Example 1A, except that the following monomers (1A) to (16A) which derive the structural units constituting each polymeric compound were used with a molar ratio indicated in Table 20.

The type of the used polymerization initiator and the weight average molecular weight (Mw) and the molecular weight distribution (Mw/Mn) of the obtained polymeric compounds (16A) to (28A) are shown in Table 20.

### Comparative Example 18A

### Synthesis of Polymeric Compound (29A)

Polymeric compound (29A) was produced in the same manner as in Example 1A, except that the following monomers (1A) and (2A) which derive the structural units constituting the polymeric compound were used with a molar ratio indicated in Table 20.

The type of the used polymerization initiator and the weight average molecular weight (Mw) and the molecular weight distribution (Mw/Mn) of the obtained polymeric compound (29A) are shown in Table 20.

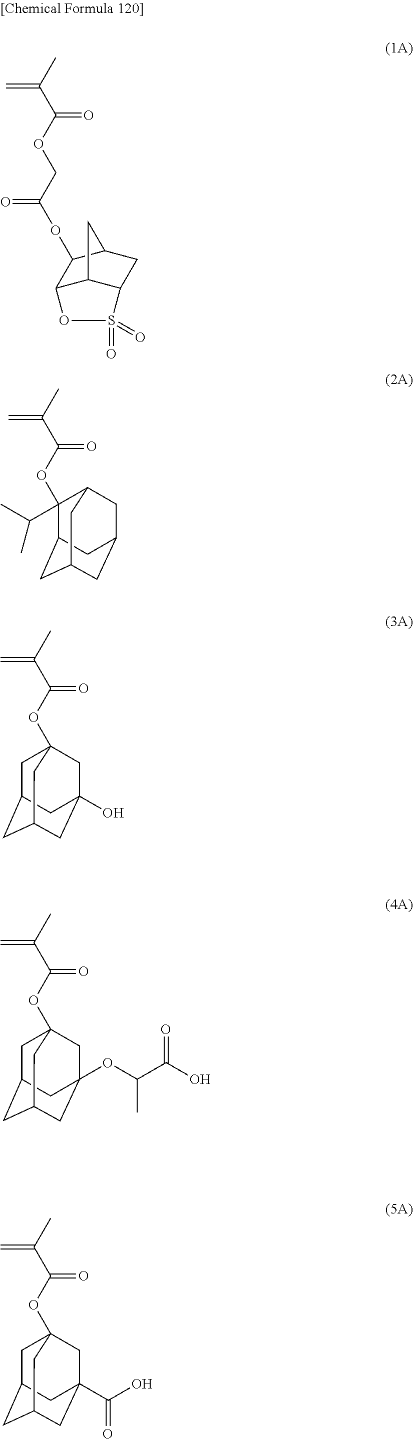 [SMILES: C=C(C)C(=O)OCC(=O)OC1C2CC3C1OS(=O)(=O)C3C2 ; C=C(C)C(=O)OC1(C(C)C)C2CC3CC(C2)CC1C3 ; C=C(C)C(=O)OC12CC3CC(CC(O)(C3)C1)C2 ; C=C(C)C(=O)OC12CC3CC(C1)CC(OC(C)C(=O)O)(C3)C2 ; C=C(C)C(=O)OC12CC3CC(C1)CC(C(=O)O)(C3)C2]

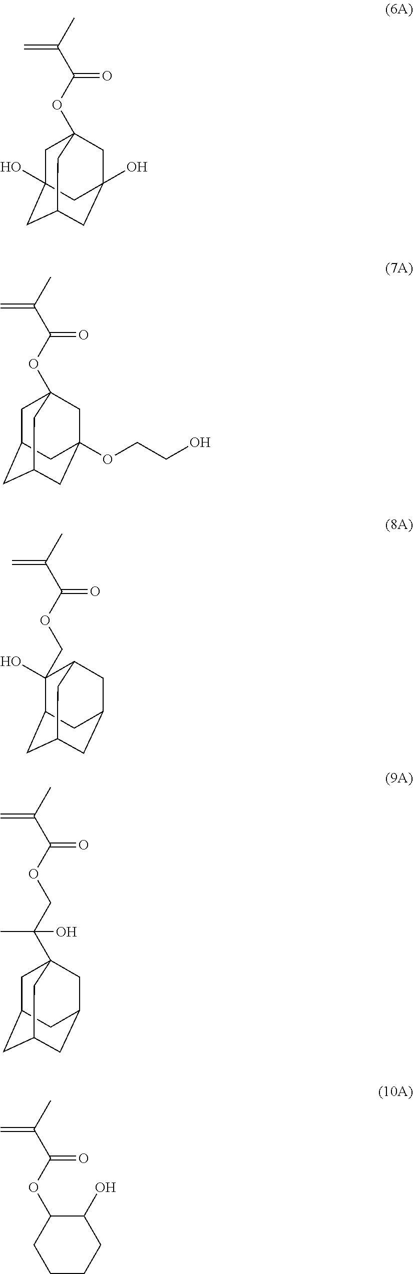

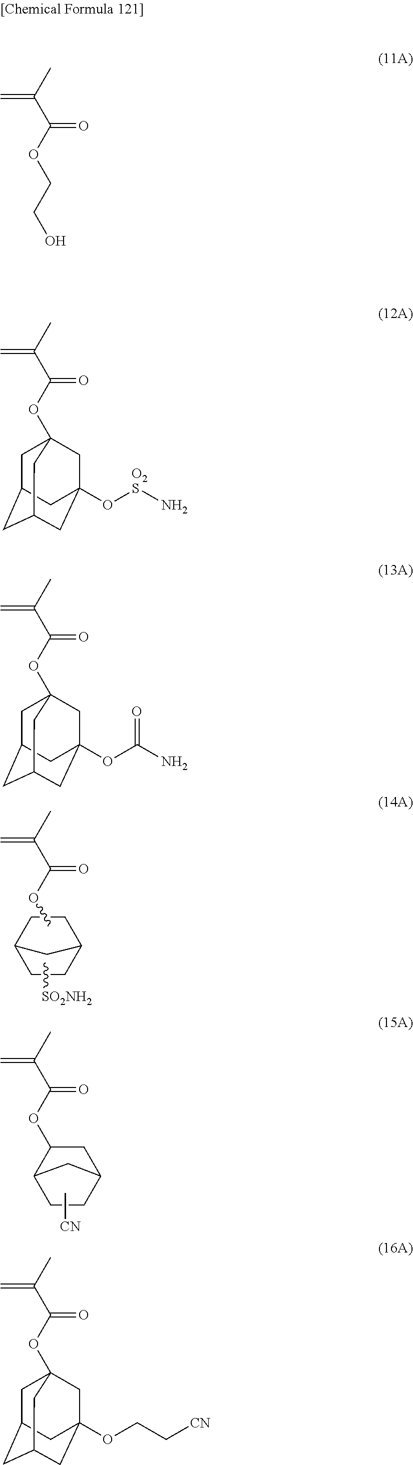

TABLE 19

| | | Polymeric compound | | | | | | | | | | | | | |
|---|---|---|---|---|---|---|---|---|---|---|---|---|---|---|---|
| | | (1A) | (2A) | (3A) | (4A) | (5A) | (6A) | (7A) | (8A) | (9A) | (10A) | (11A) | (12A) | (13A) | (14A) |
| Mono- | (1A) | 40 | 40 | 40 | 40 | 40 | 40 | 40 | 40 | 40 | 40 | 40 | 40 | 40 | 40 |
| mer | (2A) | 40 | 40 | 40 | 40 | 40 | 40 | 40 | 40 | 40 | 40 | 40 | 40 | 40 | 40 |
| | (3A) | 20 | | | | | | | | | | | | | |
| | (4A) | | 20 | | | | | | | | | | | | |
| | (5A) | | | 20 | | | | | | | | | | | |
| | (6A) | | | | 20 | | | | | | | | | | |
| | (7A) | | | | | 20 | | | | | | | | | |
| | (8A) | | | | | | 20 | | | | | | | | |
| | (9A) | | | | | | | 20 | | | | | | | |
| | (10A) | | | | | | | | 20 | | | | | | |
| | (11A) | | | | | | | | | 20 | | | | | |
| | (12A) | | | | | | | | | | 20 | | | | |
| | (13A) | | | | | | | | | | | 20 | | | |
| | (14A) | | | | | | | | | | | | 20 | | |
| | (15A) | | | | | | | | | | | | | 20 | |
| | (16A) | | | | | | | | | | | | | | 20 |

| | | | | | | | | | | | | | | |
|---|---|---|---|---|---|---|---|---|---|---|---|---|---|---|
| Polymerization | I-A | I-A | I-A | I-A | I-A | I-A | I-A | I-A | I-A | I-A | I-A | I-A | I-A | I-A |
| initiator | | | | | | | | | | | | | | |
| Mw | 7500 | 6800 | 7200 | 7300 | 7100 | 6900 | 6600 | 7000 | 6800 | 7500 | 7100 | 7300 | 7100 | 7300 |
| Mw/Mn | 1.71 | 1.66 | 1.82 | 1.79 | 1.73 | 1.80 | 1.82 | 1.79 | 1.68 | 1.74 | 1.66 | 1.73 | 1.94 | 1.73 |

TABLE 20

| | | Polymeric compound | | | | | | | |
|---|---|---|---|---|---|---|---|---|---|
| | | (15A) | (16A) | (17A) | (18A) | (19A) | (20A) | (21A) | (22A) |
| Monomer | (1A) | 40 | 40 | 40 | 40 | 40 | 40 | 40 | 40 |
| | (2A) | 40 | 40 | 40 | 40 | 40 | 40 | 40 | 40 |
| | (3A) | 20 | | | | | | | |
| | (4A) | | 20 | | | | | | |
| | (5A) | | | 20 | | | | | |
| | (6A) | | | | 20 | | | | |
| | (7A) | | | | | 20 | | | |
| | (8A) | | | | | | 20 | | |
| | (9A) | | | | | | | 20 | |
| | (10A) | | | | | | | | 20 |
| | (11A) | | | | | | | | |
| | (12A) | | | | | | | | |
| | (13A) | | | | | | | | |
| | (14A) | | | | | | | | |
| | (15A) | | | | | | | | |
| | (16A) | | | | | | | | |

| Polymerization | | V-601 | V-601 | V-601 | V-601 | V-601 | V-601 | V-601 | V-601 |
|---|---|---|---|---|---|---|---|---|---|
| initiator | | | | | | | | | |
| Mw | | 6900 | 7100 | 6900 | 6600 | 6800 | 7500 | 7700 | 6900 |
| Mw/Mn | | 1.73 | 1.70 | 1.68 | 1.73 | 1.68 | 1.66 | 1.64 | 1.66 |
| | | | Polymeric compound | | | | | | |
| | | | (23A) | (24A) | (25A) | (26A) | (27A) | (28A) | (29A) |
| | Monomer | (1A) | 40 | 40 | 40 | 40 | 40 | 40 | 52 |
| | | (2A) | 40 | 40 | 40 | 40 | 40 | 40 | 48 |
| | | (3A) | | | | | | | |
| | | (4A) | | | | | | | |
| | | (5A) | | | | | | | |
| | | (6A) | | | | | | | |
| | | (7A) | | | | | | | |
| | | (8A) | | | | | | | |
| | | (9A) | | | | | | | |
| | | (10A) | | | | | | | |
| | | (11A) | 20 | | | | | | |
| | | (12A) | | 20 | | | | | |
| | | (13A) | | | 20 | | | | |
| | | (14A) | | | | 20 | | | |
| | | (15A) | | | | | 20 | | |
| | | (16A) | | | | | | 20 | |

| | | | | | | | |
|---|---|---|---|---|---|---|---|
| Polymerization | V-601 | V-601 | V-601 | V-601 | V-601 | V-601 | I-A |
| initiator | | | | | | | |
| Mw | 7000 | 6900 | 6600 | 7300 | 7100 | 6900 | 7400 |
| Mw/Mn | 1.68 | 1.68 | 1.73 | 1.66 | 1.82 | 1.79 | 1.77 |

### Example 1B

### Synthesis of Polymeric Compound (1B)

In a flask equipped with a thermometer, a reflux tube, a stirrer, and a nitrogen inlet tube, 13.2 g of γ-butyrolactone was added under a nitrogen atmosphere, and the internal temperature was raised to 85° C. while stirring.

5.0 g (15.8 mmol) of the monomer (1B), 4.6 g (19.5 mmol) of the monomer (2B) and 1.9 g (8.2 mmol) of the monomer (3B) were dissolved in 79.6 g of γ-butyrolactone to obtain a solution. Then, 3.43 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer.

Thereafter, the precipitated white powder was separated by filtration, followed by washing with a mixed solution of methanol and water and drying under reduced pressure, thereby obtaining 5.7 g of a polymeric compound (1B) as an objective compound.

With respect to the polymeric compound (1B), the weight average molecular weight (Mw) and the dispersity (Mw/Mn) were determined by the polystyrene equivalent value as measured by gel permeation chromatography (GPC). As a result, it was found that the weight average molecular weight was 7,500, and the dispersity was 1.71.

Further, as a result of an analysis by ¹³C-NMR, it was found that the composition of the copolymer (ratio (molar ratio) of the respective structural units within the structural formula) was l/m/n=40/40/20.

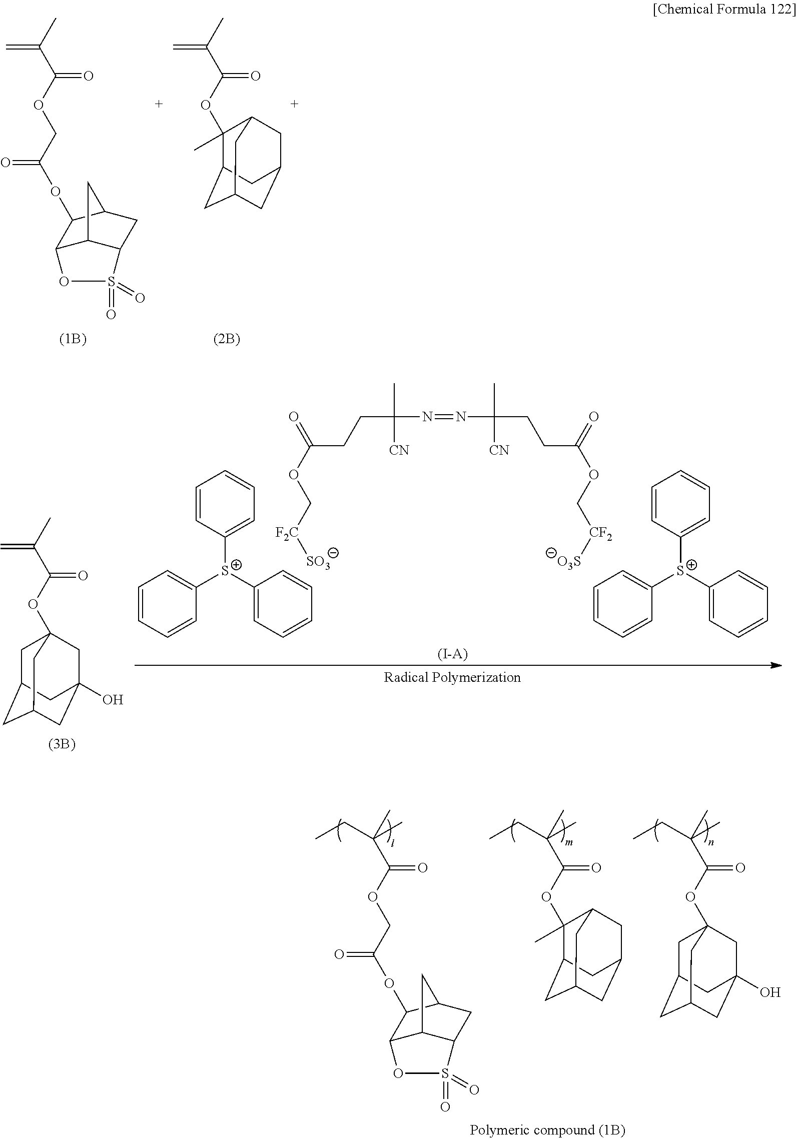

### Examples 2B to 21B

### Synthesis of Polymeric Compounds (2B) to (21B)

Polymeric compounds (2B) to (21B) were produced in the same manner as in Example 1B, except that the following monomers (1B) to (20B) which derive the structural units constituting each polymeric compound were used with a molar ratio indicated in Table 21.

The type of the used polymerization initiator and the weight average molecular weight (Mw) and the molecular weight distribution (Mw/Mn) of the obtained polymeric compounds (2B) to (21B) are shown in Table 21.

### Comparative Example 1B

### Synthesis of Polymeric Compound (22B)

In a flask equipped with a thermometer, a reflux tube, a stirrer, and a nitrogen inlet tube, 13.2 g of γ-butyrolactone was added under a nitrogen atmosphere, and the internal temperature was raised to 85° C. while stirring.

5.0 g (15.8 mmol) of the monomer (1B), 4.6 g (19.5 mmol) of the monomer (2B) and 1.9 g (8.2 mmol) of the monomer (3B) were dissolved in 79.6 g of γ-butyrolactone to obtain a solution. Then, 0.72 g of dimethyl 2,2′-azobis(isobutyrate) (product name: V-601, manufactured by Wako Pure Chemical Industries, Ltd.) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer.

Thereafter, the precipitated white powder was separated by filtration, followed by washing with a mixed solution of methanol and water and drying under reduced pressure, thereby obtaining 8.1 g of a polymeric compound (22B) as an objective compound.

With respect to the polymeric compound (22B), the weight average molecular weight (Mw) and the dispersity (Mw/Mn) were determined by the polystyrene equivalent value as measured by gel permeation chromatography (GPC). As a result, it was found that the weight average molecular weight was 6,900, and the dispersity was 1.73.

Further, as a result of an analysis by ¹³C-NMR, it was found that the composition of the copolymer (ratio (molar ratio) of the respective structural units within the structural formula) was l/m/n=40/40/20.

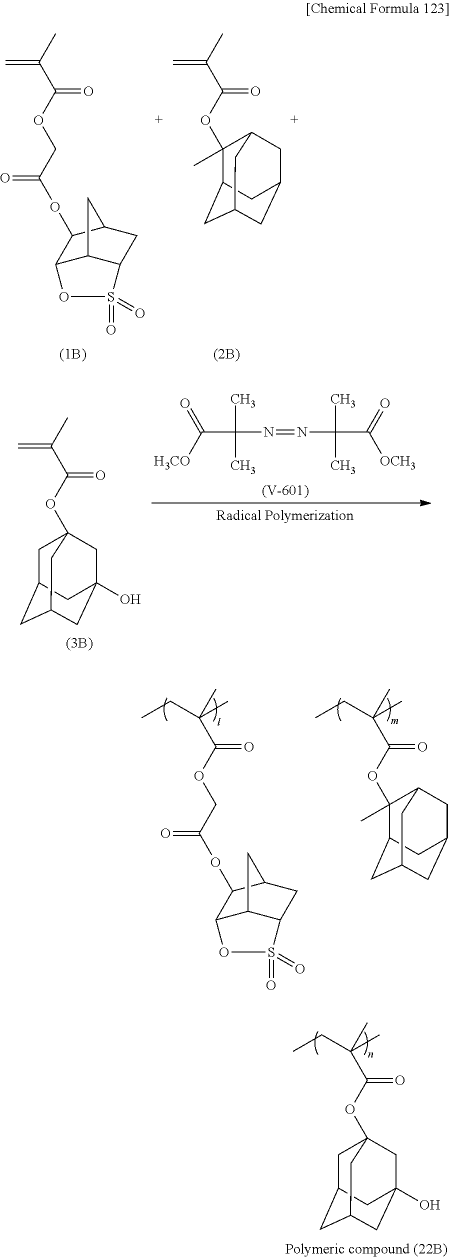

### Comparative Examples 2B to 21B

### Synthesis of polymeric compounds (23B) to (42B)

Polymeric compounds (23B) to (42B) were produced in the same manner as in Comparative Example 1B, except that the following monomers (1B) to (20B) which derive the structural units constituting each polymeric compound were used with a molar ratio indicated in Table 22.

The type of the used polymerization initiator and the weight average molecular weight (Mw) and the molecular weight distribution (Mw/Mn) of the obtained polymeric compounds (13B) to (42B) are shown in Table 22.

### Comparative Example 22B

### Synthesis of polymeric compound (43B)

Polymeric compound (43B) was produced in the same manner as in Example 1B, except that the following monomers (7B), (2B) and (3B) which derive the structural units constituting the polymeric compound were used with a molar ratio indicated in Table 22.

The type of the used polymerization initiator and the weight average molecular weight (Mw) and the molecular weight distribution (Mw/Mn) of the obtained polymeric compound (43B) are shown in Table 22.

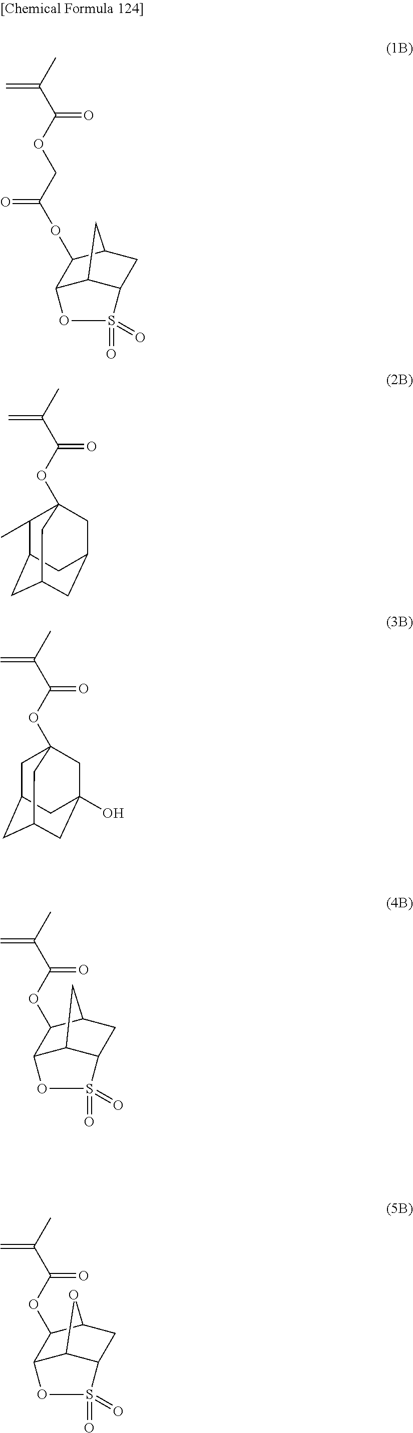

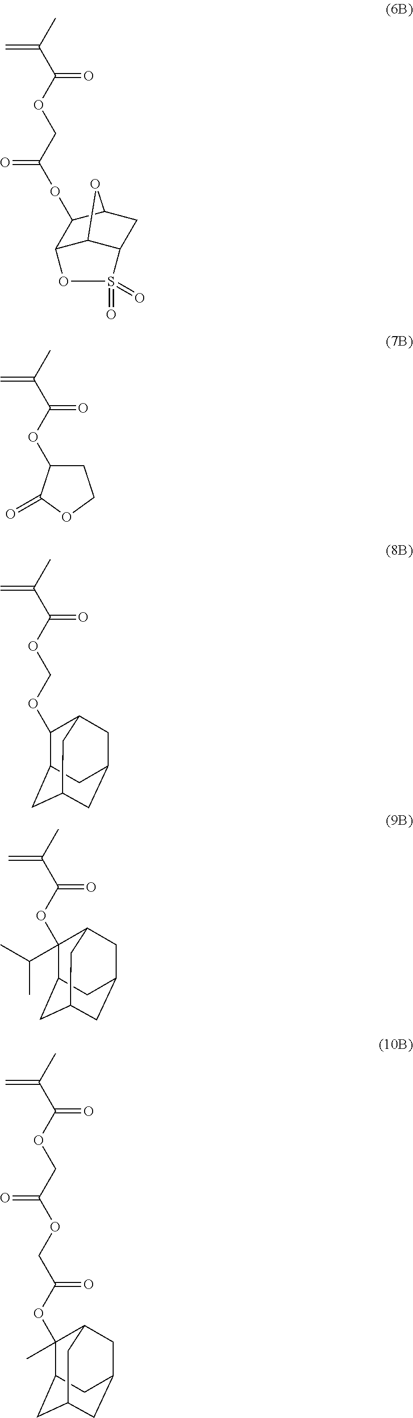

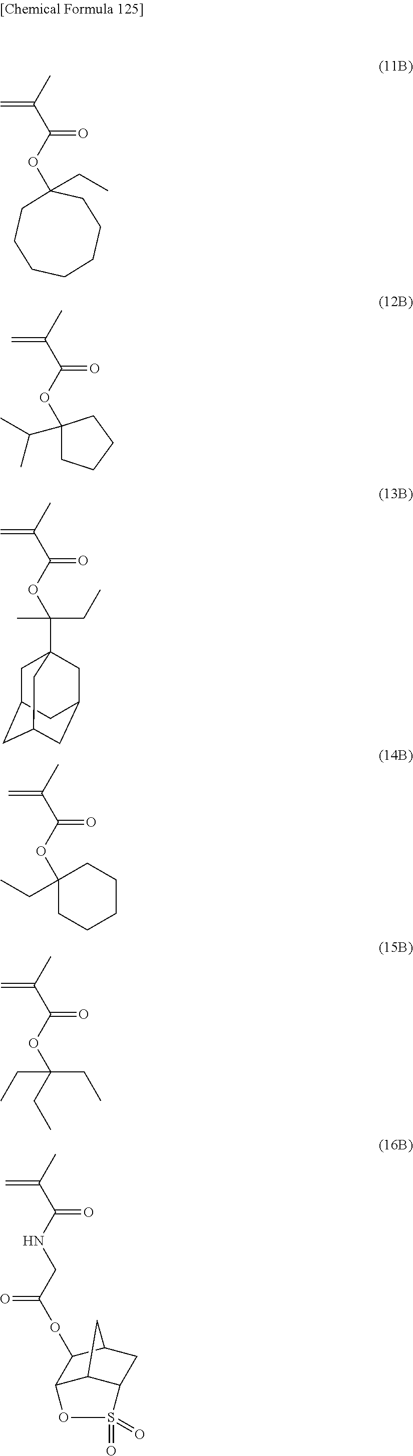

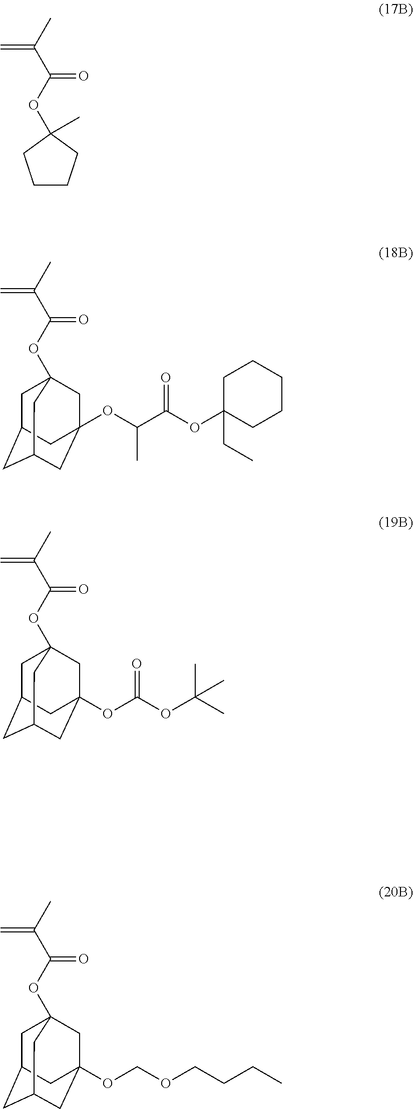

TABLE 21

| | | Polymeric compound | | | | | | | | | | |
|---|---|---|---|---|---|---|---|---|---|---|---|---|
| | | (1B) | (2B) | (3B) | (4B) | (5B) | (6B) | (78) | (8B) | (9B) | (10B) | (11B) |
| Monomer | (1B) | 40 | 40 | 40 | 40 | 40 | 40 | 40 | 40 | 40 | 40 | |
| | (2B) | 40 | | | | | | | | | | |
| | (3B) | 20 | 20 | 20 | 20 | 20 | 20 | 20 | 20 | 20 | 20 | 20 |
| | (4B) | | | | | | | | | | | 40 |
| | (5B) | | | | | | | | | | | |
| | (6B) | | | | | | | | | | | |
| | (7B) | | | | | | | | | | | |
| | (8B) | | 40 | | | | | | | | 20 | 40 |
| | (9B) | | | 40 | | | | | | | | |
| | (10B) | | | | 40 | | | | | | | |
| | (11B) | | | | | 40 | | | | | | |
| | (12B) | | | | | | 40 | | | | 20 | |
| | (13B) | | | | | | | 40 | | | | |
| | (14B) | | | | | | | | 40 | | | |
| | (15B) | | | | | | | | | 40 | | |
| | (16B) | | | | | | | | | | | |
| | (17B) | | | | | | | | | | | |
| | (18B) | | | | | | | | | | | |
| | (19B) | | | | | | | | | | | |
| | (20B) | | | | | | | | | | | |

| | | | | | | | | | | | |
|---|---|---|---|---|---|---|---|---|---|---|---|
| Polymerization | I-A | I-A | I-A | I-A | I-A | I-A | I-A | I-A | I-A | I-A | I-A |
| initiator | | | | | | | | | | | |
| Mw | 7500 | 7700 | 6900 | 7000 | 6800 | 7200 | 7300 | 7100 | 6900 | 6600 | 7000 |
| Mw/Mn | 1.71 | 1.70 | 1.68 | 1.73 | 1.66 | 1.82 | 1.79 | 1.73 | 1.80 | 1.82 | 1.79 |

| | | Polymeric compound | | | | | | | | | |
|---|---|---|---|---|---|---|---|---|---|---|---|
| | | (12B) | (13B) | (14B) | (15B) | (16B) | (17B) | (18B) | (19B) | (20B) | (21B) |
| Monomer | (1B) | | | | 40 | 24 | | | 40 | 40 | 40 |
| | (2B) | | | | | | | | | | |
| | (3B) | 20 | 20 | | 20 | 12 | 12 | 12 | | | |
| | (4B) | | | | | | | | | | |
| | (5B) | 40 | | | | | | | | | |
| | (6B) | | 40 | 52 | | | 24 | | | | |
| | (7B) | | | | | 35 | 35 | 35 | | | |
| | (8B) | 40 | 40 | | 20 | | | | | | |
| | (9B) | | | | 20 | 16 | 16 | 16 | 40 | 40 | 40 |
| | (10B) | | | | | | | | | | |
| | (11B) | | | | | | | | | | |
| | (12B) | | | | | | | | | | |
| | (13B) | | | | | | | | | | |
| | (14B) | | | 48 | | | | | | | |
| | (15B) | | | | | | | | | | |
| | (16B) | | | | | | | 24 | | | |
| | (17B) | | | | | 13 | 13 | 13 | | | |
| | (18B) | | | | | | | | 20 | | |
| | (19B) | | | | | | | | | 20 | |
| | (20B) | | | | | | | | | | 20 |

| | | | | | | | | | | |
|---|---|---|---|---|---|---|---|---|---|---|
| Polymerization | I-A | I-A | I-A | I-A | I-A | I-A | I-A | I-A | I-A | I-A |
| initiator | | | | | | | | | | |
| Mw | 6800 | 7500 | 7100 | 7300 | 7100 | 7300 | 7700 | 7700 | 6900 | 7000 |
| Mw/Mn | 1.68 | 1.74 | 1.66 | 1.73 | 1.94 | 1.73 | 1.75 | 1.70 | 1.68 | 1.73 |

TABLE 22

| | | Polymeric compound | | | | | | | | | | |
|---|---|---|---|---|---|---|---|---|---|---|---|---|
| | | (22B) | (23B) | (24B) | (25B) | (26B) | (27B) | (28B) | (29B) | (30B) | (31B) | (32B) |
| Monomer | (1B) | 40 | 40 | 40 | 40 | 40 | 40 | 40 | 40 | 40 | 40 | |
| | (2B) | 40 | | | | | | | | | | |
| | (3B) | 20 | 20 | 20 | 20 | 20 | 20 | 20 | 20 | 20 | 20 | 20 |
| | (4B) | | | | | | | | | | | 40 |
| | (5B) | | | | | | | | | | | |
| | (6B) | | | | | | | | | | | |
| | (7B) | | | | | | | | | | | |
| | (8B) | | 40 | | | | | | | | 20 | 40 |
| | (9B) | | | 40 | | | | | | | | |
| | (10B) | | | | 40 | | | | | | | |
| | (11B) | | | | | 40 | | | | | | |
| | (12B) | | | | | | 40 | | | | 20 | |
| | (13B) | | | | | | | 40 | | | | |
| | (14B) | | | | | | | | 40 | | | |
| | (15B) | | | | | | | | | 40 | | |
| | (16B) | | | | | | | | | | | |
| | (17B) | | | | | | | | | | | |
| | (18B) | | | | | | | | | | | |
| | (19B) | | | | | | | | | | | |
| | (20B) | | | | | | | | | | | |
| Polymerization | | V-601 | V-601 | V-601 | V-601 | V-601 | V-601 | V-601 | V-601 | V-601 | V-601 | V-601 |
| initiator | | | | | | | | | | | | |
| Mw | | 6900 | 6600 | 7000 | 6800 | 7100 | 6900 | 6600 | 6800 | 7500 | 7700 | 6900 |
| Mw/Mn | | 1.73 | 1.66 | 1.82 | 1.79 | 1.70 | 1.68 | 1.73 | 1.68 | 1.66 | 1.64 | 1.66 |
| | | Polymeric compound | | | | | | | | | | |
| | | (33B) | (34B) | (35B) | (36B) | (37B) | (38B) | (39B) | (40B) | (41B) | (42B) | (43B) |
| Monomer | (1B) | | | | 40 | 24 | | | 40 | 40 | 40 | |
| | (2B) | | | | | | | | | | | 40 |
| | (3B) | 20 | 20 | | 20 | 12 | 12 | 12 | | | | 20 |
| | (4B) | | | | | | | | | | | |
| | (5B) | 40 | | | | | | | | | | |
| | (6B) | | 40 | 52 | | | 24 | | | | | |
| | (7B) | | | | | 35 | 35 | 35 | | | | 40 |
| | (8B) | 40 | 40 | | 20 | | | | | | | |
| | (9B) | | | | 20 | 16 | 16 | 16 | 40 | 40 | 40 | |
| | (10B) | | | | | | | | | | | |
| | (11B) | | | | | | | | | | | |
| | (12B) | | | | | | | | | | | |
| | (13B) | | | | | | | | | | | |
| | (14B) | | | 48 | | | | | | | | |
| | (15B) | | | | | | | | | | | |
| | (16B) | | | | | | | 24 | | | | |
| | (17B) | | | | | 13 | 13 | 13 | | | | |
| | (18B) | | | | | | | | 20 | | | |
| | (19B) | | | | | | | | | 20 | | |
| | (20B) | | | | | | | | | | 20 | |

| | | | | | | | | | | | |
|---|---|---|---|---|---|---|---|---|---|---|---|
| Polymerization | V-601 | V-601 | V-601 | V-601 | V-601 | V-601 | V-601 | V-601 | V-601 | V-601 | I-A |
| initiator | | | | | | | | | | | |
| Mw | 7000 | 6900 | 6600 | 7300 | 7100 | 6900 | 7700 | 6600 | 7000 | 6800 | 7400 |
| Mw/Mn | 1.68 | 1.68 | 1.73 | 1.66 | 1.82 | 1.79 | 1.75 | 1.66 | 1.82 | 1.79 | 1.77 |

### Example 1C

### Synthesis of polymeric compound (1C)

In a flask equipped with a thermometer, a reflux tube, a stirrer, and a nitrogen inlet tube, 15.5 g of γ-butyrolactone was added under a nitrogen atmosphere, and the internal temperature was raised to 85° C. while stirring.

4.0 g (12.7 mmol) of the monomer (1C), 5.6 g (21.2 mmol) of the monomer (2C), 1.7 g (7.4 mmol) of the monomer (3C) and 2.2 g (4.5 mmol) of the monomer (4C) were dissolved in 93.5 g of γ-butyrolactone to obtain a solution.

Then, 3.60 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer.

Thereafter, the precipitated white powder was separated by filtration, followed by washing with a mixed solution of methanol and water and drying under reduced pressure, thereby obtaining 6.8 g of a polymeric compound (1C) as an objective compound.

With respect to the polymeric compound (1C), the weight average molecular weight (Mw) and the dispersity (Mw/Mn) were determined by the polystyrene equivalent value as measured by gel permeation chromatography (GPC). As a result, it was found that the weight average molecular weight was 12,500, and the dispersity was 1.71.

Further, as a result of an analysis by ¹³C-NMR, it was found that the composition of the copolymer (ratio (molar ratio) of the respective structural units within the structural formula) was l/m/n/o=35/35/18/12.

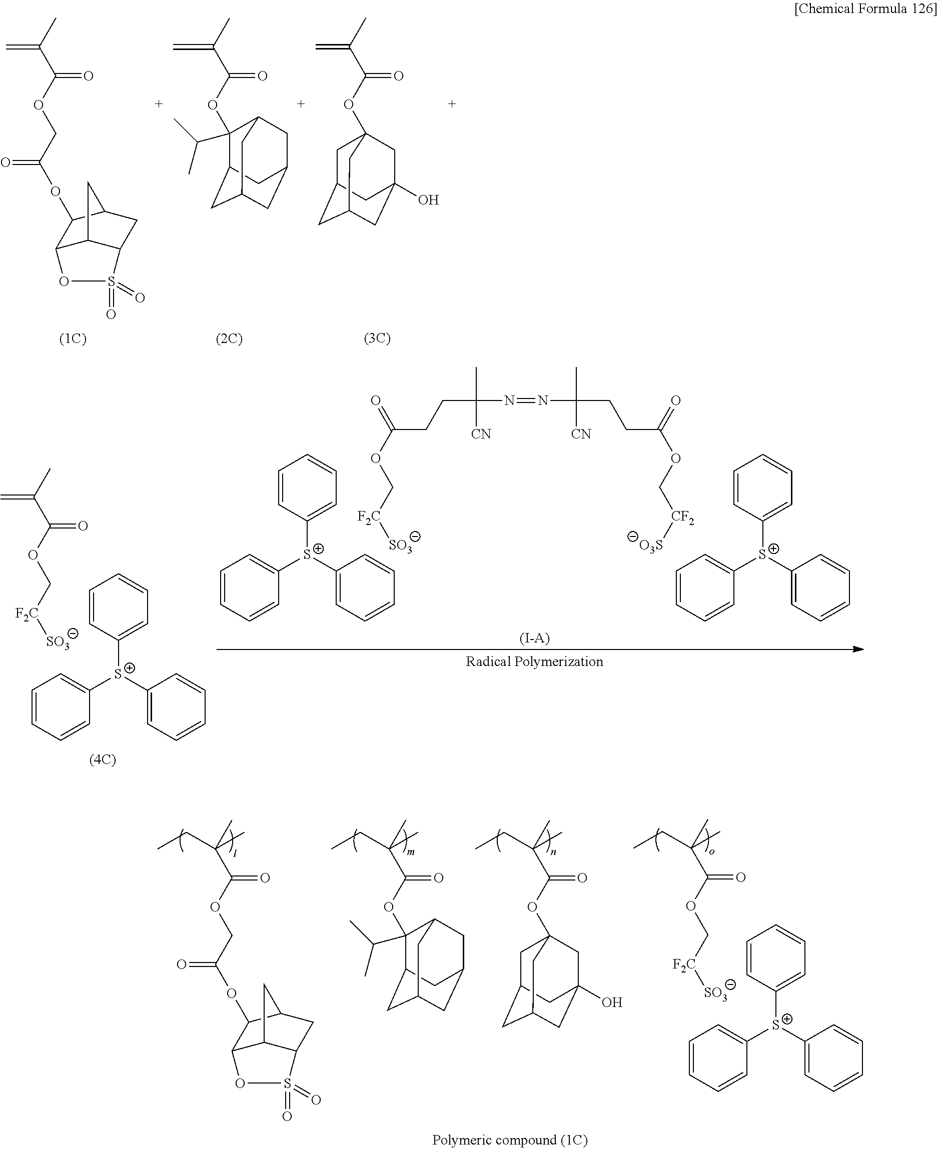

### Examples 2C to 9C

### Synthesis of Polymeric Compounds (2C) to (9C)

Polymeric compounds (2C) to (9C) were produced in the same manner as in Example 1C, except that the following monomers (1C) to (11C) which derive the structural units constituting each polymeric compound were used with a molar ratio indicated in Table 23.

The weight average molecular weight (Mw) and the molecular weight distribution (Mw/Mn) of the obtained polymeric compounds (2C) to (9C) are shown in Table 23.

### Comparative Example 1C

### Synthesis of polymeric compound (10C)

In a flask equipped with a thermometer, a reflux tube, a stirrer, and a nitrogen inlet tube, 15.5 g of γ-butyrolactone was added under a nitrogen atmosphere, and the internal temperature was raised to 85° C. while stirring.

4.0 g (12.7 mmol) of the monomer (1C), 5.6 g (21.2 mmol) of the monomer (2C), 1.7 g (7.4 mmol) of the monomer (3C) and 2.2 g (4.5 mmol) of the monomer (4C) were dissolved in 93.5 g of γ-butyrolactone to obtain a solution.

Then, 0.76 g of dimethyl 2,2′-azobis(isobutyrate) (product name: V-601, manufactured by Wako Pure Chemical Industries, Ltd.) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water, and to precipitate a polymer.

Thereafter, the precipitated white powder was separated by filtration, followed by washing with a mixed solution of methanol and water and drying under reduced pressure, thereby obtaining 9.5 g of a polymeric compound (10C) as an objective compound.

With respect to the polymeric compound (10C), the weight average molecular weight (Mw) and the dispersity (Mw/Mn) were determined by the polystyrene equivalent value as measured by gel permeation chromatography (GPC). As a result, it was found that the weight average molecular weight was 11,900, and the dispersity was 1.73.

Further, as a result of an analysis by ¹³C-NMR, it was found that the composition of the copolymer (ratio (molar ratio) of the respective structural units within the structural formula) was l/m/n/o=35/35/18/12.

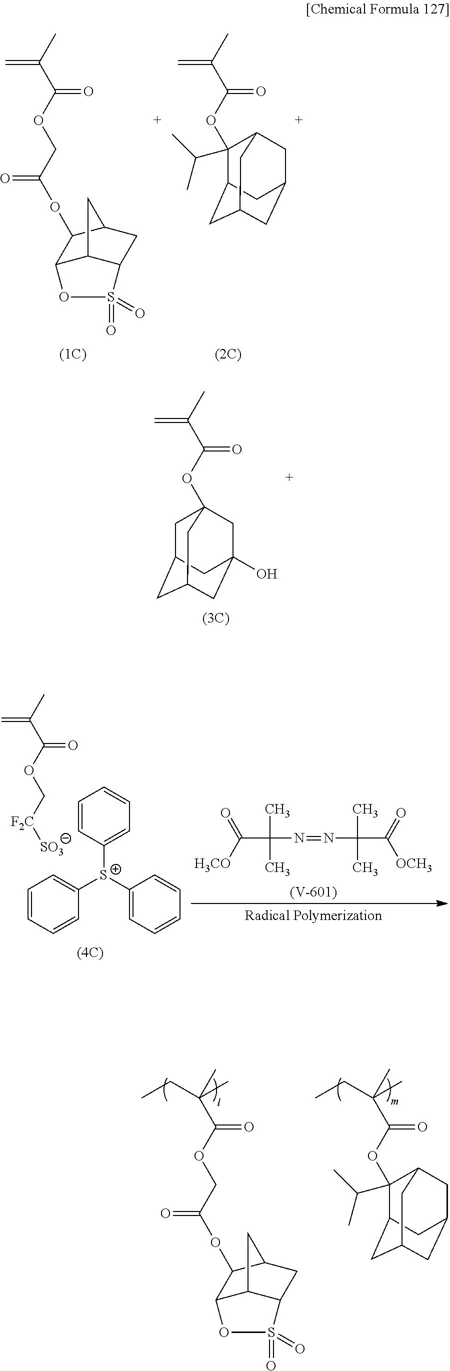

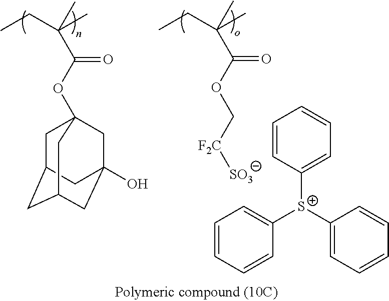

### Comparative Examples 2C to 9C

### Synthesis of polymeric compounds (11C) to (18C)

Polymeric compounds (11C) to (18C) were produced in the same manner as in Comparative Example 1C, except that the following monomers (1C) to (11C) which derive the structural units constituting each polymeric compound were used with a molar ratio indicated in Table 24.

The weight average molecular weight (Mw) and the molecular weight distribution (Mw/Mn) of the obtained polymeric compounds (11C) to (18C) are shown in Table 24.

### Comparative Example 10C

### Synthesis of polymeric compound (19C)

Polymeric compound (19C) were produced in the same manner as in Example 1C, except that the following monomers (1C) to (3C) which derive the structural units constituting the polymeric compound were used with a molar ratio indicated in Table 24.

The weight average molecular weight (Mw) and the molecular weight distribution (Mw/Mn) of the obtained polymeric compound (19C) are shown in Table 24.

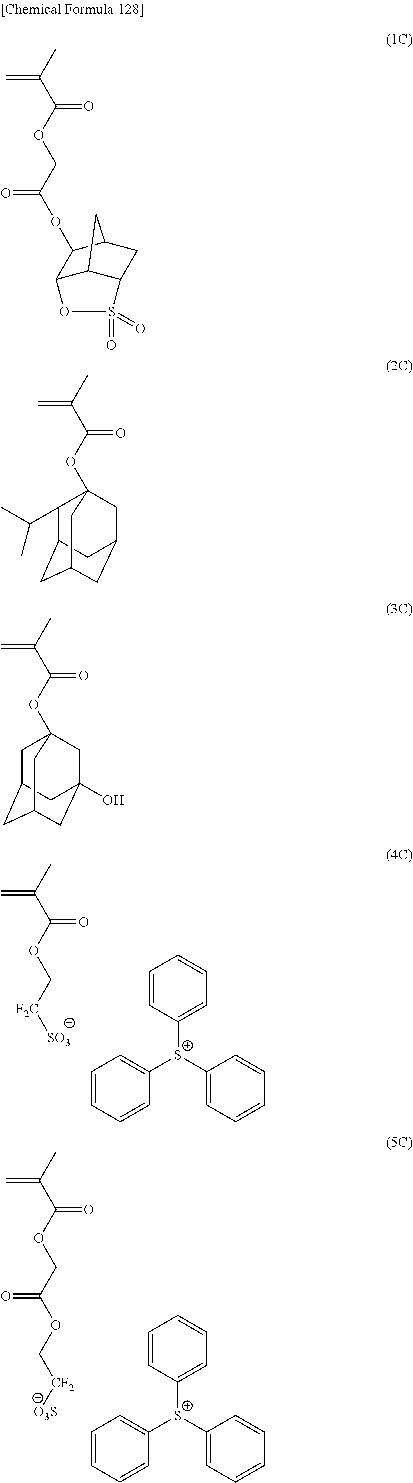

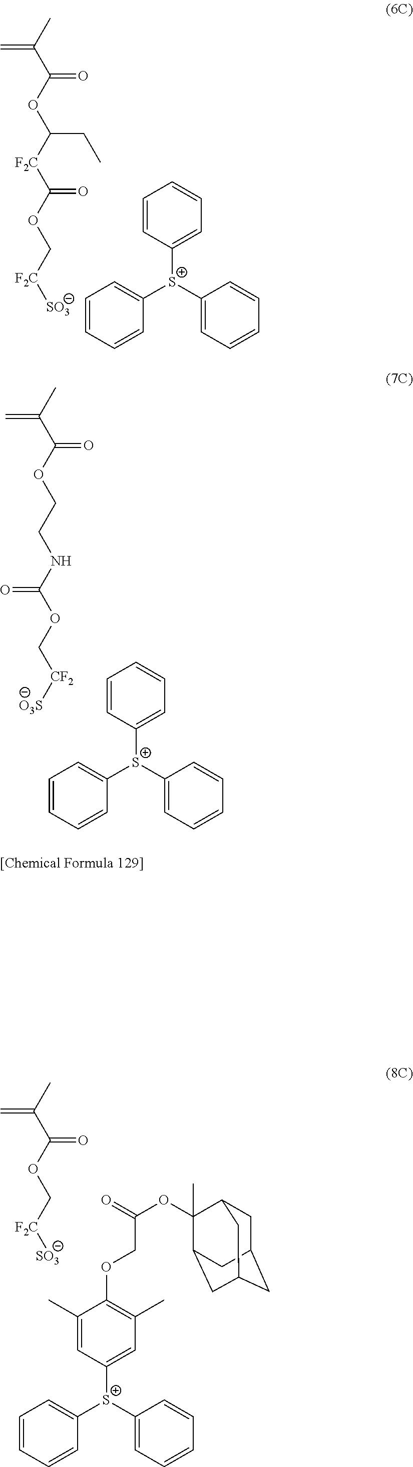

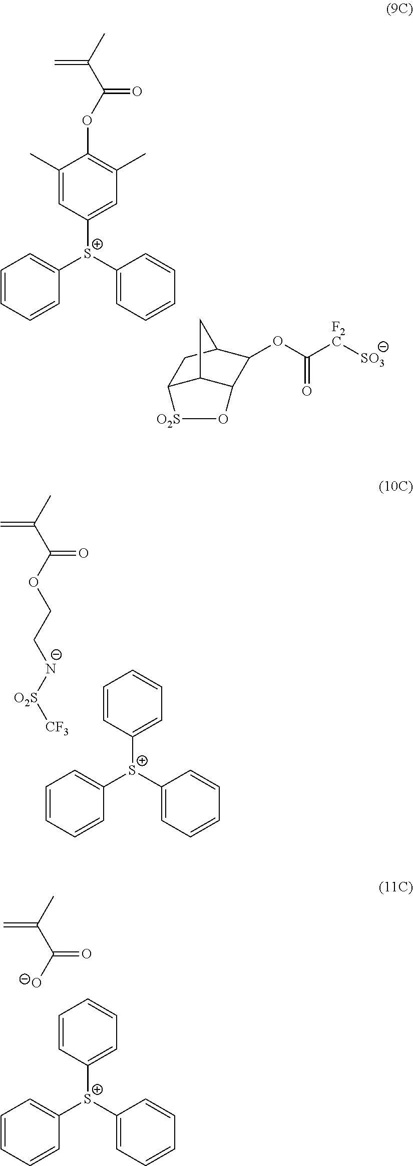

TABLE 23

| | | Polymeric compound | | | | | | | | |
|---|---|---|---|---|---|---|---|---|---|---|
| | | (1C) | (2C) | (3C) | (4C) | (5C) | (6C) | (7C) | (8C) | (9C) |
| monomer | (1C) | 35 | 35 | 35 | 35 | 35 | 35 | 40 | 40 | 35 |
| | (2C) | 35 | 35 | 35 | 35 | 35 | 35 | 40 | 40 | 35 |
| | (3C) | 18 | 18 | 18 | 18 | 18 | 18 | 18 | 18 | 16 |
| | (4C) | 12 | | | | | | | | 12 |
| | (5C) | | 12 | | | | | | | |
| | (6C) | | | 12 | | | | | | |
| | (7C) | | | | 12 | | | | | |
| | (8C) | | | | | 12 | | | | |
| | (9C) | | | | | | 12 | | | |
| | (10C) | | | | | | | 2 | | 2 |
| | (11C) | | | | | | | | 2 | |

| | | | | | | | | | |
|---|---|---|---|---|---|---|---|---|---|
| Polymerization | I-A | I-A | I-A | I-A | I-A | I-A | I-A | I-A | I-A |
| initiator | | | | | | | | | |
| Mw | 12500 | 12700 | 11900 | 12000 | 11800 | 12200 | 12300 | 12100 | 11900 |
| Mw/Mn | 1.71 | 1.70 | 1.68 | 1.73 | 1.66 | 1.82 | 1.79 | 1.73 | 1.80 |

TABLE 24

| | | Polymeric compound | | | | | | | | | |
|---|---|---|---|---|---|---|---|---|---|---|---|
| | | (10C) | (11C) | (12C) | (13C) | (14C) | (15C) | (16C) | (17C) | (18C) | (19C) |
| monomer | (1C) | 35 | 35 | 35 | 35 | 35 | 35 | 40 | 40 | 35 | 40 |
| | (2C) | 35 | 35 | 35 | 35 | 35 | 35 | 40 | 40 | 35 | 40 |
| | (3C) | 18 | 18 | 18 | 18 | 18 | 18 | 18 | 18 | 16 | 20 |
| | (4C) | 12 | | | | | | | | 12 | |
| | (5C) | | 12 | | | | | | | | |
| | (6C) | | | 12 | | | | | | | |
| | (7C) | | | | 12 | | | | | | |
| | (8C) | | | | | 12 | | | | | |
| | (9C) | | | | | | 12 | | | | |
| | (10C) | | | | | | | 2 | | 2 | |
| | (11C) | | | | | | | | 2 | | |

| | | | | | | | | | | |
|---|---|---|---|---|---|---|---|---|---|---|
| Polymerization | V-601 | V-601 | V-601 | V-601 | V-601 | V-601 | V-601 | V-601 | V-601 | I-A |
| initiator | | | | | | | | | | |
| Mw | 11900 | 11600 | 12000 | 11800 | 12100 | 11900 | 11600 | 11800 | 12500 | 12400 |
| Mw/Mn | 1.73 | 1.66 | 1.82 | 1.79 | 1.70 | 1.68 | 1.73 | 1.68 | 1.66 | 1.77 |

### Example 1E

### Synthesis of Polymeric Compound (1E)

In a flask equipped with a thermometer, a reflux tube, a stirrer, and a nitrogen inlet tube, 15.5 g of γ-butyrolactone was added under a nitrogen atmosphere, and the internal temperature was raised to 85° C. while stirring.

4.0 g (12.7 mmol) of the monomer (1E), 5.6 g (21.2 mmol) of the monomer (2E), 1.7 g (7.4 mmol) of the monomer (3E) and 2.2 g (4.5 mmol) of the monomer (4E) were dissolved in 93.5 g of γ-butyrolactone to obtain a solution. Then, 3.60 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer.

Thereafter, the precipitated white powder was separated by filtration, followed by washing with a mixed solution of methanol and water and drying under reduced pressure, thereby obtaining 6.8 g of a polymeric compound (1E) as an objective compound.

With respect to the polymeric compound (1E), the weight average molecular weight (Mw) and the dispersity (Mw/Mn) were determined by the polystyrene equivalent value as measured by gel permeation chromatography (GPC). As a result, it was found that the weight average molecular weight was 12,500, and the dispersity was 1.71.

Further, as a result of an analysis by ¹³C-NMR, it was found that the composition of the copolymer (ratio (molar ratio) of the respective structural units within the structural formula) was l/m/n/o=35/35/18/12.

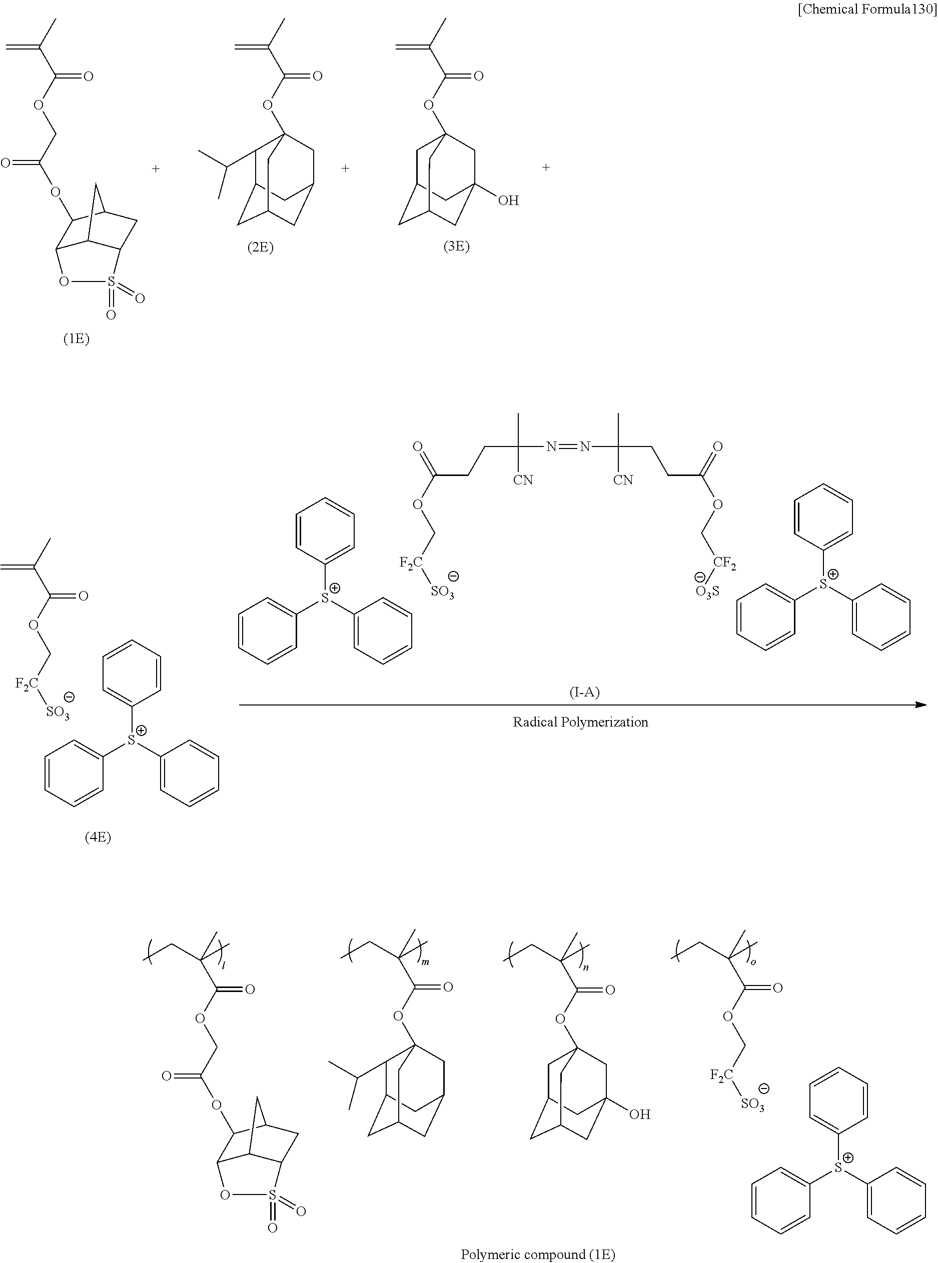

### Examples 2E to 14E

### Synthesis of Polymeric Compounds (2E) to (14E)

Polymeric compounds (2E) to (14E) were produced in the same manner as in Example 1E, except that the following monomers (1E) to (14E) which derive the structural units constituting each polymeric compound were used.

The type of the used polymerization initiator and the composition of the copolymer (ratio (molar ratio) as determined by ¹³C-NMR), the weight average molecular weight (Mw) and the molecular weight distribution (Mw/Mn) of the obtained polymeric compounds (1E) to (14E) are shown in Table 25.

### Comparative Example 1E

### Synthesis of Polymeric Compound (15E)

In a flask equipped with a thermometer, a reflux tube, a stirrer, and a nitrogen inlet tube, 15.4 g of γ-butyrolactone was added under a nitrogen atmosphere, and the internal temperature was raised to 85° C. while stirring.

4.0 g (12.7 mmol) of the monomer (1E), 5.6 g (21.2 mmol) of the monomer (2E), 1.7 g (7.4 mmol) of the monomer (3E) and 2.2 g (4.5 mmol) of the monomer (4E) were dissolved in 93.4 g of γ-butyrolactone to obtain a solution. Then, 1.54 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer.

Thereafter, the precipitated white powder was separated by filtration, followed by washing with a mixed solution of methanol and water and drying under reduced pressure, thereby obtaining 6.8 g of a polymeric compound (1E) as an objective compound. The reaction formula is the same as in synthetic example of the polymeric compound (1E) shown in Example 1E.

With respect to the polymeric compound (15E), the weight average molecular weight (Mw) and the dispersity (Mw/Mn) were determined by the polystyrene equivalent value as measured by gel permeation chromatography (GPC). As a result, it was found that the weight average molecular weight was 28,500, and the dispersity was 1.85.

Further, as a result of an analysis by ¹³C-NMR, it was found that the composition of the copolymer (ratio (molar ratio) of the respective structural units within the structural formula) was l/m/n/o=35/35/18/12.

### Comparative Examples 2E to 11E

### Synthesis of polymeric compounds (16E) to (25E)

Polymeric compounds (16E) to (25E) were produced in the same manner as in Comparative Example 1E, except that the following monomers (1E) to (14E) which derive the structural units constituting each polymeric compound were used.

### Comparative Example 12E

### Synthesis of polymeric compound (26E)

Polymeric compound (26E) was produced in the same manner as in Comparative Example 1E, except that the following monomers (12E), (13E) and (3E) which derive the structural units constituting each polymeric compound were used.

The type of the used polymerization initiator and the composition of the copolymer (ratio (molar ratio) as determined by ¹³C-NMR), the weight average molecular weight (Mw) and the molecular weight distribution (Mw/Mn) of the obtained polymeric compounds (15E) to (26E) are shown in Table 26.

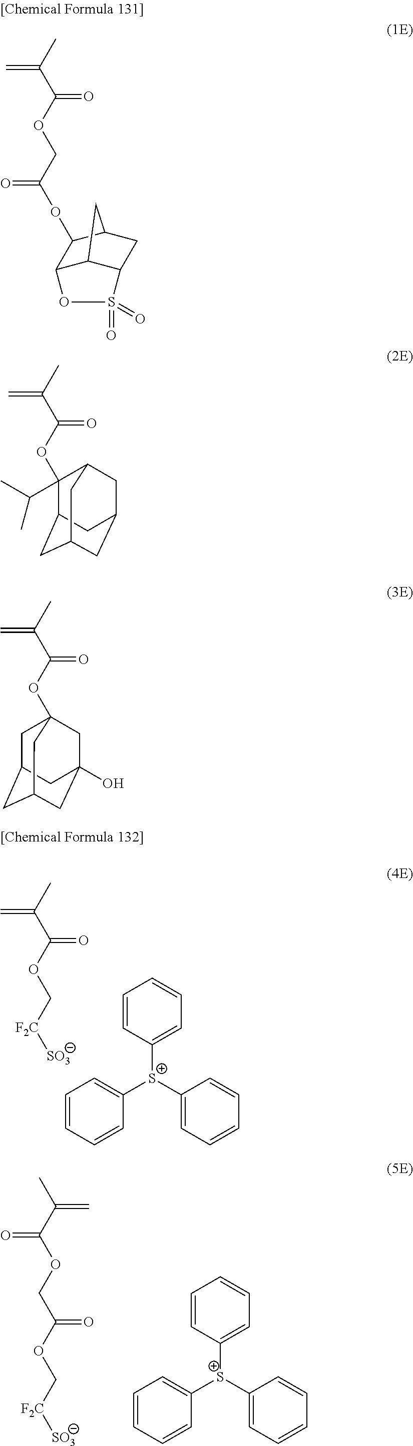

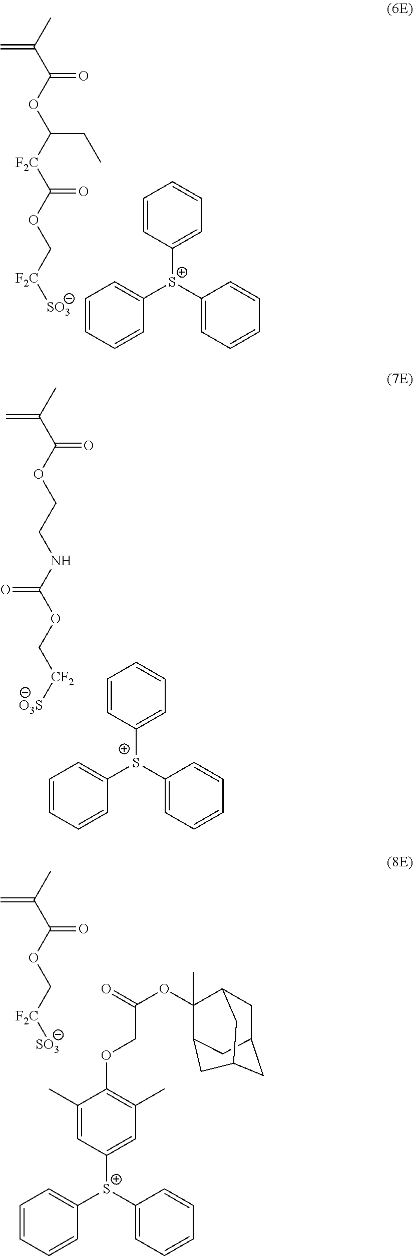

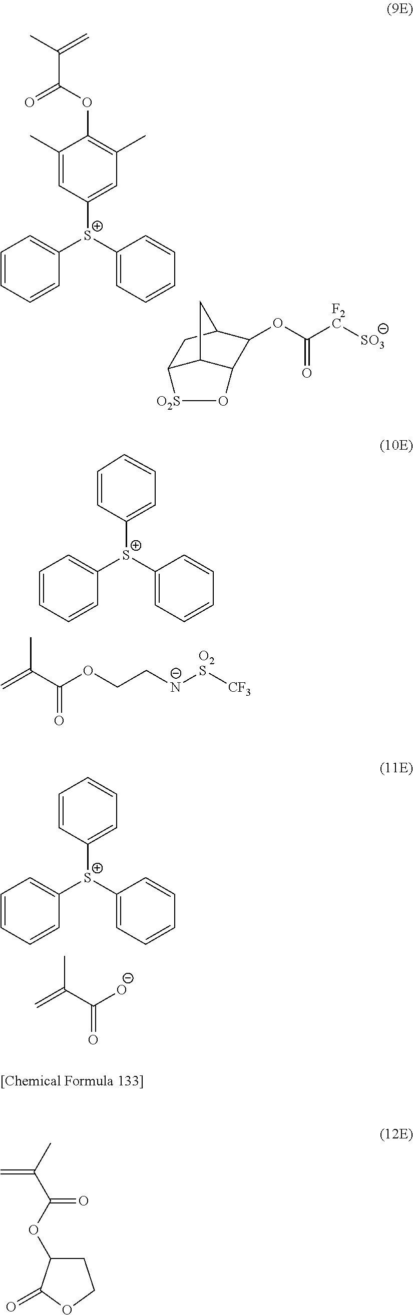

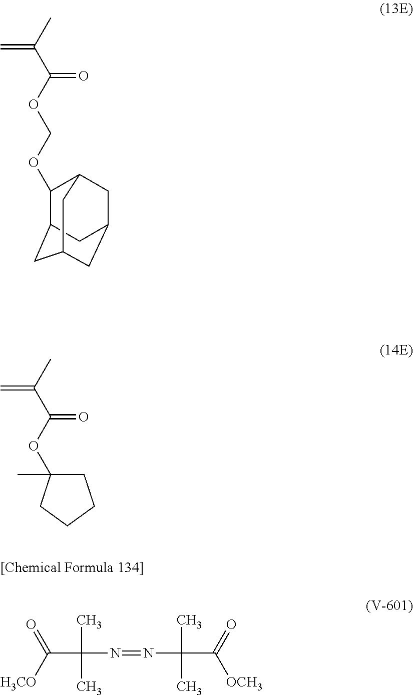 [SMILES: C=C(C)C(=O)OCOC1C2CC3CC(C2)CC1C3 ; C=C(C)C(=O)OC1(C)CCCC1 ; COC(=O)C(C)(C)N=NC(C)(C)C(=O)OC]

TABLE 25

| | | Polymeric compound | | | | | | |
|---|---|---|---|---|---|---|---|---|
| | | (1E) | (2E) | (3E) | (4E) | (5E) | (6E) | (7E) |
| Monomer | (1E) | 35 | 35 | 35 | 35 | 35 | 35 | 40 |
| | (2E) | 35 | 35 | 35 | 35 | 35 | 35 | 40 |
| | (3E) | 18 | 18 | 18 | 18 | 18 | 18 | 18 |
| | (4E) | 12 | | | | | | |
| | (5E) | | 12 | | | | | |
| | (6E) | | | 12 | | | | |
| | (7E) | | | | 12 | | | |
| | (8E) | | | | | 12 | | |
| | (9E) | | | | | | 12 | |
| | (10E) | | | | | | | 2 |
| | (11E) | | | | | | | |
| | (12E) | | | | | | | |
| | (13E) | | | | | | | |
| | (14E) | | | | | | | |

| | | | | | | | |
|---|---|---|---|---|---|---|---|
| Polymerization | I-A | I-A | I-A | I-A | I-A | I-A | I-A |
| initiator | | | | | | | |
| Mw | 12500 | 12700 | 11900 | 12000 | 11800 | 12200 | 12300 |
| Mw/Mn | 1.71 | 1.70 | 1.68 | 1.73 | 1.66 | 1.82 | 1.79 |

| | | Polymeric compound | | | | | | |
|---|---|---|---|---|---|---|---|---|
| | | (8E) | (9E) | (10E) | (11E) | (12E) | (13E) | (14E) |
| Monomer | (1E) | 40 | 35 | | | | | |
| | (2E) | 40 | 35 | | | | | |
| | (3E) | 18 | 16 | 24 | | 22 | 22 | 22 |
| | (4E) | | 12 | | | | | |
| | (5E) | | | | | | | |
| | (6E) | | | | | | | |
| | (7E) | | | | | | | |
| | (8E) | | | | | | | |
| | (9E) | | | | | | | |
| | (10E) | | 2 | | | | | |
| | (11E) | 2 | | | | | | |
| | (12E) | | | 36 | 45 | 40 | 38 | 36 |
| | (13E) | | | 40 | | 38 | 40 | 42 |
| | (14E) | | | | 55 | | | |

| | | | | | | | |
|---|---|---|---|---|---|---|---|
| Polymerization | I-A | I-A | I-A | I-A | I-A | I-A | I-A |
| initiator | | | | | | | |
| Mw | 12100 | 11900 | 10150 | 11000 | 5700 | 7700 | 19700 |
| Mw/Mn | 1.73 | 1.80 | 1.78 | 1.90 | 1.59 | 1.65 | 1.82 |

TABLE 26

| | | Polymeric compound | | | | | |
|---|---|---|---|---|---|---|---|
| | | (15E) | (16E) | (17E) | (18E) | (19E) | (20E) |
| Monomer | (1E) | 35 | 35 | 35 | 35 | 35 | 35 |
| | (2E) | 35 | 35 | 35 | 35 | 35 | 35 |
| | (3E) | 18 | 18 | 18 | 18 | 18 | 18 |
| | (4E) | 12 | | | | | |
| | (5E) | | 12 | | | | |
| | (6E) | | | 12 | | | |
| | (7E) | | | | 12 | | |
| | (8E) | | | | | 12 | |
| | (9E) | | | | | | 12 |
| | (10E) | | | | | | |
| | (11E) | | | | | | |
| | (12E) | | | | | | |
| | (13E) | | | | | | |
| | (14E) | | | | | | |
| Polymerization | | I-A | I-A | I-A | I-A | I-A | I-A |
| initiator | | | | | | | |
| Mw | | 28500 | 30700 | 27500 | 28000 | 24300 | 22500 |
| Mw/Mn | | 1.85 | 1.92 | 1.68 | 1.73 | 1.66 | 1.82 |
| | | Polymeric compound | | | | | |
| | | (21E) | (22E) | (23E) | (24E) | (25E) | (26E) |
| Monomer | (1E) | 40 | 40 | 35 | | | |
| | (2E) | 40 | 40 | 35 | | | |
| | (3E) | 18 | 18 | 16 | 24 | | 22 |
| | (4E) | | | 12 | | | |
| | (5E) | | | | | | |
| | (6E) | | | | | | |
| | (7E) | | | | | | |
| | (8E) | | | | | | |
| | (9E) | | | | | | |
| | (10E) | 2 | | 2 | | | |
| | (11E) | | 2 | | | | |
| | (12E) | | | | 36 | 45 | 37 |
| | (13E) | | | | 40 | | 41 |
| | (14E) | | | | | 55 | |

| | | | | | | |
|---|---|---|---|---|---|---|
| Polymerization | I-A | I-A | I-A | I-A | I-A | V-601 |
| initiator | | | | | | |
| Mw | 32000 | 33000 | 28400 | 21700 | 33000 | 7500 |
| Mw/Mn | 1.79 | 1.73 | 1.80 | 1.78 | 1.90 | 1.72 |

### Example 1D

### Synthesis of Polymeric Compound (F)-1D

In a flask equipped with a thermometer, a reflux tube, a stirrer, and a nitrogen inlet tube, 13.1 g of γ-butyrolactone was added under a nitrogen atmosphere, and the internal temperature was raised to 85° C. while stirring.

8.0 g (35.4 mmol) of the monomer (1D) and 3.4 g (15.2 mmol) of the monomer (2D) were dissolved in 78.9 g of γ-butyrolactone to obtain a solution. Then, 1.71 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained polymer reaction solution was washed with n-heptane, methanol, acetonitrile and MEK, followed by drying under reduced pressure, thereby obtaining 5.5 g of a polymeric compound (F)-1D as an objective compound.

With respect to the polymeric compound (F)-1D, the weight average molecular weight (Mw) and the dispersity (Mw/Mn) were determined by the polystyrene equivalent value as measured by gel permeation chromatography (GPC). As a result, it was found that the weight average molecular weight was 20,700, and the dispersity was 1.58.

Further, as a result of an analysis by ¹³C-NMR, it was found that the composition of the copolymer (ratio (molar ratio) of the respective structural units within the structural formula) was l/m=77/23.

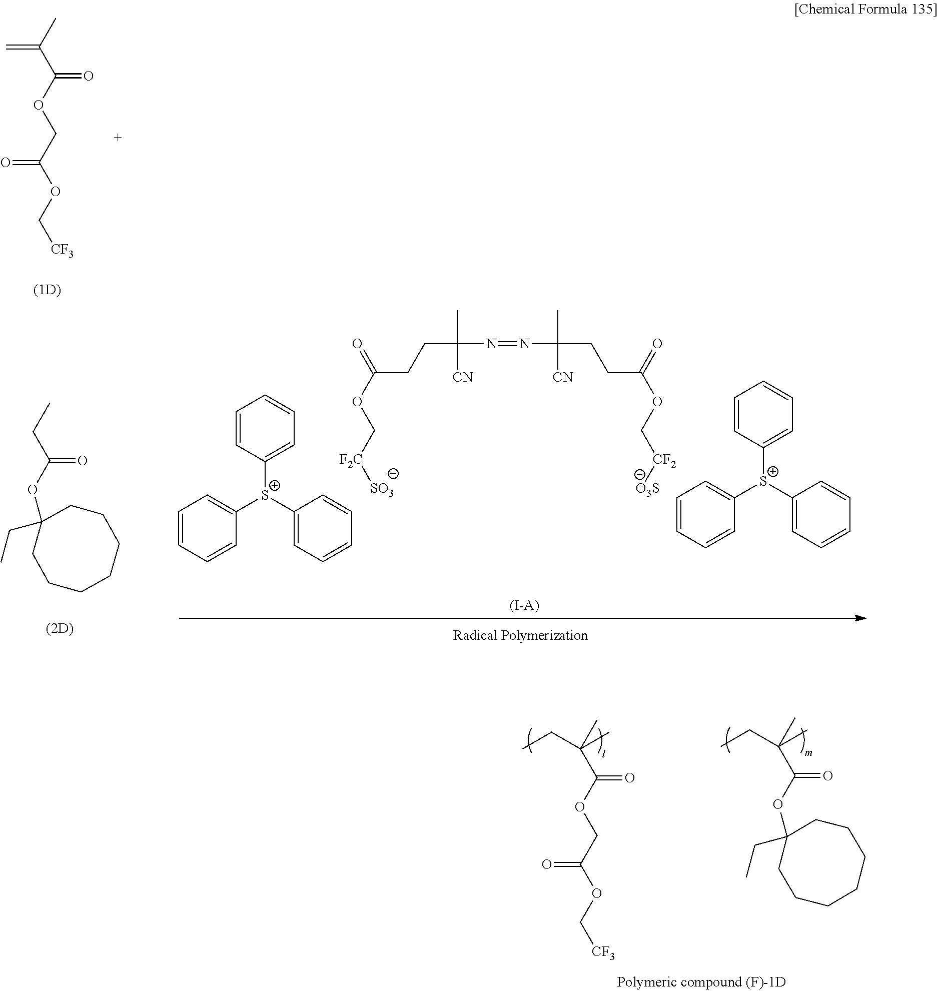

### Example 2D

### Synthesis of polymeric compound (F)-2D

Polymeric compound (F)-2D was produced in the same manner as in Example 1D, except that compounds which derives the structural unit constituting each polymeric compound was used in a predetermined molar ratio.

Further, with respect to the obtained polymeric compound (F)-2D, the structure of the polymeric compound (F)-2D, the composition of the copolymer as determined by carbon 13 nuclear magnetic resonance spectroscopy (600 MHz, ¹³C-NMR), and the weight average molecular weight (Mw) and the molecular weight distribution (Mw/Mn) determined by the polystyrene equivalent value as measured by GPC are shown below.

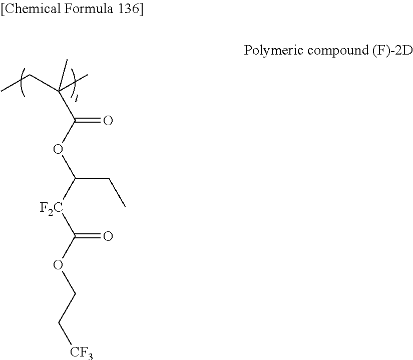

[Mw=24,000, Mw/Mn=1.51, l=100 (molar ratio), polymerized using the compound (I-A) as a radical polymerization initiator]

### Comparative Examples 1D and 2D

### Synthesis of polymeric compounds (F)-3D and (F)-4D

Polymeric compounds (F)-3D and (F)-4D were produced in the same manner as in Examples 1D and 2D, except that the V-601 represented by following formula was used as a radical polymerization initiator.

Further, with respect to the obtained polymeric compounds (F)-3D to (F)-4D, the structure of the polymeric compounds (3D) and (4D), the composition of the copolymer as determined by carbon 13 nuclear magnetic resonance spectroscopy (600 MHz, ¹³C-NMR), and the weight average molecular weight and the molecular weight (Mw) distribution (Mw/Mn) determined by the polystyrene equivalent value as measured by GPC are shown below.

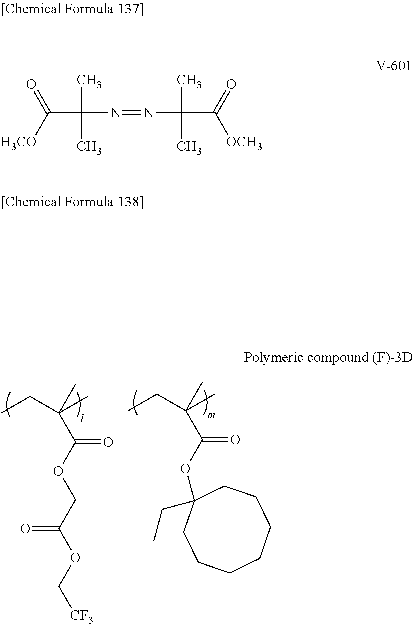

[Mw=23,000, Mw/Mn=1.61, l/m=77/23 (molar ratio), polymerized using V-601 as a radical polymerization initiator]

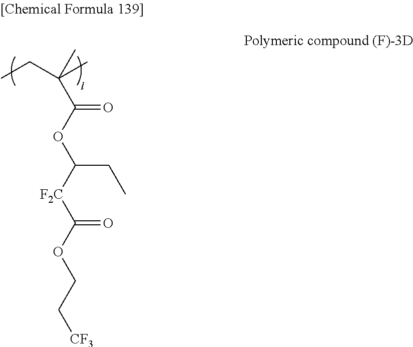

[Mw=22,000, Mw/Mn=1.58, l=100 (molar ratio), polymerized using V-601 as a radical polymerization initiator]

### Production Example 1D

### Synthesis of polymeric compound (A)-1D

In a flask equipped with a thermometer, a reflux tube, a stirrer, and a nitrogen inlet tube, 12.4 g of γ-butyrolactone was added under a nitrogen atmosphere, and the internal temperature was raised to 85° C. while stirring.

5.0 g (15.8 mmol) of the monomer (3D), 4.0 g (15.8 mmol) of the monomer (4D) and 1.9 g (7.9 mmol) of the monomer (5D) were dissolved in 74.9 g of γ-butyrolactone to obtain a solution. Then, 3.12 g of the compound (I-A) as a radical polymerization initiator was added and dissolved in the obtained solution.

The resulting mixed solution was added to the flask in a dropwise manner at a constant rate over 4 hour, and heated while stirring for 1 hour, and then the reaction solution was cooled to room temperature.

The obtained reaction polymer solution was added in a dropwise manner to an excess amount of a mixed solution of methanol and water to precipitate a polymer.

Thereafter, the precipitated white powder was separated by filtration, followed by washing with a mixed solution of methanol and water and drying under reduced pressure, thereby obtaining 5.6 g of a polymeric compound (A)-1D as an objective compound.

With respect to the polymeric compound (A)-1 D, the weight average molecular weight (Mw) and the dispersity (Mw/Mn) were determined by the polystyrene equivalent value as measured by gel permeation chromatography (GPC). As a result, it was found that the weight average molecular weight was 7,700, and the dispersity was 1.70.

Further, as a result of an analysis by ¹³C-NMR, it was found that the composition of the copolymer (ratio (molar ratio) of the respective structural units within the structural formula) was l/m/n=40/40/20.

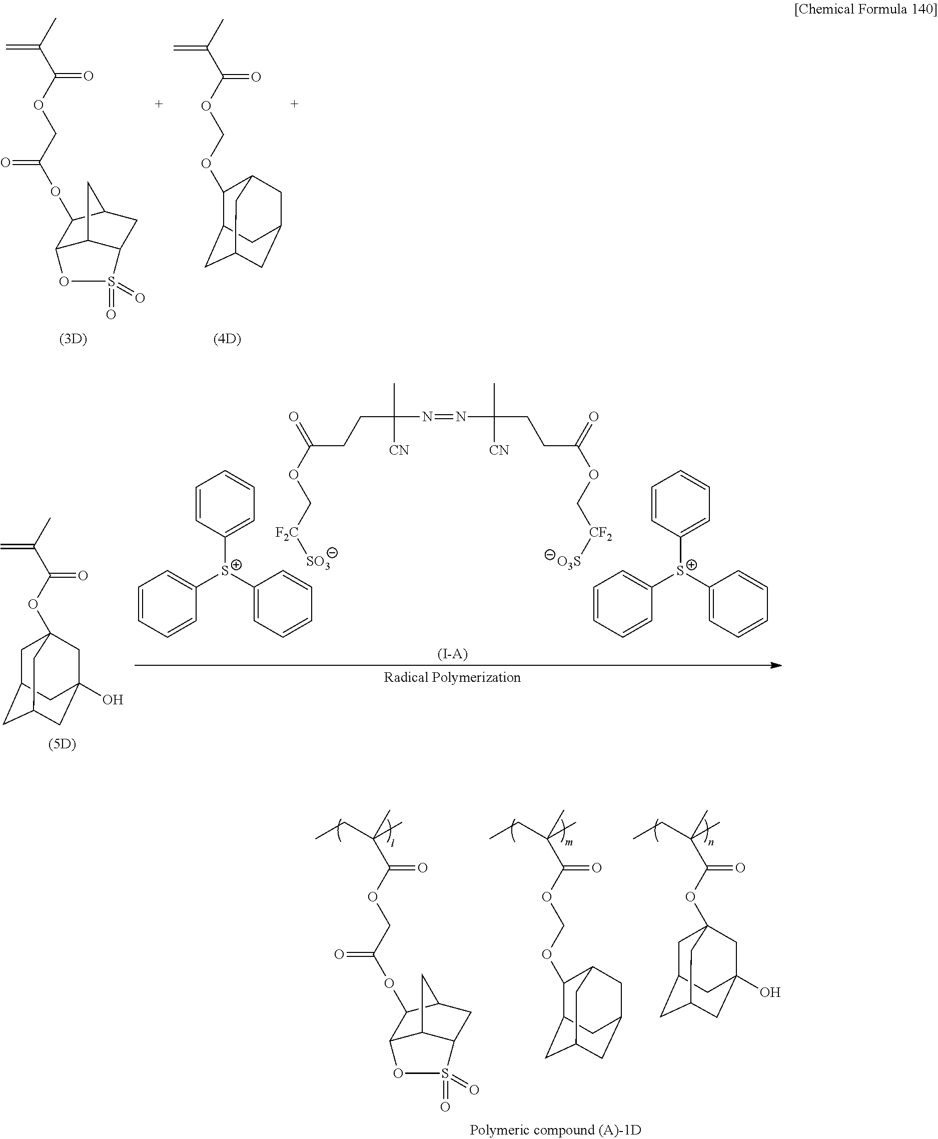

### Production Examples 2D and 3D

### Synthesis of polymeric compounds (A)-2D and (A)-3D

Polymeric compounds (A)-2D and (A)-3D was produced in the same manner as in Production Example 1D, except that compounds which derives the structural units constituting the polymeric compound was used in predetermined molar ratio.

Further, with respect to the obtained polymeric compounds (A)-2D and (A)-3D, the structure of the polymeric compounds (A)-2D and (A)-3D, the composition of the copolymers as determined by carbon 13 nuclear magnetic resonance spectroscopy (600 MHz, ¹³C-NMR), and the weight average molecular weight (Mw) and the molecular weight distribution (Mw/Mn) determined by the polystyrene equivalent value as measured by GPC are shown below.

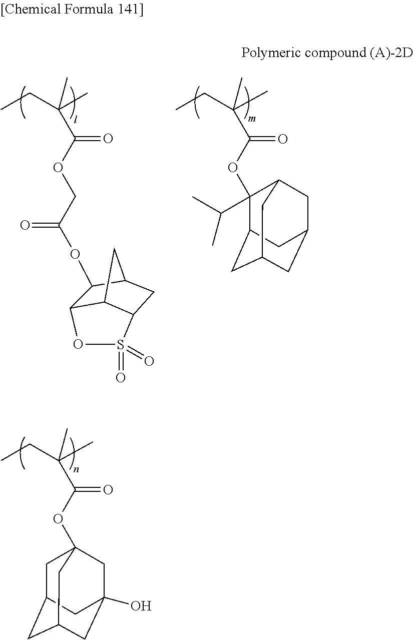

[Mw=6,900, Mw/Mn=1.68, l/m/n=40/40/20 (molar ratio), polymerized using the compound (I-A) as a radical polymerization initiator]

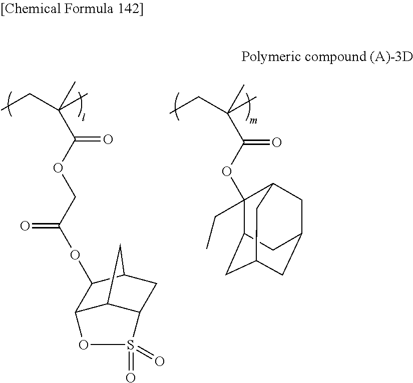

[Mw=8,200, Mw/Mn=1.73, l/m=49/51 (molar ratio), polymerized using the compound (I-A) as a radical polymerization initiator]

### Production Example 4D

### Synthesis of Polymeric Compound (A)-4D

Polymeric compound (A)-4D were produced in the same manner as in [Production Example 2D], except that V-601 represented by the aforementioned formula was used as a radical polymerization initiator.

Further, with respect to the obtained polymeric compound (A)-4D, the structure of the polymeric compound (A)-4D, the composition of the copolymer as determined by carbon 13 nuclear magnetic resonance spectroscopy (600 MHz, ¹³C-NMR), and the weight average molecular weight and the molecular weight distribution (Mw/Mn) determined by the polystyrene equivalent value as measured by GPC are shown below.

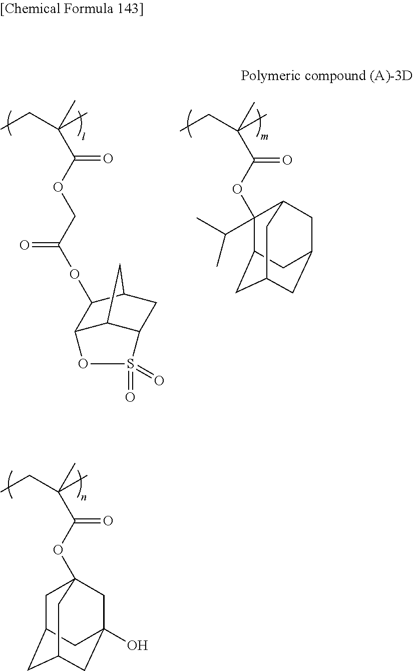

[Mw=7,500, Mw/Mn=1.78, l/m/n=40/40/20 (molar ratio), polymerized using V-601 as a radical polymerization initiator]

### Examples 15A to 28A and Comparative Examples 19A to 33A

### Preparation of Resist Composition

The components shown in Tables 27 and 28 were mixed together and dissolved to obtain resist compositions.

TABLE 27

| | Com- | Com- | Com- | Com- | Com- | Com- |
|---|---|---|---|---|---|---|
| | ponent | ponent | ponent | ponent | ponent | ponent |
| | (A) | (B) | (D) | (E) | (F) | (S) |
| Example | (A)-1A | (B)-1 | (D)-1 | (E)-1 | (F)-1 | (S)-1 |
| 15A | [100] | [15.0] | [1.20] | [0.50] | [1.50] | [3000] |
| Example | (A)-2A | (B)-1 | (D)-1 | (E)-1 | (F)-1 | (S)-1 |
| 16A | [100] | [15.0] | [1.20] | [0.50] | [1.50] | [3000] |
| Example | (A)-3A | (B)-1 | (D)-1 | (E)-1 | (F)-1 | (S)-1 |
| 17A | [100] | [15.0] | [1.20] | [0.50] | [1.50] | [3000] |
| Example | (A)-4A | (B)-1 | (D)-1 | (E)-1 | (F)-1 | (S)-1 |
| 18A | [100] | [15.0] | [1.20] | [0.50] | [1.50] | [3000] |
| Example | (A)-5A | (B)-1 | (D)-1 | (E)-1 | (F)-1 | (S)-1 |
| 19A | [100] | [15.0] | [1.20] | [0.50] | [1.50] | [3000] |
| Example | (A)-6A | (B)-1 | (D)-1 | (E)-1 | (F)-1 | (S)-1 |
| 20A | [100] | [15.0] | [1.20] | [0.50] | [1.50] | [3000] |
| Example | (A)-7A | (B)-1 | (D)-1 | (E)-1 | (F)-1 | (S)-1 |
| 21A | [100] | [15.0] | [1.20] | [0.50] | [1.50] | [3000] |
| Example | (A)-8A | (B)-1 | (D)-1 | (E)-1 | (F)-1 | (S)-1 |
| 22A | [100] | [15.0] | [1.20] | [0.50] | [1.50] | [3000] |
| Example | (A)-9A | (B)-1 | (D)-1 | (E)-1 | (F)-1 | (S)-1 |
| 23A | [100] | [15.0] | [1.20] | [0.50] | [1.50] | [3000] |
| Example | (A)-10A | (B)-1 | (D)-1 | (E)-1 | (F)-1 | (S)-1 |
| 24A | [100] | [15.0] | [1.20] | [0.50] | [1.50] | [3000] |
| Example | (A)-11A | (B)-1 | (D)-1 | (E)-1 | (F)-1 | (S)-1 |
| 25A | [100] | [15.0] | [1.20] | [0.50] | [1.50] | [3000] |
| Example | (A)-12A | (B)-1 | (D)-1 | (E)-1 | (F)-1 | (S)-1 |
| 26A | [100] | [15.0] | [1.20] | [0.50] | [1.50] | [3000] |
| Example | (A)-13A | (B)-1 | (D)-1 | (E)-1 | (F)-1 | (S)-1 |
| 27A | [100] | [15.0] | [1.20] | [0.50] | [1.50] | [3000] |
| Example | (A)-14A | (B)-1 | (D)-1 | (E)-1 | (F)-1 | (S)-1 |
| 28A | [100] | [15.0] | [1.20] | [0.50] | [1.50] | [3000] |

TABLE 28

| | Com- | Com- | Com- | Com- | Com- | Com- |
|---|---|---|---|---|---|---|
| | ponent | ponent | ponent | ponent | ponent | ponent |
| | (A) | (B) | (D) | (E) | (F) | (S) |
| Comparative | (A)-15A | (B)-1 | (D)-1 | (E)-1 | (F)-1 | (S)-1 |
| Example | [100] | [15.0] | [1.20] | [0.50] | [1.50] | [3000] |
| 19A | | | | | | |
| Comparative | (A)-16A | (B)-1 | (D)-1 | (E)-1 | (F)-1 | (S)-1 |
| Example | [100] | [15.0] | [1.20] | [0.50] | [1.50] | [3000] |
| 20A | | | | | | |
| Comparative | (A)-17A | (B)-1 | (D)-1 | (E)-1 | (F)-1 | (S)-1 |
| Example | [100] | [15.0] | [1.20] | [0.50] | [1.50] | [3000] |
| 21A | | | | | | |
| Comparative | (A)-18A | (B)-1 | (D)-1 | (E)-1 | (F)-1 | (S)-1 |
| Example | [100] | [15.0] | [1.20] | [0.50] | [1.50] | [3000] |
| 22A | | | | | | |
| Comparative | (A)-19A | (B)-1 | (D)-1 | (E)-1 | (F)-1 | (S)-1 |
| Example | [100] | [15.0] | [1.20] | [0.50] | [1.50] | [3000] |
| 23A | | | | | | |
| Comparative | (A)-20A | (B)-1 | (D)-1 | (E)-1 | (F)-1 | (S)-1 |
| Example | [100] | [15.0] | [1.20] | [0.50] | [1.50] | [3000] |
| 24A | | | | | | |
| Comparative | (A)-21A | (B)-1 | (D)-1 | (E)-1 | (F)-1 | (S)-1 |
| Example | [100] | [15.0] | [1.20] | [0.50] | [1.50] | [3000] |
| 25A | | | | | | |
| Comparative | (A)-22A | (B)-1 | (D)-1 | (E)-1 | (F)-1 | (S)-1 |
| Example | [100] | [15.0] | [1.20] | [0.50] | [1.50] | [3000] |
| 26A | | | | | | |
| Comparative | (A)-23A | (B)-1 | (D)-1 | (E)-1 | (F)-1 | (S)-1 |
| Example | [100] | [15.0] | [1.20] | [0.50] | [1.50] | [3000] |
| 27A | | | | | | |
| Comparative | (A)-24A | (B)-1 | (D)-1 | (E)-1 | (F)-1 | (S)-1 |
| Example | [100] | [15.0] | [1.20] | [0.50] | [1.50] | [3000] |
| 28A | | | | | | |
| Comparative | (A)-25A | (B)-1 | (D)-1 | (E)-1 | (F)-1 | (S)-1 |
| Example | [100] | [15.0] | [1.20] | [0.50] | [1.50] | [3000] |
| 29A | | | | | | |
| Comparative | (A)-26A | (B)-1 | (D)-1 | (E)-1 | (F)-1 | (S)-1 |
| Example | [100] | [15.0] | [1.20] | [0.50] | [1.50] | [3000] |
| 30A | | | | | | |
| Comparative | (A)-27A | (B)-1 | (D)-1 | (E)-1 | (F)-1 | (S)-1 |
| Example | [100] | [15.0] | [1.20] | [0.50] | [1.50] | [3000] |
| 31A | | | | | | |
| Comparative | (A)-28A | (B)-1 | (D)-1 | (E)-1 | (F)-1 | (S)-1 |
| Example | [100] | [15.0] | [1.20] | [0.50] | [1.50] | [3000] |
| 32A | | | | | | |
| Comparative | (A)-29A | (B)-1 | (D)-1 | (E)-1 | (F)-1 | (S)-1 |
| Example | [100] | [15.0] | [1.20] | [0.50] | [1.50] | [3000] |
| 33A | | | | | | |

In Tables 27 and 28, the reference characters indicate the following. Further, the values in brackets [ ] indicate the amount (in terms of parts by weight) of the component added.

(A)-1A to (A)-29A: the aforementioned polymeric compounds (1A) to (29A)

(B)-1: compound (B)-1 shown below

(D)-1: tri-n-octylamine.

(E)-1: salicylic acid

(F)-1: polymeric compound (F)-1 shown below [l=100 (molar ratio), Mw=22,000, Mw/Mn=1.58, a polymer polymerized by a radical polymerization using a radical polymerization initiator V-601]

(S)-1: a mixed solvent of PGMEA/PGME/cyclohexanone=45/30/25 (weight ratio)

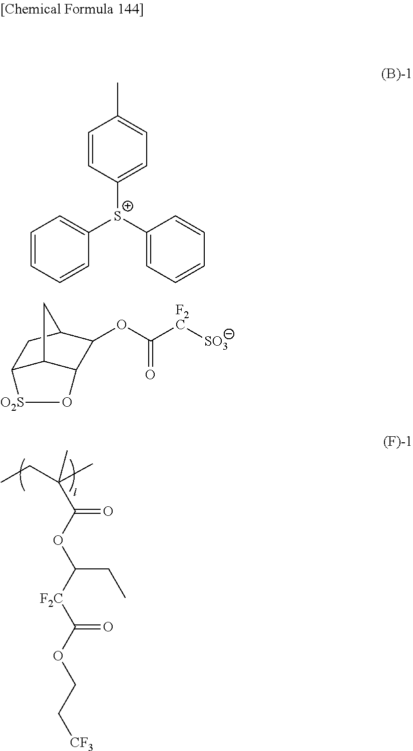

### Examples 22B to 42B and Comparative Examples 23B to 44B

### Preparation of Resist Composition

The components shown in Tables 29 to 33 were mixed together and dissolved to obtain resist compositions.

TABLE 29

| | Com- | Com- | Com- | Com- | Com- | |
|---|---|---|---|---|---|---|
| | ponent | ponent | ponent | ponent | ponent | Component |
| | (A) | (B) | (D) | (E) | (F) | (S) |
| Example | (A)-1B | (B)-1 | (D)-1 | (E)-1 | (F)-1 | (S)-1 |
| 22B | [100] | [15.0] | [1.20] | [0.50] | [1.50] | [3000] |
| Example | (A)-2B | (B)-1 | (D)-1 | (E)-1 | (F)-1 | (S)-1 |
| 23B | [100] | [15.0] | [1.20] | [0.50] | [1.50] | [3000] |
| Example | (A)-3B | (B)-1 | (D)-1 | (E)-1 | (F)-1 | (S)-1 |
| 24B | [100] | [15.0] | [1.20] | [0.50] | [1.50] | [3000] |
| Example | (A)-4B | (B)-1 | (D)-1 | (E)-1 | (F)-1 | (S)-1 |
| 25B | [100] | [15.0] | [1.20] | [0.50] | [1.50] | [3000] |
| Example | (A)-5B | (B)-1 | (D)-1 | (E)-1 | (F)-1 | (S)-1 |
| 26B | [100] | [15.0] | [1.20] | [0.50] | [1.50] | [3000] |
| Example | (A)-6B | (B)-1 | (D)-1 | (E)-1 | (F)-1 | (S)-1 |
| 27B | [100] | [15.0] | [1.20] | [0.50] | [1.50] | [3000] |
| Example | (A)-7B | (B)-1 | (D)-1 | (E)-1 | (F)-1 | (S)-1 |
| 28B | [100] | [15.0] | [1.20] | [0.50] | [1.50] | [3000] |
| Example | (A)-8B | (B)-1 | (D)-1 | (E)-1 | (F)-1 | (S)-1 |
| 29B | [100] | [15.0] | [1.20] | [0.50] | [1.50] | [3000] |
| Example | (A)-9B | (B)-1 | (D)-1 | (E)-1 | (F)-1 | (S)-1 |
| 30B | [100] | [15.0] | [1.20] | [0.50] | [1.50] | [3000] |
| Example | (A)-10B | (B)-1 | (D)-1 | (E)-1 | (F)-1 | (S)-1 |
| 31B | [100] | [15.0] | [1.20] | [0.50] | [1.50] | [3000] |

TABLE 30

| | Com- | Com- | Com- | Com- | Com- | |
|---|---|---|---|---|---|---|
| | ponent | ponent | ponent | ponent | ponent | Component |
| | (A) | (B) | (D) | (E) | (F) | (S) |
| Example | (A)-11B | (B)-1 | (D)-1 | (E)-1 | (F)-1 | (S)-1 |
| 32B | [100] | [15.0] | [1.20] | [0.50] | [1.50] | [3000] |
| Example | (A)-12B | (B)-1 | (D)-1 | (E)-1 | (F)-1 | (S)-1 |
| 33B | [100] | [15.0] | [1.20] | [0.50] | [1.50] | [3000] |
| Example | (A)-13B | (B)-1 | (D)-1 | (E)-1 | (F)-1 | (S)-1 |
| 34B | [100] | [15.0] | [1.20] | [0.50] | [1.50] | [3000] |
| Example | (A)-14B | (B)-1 | (D)-1 | (E)-1 | (F)-1 | (S)-1 |
| 35B | [100] | [15.0] | [1.20] | [0.50] | [1.50] | [3000] |
| Example | (A)-15B | (B)-1 | (D)-1 | (E)-1 | (F)-1 | (S)-1 |
| 36B | [100] | [15.0] | [1.20] | [0.50] | [1.50] | [3000] |
| Example | (A)-16B | (B)-1 | (D)-1 | (E)-1 | (F)-1 | (S)-1 |
| 37B | [100] | [15.0] | [1.20] | [0.50] | [1.50] | [3000] |
| Example | (A)-17B | (B)-1 | (D)-1 | (E)-1 | (F)-1 | (S)-1 |
| 38B | [100] | [15.0] | [1.20] | [0.50] | [1.50] | [3000] |
| Example | (A)-18B | (B)-1 | (D)-1 | (E)-1 | (F)-1 | (S)-1 |
| 39B | [100] | [15.0] | [1.20] | [0.50] | [1.50] | [3000] |
| Example | (A)-19B | (B)-1 | (D)-1 | (E)-1 | (F)-1 | (S)-1 |
| 40B | [100] | [15.0] | [1.20] | [0.50] | [1.50] | [3000] |
| Example | (A)-20B | (B)-1 | (D)-1 | (E)-1 | (F)-1 | (S)-1 |
| 41B | [100] | [15.0] | [1.20] | [0.50] | [1.50] | [3000] |
| Example | (A)-21B | (B)-1 | (D)-1 | (E)-1 | (F)-1 | (S)-1 |
| 42B | [100] | [15.0] | [1.20] | [0.50] | [1.50] | [3000] |

TABLE 31

| | Com- | Com- | Com- | Com- | Com- | Com- |
|---|---|---|---|---|---|---|
| | ponent | ponent | ponent | ponent | ponent | ponent |
| | (A) | (B) | (D) | (E) | (F) | (S) |
| Comparative | (A)-22B | (B)-1 | (D)-1 | (E)-1 | (F)-1 | (S)-1 |
| Example | [100] | [15.0] | [1.20] | [0.50] | [1.50] | [3000] |
| 23B | | | | | | |
| Comparative | (A)-23B | (B)-1 | (D)-1 | (E)-1 | (F)-1 | (S)-1 |
| Example | [100] | [15.0] | [1.20] | [0.50] | [1.50] | [3000] |
| 24B | | | | | | |
| Comparative | (A)-24B | (B)-1 | (D)-1 | (E)-1 | (F)-1 | (S)-1 |
| Example | [100] | [15.0] | [1.20] | [0.50] | [1.50] | [3000] |
| 25B | | | | | | |
| Comparative | (A)-25B | (B)-1 | (D)-1 | (E)-1 | (F)-1 | (S)-1 |
| Example | [100] | [15.0] | [1.20] | [0.50] | [1.50] | [3000] |
| 26B | | | | | | |
| Comparative | (A)-26B | (B)-1 | (D)-1 | (E)-1 | (F)-1 | (S)-1 |
| Example | [100] | [15.0] | [1.20] | [0.50] | [1.50] | [3000] |
| 27B | | | | | | |
| Comparative | (A)-27B | (B)-1 | (D)-1 | (E)-1 | (F)-1 | (S)-1 |
| Example | [100] | [15.0] | [1.20] | [0.50] | [1.50] | [3000] |
| 28B | | | | | | |
| Comparative | (A)-28B | (B)-1 | (D)-1 | (E)-1 | (F)-1 | (S)-1 |
| Example | [100] | [15.0] | [1.20] | [0.50] | [1.50] | [3000] |
| 29B | | | | | | |
| Comparative | (A)-29B | (B)-1 | (D)-1 | (E)-1 | (F)-1 | (S)-1 |
| Example | [100] | [15.0] | [1.20] | [0.50] | [1.50] | [3000] |
| 30B | | | | | | |
| Comparative | (A)-30B | (B)-1 | (D)-1 | (E)-1 | (F)-1 | (S)-1 |
| Example | [100] | [15.0] | [1.20] | [0.50] | [1.50] | [3000] |
| 31B | | | | | | |
| Comparative | (A)-31B | (B)-1 | (D)-1 | (E)-1 | (F)-1 | (S)-1 |
| Example | [100] | [15.0] | [1.20] | [0.50] | [1.50] | [3000] |
| 32B | | | | | | |

TABLE 32

| | Com- | Com- | Com- | Com- | Com- | |
|---|---|---|---|---|---|---|
| | ponent | ponent | ponent | ponent | ponent | Com- |
| | (A) | (B) | (D) | (E) | (F) | ponent (S) |
| Comparative | (A)-32B | (B)-1 | (D)-1 | (E)-1 | (F)-1 | (S)-1 |
| Example | [100] | [15.0] | [1.20] | [0.50] | [1.50] | [3000] |
| 33B | | | | | | |
| Comparative | (A)-33B | (B)-1 | (D)-1 | (E)-1 | (F)-1 | (S)-1 |
| Example | [100] | [15.0] | [1.20] | [0.50] | [1.50] | [3000] |
| 34B | | | | | | |
| Comparative | (A)-34B | (B)-1 | (D)-1 | (E)-1 | (F)-1 | (S)-1 |
| Example | [100] | [15.0] | [1.20] | [0.50] | [1.50] | [3000] |
| 35B | | | | | | |
| Comparative | (A)-35B | (B)-1 | (D)-1 | (E)-1 | (F)-1 | (S)-1 |
| Example | [100] | [15.0] | [1.20] | [0.50] | [1.50] | [3000] |
| 36B | | | | | | |
| Comparative | (A)-36B | (B)-1 | (D)-1 | (E)-1 | (F)-1 | (S)-1 |
| Example | [100] | [15.0] | [1.20] | [0.50] | [1.50] | [3000] |
| 37B | | | | | | |
| Comparative | (A)-37B | (B)-1 | (D)-1 | (E)-1 | (F)-1 | (S)-1 |
| Example | [100] | [15.0] | [1.20] | [0.50] | [1.50] | [3000] |
| 38B | | | | | | |
| Comparative | (A)-38B | (B)-1 | (D)-1 | (E)-1 | (F)-1 | (S)-1 |
| Example | [100] | [15.0] | [1.20] | [0.50] | [1.50] | [3000] |
| 39B | | | | | | |
| Comparative | (A)-39B | (B)-1 | (D)-1 | (E)-1 | (F)-1 | (S)-1 |
| Example | [100] | [15.0] | [1.20] | [0.50] | [1.50] | [3000] |
| 40B | | | | | | |
| Comparative | (A)-40B | (B)-1 | (D)-1 | (E)-1 | (F)-1 | (S)-1 |
| Example | [100] | [15.0] | [1.20] | [0.50] | [1.50] | [3000] |
| 41B | | | | | | |
| Comparative | (A)-41B | (B)-1 | (D)-1 | (E)-1 | (F)-1 | (S)-1 |
| Example | [100] | [15.0] | [1.20] | [0.50] | [1.50] | [3000] |
| 42B | | | | | | |
| Comparative | (A)-42B | (B)-1 | (D)-1 | (E)-1 | (F)-1 | (S)-1 |
| Example | [100] | [15.0] | [1.20] | [0.50] | [1.50] | [3000] |
| 43B | | | | | | |
| Comparative | (A)-43B | (B)-1 | (D)-1 | (E)-1 | (F)-1 | (S)-1 |
| Example | [100] | [15.0] | [1.20] | [0.50] | [1.50] | [3000] |
| 44B | | | | | | |

In Tables 29 to 32, the reference characters indicate the following. Further, the values in brackets [ ] indicate the amount (in terms of parts by weight) of the component added.

(A)-1B to (A)-43B: the aforementioned polymeric compounds (1B) to (43B)

(B)-1: compound (B)-1 shown below

(D)-1: tri-n-octylamine.

(E)-1: salicylic acid

(F)-1: polymeric compound (F)-1 shown below [l=100 (molar ratio), Mw=22,000, Mw/Mn=1.58, a polymer polymerized by a radical polymerization using a radical polymerization initiator V-601]

(S)-1: a mixed solvent of PGMEA/PGME/cyclohexanone=45/30/25 (weight ratio)

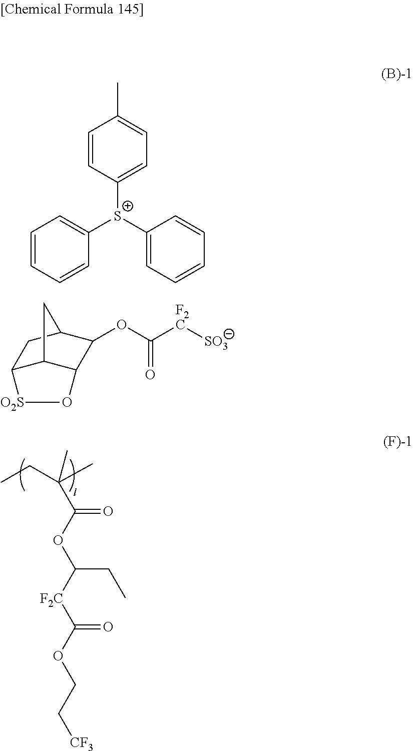

### Examples 10C to 18C and Comparative Examples 11C to 21C

### Preparation of Resist Composition

The components shown in Tables 33 and 34 were mixed together and dissolved to obtain resist compositions.

TABLE 33

| | Component | Component | Component | Component | Component |
|---|---|---|---|---|---|
| | (A) | (B) | (D) | (F) | (S) |
| Example | (A)-1C | | (D)-1 | (F)-1 | (S)-1 |
| 10C | [100] | | [1.20] | [1.50] | [3000] |
| Example | (A)-2C | | (D)-1 | (F)-1 | (S)-1 |
| 11C | [100] | | [1.20] | [1.50] | [3000] |
| Example | (A)-3C | | (D)-1 | (F)-1 | (S)-1 |
| 12C | [100] | | [1.20] | [1.50] | [3000] |
| Example | (A)-4C | | (D)-1 | (F)-1 | (S)-1 |
| 13C | [100] | | [1.20] | [1.50] | [3000] |
| Example | (A)-5C | | (D)-1 | (F)-1 | (S)-1 |
| 14C | [100] | | [1.20] | [1.50] | [3000] |
| Example | (A)-6C | | (D)-1 | (F)-1 | (S)-1 |
| 15C | [100] | | [1.20] | [1.50] | [3000] |
| Example | (A)-7C | (B)-1 | (D)-1 | (F)-1 | (S)-1 |
| 16C | [100] | [15.0] | [0.10] | [1.50] | [3000] |
| Example | (A)-8C | (B)-1 | (D)-1 | (F)-1 | (S)-1 |
| 17C | [100] | [15.0] | [0.10] | [1.50] | [3000] |
| Example | (A)-9C | | (D)-1 | (F)-1 | (S)-1 |
| 18C | [100] | | [1.20] | [1.50] | [3000] |

TABLE 34

| | Component | Component | Component | Component | Component |
|---|---|---|---|---|---|
| | (A) | (B) | (D) | (F) | (S) |
| Comparative | (A)-10C | | (D)-1 | (F)-1 | (S)-1 |
| Example | [100] | | [1.20] | [1.50] | [3000] |
| 11C | | | | | |
| Comparative | (A)-11C | | (D)-1 | (F)-1 | (S)-1 |
| Example | [100] | | [1.20] | [1.50] | [3000] |
| 12C | | | | | |
| Comparative | (A)-12C | | (D)-1 | (F)-1 | (S)-1 |
| Example | [100] | | [1.20] | [1.50] | [3000] |
| 13C | | | | | |
| Comparative | (A)-13C | | (D)-1 | (F)-1 | (S)-1 |
| Example | [100] | | [1.20] | [1.50] | [3000] |
| 14C | | | | | |
| Comparative | (A)-14C | | (D)-1 | (F)-1 | (S)-1 |
| Example | [100] | | [1.20] | [1.50] | [3000] |
| 15C | | | | | |
| Comparative | (A)-15C | | (D)-1 | (F)-1 | (S)-1 |
| Example | [100] | | [1.20] | [1.50] | [3000] |
| 16C | | | | | |
| Comparative | (A)-16C | (B)-1 | (D)-1 | (F)-1 | (S)-1 |
| Example | [100] | [15.0] | [0.10] | [1-50] | [3000] |
| 17C | | | | | |
| Comparative | (A)-17C | (B)-1 | (D)-1 | (F)-1 | (S)-1 |
| Example | [100] | [15.0] | [0.10] | [1.50] | [3000] |
| 18C | | | | | |
| Comparative | (A)-18C | | (D)-1 | (F)-1 | (S)-1 |
| Example | [100] | | [0.10] | [1.50] | [3000] |
| 19C | | | | | |
| Comparative | (A)-19C | (B)-1 | (D)-1 | (F)-1 | (S)-1 |
| Example | [100] | [30.6] | [1.20] | [1.50] | [3000] |
| 20C | | | | | |
| Comparative | (A)-19C | (B)-1 | (D)-2 | (F)-1 | (S)-1 |
| Example | [100] | [15.0] | [2.54] | [1.50] | [3000] |
| 21C | | | | | |

In Tables 33 and 34, the reference characters indicate the following. Further, the values in brackets [ ] indicate the amount (in terms of parts by weight) of the component added.

(A)-1C to (A)-19C: the aforementioned polymeric compounds (1C) to (19C)

(B)-1: compound (B)-1 shown below

(D)-1: tri-n-octylamine.

(D)-2: the aforementioned monomer (10C)

(F)-1: polymeric compound (F)-1 shown below [l=100 (molar ratio), Mw=22,000, Mw/Mn=1.58, a polymer polymerized by a radical polymerization using a radical polymerization initiator V-601]

(S)-1: a mixed solvent of PGMEA/PGME/cyclohexanone=45/30/25 (weight ratio)

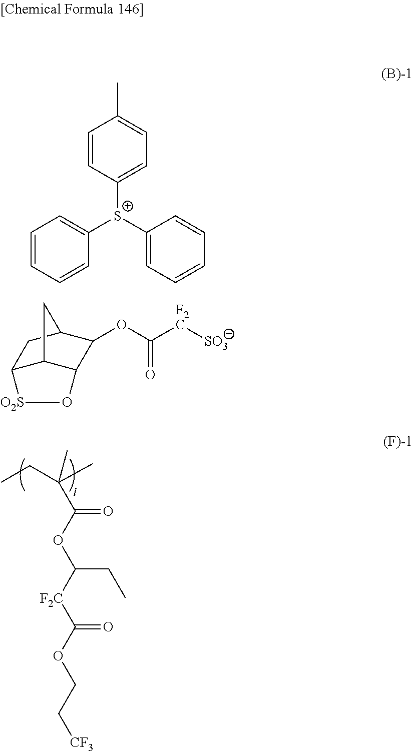

### Examples 15E to 28E and Comparative Examples 13E to 24E

### Preparation of Resist Composition

The components shown in Tables 35 and 36 were mixed together and dissolved to obtain resist compositions.

TABLE 35

| | Component | Component | Component | Component | Component | Component | |
|---|---|---|---|---|---|---|---|
| | (A) | (B) | (D) | (F) | (E) | (S) | |
| Example | (A)-1E | — | (D)-1 | (F)-1 | — | (S)-1 | (S)-2 |
| 15E | [100] | | [1.20] | [1.50] | | [25.0] | [3000] |
| Example | (A)-2E | — | (D)-1 | (F)-1 | — | (S)-1 | (S)-2 |
| 16E | [100] | | [1.20] | [1.50] | | [25.0] | [3000] |
| Example | (A)-3E | — | (D)-1 | (F)-1 | — | (S)-1 | (S)-2 |
| 17E | [100] | | [1.20] | [1.50] | | [25.0] | [3000] |
| Example | (A)-4E | — | (D)-1 | (F)-1 | — | (S)-1 | (S)-2 |
| 18E | [100] | | [1.20] | [1.50] | | [25.0] | [3000] |
| Example | (A)-5E | — | (D)-1 | (F)-1 | — | (S)-1 | (S)-2 |
| 19E | [100] | | [1.20] | [1.50] | | [25.0] | [3000] |
| Example | (A)-6E | — | (D)-1 | (F)-1 | — | (S)-1 | (S)-2 |
| 20E | [100] | | [1.20] | [1.50] | | [25.0] | [3000] |
| Example | (A)-7E | (B)-1 | (D)-1 | (F)-1 | — | (S)-1 | (S)-2 |
| 21E | [100] | [15.0] | [0.10] | [1.50] | | [25.0] | [3000] |
| Example | (A)-8E | (B)-1 | (D)-1 | (F)-1 | — | (S)-1 | (S)-2 |
| 22E | [100] | [15.0] | [0.10] | [1.50] | | [25.0] | [3000] |
| Example | (A)-9E | — | (D)-1 | (F)-1 | — | (S)-1 | (S)-2 |
| 23E | [100] | | [0.10] | [1.50] | | [25.0] | [3000] |
| Example | (A)-10E | (B)-2 | (D)-1 | (F)-1 | (E)-1 | (S)-1 | (S)-2 |
| 24E | [100] | [15.0] | [1.20] | [1.50] | [0.50] | [25.0] | [3000] |
| Example | (A)-11E | (B)-2 | (D)-1 | (F)-1 | (E)-1 | (S)-1 | (S)-2 |
| 25E | [100] | [15.0] | [1.20] | [1.50] | [0.50] | [25.0] | [3000] |
| Example | (A)-12E | (B)-2 | (D)-1 | (F)-1 | (E)-1 | (S)-1 | (S)-2 |
| 26E | [100] | [15.0] | [1.20] | [1.50] | [0.50] | [25.0] | [3000] |
| Example | (A)-13E | (B)-2 | (D)-1 | (F)-1 | (E)-1 | (S)-1 | (S)-2 |
| 27E | [100] | [15.0] | [1.20] | [1.50] | [0.50] | [25.0] | [3000] |
| Example | (A)-14E | (B)-2 | (D)-1 | (F)-1 | (E)-1 | (S)-1 | (S)-2 |
| 28E | [100] | [15.0] | [1.20] | [1.50] | [0.50] | [25.0] | [3000] |

TABLE 36

| | Component | Component | Component | Component | Component | Component | |
|---|---|---|---|---|---|---|---|
| | (A) | (B) | (D) | (F) | (E) | (S) | |
| Comparative | (A)-15E | — | (D)-1 | (F)-1 | — | (S)-1 | (S)-2 |
| Example | [100] | | [1.20] | [1.50] | | [25.0] | [3000] |
| 13E | | | | | | | |
| Comparative | (A)-16E | — | (D)-1 | (F)-1 | — | (S)-1 | (S)-2 |
| Example | [100] | | [1.20] | [1.50] | | [25.0] | [3000] |
| 14E | | | | | | | |
| Comparative | (A)-17E | — | (D)-1 | (F)-1 | — | (S)-1 | (S)-2 |
| Example | [100] | | [1.20] | [1.50] | | [25.0] | [3000] |
| 15E | | | | | | | |
| Comparative | (A)-18E | — | (D)-1 | (F)-1 | — | (S)-1 | (S)-2 |
| Example | [100] | | [1.20] | [1.50] | | [25.0] | [3000] |
| 16E | | | | | | | |
| Comparative | (A)-19E | — | (D)-1 | (F)-1 | — | (S)-1 | (S)-2 |
| Example | [100] | | [1.20] | [1.50] | | [25.0] | [3000] |
| 17E | | | | | | | |
| Comparative | (A)-20E | — | (D)-1 | (F)-1 | — | (S)-1 | (S)-2 |
| Example | [100] | | [1.20] | [1.50] | | [25.0] | [3000] |
| 18E | | | | | | | |
| Comparative | (A)-21E | (B)-1 | (D)-1 | (F)-1 | — | (S)-1 | (S)-2 |
| Example | [100] | [15.0] | [0.10] | [1.50] | | [25.0] | [3000] |
| 19E | | | | | | | |
| Comparative | (A)-22E | (B)-1 | (D)-1 | (F)-1 | — | (S)-1 | (S)-2 |
| Example | [100] | [15.0] | [0.10] | [1.50] | | [25.0] | [3000] |
| 20E | | | | | | | |
| Comparative | (A)-23E | — | (D)-1 | (F)-1 | — | (S)-1 | (S)-2 |
| Example | [100] | | [0.10] | [1.50] | | [25.0] | [3000] |
| 21E | | | | | | | |
| Comparative | (A)-24E | (B)-2 | (D)-1 | (F)-1 | (E)-1 | (S)-1 | (S)-2 |
| Example | [100] | [15.0] | [1.20] | [1.50] | [0.50] | [25.0] | [3000] |
| 22E | | | | | | | |
| Comparative | (A)-25E | (B)-2 | (D)-1 | (F)-1 | (E)-1 | (S)-1 | (S)-2 |
| Example | [100] | [15.0] | [1.20] | [1.50] | [0.50] | [25.0] | [3000] |
| 23E | | | | | | | |
| Comparative | (A)-26E | (B)-2 | (D)-1 | (F)-1 | (E)-1 | (S)-1 | (S)-2 |
| Example | [100] | [15.0] | [1.20] | [1.50] | [0.50] | [25.0] | [3000] |
| 24E | | | | | | | |

In Tables 35 and 36, the reference characters indicate the following. Further, the values in brackets [ ] indicate the amount (in terms of parts by weight) of the component added.

(A)-1E to (A)-26E: the aforementioned polymeric compounds (1E) to (26E)

(B)-1: compound (B)-1 shown below

(B)-2: compound (B)-2 shown below

(D)-1: tri-n-octylamine.

(F)-1: polymeric compound (F)-1 shown below [l=100 (molar ratio), Mw=22,000, Mw/Mn=1.58, a polymer polymerized by a radical polymerization using a radical polymerization initiator V-601]

(E)-1: salicylic acid

(S)-1: γ-butyrolactone

(S)-1: a mixed solvent of PGMEA/PGME/cyclohexanone=45/30/25 (weight ratio)

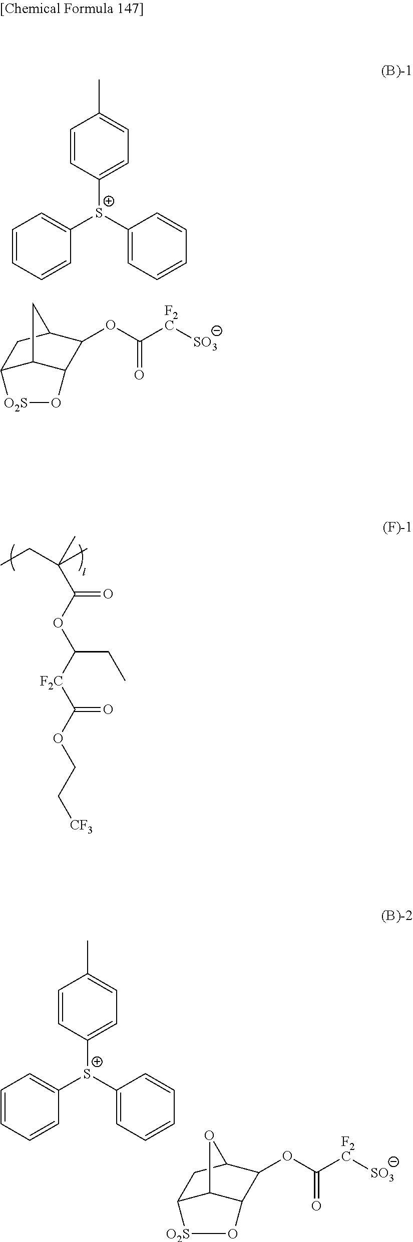

### Examples 3D to 7D and Comparative Examples 3D to 7D

### Preparation of Resist Composition

The components shown in Table 37 were mixed together and dissolved to obtain resist compositions.

TABLE 37

| | Com- | Com- | Com- | Com- | Com- | |
|---|---|---|---|---|---|---|
| | ponent | ponent | ponent | ponent | ponent | Com- |
| | (A) | (B) | (F) | (D) | (E) | ponent (S) |
| Example | (A)-1D | (B)-2 | (F)-1D | (D)-2 | (E)-1 | (S)-1 |
| 3D | [100] | [15.0] | [1.50] | [1.50] | [0.5] | [3000] |
| Example | (A)-2D | (B)-2 | (F)-1D | (D)-2 | (E)-1 | (S)-1 |
| 4D | [100] | [15.0] | [1.50] | [1.50] | [0.5] | [3000] |
| Example | (A)-3D | (B)-2 | (F)-1D | (D)-2 | (E)-1 | (S)-1 |
| 5D | [100] | [15.0] | [1.50] | [1.50] | [0.5] | [3000] |
| Example | (A)-4D | (B)-2 | (F)-1D | (D)-2 | (E)-1 | (S)-1 |
| 6D | [100] | [15.0] | [1.50] | [1.50] | [0.5] | [3000] |
| Example | (A)-1D | (B)-2 | (F)-2D | (D)-2 | (E)-1 | (S)-1 |
| 7D | [100] | [15.0] | [1.50] | [1.50] | [0.5] | [3000] |
| Comparative | (A)-1D | (B)-2 | (F)-3D | (D)-2 | (E)-1 | (S)-1 |
| Example | [100] | [15.0] | [1.50] | [1.50] | [0.5] | [3000] |
| 3D | | | | | | |
| Comparative | (A)-2D | (B)-2 | (F)-3D | (D)-2 | (E)-1 | (S)-1 |
| Example | [100] | [15.0] | [1.50] | [1.50] | [0.5] | [3000] |
| 4D | | | | | | |
| Comparative | (A)-3D | (B)-2 | (F)-3D | (D)-2 | (E)-1 | (S)-1 |
| Example | [100] | [15.0] | [1.50] | [1.50] | [0.5] | [3000] |
| 5D | | | | | | |
| Comparative | (A)-4D | (B)-2 | (F)-3D | (D)-2 | (E)-1 | (S)-1 |
| Example | [100] | [15.0] | [1.50] | [1.50] | [0.5] | [3000] |
| 6D | | | | | | |
| Comparative | (A)-1D | (B)-2 | (F)-4D | (D)-2 | (E)-1 | (S)-1 |
| Example | [100] | [15.0] | [1.50] | [1.50] | [0.5] | [3000] |
| 7D | | | | | | |

In Table 37, the reference characters indicate the following. Further, the values in brackets [ ] indicate the amount (in terms of parts by weight) of the component added.

(A)-1D to (A)-4D: the aforementioned polymeric compounds (A)-1D to (A)-4D

(B)-2: a compound represented by formula (B)-2 shown below

(F)-1D to (F)-4D: the aforementioned polymeric compounds (F)-1D to (F)-4D

(D)-2: a compound represented by formula (D)-2 shown below

(E)-1: salicylic acid

(S)-1: a mixed solvent of PGMEA/PGME/cyclohexanone=45/30/25 (weight ratio)

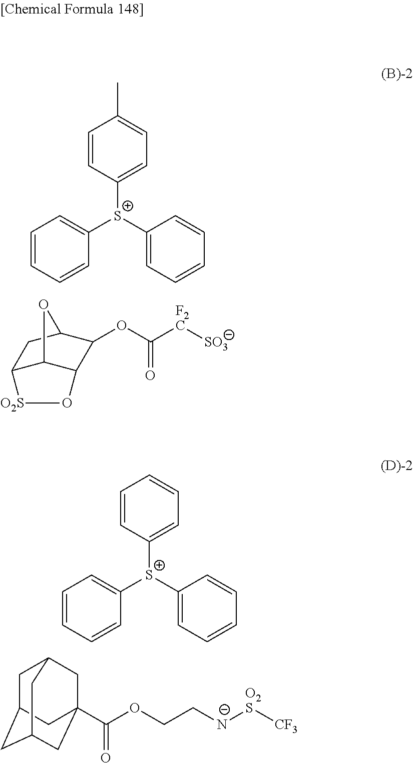

### [Formation of Resist Pattern 1]

An organic anti-reflection film composition (product name: ARC95, manufactured by Brewer Science Ltd.) was applied to a 12-inch silicon wafer using a spinner, and the composition was then baked at 205° C. for 90 seconds on a hotplate, thereby forming an organic anti-reflection film having a film thickness of 90 nm.

Then, each resist composition obtained in the examples was applied to the organic anti-reflection film using a spinner, and was then prebaked (PAB) on a hotplate at a temperature indicated in Tables 38 to 45 for 60 seconds and dried, thereby forming a resist film having a film thickness of 100 nm.

Subsequently, the resist film was selectively irradiated with an ArF excimer laser (193 nm) through a mask pattern (6% half tone), using an ArF immersion exposure apparatus NSR-S609B (manufactured by Nikon Corporation, NA (numerical aperture)=1.07, Dipole (in/out: 0.78/0.97), w /POLANO).

Thereafter, a post exposure bake (PEB) treatment was conducted at a temperature indicated in Tables 38 to 45 for 60 seconds, followed by development for 10 seconds at 23° C. in a 2.38% by weight aqueous solution of tetramethylammonium hydroxide (TMAH) (product name: NMD-3; manufactured by Tokyo Ohka Kogyo Co., Ltd.). Then, the resist film was washed for 15 seconds with pure water, followed by drying by shaking.

Further, a post bake was conducted at 100° C. for 45 seconds on the hot plate.

As a result, in each of Examples and Comparative examples except of Comparative Example 20, a line and space pattern (LS pattern) having a line width of 50 nm and a pitch of 100 nm was formed. In Comparative Example 20, a pattern could not be formed.

The optimum exposure dose Eon (mJ/cm²; sensitivity) with which the LS pattern was formed was determined. The results are shown in Tables 38 to 45.

### [Evaluation of Exposure Latitude (EL Margin)]

With respect to the above Eon, the exposure dose with which an LS pattern having a dimension of the target dimension (line width: 50 nm)±5% (i.e., 47.5 nm to 52.5 nm) was determined, and the EL margin (unit: %) was determined by the following formula. The results are shown in Tables 38 to 45.

EL margin (%)=(|E1−E2|/Eop)×100

E1: Exposure dose (mJ/cm²) with which an LS pattern having a line width of 47.5 nm was formed

E2: Exposure dose (mJ/cm²) with which an L/S pattern having a line width of 52.5 nm was formed

The larger the value of the “EL margin”, the smaller the change in the pattern size by the variation of the exposure dose.

### [Evaluation of Mask Error Factor (MEF)]

In the same manner as described above, with the above Eon, LS patterns were formed using a mask pattern targeting a space width of 50 nm and a pitch of 100 nm, and a mask pattern targeting a space width of 55 nm and a pitch of 100 nm, and the MEF value was calculated by the following formula. The results are shown in Tables 38 to 45.

MEF=|CD55−CD50|/|MD55−MD50|

In the formula, CD50 and CD55 represent the respective line widths (nm) of the actual LS patterns respectively formed using the mask pattern targeting a line width of 50 nm and the mask pattern targeting a line width of 55 nm. MD50 and MD55 represent the respective target line widths (nm), meaning MD50=50 nm, and MD55=55 nm.

A MEF value closer to 1 indicates that a resist pattern faithful to the mask pattern was formed.

### [Evaluation of Line Width Roughness (LWR)]

With respect to each of the LS patterns formed with the above optimum exposure dose Eon and having a line width of 50 nm and a pitch of 100 nm, the space width at 400 points in the lengthwise direction of the space were measured using a measuring scanning electron microscope (SEM) (product name: S-9380, manufactured by Hitachi High-Technologies Corporation; acceleration voltage: 300V). From the results, the value of 3 times the standard deviation s (i.e., 3s) was determined, and the average of the 3s values at 400 points was calculated as a yardstick of LWR. The results are shown in Tables 38 to 45.

The smaller this 3s value is, the lower the level of roughness of the line width, indicating that a LS pattern with a uniform width was obtained.

### [Evaluation of Pattern Shape]

The cross-sectional shape of the pattern formed with the above optimum exposure dose Eon was observed using a scanning electron microscope (product name: SU-8000, manufactured by Hitachi High-Technologies Corporation), and the cross-sectional shape was evaluated with the following criteria. The results are shown in Tables 38 to 45.

A: high rectangularity and excellent shape

B: moderate T-top shape

C: rounded top shape (tapered shape)

### [Formation of Resist Pattern 2: Evaluation of Defect]

A 1:1 line and space pattern (L/S pattern) having a line width of 55 nm and a pitch of 110 nm was formed in the same manner as in the aforementioned [Formation of resist pattern 1], except that an organic anti-reflection film composition (product name: ARC29A, manufactured by Brewer Science Ltd.) was used, and mask was changed in accordance with the type of targets, and development time was changed to 40 seconds.

The obtained 1:1 LS pattern was observed using a surface defect observation apparatus manufactured by KLA-TENCOR CORPORATION (product name: KLA2371). The number of development defects at unexposed portion per one silicon wafer was determined. The results are shown in Table 45.

TABLE 38

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Example | 90 | 90 | 27.5 | 7.91 | 2.30 | 4.94 | A |
| 15A | | | | | | | |
| Example | 90 | 90 | 30.3 | 8.13 | 2.33 | 4.78 | A |
| 16A | | | | | | | |
| Example | 90 | 90 | 31.1 | 7.79 | 2.23 | 5.01 | A |
| 17A | | | | | | | |
| Example | 90 | 90 | 32.2 | 8.22 | 2.17 | 4.69 | A |
| 18A | | | | | | | |
| Example | 90 | 80 | 26.8 | 7.72 | 2.50 | 4.68 | A |
| 19A | | | | | | | |
| Example | 90 | 90 | 27.9 | 7.75 | 2.35 | 4.89 | A |
| 20A | | | | | | | |
| Example | 90 | 90 | 27.7 | 8.05 | 2.25 | 4.81 | A |
| 21A | | | | | | | |
| Example | 90 | 80 | 30.5 | 7.79 | 2.47 | 4.53 | A |
| 22A | | | | | | | |
| Example | 90 | 80 | 25.9 | 7.59 | 2.52 | 4.46 | A |
| 23A | | | | | | | |
| Example | 90 | 90 | 29.9 | 8.11 | 2.28 | 4.69 | A |
| 24A | | | | | | | |
| Example | 90 | 90 | 28.7 | 8.03 | 2.26 | 4.69 | A |
| 25A | | | | | | | |
| Example | 90 | 90 | 31.4 | 8.22 | 2.19 | 4.90 | A |
| 26A | | | | | | | |
| Example | 90 | 90 | 29.9 | 7.79 | 2.33 | 4.82 | A |
| 27A | | | | | | | |
| Example | 90 | 85 | 30.2 | 7.53 | 2.51 | 4.77 | A |
| 28A | | | | | | | |

TABLE 39

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Comparative | 90 | 90 | 29.2 | 7.41 | 2.50 | 5.77 | B |
| Example | | | | | | | |
| 19A | | | | | | | |
| Comparative | 90 | 90 | 32.1 | 7.62 | 2.53 | 5.24 | B |
| Example | | | | | | | |
| 20A | | | | | | | |
| Comparative | 90 | 90 | 33.0 | 7.30 | 2.42 | 5.59 | B |
| Example | | | | | | | |
| 21A | | | | | | | |
| Comparative | 90 | 90 | 34.1 | 7.70 | 2.36 | 5.23 | B |
| Example | | | | | | | |
| 22A | | | | | | | |
| Comparative | 90 | 80 | 28.4 | 7.23 | 2.72 | 5.23 | B |
| Example | | | | | | | |
| 23A | | | | | | | |
| Comparative | 90 | 90 | 29.6 | 7.26 | 2.55 | 5.46 | B |
| Example | | | | | | | |
| 24A | | | | | | | |
| Comparative | 90 | 90 | 29.4 | 7.54 | 2.44 | 5.37 | B |
| Example | | | | | | | |
| 25A | | | | | | | |
| Comparative | 90 | 80 | 32.3 | 7.30 | 2.68 | 5.09 | B |
| Example | | | | | | | |
| 26A | | | | | | | |
| Comparative | 90 | 80 | 27.5 | 7.11 | 2.74 | 5.15 | B |
| Example | | | | | | | |
| 27A | | | | | | | |
| Comparative | 90 | 90 | 31.7 | 7.60 | 2.48 | 5.24 | B |
| Example | | | | | | | |
| 28A | | | | | | | |
| Comparative | 90 | 90 | 30.4 | 7.52 | 2.46 | 5.23 | B |
| Example | | | | | | | |
| 29A | | | | | | | |
| Comparative | 90 | 90 | 33.3 | 7.70 | 2.38 | 5.47 | B |
| Example | | | | | | | |
| 30A | | | | | | | |
| Comparative | 90 | 90 | 31.7 | 7.30 | 2.53 | 5.38 | B |
| Example | | | | | | | |
| 31A | | | | | | | |
| Comparative | 90 | 85 | 32.0 | 7.06 | 2.73 | 5.23 | B |
| Example | | | | | | | |
| 32A | | | | | | | |
| Comparative | 90 | 90 | 22.5 | 5.92 | 2.98 | 5.48 | C |
| Example | | | | | | | |
| 33A | | | | | | | |

TABLE 40

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Example | 110 | 105 | 34.8 | 7.91 | 2.30 | 4.94 | A |
| 22B | | | | | | | |
| Example | 105 | 100 | 29.7 | 8.02 | 2.19 | 4.68 | A |
| 23B | | | | | | | |
| Example | 90 | 80 | 24.8 | 7.99 | 2.29 | 4.55 | A |
| 24B | | | | | | | |
| Example | 100 | 90 | 28.1 | 8.03 | 2.38 | 4.81 | A |
| 25B | | | | | | | |
| Example | 90 | 80 | 22.9 | 7.24 | 2.52 | 4.34 | A |
| 26B | | | | | | | |
| Example | 90 | 80 | 23.5 | 7.79 | 2.21 | 5.01 | A |
| 27B | | | | | | | |
| Example | 90 | 80 | 26.3 | 7.58 | 2.31 | 4.73 | A |
| 28B | | | | | | | |
| Example | 100 | 100 | 23.5 | 8.00 | 2.40 | 4.68 | A |
| 29B | | | | | | | |
| Example | 100 | 100 | 24.4 | 7.37 | 2.54 | 4.55 | A |
| 30B | | | | | | | |
| Example | 90 | 80 | 27.7 | 7.48 | 2.23 | 4.81 | A |
| 31B | | | | | | | |
| Example | 110 | 105 | 34.7 | 7.79 | 2.33 | 4.34 | A |
| 32B | | | | | | | |
| Example | 110 | 105 | 35.2 | 7.91 | 2.28 | 4.46 | A |
| 33B | | | | | | | |
| Example | 105 | 100 | 35.1 | 8.11 | 2.28 | 4.73 | A |
| 34B | | | | | | | |
| Example | 90 | 85 | 26.8 | 8.03 | 2.24 | 4.69 | A |
| 35B | | | | | | | |
| Example | 90 | 80 | 22.6 | 7.58 | 2.35 | 4.56 | A |
| 36B | | | | | | | |
| Example | 90 | 80 | 27.3 | 7.79 | 2.30 | 4.82 | A |
| 37B | | | | | | | |
| Example | 90 | 80 | 28.2 | 7.92 | 2.28 | 4.77 | A |
| 38B | | | | | | | |
| Example | 90 | 80 | 29.1 | 8.18 | 2.33 | 4.95 | A |
| 39B | | | | | | | |
| Example | 90 | 85 | 29.7 | 8.02 | 2.21 | 4.68 | A |
| 40B | | | | | | | |
| Example | 90 | 90 | 24.8 | 7.75 | 2.43 | 4.89 | A |
| 41B | | | | | | | |
| Example | 90 | 80 | 28.1 | 8.03 | 2.48 | 4.81 | A |
| 42B | | | | | | | |

TABLE 41

| | | | | 5% | | | |
|---|---|---|---|---|---|---|---|
| | PAB | PEB | Eop | EL | | LWR | |
| | (° C.) | (° C.) | (mJ/cm²) | (%) | MEF | (nm) | Shape |
| Comparative | 110 | 110 | 36.9 | 7.41 | 2.50 | 5.77 | B |
| Example 23B | | | | | | | |
| Comparative | 105 | 100 | 31.5 | 7.51 | 2.38 | 5.22 | B |
| Example 24B | | | | | | | |
| Comparative | 90 | 80 | 26.3 | 7.49 | 2.49 | 5.08 | B |
| Example 25B | | | | | | | |
| Comparative | 100 | 90 | 29.8 | 7.52 | 2.59 | 5.37 | B |
| Example 26B | | | | | | | |
| Comparative | 90 | 80 | 24.3 | 6.78 | 2.74 | 5.24 | B |
| Example 27B | | | | | | | |
| Comparative | 90 | 80 | 24.9 | 7.30 | 2.40 | 5.59 | B |
| Example 28B | | | | | | | |
| Comparative | 90 | 80 | 27.9 | 7.10 | 2.51 | 5.28 | B |
| Example 29B | | | | | | | |
| Comparative | 100 | 100 | 24.9 | 7.50 | 2.61 | 5.23 | B |
| Example 30B | | | | | | | |
| Comparative | 100 | 100 | 25.9 | 6.91 | 2.76 | 5.08 | B |
| Example 31B | | | | | | | |
| Comparative | 90 | 80 | 29.4 | 7.01 | 2.42 | 5.37 | B |
| Example 32B | | | | | | | |
| Comparative | 110 | 105 | 36.8 | 7.30 | 2.53 | 5.09 | B |
| Example 33B | | | | | | | |
| Comparative | 110 | 105 | 37.3 | 7.41 | 2.48 | 5.15 | B |
| Example 34B | | | | | | | |
| Comparative | 105 | 100 | 37.2 | 7.60 | 2.48 | 5.28 | B |
| Example 35B | | | | | | | |
| Comparative | 90 | 85 | 28.4 | 7.52 | 2.44 | 5.23 | B |
| Example 36B | | | | | | | |
| Comparative | 90 | 80 | 24.0 | 7.10 | 2.55 | 5.09 | B |
| Example 37B | | | | | | | |
| Comparative | 90 | 80 | 28.9 | 7.30 | 2.50 | 5.38 | B |
| Example 38B | | | | | | | |
| Comparative | 90 | 80 | 29.9 | 7.42 | 2.48 | 5.23 | B |
| Example 398 | | | | | | | |
| Comparative | 90 | 80 | 30.8 | 6.94 | 2.72 | 5.23 | B |
| Example 40B | | | | | | | |
| Comparative | 90 | 85 | 31.5 | 7.51 | 2.40 | 5.22 | B |
| Example 41B | | | | | | | |
| Comparative | 90 | 90 | 26.3 | 7.26 | 2.64 | 5.46 | B |
| Example 42B | | | | | | | |
| Comparative | 90 | 80 | 29.8 | 7.52 | 2.70 | 5.37 | B |
| Example 43B | | | | | | | |
| Comparative | 115 | 115 | 31.4 | 6.21 | 2.87 | 6.01 | C |
| Example 44B | | | | | | | |

TABLE 42

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Example | 120 | 110 | 35.5 | 8.31 | 2.15 | 4.77 | A |
| 10C | | | | | | | |
| Example | 120 | 110 | 32.6 | 8.23 | 2.25 | 4.68 | A |
| 11C | | | | | | | |
| Example | 120 | 110 | 31.3 | 8.20 | 2.20 | 4.65 | A |
| 12C | | | | | | | |
| Example | 120 | 110 | 30.8 | 8.18 | 2.31 | 4.81 | A |
| 13C | | | | | | | |
| Example | 120 | 110 | 38.9 | 8.44 | 2.08 | 4.58 | A |
| 14C | | | | | | | |
| Example | 90 | 80 | 22.3 | 7.29 | 2.68 | 5.17 | A |
| 15C | | | | | | | |
| Example | 90 | 80 | 34.1 | 7.56 | 2.55 | 5.08 | A |
| 16C | | | | | | | |
| Example | 90 | 80 | 32.3 | 7.44 | 2.52 | 5.11 | A |
| 17C | | | | | | | |
| Example | 120 | 110 | 33.7 | 8.40 | 2.09 | 4.66 | A |
| 18C | | | | | | | |
| Comparative | 120 | 110 | 37.6 | 7.79 | 2.34 | 5.96 | B |
| Example | | | | | | | |
| 11C | | | | | | | |
| Comparative | 120 | 110 | 34.6 | 7.71 | 2.45 | 5.85 | B |
| Example | | | | | | | |
| 12C | | | | | | | |
| Comparative | 120 | 110 | 33.2 | 7.68 | 2.39 | 5.81 | B |
| Example | | | | | | | |
| 13C | | | | | | | |
| Comparative | 120 | 110 | 32.6 | 7.66 | 2.51 | 6.01 | B |
| Example | | | | | | | |
| 14C | | | | | | | |
| Comparative | 120 | 110 | 41.2 | 7.91 | 2.26 | 5.73 | B |
| Example | | | | | | | |
| 15C | | | | | | | |
| Comparative | 90 | 80 | 23.6 | 6.83 | 2.91 | 6.46 | B |
| Example | | | | | | | |
| 16C | | | | | | | |
| Comparative | 90 | 80 | 36.1 | 7.08 | 2.77 | 6.35 | B |
| Example | | | | | | | |
| 17C | | | | | | | |
| Comparative | 90 | 80 | 34.2 | 6.97 | 2.74 | 6.39 | B |
| Example | | | | | | | |
| 18C | | | | | | | |
| Comparative | 120 | 110 | 35.7 | 7.87 | 2.27 | 5.83 | B |
| Example | | | | | | | |
| 19C | | | | | | | |
| Comparative | 120 | 110 | pattern could not be formed | | | | |
| Example | | | | | | | |
| 20C | | | | | | | |
| Comparative | 90 | 80 | 32.2 | 6.72 | 2.76 | 6.12 | B |
| Example | | | | | | | |
| 21C | | | | | | | |

TABLE 43

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Example | 120 | 110 | 35.5 | 8.31 | 2.15 | 4.77 | A |
| 15E | | | | | | | |
| Example | 120 | 110 | 32.6 | 8.23 | 2.25 | 4.68 | A |
| 16E | | | | | | | |
| Example | 120 | 110 | 31.3 | 8.20 | 2.20 | 4.65 | A |
| 17E | | | | | | | |
| Example | 120 | 110 | 30.8 | 8.18 | 2.31 | 4.81 | A |
| 18E | | | | | | | |
| Example | 120 | 110 | 38.9 | 8.44 | 2.08 | 4.58 | A |
| 19E | | | | | | | |
| Example | 90 | 80 | 22.3 | 7.29 | 2.68 | 5.17 | A |
| 20E | | | | | | | |
| Example | 90 | 80 | 34.1 | 7.56 | 2.55 | 5.08 | A |
| 21E | | | | | | | |
| Example | 90 | 80 | 32.3 | 7.44 | 2.52 | 5.11 | A |
| 22E | | | | | | | |
| Example | 120 | 110 | 33.7 | 8.40 | 2.09 | 4.66 | A |
| 23E | | | | | | | |
| Example | 105 | 105 | 29.8 | 8.53 | 2.32 | 4.71 | A |
| 24E | | | | | | | |
| Example | 100 | 95 | 30.2 | 7.80 | 2.79 | 5.08 | A |
| 25E | | | | | | | |
| Example | 105 | 105 | 23.8 | 8.14 | 2.53 | 4.61 | A |
| 26E | | | | | | | |
| Example | 105 | 105 | 25.7 | 8.22 | 2.44 | 4.71 | A |
| 27E | | | | | | | |
| Example | 105 | 105 | 31.2 | 8.71 | 2.33 | 5.12 | A |
| 28E | | | | | | | |

TABLE 44

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Comparative | 120 | 110 | 42.1 | 7.44 | 2.39 | 5.80 | B |
| Example | | | | | | | |
| 13E | | | | | | | |
| Comparative | 120 | 110 | 38.7 | 7.37 | 2.50 | 5.69 | B |
| Example | | | | | | | |
| 14E | | | | | | | |
| Comparative | 120 | 110 | 37.1 | 7.34 | 2.45 | 5.65 | B |
| Example | | | | | | | |
| 15E | | | | | | | |
| Comparative | 120 | 110 | 36.5 | 7.33 | 2.57 | 5.84 | B |
| Example | | | | | | | |
| 16E | | | | | | | |
| Comparative | 120 | 110 | 46.1 | 7.56 | 2.32 | 5.56 | B |
| Example | | | | | | | |
| 17E | | | | | | | |
| Comparative | 90 | 80 | 26.4 | 6.53 | 2.98 | 6.28 | B |
| Example | | | | | | | |
| 18E | | | | | | | |
| Comparative | 90 | 80 | 40.4 | 6.77 | 2.84 | 6.17 | B |
| Example | | | | | | | |
| 19E | | | | | | | |
| Comparative | 90 | 80 | 38.3 | 6.66 | 2.80 | 6.21 | B |
| Example | | | | | | | |
| 20E | | | | | | | |
| Comparative | 120 | 110 | 40.0 | 7.52 | 2.33 | 5.66 | B |
| Example | | | | | | | |
| 21E | | | | | | | |
| Comparative | 105 | 105 | 35.3 | 7.64 | 2.58 | 5.72 | B |
| Example | | | | | | | |
| 22E | | | | | | | |
| Comparative | 100 | 95 | 35.8 | 6.99 | 3.11 | 6.17 | B |
| Example | | | | | | | |
| 23E | | | | | | | |
| Comparative | 105 | 105 | 28.2 | 7.29 | 2.82 | 5.60 | B |
| Example | | | | | | | |
| 24E | | | | | | | |

TABLE 45

| | | | | | | | | number |
|---|---|---|---|---|---|---|---|---|
| | PAB | PEB | Eop | 5% EL | | | | of |
| | (° C.) | (° C.) | (mJ/cm²) | (%) | MEF | LWR (nm) | Shape | defect |
| Example 3D | 105 | 100 | 32.7 | 8.22 | 2.09 | 4.49 | A | 11 |
| Example 4D | 90 | 80 | 31.8 | 8.18 | 2.16 | 4.37 | A | 16 |
| Example 5D | 105 | 105 | 28.7 | 7.73 | 2.31 | 4.73 | A | 9 |
| Example 6D | 90 | 80 | 35.3 | 8.02 | 2.21 | 4.91 | A | 17 |
| Example 7D | 90 | 80 | 30.9 | 8.04 | 2.21 | 4.29 | A | 20 |
| Comparative | 105 | 100 | 34.9 | 8.04 | 2.13 | 5.57 | B | 128 |
| Example 3D | | | | | | | | |
| Comparative | 90 | 80 | 33.9 | 8.00 | 2.21 | 5.42 | B | 276 |
| Example 4D | | | | | | | | |
| Comparative | 105 | 105 | 30.6 | 7.56 | 2.36 | 5.87 | B | 115 |
| Example 5D | | | | | | | | |
| Comparative | 90 | 80 | 37.7 | 7.84 | 2.26 | 6.09 | B | 320 |
| Example 6D | | | | | | | | |
| Comparative | 90 | 80 | 33.0 | 7.86 | 2.26 | 5.32 | B | 233 |
| Example 7D | | | | | | | | |

From the results shown in Tables 38 and 39, it was confirmed that the resist composition of Examples 15A to 28A according to the present invention were superior to the resist composition of Comparative Example 19A to 33A in that they exhibited excellent lithography properties (EL margin, MEF and LWR) and excellent pattern shape.

From the results shown in Tables 40 and 41, it was confirmed that the resist composition of Examples 22B to 42B according to the present invention were superior to the resist composition of Comparative Example 44B to 44B in that they exhibited excellent lithography properties (EL margin, MEF and LWR) and excellent pattern shape.

From the results shown in Table 42, it was confirmed that the resist composition of Examples 10C to 18C according to the present invention were superior to the resist composition of Comparative Example 11C to 21C in that they exhibited excellent lithography properties (EL margin, MEF and LWR) and excellent pattern shape.

From the results shown in Tables 43 and 44, it was confirmed that the resist composition of Examples 15E to 28E according to the present invention were superior to the resist composition of Comparative Example 19E to 33E in that they exhibited excellent lithography properties (EL margin, MEF and LWR) and excellent pattern shape.

From the results shown in Table 45, it was confirmed that the resist composition of Examples 3D to 7D according to the present invention were superior to the resist composition of Comparative Example 3D to 7D in that they exhibited excellent lithography properties (EL margin, MEF and LWR) and excellent pattern shape, and were able to reduce defects.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A polymer comprising: an anion part which generates acid upon exposure on at least one terminal of the main chain, and at least one structural unit selected from the group consisting of:
a structural unit (a0) containing a —SO₂-containing cyclic group,
a structural unit (a3) containing at least one group selected from the group consisting of —OH, —COOH, —CN, —SO₂NH₂ and —CONH₂, and
a structural unit (a5) which generates acid upon exposure.

2. The polymer according to claim 1, which comprises a group represented by general formula (I-1) shown below on at least one terminal of the main chain: 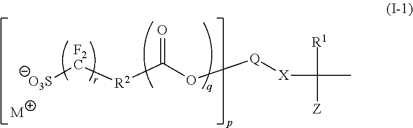
wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having one of —O—C(═O)—, —NH—C(═O)— and —NH—C(═NH)— on at least the terminal bonded to Q; p represents an integer of 0 to 3; Q represents a hydrocarbon group having a valence of (p+1), provided that, when p represents 1, Q may represent a single bond; R² represents a single bond, an alkylene group which may have a substituent or an aromatic group which may have a substituent; q represents 0 or 1; r represents an integer of 0 to 8; and M⁺ represents an organic cation.

3. The polymer according to claim 2, which is a radical polymer obtained by radial polymerization using a radical polymerization initiator comprising a compound represented by general formula (I) shown below: 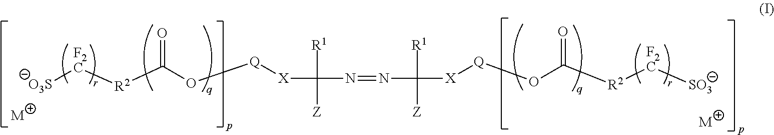
wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having one of —O—C(═O)—, —NH—C(═O)— and —NH—C(═NH)— on at least the terminal bonded to Q; p represents an integer of 0 to 3; Q represents a hydrocarbon group having a valency of (p+1), provided that, when p represents 1, Q may represent a single bond; R² represents a single bond, an alkylene group which may have a substituent or an aromatic group which may have a substituent; q represents 0 or 1; r represents an integer of 0 to 8; and M⁺ represents an organic cation; provided that the plurality of R¹, Z, X, p, Q, R², q, r and M⁺ may be the same or different from each other.

4. The polymer according to claim 1, wherein the structural unit (a0) is a structural unit derived from an acrylate ester which may have the hydrogen atom bonded to the carbon atom on the α-position substituted with a substituent.

5. The polymer according to claim 4, wherein the structural unit (a0) is represented by general formula (a0-0-11) or general formula (a0-0-12) shown below: 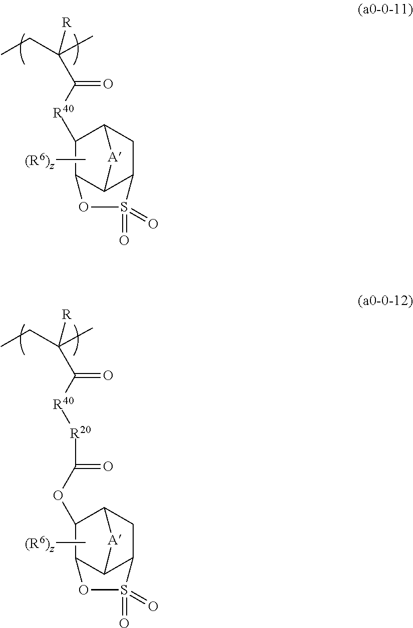
In the formulas, R represents a hydrogen atom, an alkyl group of 1 to 5 carbon atoms, or a halogenated alkyl group of 1 to 5 carbon atoms; R⁴⁰ represents —O— or —NH—; R²⁰ a divalent linking group; A′ represents an oxygen atom, a sulfur atom or an alkylene group of 1 to 5 carbon atoms which may contain an oxygen atom or a sulfur atom; z represents an integer of 0 to 2; and R⁶ represents an alkyl group, an alkoxy group, a halogenated alkyl group, a hydroxy group, —COOR″, —OC(═O)R″, a hydroxyalkyl group or a cyano group, wherein R″ represents a hydrogen atom or an alkyl group.

6. The polymer according to claim 1, wherein the structural unit (a3) is represented by general formula (a3-1) shown below: 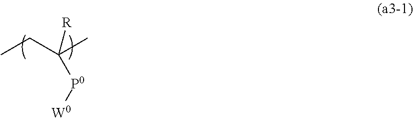
In the formula, R represents a hydrogen atom, an alkyl group of 1 to 5 carbon atoms or a halogenated alkyl group of 1 to 5 carbon atoms; P⁰ represents —C(═O)—O—, —C(═O)—NR⁰— (wherein R⁰ represents a hydrogen atom or an alkyl group of 1 to 5 carbon atoms) or a single bond; and W⁰ is a hydrocarbon group containing at leas one group selected from the group consisting of —OH, —COOH, —CN, —SO₂NH₂ and —CONH₂ and may contain an oxygen atom or a sulfur atom at an arbitrary position.

7. The polymer according to claim 1, wherein the structural unit (a5) has a group represented by general formula (a5-1) or (a5-2) shown below: 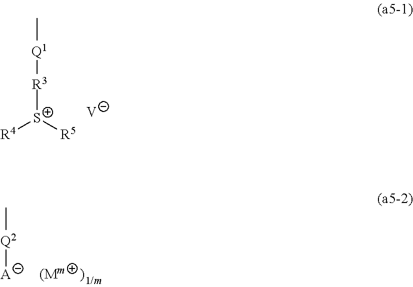
wherein each of Q¹ and Q² independently represents a single bond or a divalent linking group; each of R³, R⁴ and R⁵ independently represents an organic group, provided that R⁴ and R⁵ may be mutually bonded to form a ring with the sulfur atom; V⁻ represents a counteranion; A⁻ represents an organic group containing an anion; M^{m+} represents a countercation; and m represents an integer of 1 to 3.

8. The polymer according to claim 1, which has a weight average molecular weight of 20,000 or less.

9. The polymer according to claim 1, further comprising a structural unit (a1) containing an acid decomposable group that exhibits increased polarity by the action of acid.

10. A resist composition comprising the polymer according to claim 1.

11. A resist composition comprising:
a base component (A) which exhibits changed solubility in a developing solution under action of acid, and generates acid upon exposure; and
an acid generator component (B) which generates acid upon exposure, provided that the base component (A) is excluded,
wherein the base component (A) comprises the polymer according to claim 9.

12. A method of forming a resist pattern, comprising: forming a resist film using a resist composition of claim 10; conducting exposure of the resist film; and developing the resist film to form a resist pattern.

13. A polymer comprising:
an anion part which generates acid upon exposure on at least one terminal of the main chain, and
a structural unit (f1) having a fluorine atom.

14. The polymer according to claim 13, which comprises a group represented by general formula (I-1) shown below on at least one terminal of the main chain: 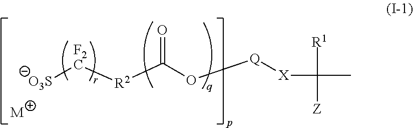
wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having one of —O—C(═O)—, —NH—C(═O)— and —NH—C(═NH)— on at least the terminal bonded to Q; p represents an integer of 0 to 3; Q represents a hydrocarbon group having a valency of (p+1), provided that, when p represents 1, Q may represent a single bond; R² represents a single bond, an alkylene group which may have a substituent or an aromatic group which may have a substituent; q represents 0 or 1; r represents an integer of 0 to 8; and M⁺ represents an organic cation.

15. The polymer according to claim 14, which is a radical polymer obtained by radial polymerization using a radical polymerization initiator comprising a compound represented by general formula (I) shown below: 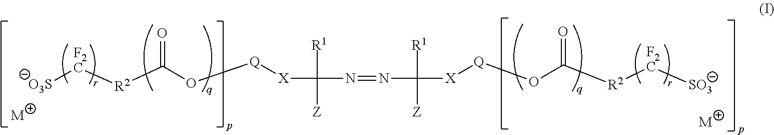
wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having one of —O—C(═O)—, —NH—C(═O)— and —NH—C(═NH)— on at least the terminal bonded to Q; p represents an integer of 0 to 3; Q represents a hydrocarbon group having a valency of (p+1), provided that, when p represents 1, Q may represent a single bond; R² represents a single bond, an alkylene group which may have a substituent or an aromatic group which may have a substituent; q represents 0 or 1; r represents an integer of 0 to 8; and M⁺ represents an organic cation, provided that the plurality of R¹, Z, X, p, Q, R², q, r and M⁺ may be the same or different from each other.

16. The polymer according to claim 13, wherein the structural unit (f1) is represented by general formula (f1-1) shown below: 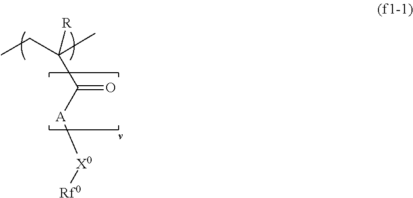
wherein R represents a hydrogen atom, an alkyl group of 1 to 5 carbon atoms or a halogenated alkyl group of 1 to 5 carbon atoms; A represents —O— or —NH—; X⁰ represents a single bond or a divalent linking group; Rf⁰ represents an organic group, provided that at least one of X⁰ and Rf⁰ has a fluorine atom; and v represents 0 or 1.

17. The polymer according to claim 13, further comprising a structural unit (f2) containing an acid decomposable group that exhibits increased polarity by the action of acid.

18. A resist composition comprising:
a base component (A) which exhibits changed solubility in a developing solution under action of acid;
a fluorine-containing polymeric compound component (F) which generates acid upon exposure; and
an acid generator component (B) which generates acid upon exposure, provided that the fluorine-containing polymeric compound component (F) is excluded,
wherein the fluorine-containing polymeric compound component (F) comprises the polymer acccording to claim 13.

19. A resist composition according to claim 18, wherein the base component (A) comprises a base component (A1′) which exhibits changed solubility in a developing solution under action of acid and generates acid upon exposure, and
the base component (A1′) comprises an anion part which generates acid upon exposure on at least one terminal of the main chain.

20. A method of forming a resist pattern, comprising: forming a resist film using a resist composition of claim 18; conducting exposure of said resist film; and developing the resist film to form a resist pattern.
